(19) United States
(12) Patent Application Publication
(10) Pub. No.: US 2025/0188105 A1
(43) Pub. Date: Jun. 12, 2025

(54) ORGANOMETALLIC COMPOUND, ORGANIC LIGHT EMITTING DIODE AND ORGANIC LIGHT EMITTING DEVICE INCLUDING THE SAME

(71) Applicants: LG Display Co., Ltd., Seoul (KR); DuPont Specialty Materials Korea Ltd., Cheonan-si (KR)

(72) Inventors: Han-Sol PARK, Paju-si (KR); Tae-Ryang HONG, Paju-si (KR); Ku-Sun CHOUNG, Paju-si (KR); Soon-Jae HWANG, Paju-si (KR); Kyoung-Jin PARK, Hwaseong-si (KR); Hyun KIM, Hwaseong-si (KR); Soo-Yong LEE, Hwaseong-si (KR); Samuel KIM, Hwaseong-si (KR)

(73) Assignees: LG Display Co., Ltd., Seoul (KR); DuPont Specialty Materials Korea Ltd., Cheonan-si (KR)

(21) Appl. No.: 18/781,310

(22) Filed: Jul. 23, 2024

(30) Foreign Application Priority Data
Dec. 11, 2023 (KR) 10-2023-0178616

(51) Int. Cl. C07F 15/00; C07B 59/00; C09K 11/06; H10K 85/30; H10K 85/60

(52) U.S. Cl. CPC C07F 15/0033; C07B 59/004; C09K 11/06; H10K 85/342; H10K 85/615; H10K 85/654; H10K 85/6572; H10K 85/6574; C07B 2200/05

(57) ABSTRACT

An organometallic compound, as well as an OLED and an organic light emitting device comprising the OLED are described. Specifically, the organometallic compound is an emitting compound of following structure, where the variables are as defined herein. An organic light emitting device (e.g., a display device or a lighting device) is also described, which comprises a display comprising an array of pixels on a substrate, wherein each pixel comprises one or more individually addressable organic light emitting diodes described herein.

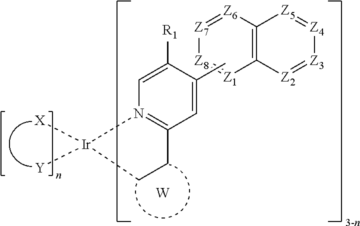

### CROSS-REFERENCE TO RELATED APPLICATIONS

The present application claims priority, under 35 U.S.C. § 119, to Korean Patent Application No. 10-2023-0178616 filed in the Republic of Korea on Dec. 11, 2023, which is hereby incorporated by reference in its entirety into the present application.

### BACKGROUND

### Technical Field

The present disclosure relates to an organometallic compound, and more particularly, to an organometallic compound capable of improving an emitting efficiency and an emission lifespan in an organic light emitting diode (OLED) including the organometallic compound, as well as an organic light emitting device including the organic light emitting diode.

### Discussion of the Related Art

As demand increases for flat panel display devices that occupy a small space, organic electroluminescent devices have been a focus of research and development. Among the flat panel display devices, the use of an organic light emitting display device that includes an organic light emitting diode (OLED), such as an organic electroluminescent device, is rapidly developing.

The OLED includes a cathode as an electron injection electrode, an anode as a hole injection electrode and an organic light emitting layer, which is disposed between the cathode and the anode and includes a host and a dopant. When electrons from the cathode and holes from the anode enter into the organic light emitting layer, the electrons and holes are combined to generate an exciton, and the exciton is transformed from an excited state to a ground state. As a result, the light is emitted from the OLED. The OLED can be formed on a flexible transparent substrate, e.g., a plastic substrate, and can be driven by low voltage. In addition, the OLED has low power consumption and high color purity.

The dopant can be classified into fluorescent materials and phosphorescent materials.

Among these, fluorescent materials from the related art have shown low luminous efficiency, because only the singlet excitons are involved in the luminescence process thereof. Phosphorescent materials, in which triplet excitons as well as the singlet excitons are involved in the luminescence process have relatively high luminous efficiency compared to the fluorescent material. For instance, many metal complexes from the prior art, which are used as phosphorescent materials may have a luminous lifespan that is too short for many commercial devices. Therefore, there exists a need to develop a compound with improved emitting efficiency and emission lifespan.

### SUMMARY OF THE DISCLOSURE

Embodiments of the present disclosure are directed to an organometallic compound, an OLED and an organic light emitting device that address one or more of the problems and disadvantages of the related art.

An object of the present disclosure is to provide an organometallic compound having improved emitting efficiency and emission lifespan, e.g., when used in an OLED.

An object of the present disclosure is to provide an OLED and an organic light emitting device including the organometallic compound.

Additional features and aspects will be set forth in the description that follows, and in part will be apparent from the description, or can be learned by practice of the present disclosure concepts provided herein. Other features and aspects of the present disclosure concepts can be realized and attained by the structure particularly pointed out in the written description, or derivable therefrom, and the claims hereof as well as the appended drawings.

As described herein, an aspect of the present disclosure is an organometallic compound represented by Formula 1:

### [Formula 1]

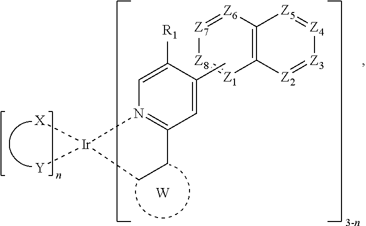

wherein in the Formula 1, n is an integer of 0 to 2, each of Z₁, Z₂, Z₃, Z₄, Z₅, Z₆, Z₇ and Z₈ is independently C, CR₂ or N, one of Z₁, Z₂, Z₃, Z₄, Z₅, Z₆, Z₇ and Z₈ is C, R₁ is selected from the group consisting of hydrogen, deuterium and a substituted or unsubstituted C1 to C20 alkyl group, R₂ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group, each of X and Y is independently selected from the group consisting of C, N and O, and a W ring is represented by one of Formulas 1a-1, 1a-2 and 1a-3,

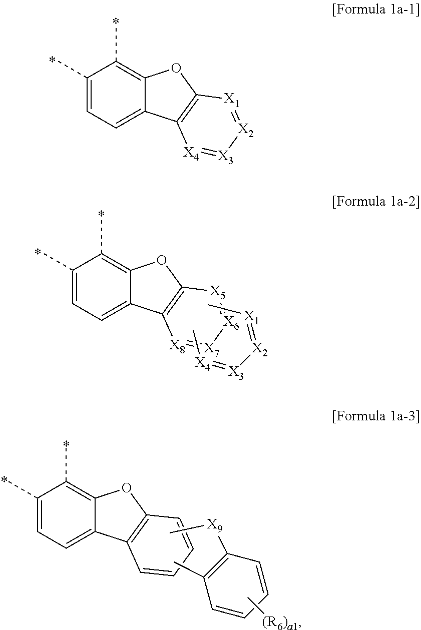

wherein in each of the Formulas 1a-1 and 1a-2, each of X₁, X₂, X₃ and X₄ is independently CR₄ or N, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
wherein in the Formula 1a-2, each of X₅, X₆, X₇ and X₈ is independently CR₅ or N, at least two of X₅, X₆, X₇ and X₈ are CR₅, and R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group, and
wherein in the Formula 1a-3, X₉ is O or S, a1 is an integer of 0 to 4, and R₆ is selected from the group consisting of deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group.

Another aspect of the present disclosure is an organic light emitting diode comprising a first electrode; a second electrode facing the first electrode; and a first emitting part positioned between the first and second electrodes and including a first emitting material layer, wherein the first emitting material layer includes the above organometallic compound.

Another aspect of the present disclosure is an organic light emitting device comprising a substrate; and an organic light emitting diode disposed on the substrate and including a first electrode, a second electrode facing the first electrode, a first emitting part positioned between the first and second electrodes and including a first emitting material layer; and an encapsulation covering the organic light emitting diode, wherein the first emitting material layer includes the organometallic compound.

Another aspect relates to an organic light emitting device (e.g., a display device or a lighting device), comprising a substrate; and a display comprising an array of pixels on the substrate, wherein each pixel comprises one or more individually addressable organic light emitting diodes described herein.

It is to be understood that both the foregoing general description and the following detailed description are explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device according to one or more embodiments of the present disclosure.

FIG. 2 is a schematic cross-sectional view of an organic light emitting display device according to one or more embodiments of the present disclosure.

FIG. 3 is a schematic cross-sectional view of an OLED according to one or more embodiments of the present disclosure.

FIG. 4 is a schematic cross-sectional view of an OLED according to one or more embodiments of the present disclosure.

FIG. 5 is a schematic cross-sectional view of an organic light emitting display device according to one or more embodiments of the present disclosure.

FIG. 6 is a schematic cross-sectional view of an OLED according to one or more embodiments of the present disclosure.

FIG. 7 is a schematic cross-sectional view of an OLED according to one or more embodiments of the present disclosure.

FIG. 8 is a schematic cross-sectional view of an OLED according to one or more embodiments of the present disclosure.

### DETAILED DESCRIPTION OF THE EMBODIMENTS

Reference will now be made in detail to aspects of the present disclosure, examples of which can be illustrated in the accompanying drawings. All the components of each OLED and each organic light emitting display device according to all embodiments of the present disclosure are operatively coupled and configured. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts can be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Reference will now be made in detail to some of the examples and preferred embodiments, which are illustrated in the accompanying drawings.

An organometallic compound of the present disclosure has improved emitting efficiency and emission lifespan. The organometallic compound of the present disclosure is represented by Formula 1.

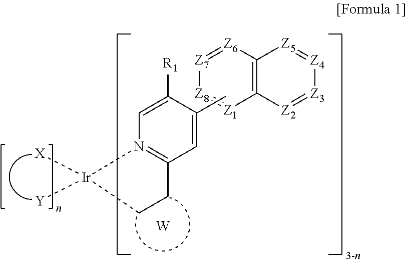

In Formula 1,
n is an integer of 0 to 2,
each of Z₁, Z₂, Z₃, Z₄, Z₅, Z₆, Z₇ and Z₈ is independently C, CR₂ or N, one of Z₁, Z₂, Z₃, Z₄, Z₅, Z₆, Z₇ and Z₈ is C,
R₁ is selected from the group consisting of hydrogen, deuterium and a substituted or unsubstituted C1 to C20 alkyl group,
R₂ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X and Y is independently selected from the group consisting of C, N and O,
a W ring is represented by one of Formulas 1a-1, 1a-2 and 1a-3,

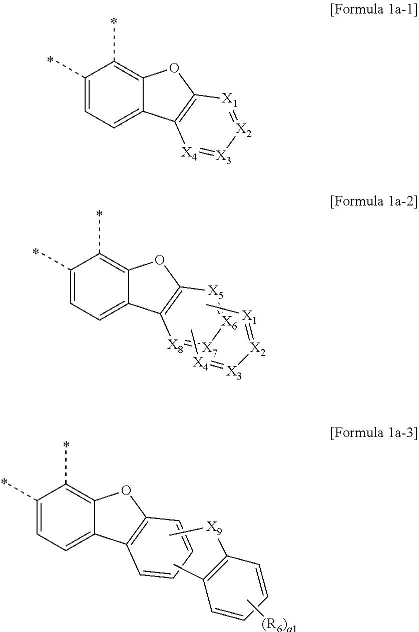

in each of Formulas 1a-1 and 1a-2,
each of X₁, X₂, X₃ and X₄ is independently CR₄ or N, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
in Formula 1a-2,
each of X₅, X₆, X₇ and X₈ is independently CR₅ or N, at least two of X₅, X₆, X₇ and X₈ are CR₅,
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
in Formula 1a-3,
X₉ is O or S, a1 is an integer of 0 to 4, and
R₆ is selected from the group consisting of deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group.

In Formulas in the present disclosure, the mark “*” denotes a bonding site. For example, in Formula 1a-1, the structure is bonded to the iridium atom at the marks “*”.

In the present disclosure, without specific definition, when an alkyl group, an alkoxy group, a cycloalkyl group, an alkylamino group, an alkylsilyl group, an alkenyl group, an alkynyl group, arylamino group, an arylsilyl group, an aryloxy group, an aryl group and/or a heteroaryl group are substituted, a substituent can be selected from the group consisting of deuterium, halogen, a cyano group, a carboxyl group, a carbonyl group, an amine group, an alkylamine group, a nitro group, a hydrazyl group, a sulfone group, an alkyl group unsubstituted or substituted with at least one of halogen and deuterium, an alkoxy group unsubstituted or substituted with at least one of halogen and deuterium, an alkylsilyl group unsubstituted or substituted with at least one of halogen and deuterium, an alkoxysilyl group unsubstituted or substituted with at least one of halogen and deuterium, a cycloalkylsilyl group unsubstituted or substituted with at least one of halogen and deuterium, an arylsilyl group unsubstituted or substituted with at least one of halogen and deuterium, an aryl group unsubstituted or substituted with at least one of halogen and deuterium and a heteroaryl group unsubstituted or substituted with at least one of halogen and deuterium.

In the present disclosure, without specific definition, a C1 to C20 alkyl group can include a linear alkyl group and a branched alkyl group. For example, a C1 to C20 alkyl group can be selected from the group consisting of methyl, ethyl, propyl and butyl, e.g., tert-butyl.

In the present disclosure, without specific definition, a ring formed by connecting adjacent two substituents can be one of a substituted or unsubstituted C3 to C30 alicyclic group, a substituted or unsubstituted C6 to C30 aromatic group and a substituted or unsubstituted C3 to C30 heteroaromatic group.

In the present disclosure, without specific definition, a C6 to C30 aryl group (or a C6 to C30 aromatic ring) can be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C3 to C30 heteroaryl group (or a C3 to C30 heteroaromatic ring) can be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, purinyl, benzoquinolinyl, benzoisoquinolinyl, benzoquinazolinyl, benzoquinoxalinyl, acridinyl, phenanthrolinyl, perimidinyl, phenanthridinyl, pteridinyl, cinnolinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In an aspect of the present disclosure, one of Z₁, Z₂, Z₃, Z₄, Z₅, Z₆, Z₇ and Z₈ can be C, and the rest of Z₁, Z₂, Z₃, Z₄, Z₅, Z₆, Z₇ and Z₈ can be CR₂.

In an aspect of the present disclosure, one of Z₁, Z₂, Z₃, Z₄, Z₅, Z₆, Z₇ and Z₈ can be C, the other one of Z₁, Z₂, Z₃, Z₄, Z₅, Z₆, Z₇ and Z₈ can be N, and the rest of Z₁, Z₂, Z₃, Z₄, Z₅, Z₆, Z₇ and Z₈ can be CR₂.

In Formula 1, the ring including Z₁, Z₂, Z₃, Z₄, Z₅, Z₆, Z₇ and Z₈ is combined to the pyridine ring at “C” being one of Z₁, Z₂, Z₃, Z₄, Z₅, Z₆, Z₇ and Z₈.

In an aspect of the present disclosure, R₁ can be a C1 to C20 alkyl group unsubstituted or substituted with deuterium. For example, R₁ can be methyl, tert-butyl or CD₃.

In an aspect of the present disclosure, R₂ can be selected from the group consisting of hydrogen, deuterium, a substituted or unsubstituted C1 to C20 alkyl group and a substituted or unsubstituted C6 to C30 aryl group. For example, R₂ can be selected from the group consisting of hydrogen, a C1 to C20 alkyl group unsubstituted or substituted with deuterium, e. g., methyl or tert-butyl, a C6 to C30 aryl group unsubstituted or substituted with at least one of methyl, tert-butyl and CD₃, e.g., phenyl.

In an aspect of the present disclosure, “X-Y” as an auxiliary ligand can be represented by one of Formulas 1b-1, 1b-2 and 1b-3.

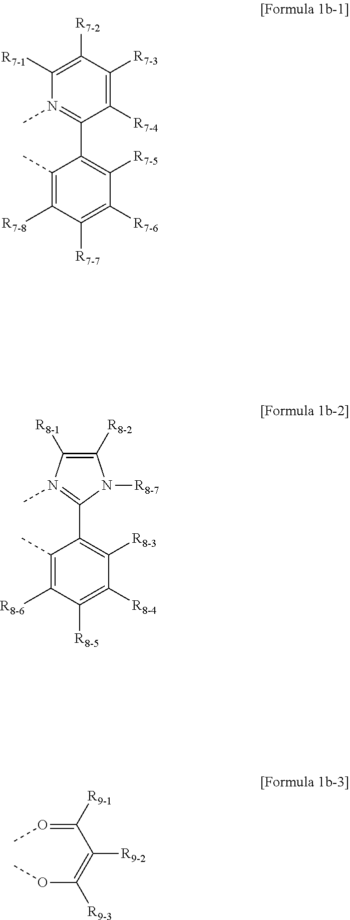

In Formula 1b-1,
each of R₇₋₁, R₇₋₂, R₇₋₃, R₇₋₄, R₇₋₅, R₇₋₆, R₇₋₇, and R₇₋₈ is independently selected from the group consisting of hydrogen, deuterium, halide, a substituted or unsubstituted C1 to C5 alkyl group and a substituted or unsubstituted C6 to C30 aryl group, or optionally, adjacent two of R₇₋₁, R₇₋₂, R₇₋₃ and R₇₋₄ or adjacent two of R₇₋₅, R₇₋₆, R₇₋₇, and R₇₋₈ are combined to form a ring,
in Formula 1b-2,
each of R₈₋₁, R₈₋₂, R₈₋₃, R₈₋₄, R₈₋₅ and R₈₋₆ is independently selected from the group consisting of hydrogen, deuterium, halide, a substituted or unsubstituted C1 to C5 alkyl group and a substituted or unsubstituted C6 to C30 aryl group, or optionally, adjacent two of R₈₋₁, R₈₋₂, R₈₋₃, R₈₋₄, R₈₋₅ and R₈₋₆ are combined to form a ring,
R₈₋₇ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
in Formula 1b-3,
each of R₉₋₁, R₉₋₂ and R₉₋₃ is independently selected from the group consisting of hydrogen, deuterium, halide, a substituted or unsubstituted C1 to C5 alkyl group and a substituted or unsubstituted C6 to C30 aryl group, or optionally, adjacent two of R₉₋₁, R₉₋₂ and R₉₋₃ are combined to form a ring.

In an aspect of the present disclosure, “X-Y” in Formula 1 can be represented by Formula 1b-1, and each of R₇₋₁, R₇₋₂, R₇₋₃, R₇₋₄, R₇₋₅, R₇₋₆, R₇₋₇, and R₇₋₈ can be independently selected from the group consisting of hydrogen, methyl, CD₃, tert-butyl and phenyl unsubstituted or substituted with methyl or CD₃.

In an aspect of the present disclosure, “X-Y” in Formula 1 can be represented by Formula 1b-2. In this case, i) each of R₈₋₁, R₈₋₂, R₈₋₃, R₈₋₄, R₈₋₅ and R₈₋₆ can be independently selected from the group consisting of hydrogen, methyl and CD₃, or ii) each of R₈₋₃, R₈₋₄, R₈₋₅ and R₈₋₆ can be independently selected from the group consisting of hydrogen, methyl and CD₃, and R₈₋₁ and R₈₋₂ can be combined to form a benzene ring.

In an aspect of the present disclosure, “X-Y” in Formula 1 can be represented by Formula 1b-2, R₈₋₇ can be selected from the group consisting of methyl, CD₃ and phenyl unsubstituted or substituted with deuterated tert-butyl.

In an aspect of the present disclosure, “X-Y” in Formula 1 can be represented by Formula 1b-3, each of R₉₋₁, R₉₋₂ and R₉₋₃ can be independently selected from the group consisting of hydrogen, methyl, tert-butyl and pentyl.

In an aspect of the present disclosure, in Formula 1a-1, i) all of X₁, X₂, X₃ and X₄ can be CR₄, or ii) one of X₁, X₂, X₃ and X₄ can be N, and the rest of X₁, X₂, X₃ and X₄ can be CR₄. In this case, R₄ can be hydrogen, methyl, CD₃ or phenyl.

In an aspect of the present disclosure, in Formula 1a-2, i) all of X₁, X₂, X₃ and X₄ can be CR₄, or ii) one of X₁, X₂, X₃ and X₄ can be N, and the rest of X₁, X₂, X₃ and X₄ can be CR₄. In addition, i) all of X₅, X₆, X₇ and X₈ can be CR₅, or ii) one of X₅, X₆, X₇ and X₈ can be N, and the rest of X₅, X₆, X₇ and X₈ can be CR₅. In this case, each of R₄ and R₅ can be independently selected from the group consisting of hydrogen, methyl, CD₃, tert-butyl and phenyl substituted with one of methyl, CD₃, tert-butyl.

In an aspect of the present disclosure, in Formula 1a-3, R₆ can be methyl or CD₃.

In an aspect of the present disclosure, the W ring can be selected from structures in Formula 1a-4.

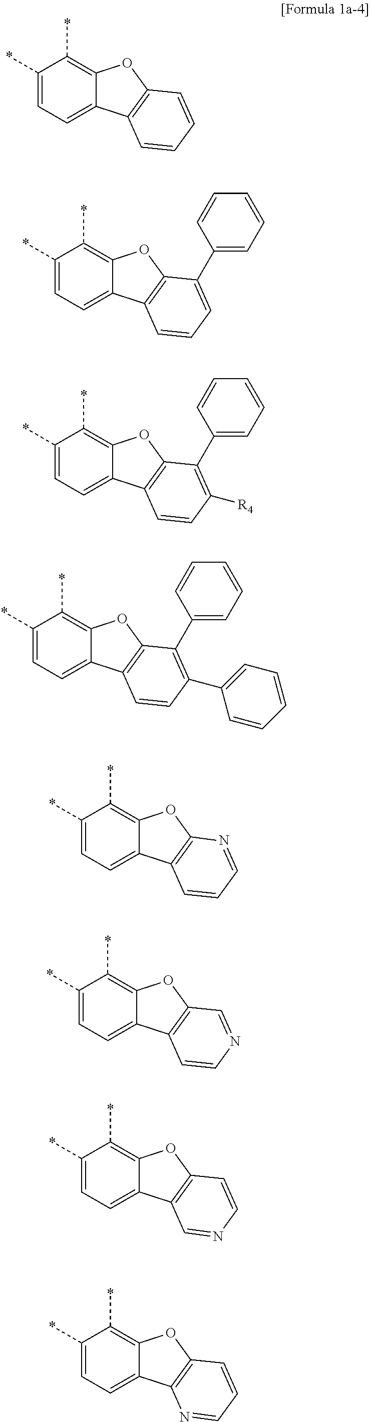

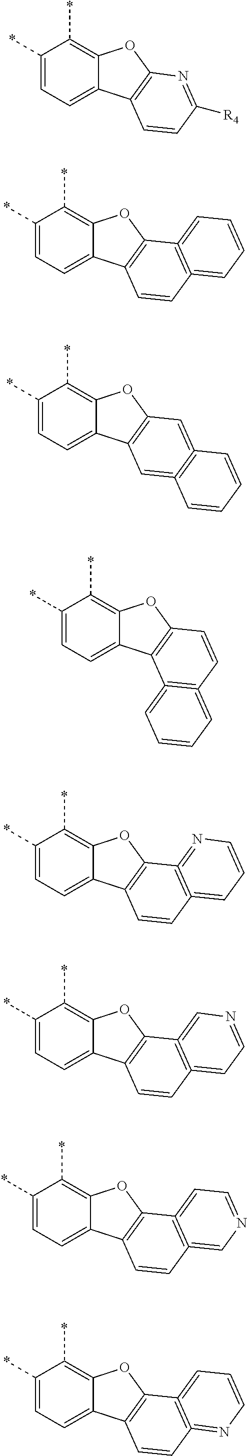

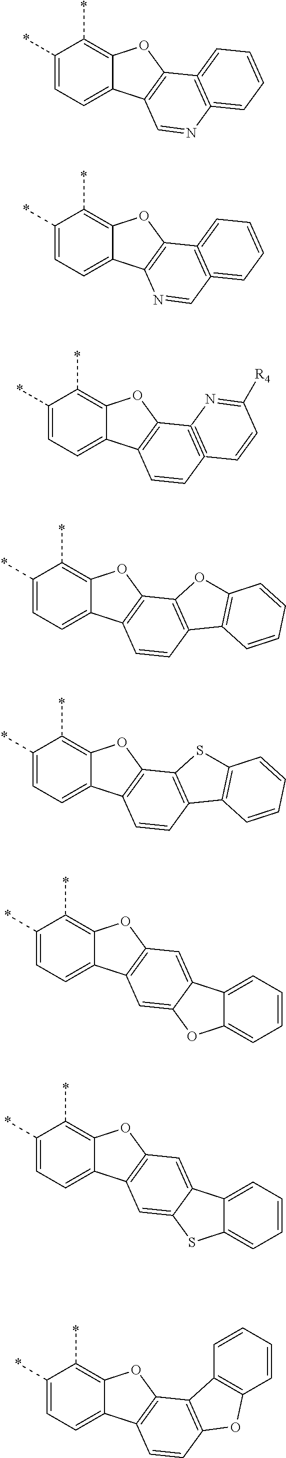

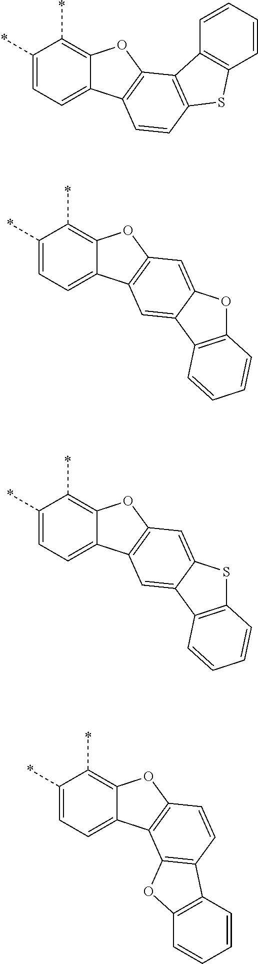

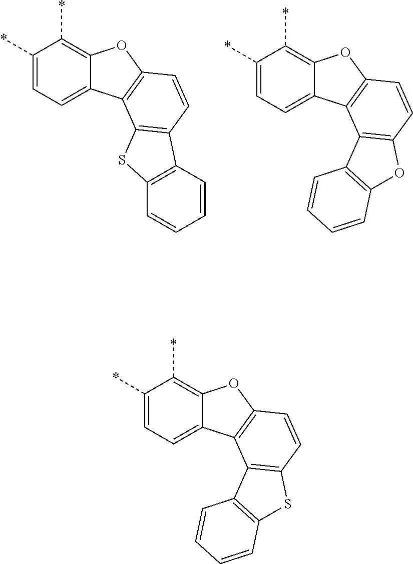

In Formula 1a-4,
R₄ is selected from the group consisting of deuterium and a C1 to C20 alkyl group unsubstituted or substituted with deuterium.

As illustrated above, the W ring in Formula 1 has a structure represented by one of Formulas 1a-1, 1a-2 and 1a-3, and the “X-Y” as an auxiliary ligand can be represented by one of Formulas 1b-1, 1b-2 and 1b-3. For example, the organometallic compound in Formula 1 can be represented by one of Formulas 1c-1 to 1c-9.

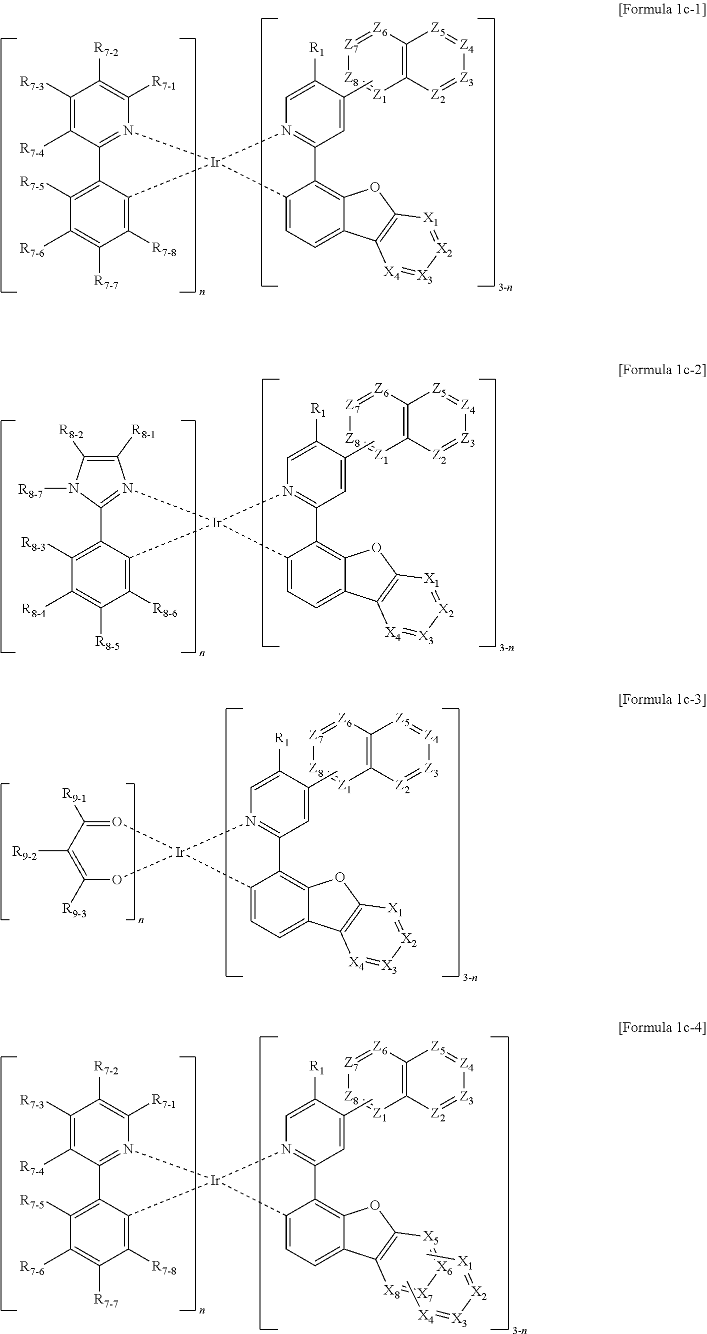

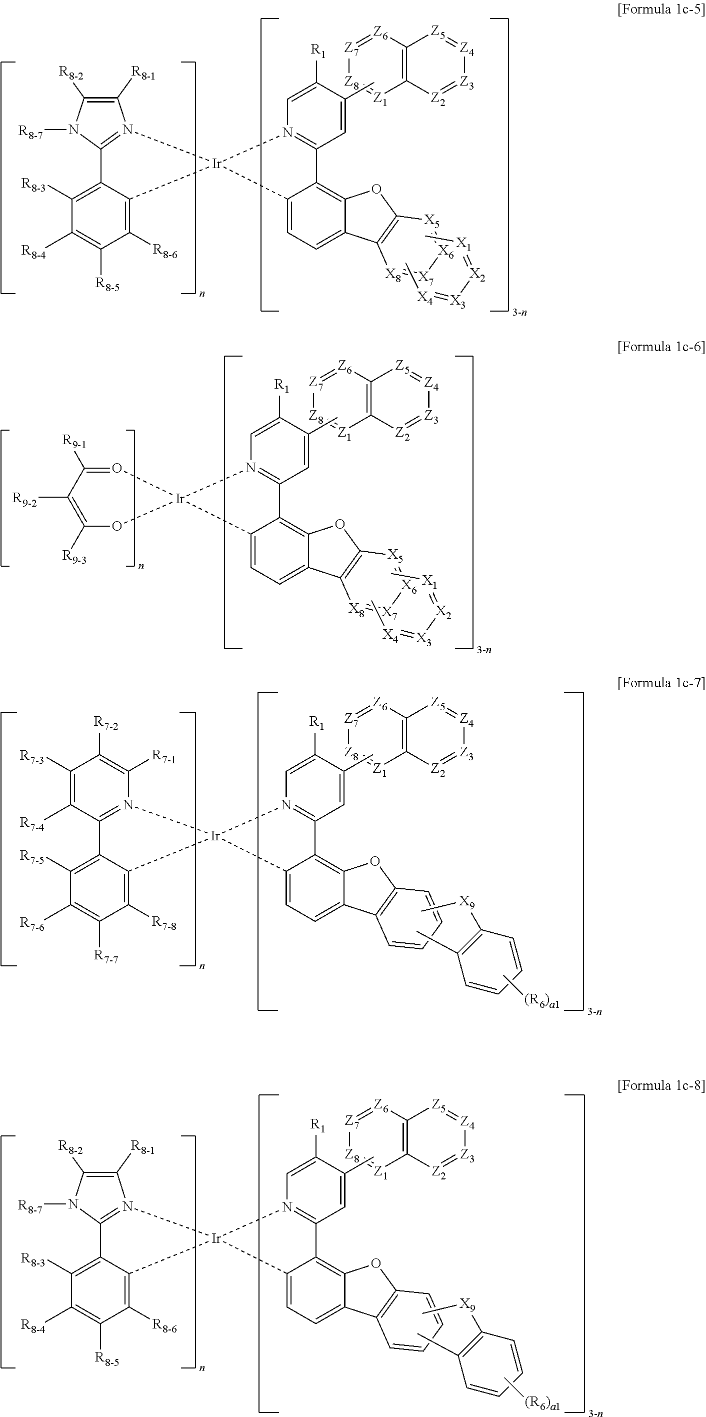

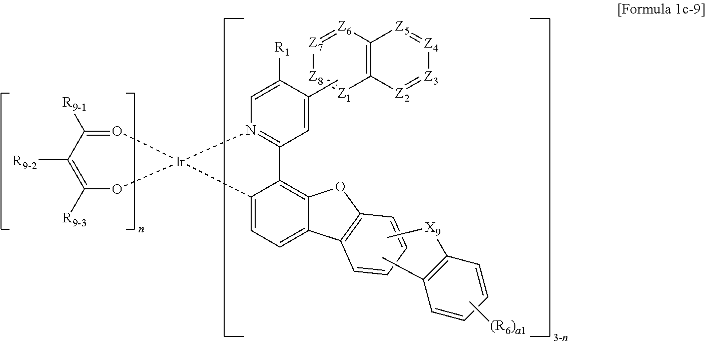

In each of Formulas 1c-1 to 1c-9,
the definitions of Z₁, Z₂, Z₃, Z₄, Z₅, Z₆, Z₇, Z₈, n, R₁ and R₂ are same as those in Formula 1,
the definitions of X₁, X₂, X₃, X₄, X₅, X₆, X₇, X₈, R₄, R₅, X₉, a1 and R₆ are same as those in Formulas 1a-1 to 1a-3, and
the definitions of R₇₋₁, R₇₋₂, R₇₋₃, R₇₋₄, R₇₋₅, R₇₋₆, R₇₋₇, R₇₋₈, R₈₋₁, R₈₋₂, R₈₋₃, R₈₋₄, R₈₋₅, R₈₋₆, R₈₋₇, R₉₋₁, R₉₋₂ and R₉₋₃ are same as those in Formulas 1b-1 to 1b-3.

In an aspect of the present disclosure, i) all of Z₁ to Z₈ can be C, or ii) one of Z₁ to Z₈ can be N, and the rest of Z₁ to Z₈ can be C. In addition, a structure of the “X-Y” can be specified. For example, the organometallic compound in Formula 1 can be represented by one of Formulas 2-1, 2-2 and 2-3.

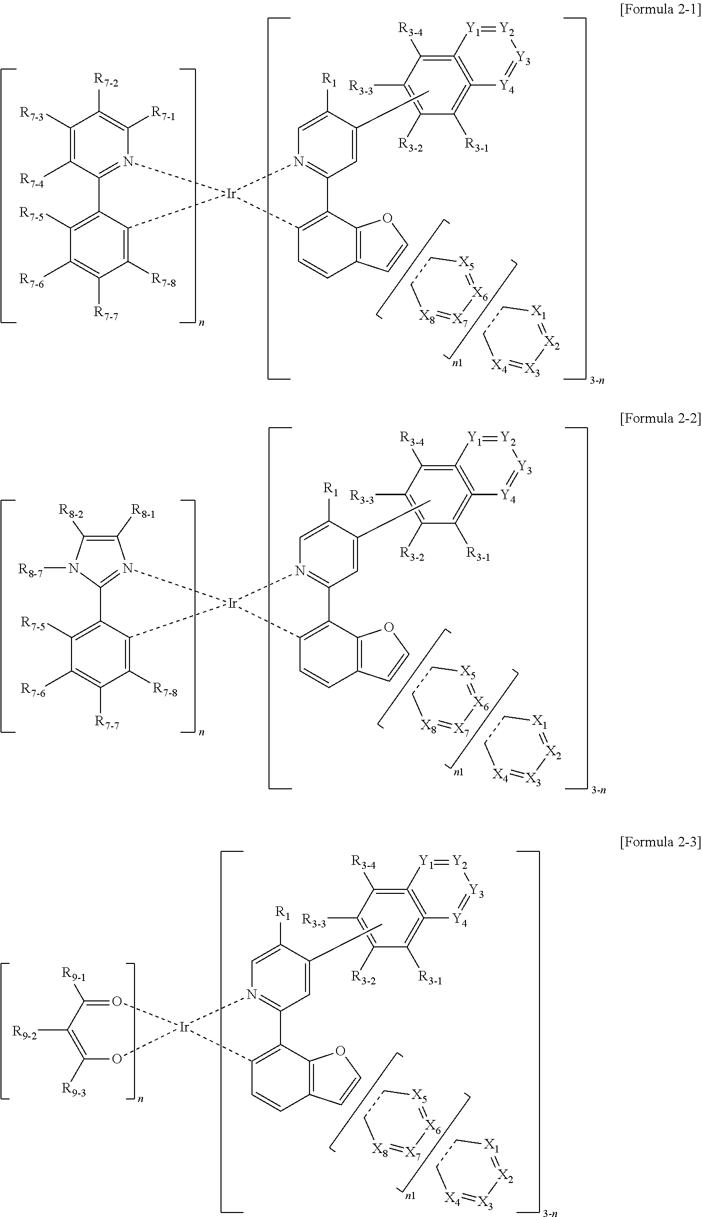

In each of Formulas 2-1 to 2-3,
n is an integer of 0 to 2, and n1 is 0 or 1,
R₁ is selected from the group consisting of hydrogen, deuterium and a C1 to C20 alkyl group unsubstituted or substituted with deuterium,
i) each of Y₁ to Y₄ is independently CR₂ or N, or ii) one of Y₁ to Y₄ is N, and the rest of Y₁ to Y₄ is CR₂,
one of R₃₋₁ to R₃₋₄ is a connecting group,
each of R₂ and the rest of R₃₋₁ to R₃₋₄ is independently selected from the group consisting of hydrogen, a C1 to C20 alkyl group unsubstituted or substituted with deuterium and a substituted or unsubstituted C6 to C30 aryl group,
each of X₁, X₂, X₃ and X₄ is independently CR₄ or N, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X₅, X₆, X₇ and X₈ is independently CR₅ or N, and two of X₅, X₆, X₇ and X₈ are CR₅, and
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
in Formula 2-1,
each of R₇₋₂, R₇₋₃, R₇₋₆ and R₇₋₇ is independently selected from the group consisting of hydrogen, deuterium, a C1 to C5 alkyl group unsubstituted or substituted with deuterium and a substituted or unsubstituted C6 to C30 aryl group,
in Formula 2-2,
each of R₈₋₁ and R₈₋₂ is independently selected from the group consisting of hydrogen and a C1 to C20 alkyl group unsubstituted or substituted with deuterium, or optionally R₈₋₁ and R₈₋₂ are combined to form a ring,
R₈₋₅ is selected from the group consisting of hydrogen and a C1 to C20 alkyl group unsubstituted or substituted with deuterium,
R₈₋₇ is selected from the group consisting of hydrogen, a C1 to C20 alkyl group unsubstituted or substituted with deuterium and a C6 to C30 aryl group unsubstituted or substituted with at least one of a C1 to C20 alkyl group and a deuterated C1 to C20 alkyl group,
in Formula 2-3,
each of R₉₋₁ and R₉₋₃ is independently selected from the group consisting of hydrogen and a C1 to C20 alkyl group unsubstituted or substituted with deuterium.

In an aspect of the present disclosure, R₁ can be a C1 to C20 alkyl group unsubstituted or substituted with deuterium, e.g., methyl or CD₃.

In an aspect of the present disclosure, a plurality of R₁s can be hydrogen.

In an aspect of the present disclosure, one of a plurality of R₁s can be a C1 to C20 alkyl group unsubstituted or substituted with deuterium, e.g., methyl, tert-butyl or CD₃, or a C6 to C30 aryl group, e.g., phenyl, unsubstituted or substituted with at least one of a C1 to C20 alkyl group, e.g., methyl or tert-butyl, and a deuterated alkyl group, e.g., CD₃, and the rest of the plurality of R₁s can be hydrogen.

In an aspect of the present disclosure, n1 can be 0, one of X₁, X₂, X₃ and X₄ can be N, and the rest of X₁, X₂, X₃ and X₄ can be CR₄.

In an aspect of the present disclosure, n1 can be 0, and all of X₁, X₂, X₃ and X₄ can be CR₄.

In an aspect of the present disclosure, n1 can be 1, one of X₁, X₂, X₃ and X₄ can be N, the rest of X₁, X₂, X₃ and X₄ can be CR₄, and all of X₅, X₆, X₇ and X₈ can be CR₅.

In this case, each of R₄ and R₅ can be independently selected from the group consisting of hydrogen, methyl and a C1 to C20 alkyl group unsubstituted or substituted with deuterium, e.g., methyl or CD₃.

In an aspect of the present disclosure, each of R₇₋₂, R₇₋₃ and R₇₋₇ can be independently a C1 to C20 alkyl group unsubstituted or substituted with deuterium, e.g., methyl or CD₃.

In an aspect of the present disclosure, R₇₋₈ can be selected from the group consisting of hydrogen and a substituted or unsubstituted C6 to C30 aryl group, e.g., phenyl.

In an aspect of the present disclosure, in Formula 1, i) all of Z₁ to Z₈ can be C, or ii) one of Z₁ to Z₈ can be N, and the rest of Z₁ to Z₈ can be C. In addition, a bonding position of a ring including Z₁ to Z₈ and a position of the substituent of the ring including Z₁ to Z₈ can be specified. Moreover, a structure of the “X-Y” as an auxiliary ligand can be specified. For example, the organometallic compound in Formula 1 can be represented by one of Formulas 2-4 to 2-6.

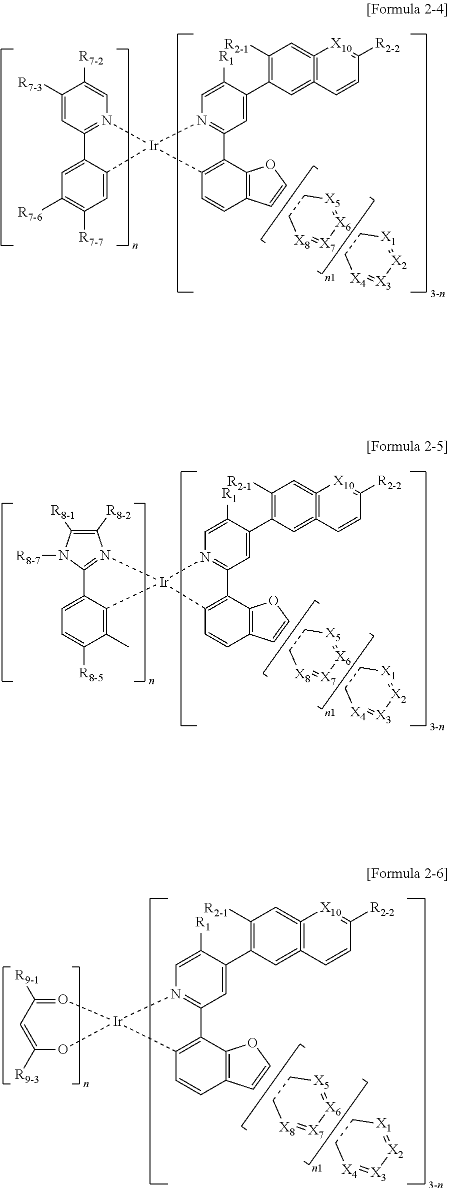

In each of Formulas 2-4 to 2-6,
n is an integer of 0 to 2, and n1 is 0 or 1,
X₁₀ is CR₁₀ or N,
R₁ is selected from the group consisting of hydrogen, deuterium and a C1 to C20 alkyl group unsubstituted or substituted with deuterium,
each of R₂₋₁, R₂₋₂ and R₁₀ is independently selected from the group consisting of hydrogen, deuterium, a C1 to C20 alkyl group unsubstituted or substituted with deuterium and a substituted or unsubstituted C6 to C30 aryl group,
each of X₁, X₂, X₃ and X₄ is independently CR₄ or N, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X₅, X₆, X₇ and X₈ is independently CR₅ or N, and two of X₅, X₆, X₇ and X₈ are CR₅, and
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
in Formula 2-4,
each of R₇₋₂, R₇₋₃, R₇₋₆ and R₇₋₇ is independently selected from the group consisting of hydrogen, deuterium, a C1 to C5 alkyl group unsubstituted or substituted with deuterium and a substituted or unsubstituted C6 to C30 aryl group,
in Formula 2-5,
each of R₈₋₁ and R₈₋₂ is independently selected from the group consisting of hydrogen and a C1 to C20 alkyl group unsubstituted or substituted with deuterium, or optionally R₈₋₁ and R₈₋₂ are combined to form a ring,
R₈₋₅ is selected from the group consisting of hydrogen and a C1 to C20 alkyl group unsubstituted or substituted with deuterium,
R₈₋₇ is selected from the group consisting of hydrogen, a C1 to C20 alkyl group unsubstituted or substituted with deuterium and a C6 to C30 aryl group unsubstituted or substituted with at least one of a C1 to C20 alkyl group and a deuterated C1 to C20 alkyl group,
in Formula 2-6,
each of R₉₋₁ and R₉₋₃ is independently selected from the group consisting of hydrogen and a C1 to C20 alkyl group unsubstituted or substituted with deuterium.

In an aspect of the present disclosure, R₁ can be a C1 to C20 alkyl group unsubstituted or substituted with deuterium, e.g., methyl or CD₃.

In an aspect of the present disclosure, R₂₋₁ can be a C1 to C20 alkyl group unsubstituted or substituted with deuterium, e.g., methyl or CD₃.

In an aspect of the present disclosure, R₂₋₂ can be hydrogen, a C1 to C20 alkyl group unsubstituted or substituted with deuterium, e.g., methyl, tert-butyl or CD₃, or a C6 to C30 aryl group, e.g., phenyl, unsubstituted or substituted with at least one of a C1 to C20 alkyl group, e.g., methyl or tert-butyl, and a deuterated alkyl group, e.g., CD₃.

In an aspect of the present disclosure, n1 can be 0, one of X₁, X₂, X₃ and X₄ can be N, and the rest of X₁, X₂, X₃ and X₄ can be CR₄.

In an aspect of the present disclosure, n1 can be 0, and all of X₁, X₂, X₃ and X₄ can be CR₄.

In an aspect of the present disclosure, n1 can be 1, one of X₁, X₂, X₃ and X₄ can be N, the rest of X₁, X₂, X₃ and X₄ can be CR₄, and all of X₅, X₆, X₇ and X₈ can be CR₅.

In this case, each of R₄ and R₅ can be independently selected from the group consisting of hydrogen, methyl and a C1 to C20 alkyl group unsubstituted or substituted with deuterium, e.g., methyl or CD₃.

In an aspect of the present disclosure, each of R₇₋₂, R₇₋₃ and R₇₋₇ can be independently a C1 to C20 alkyl group unsubstituted or substituted with deuterium, e.g., methyl or CD₃.

In an aspect of the present disclosure, R₇₋₈ can be selected from the group consisting of hydrogen and a substituted or unsubstituted C6 to C30 aryl group, e.g., phenyl.

In an aspect of the present disclosure, R₈₋₁ and R₈₋₂ can be hydrogen or can be combined to form an aromatic ring.

In an aspect of the present disclosure, R₈₋₅ can be a C1 to C20 alkyl group unsubstituted or substituted with deuterium, e.g., methyl or CD₃.

In an aspect of the present disclosure, R₈₋₇ can be selected from the group consisting of hydrogen and a C6 to C30 aryl group, e.g., phenyl, unsubstituted or substituted with at least one of a C1 to C20 alkyl group, e.g., methyl, and a deuterated C1 to C20 alkyl group, e.g., CH₂D.

In an aspect of the present disclosure, each of R₉₋₁ and R₉₋₃ can be independently selected from a substituted or unsubstituted C1 to C20 alkyl, e.g., tert-butyl or pentyl.

In an aspect of the present disclosure, n can be 2, n1 can be 0, each of X₁ to X₄ and X₁₀ can be CH, each of R₁ and R₂₋₁ can be independently a C1 to C20 alkyl group unsubstituted or substituted with deuterium, e.g., CH₃ or CD₃, and R₂₋₂ can be a substituted or unsubstituted aryl group, e.g., phenyl.

In an aspect of the present disclosure, n can be 2, n1 can be 0, each of X₁ and X₁₀ can be N, X₂ can be CR₄ (R₄=CH₃ or CD₃), each of X₃ and X₄ can be CH, each of R₁, R₂₋₁ and R₂₋₂ can be independently a C1 to C20 alkyl group unsubstituted or substituted with deuterium, e.g., CH₃ or CD₃.

In an aspect of the present disclosure, the organometallic compound is a compound represented by Formula 2-4, wherein n is an integer of 1 to 2, and n1 is 0 or 1, X₁₀ is CR₁₀ or N, R₁ is selected from the group consisting of hydrogen, deuterium and a C1 to C20 alkyl group unsubstituted or substituted with deuterium; each of R₂₋₁, R₂₋₂ and R₁₀ is independently selected from the group consisting of hydrogen, deuterium, methyl, ethyl and propyl; wherein one of X₁, X₂, X₃ and X₄ is N and the rest are CR₄; R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, each of X₅, X₆, X₇ and X₈ is independently CR₅ or N, wherein at least two of X₅, X₆, X₇ and X₈ are CR₅; R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and ach of R₇₋₂, R₇₋₃, R₇₋₆ and R₇₋₇ is independently selected from the group consisting of hydrogen, deuterium, a C1 to C5 alkyl group unsubstituted or substituted with deuterium and a substituted or unsubstituted C6 to C30 aryl group.

In an aspect of the present disclosure, the organometallic compound is a compound represented by Formula 2-5, wherein n is an integer of 1 to 2, and n1 is 0 or 1; X₁₀ is CR₁₀ or N; R₁ is selected from the group consisting of hydrogen, deuterium and a C1 to C20 alkyl group unsubstituted or substituted with deuterium; each of R₂₋₁, R₂₋₂ and R₁₀ is independently selected from the group consisting of hydrogen, deuterium, methyl, ethyl and propyl; wherein one of X₁, X₂, X₃ and X₄ is N and the rest are CR₄; R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, each of X₅, X₆, X₇ and X₈ is independently CR₅ or N, wherein at least two of X₅, X₆, X₇ and X₈ are CR₅; R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group; each of R₈₋₁ and R₈₋₂ is independently selected from the group consisting of hydrogen and a C1 to C20 alkyl group unsubstituted or substituted with deuterium; R₈s is selected from the group consisting of hydrogen and a C1 to C20 alkyl group unsubstituted or substituted with deuterium, and R₈₋₇ is selected from the group consisting of hydrogen, a C1 to C20 alkyl group unsubstituted or substituted with deuterium and a C6 to C30 aryl group unsubstituted or substituted with at least one of a C1 to C20 alkyl group and a deuterated C1 to C20 alkyl.

In an aspect of the present disclosure, the organometallic compound is a compound represented by Formula 2-6, wherein n is an integer of 1 to 2, and n1 is 0 or 1; X₁₀ is CR₁₀ or N; R₁ is selected from the group consisting of hydrogen, deuterium and a C1 to C20 alkyl group unsubstituted or substituted with deuterium; each of R₂₋₁, R₂₋₂ and R₁₀ is independently selected from the group consisting of hydrogen, deuterium, methyl, ethyl, and propyl; wherein one of X₁, X₂, X₃ and X₄ is N and the rest are CR₄; R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, each of X₅, X₆, X₇ and X₈ is independently CR₅ or N, wherein at least two of X₅, X₆, X₇ and X₈ are CR₅; R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and each of R₉₋₁ and R₉₋₃ is independently selected from the group consisting of hydrogen and a C1 to C20 alkyl group unsubstituted or substituted with deuterium.

In an aspect of the present disclosure, the organometallic compound of the present disclosure represented by Formula 1 can be one of the compounds in Formula 3.

### [Formula 3]

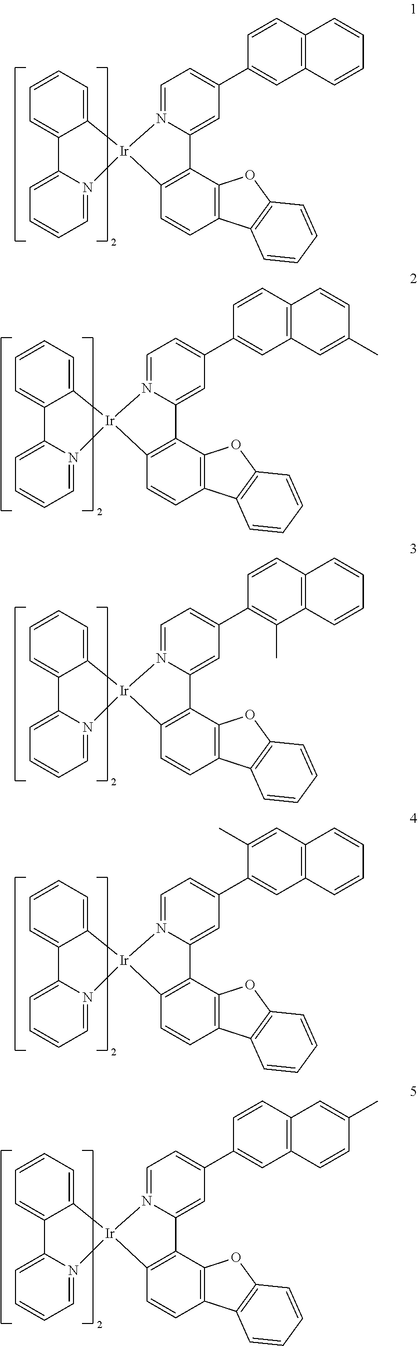

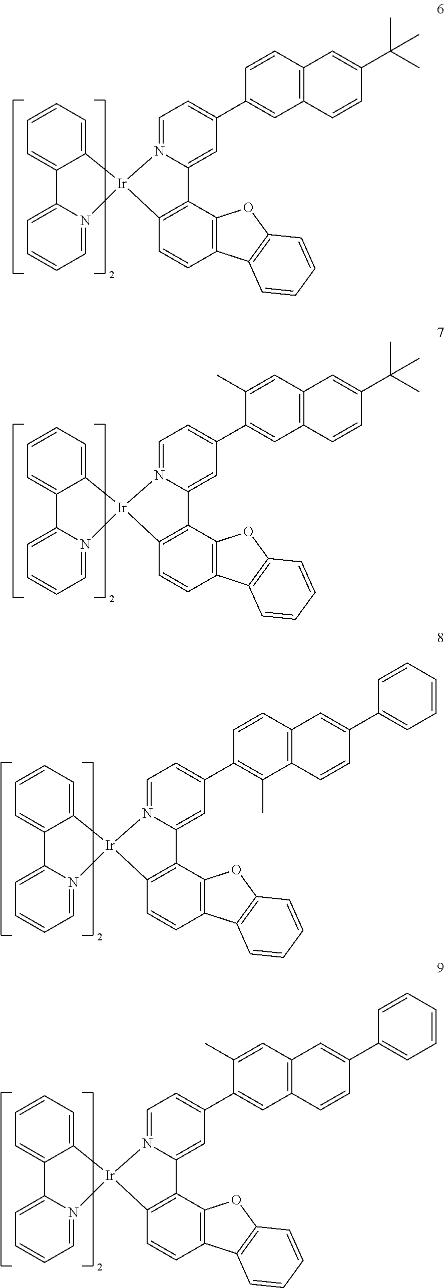

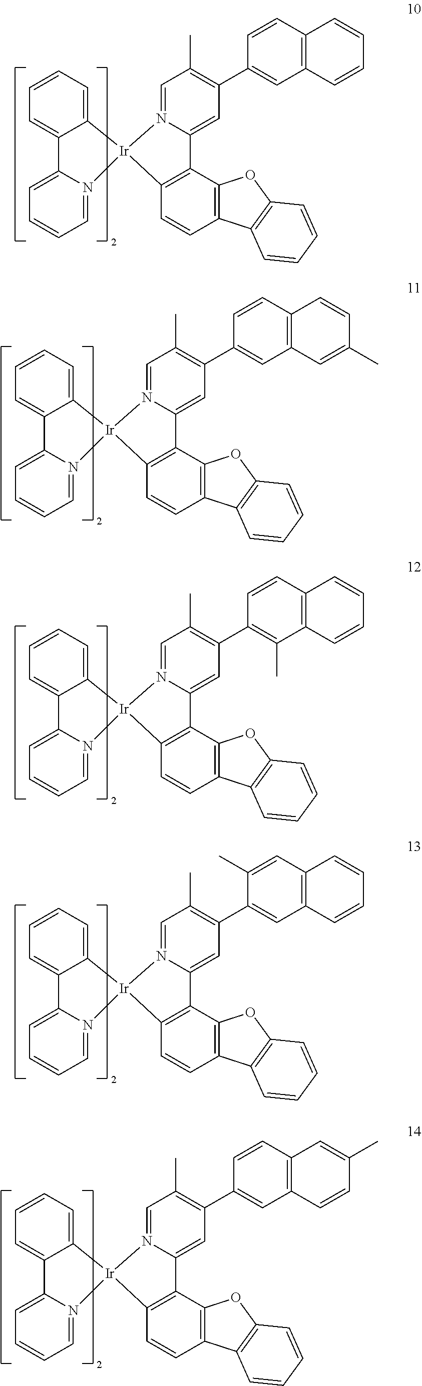

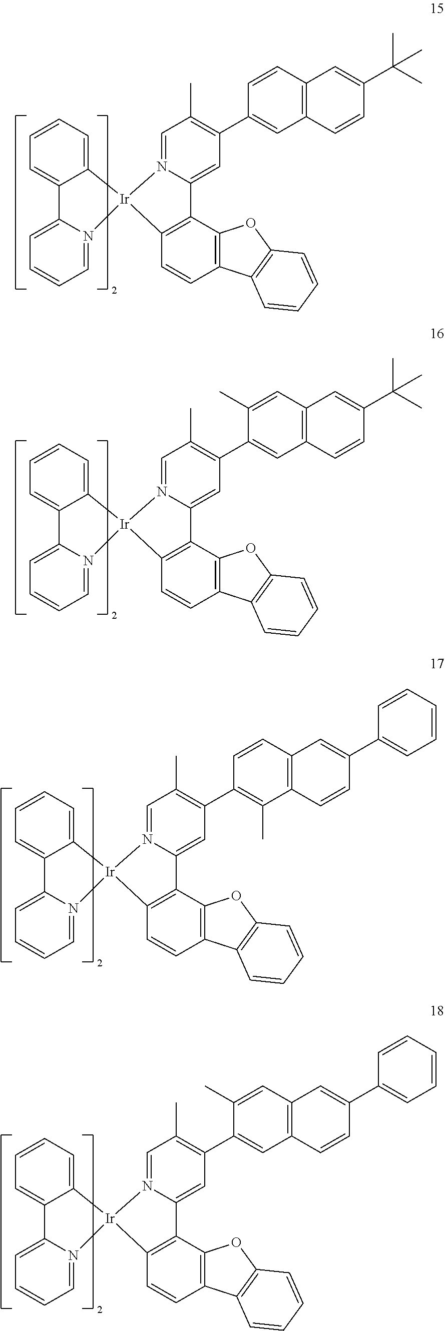

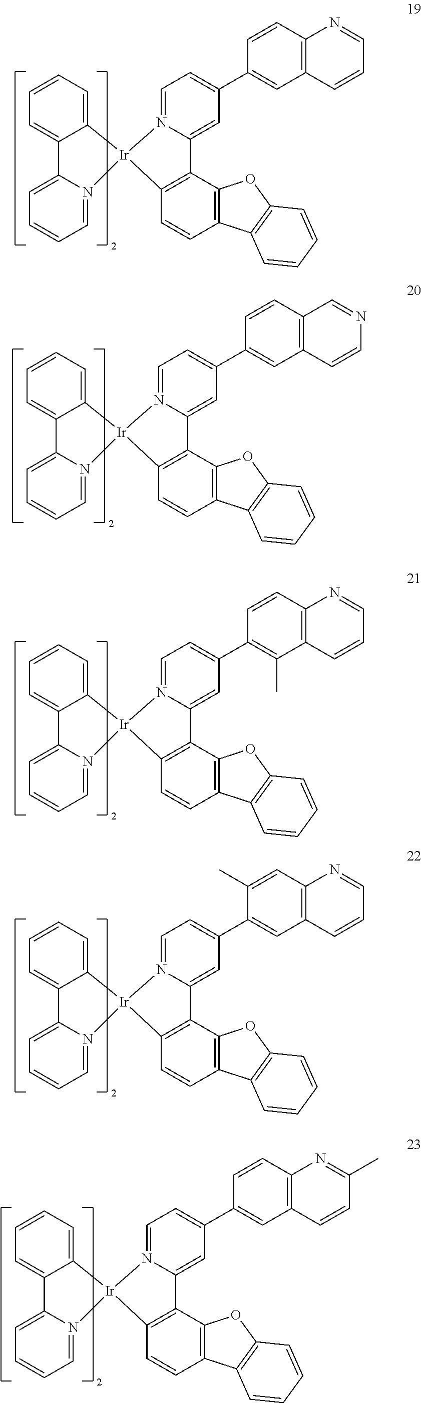

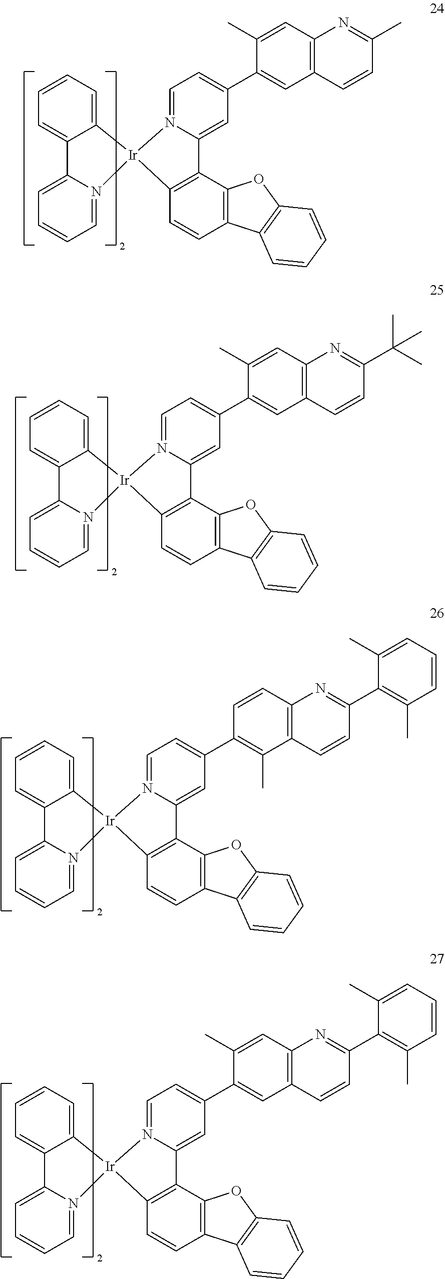

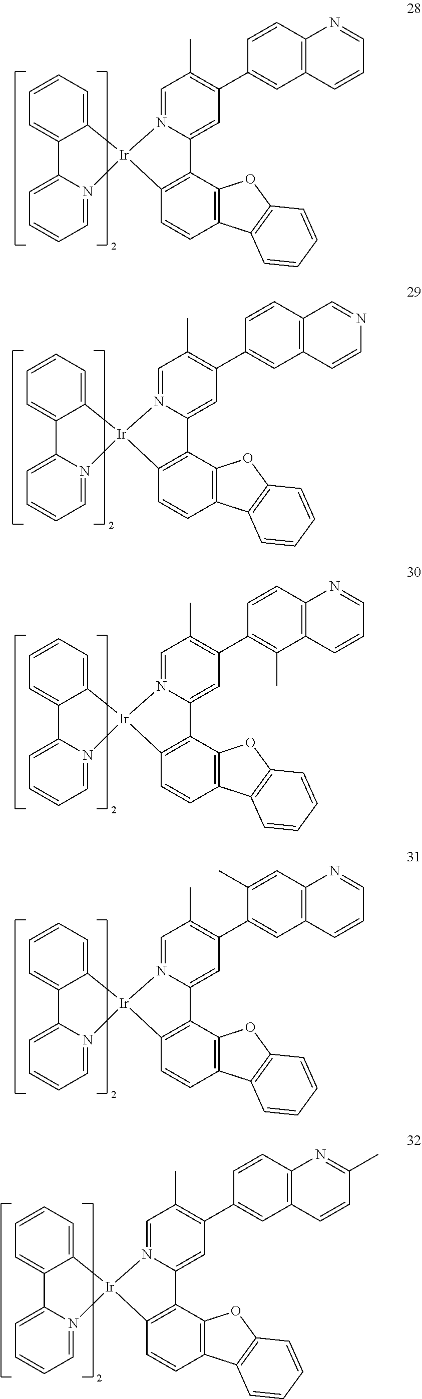

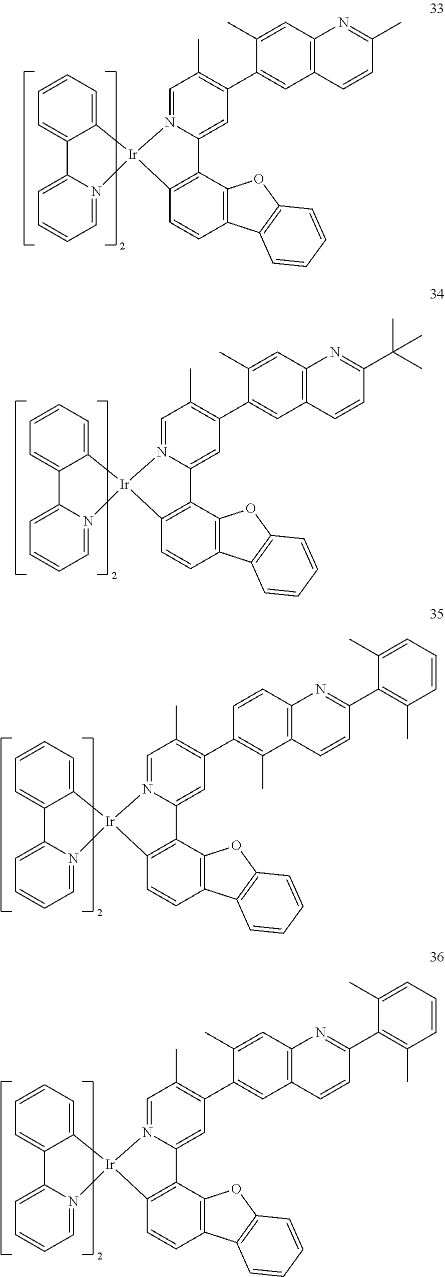

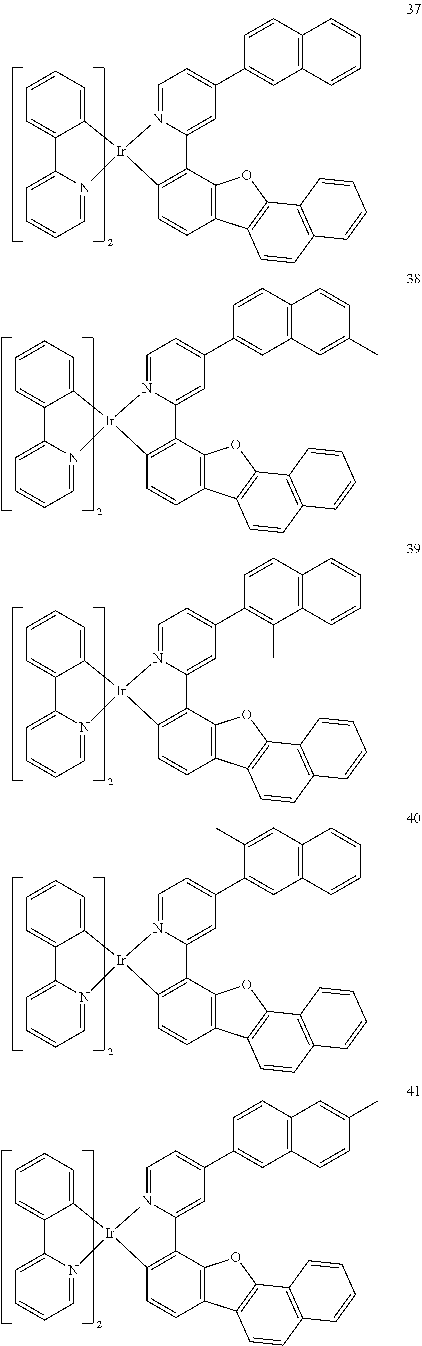

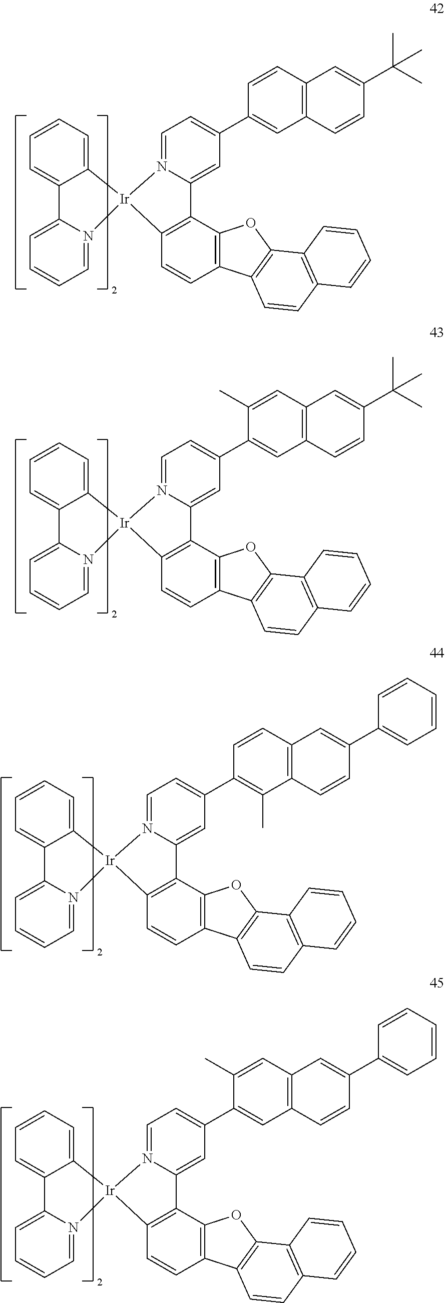

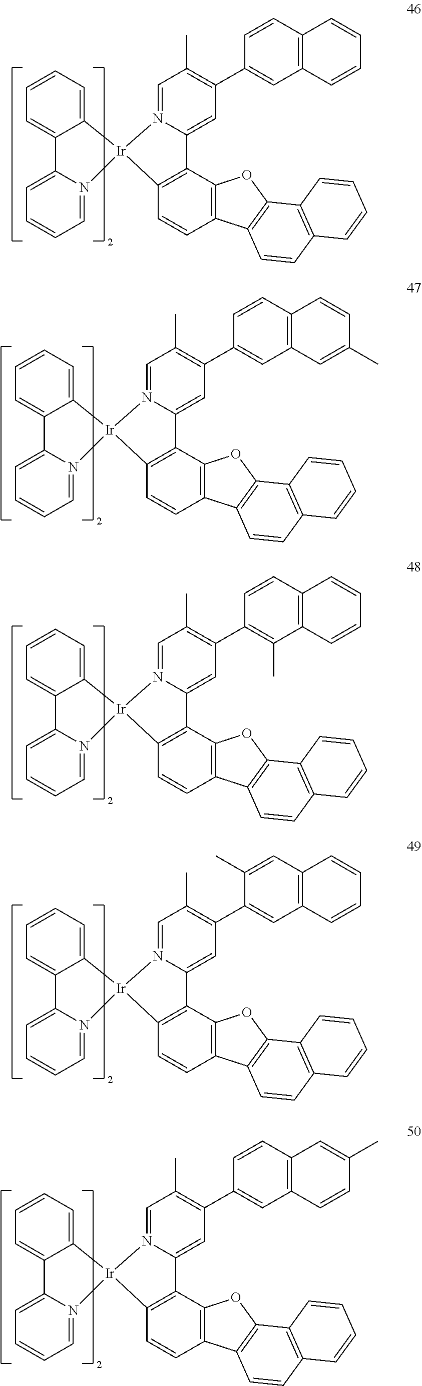

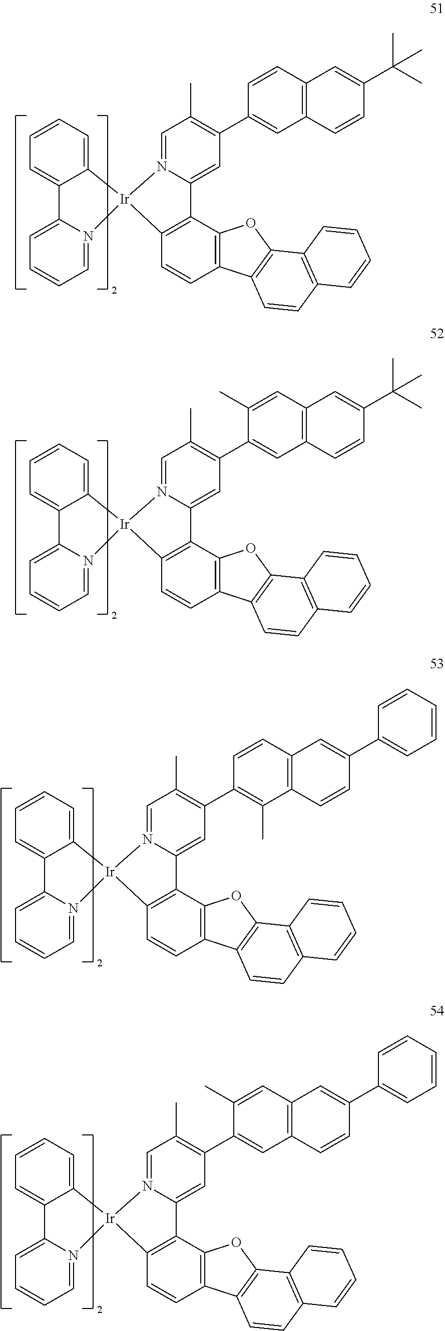

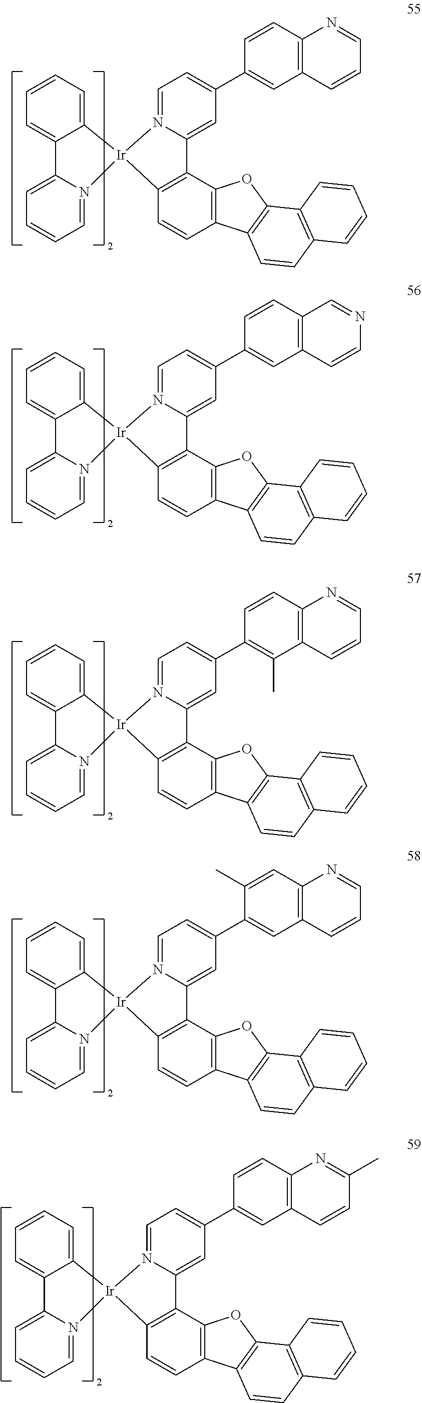

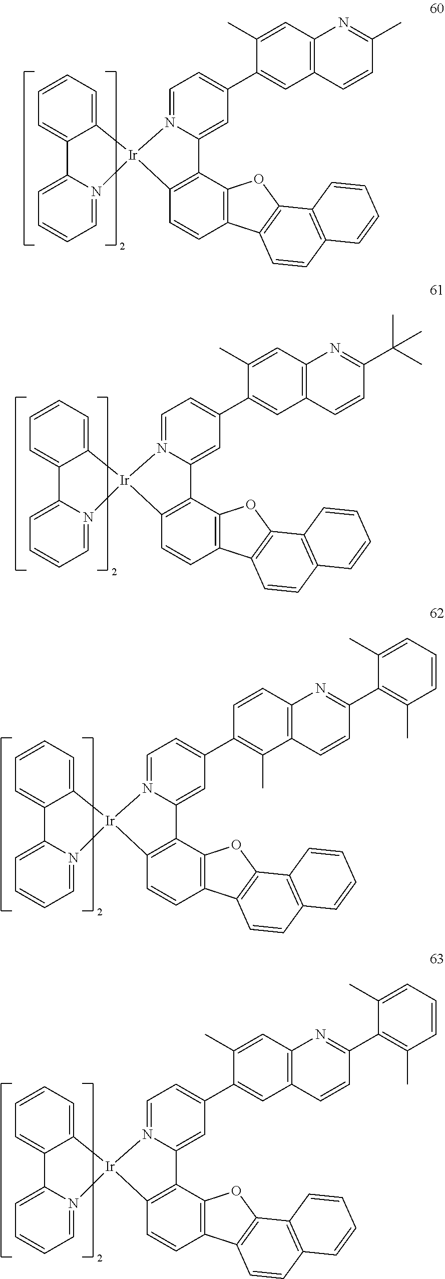

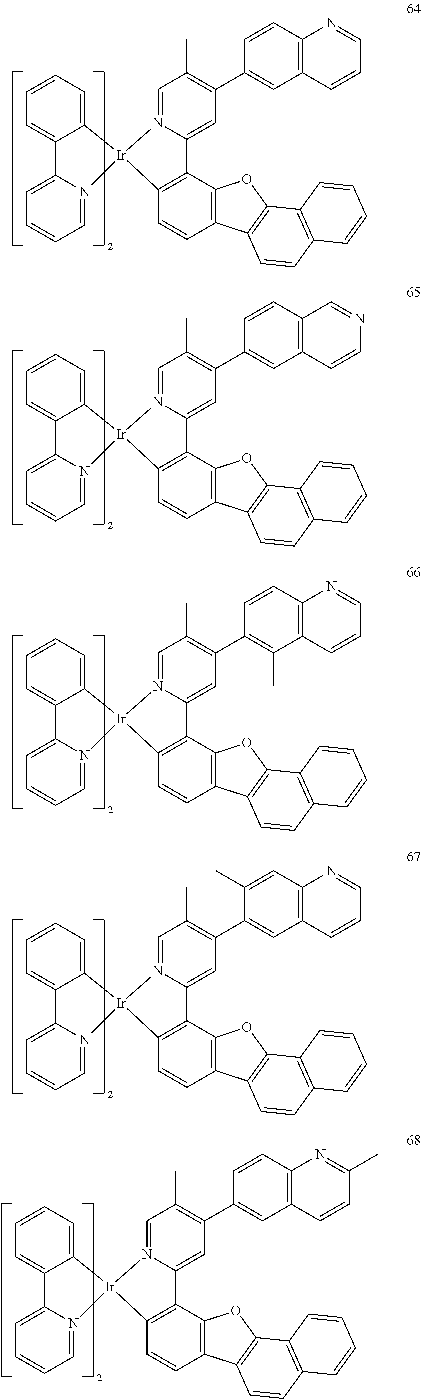

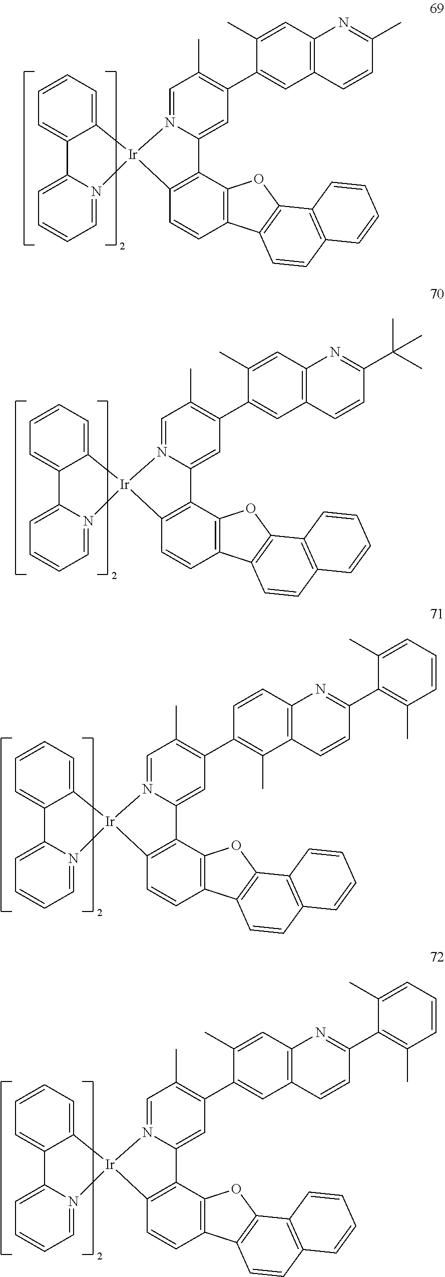

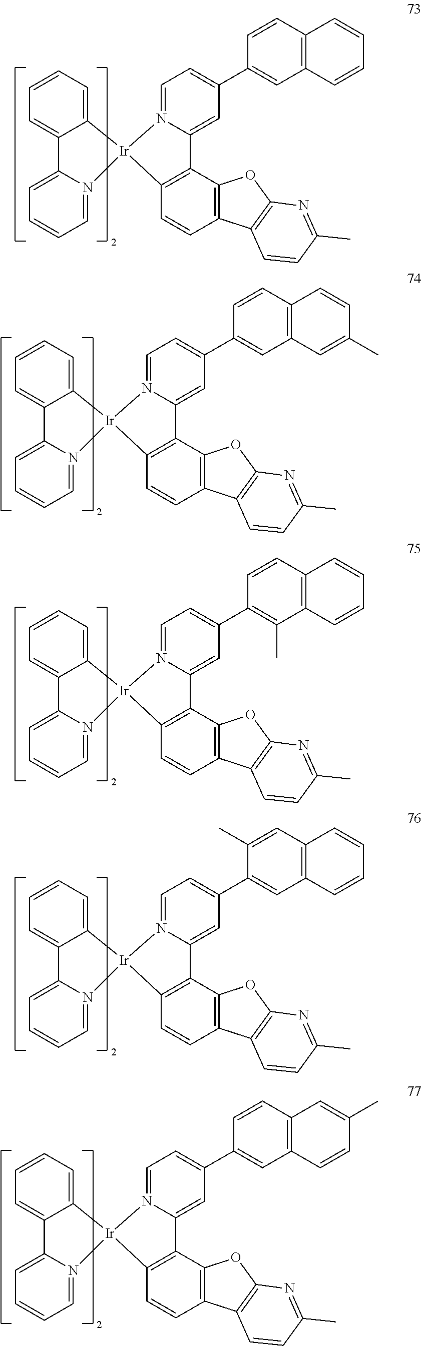

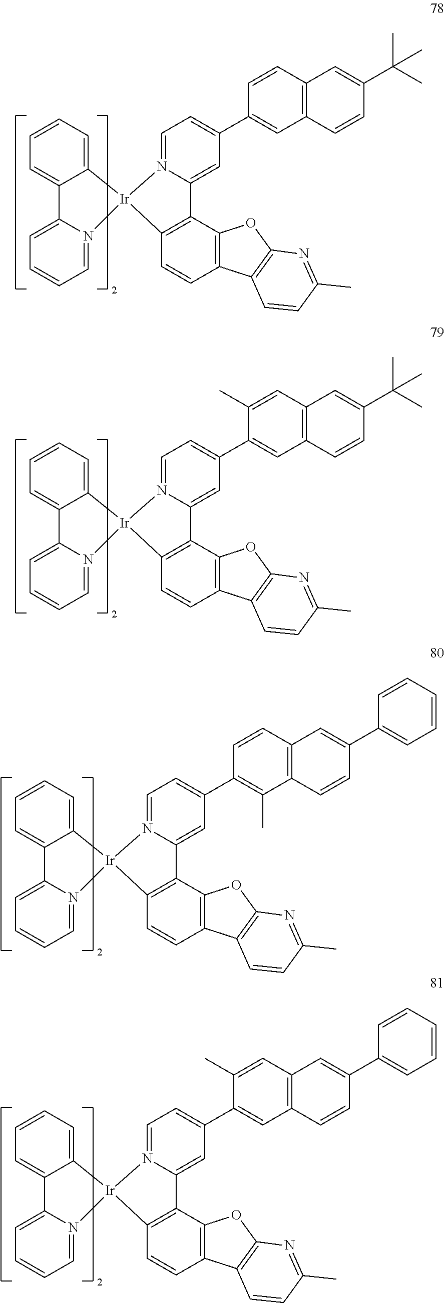

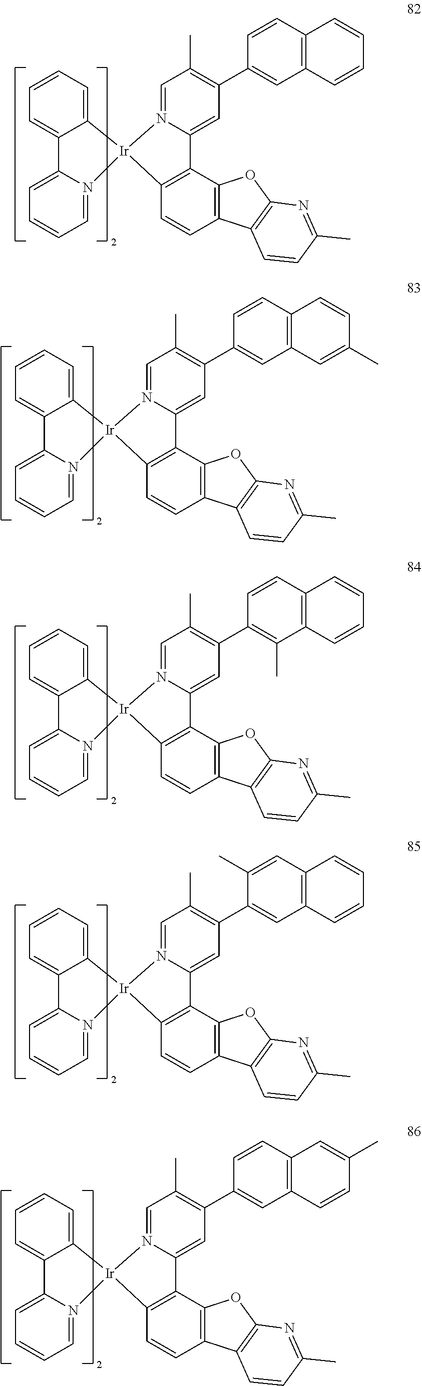

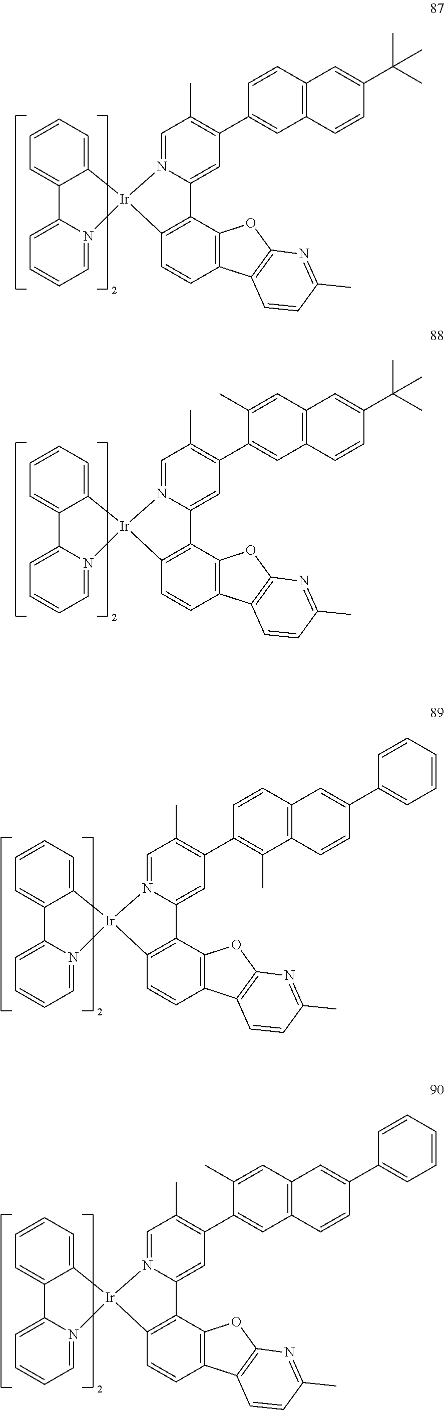

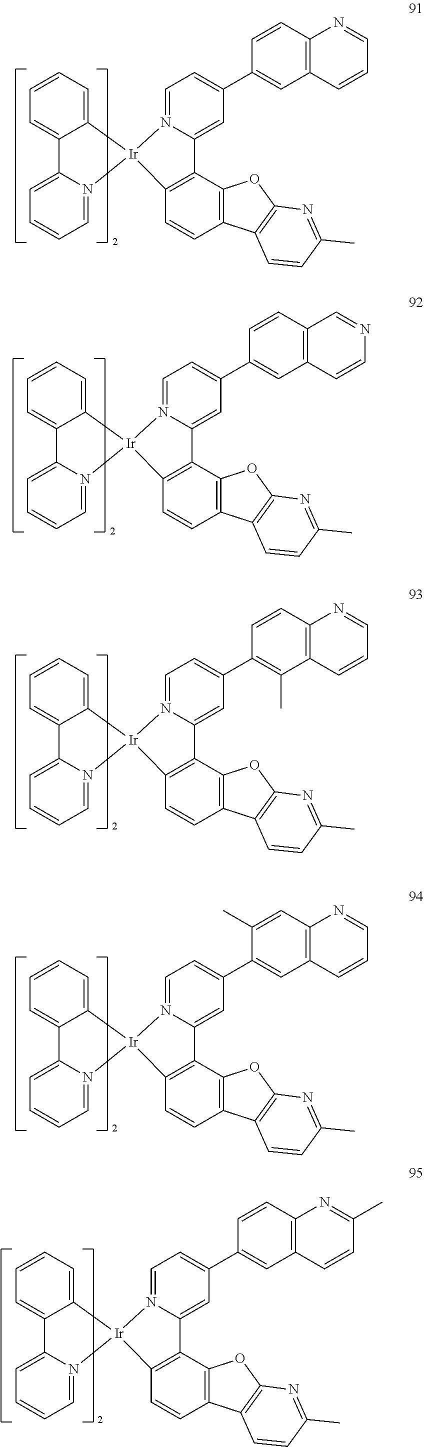

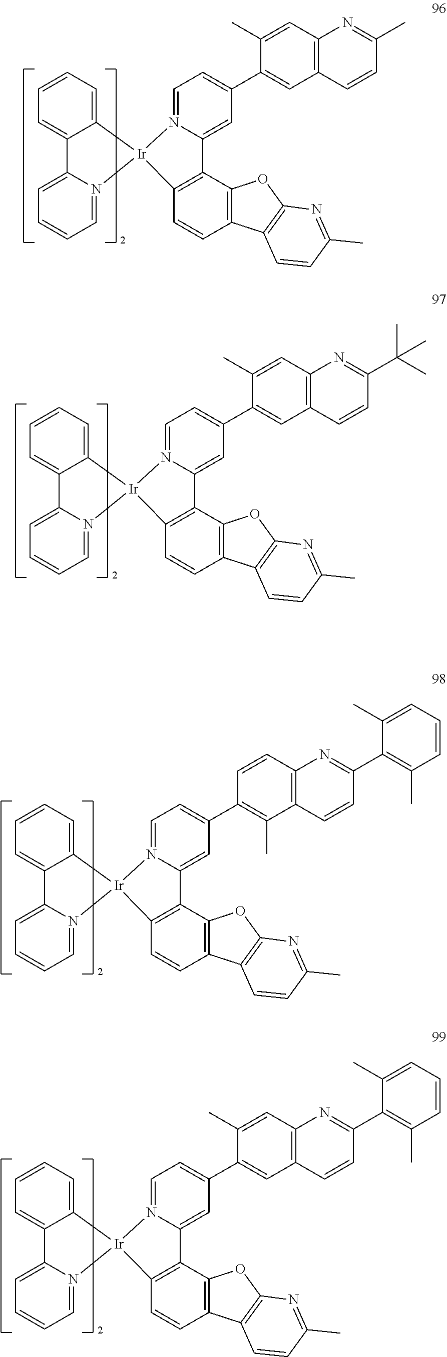

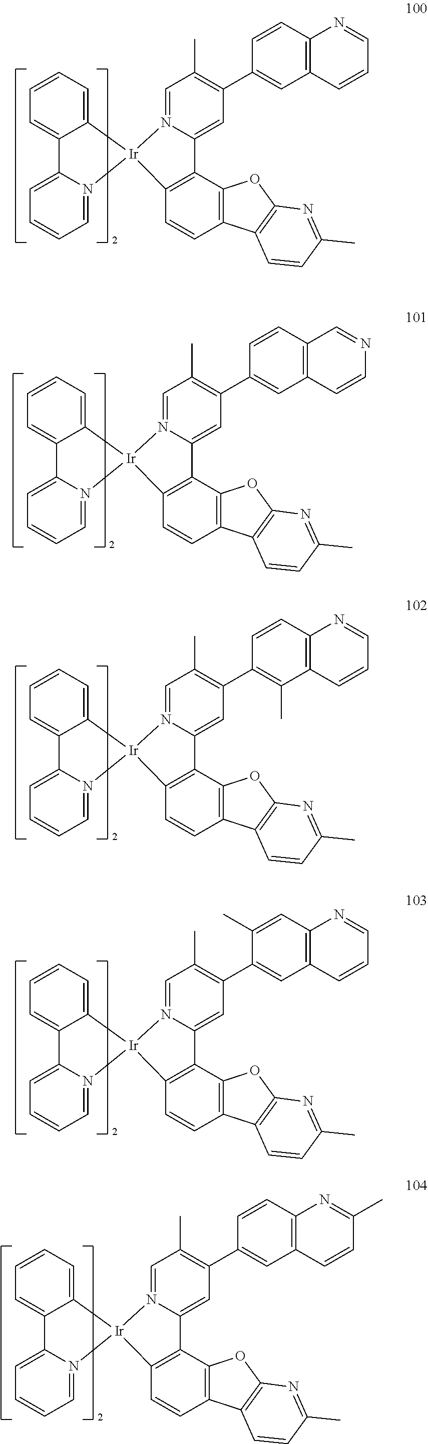

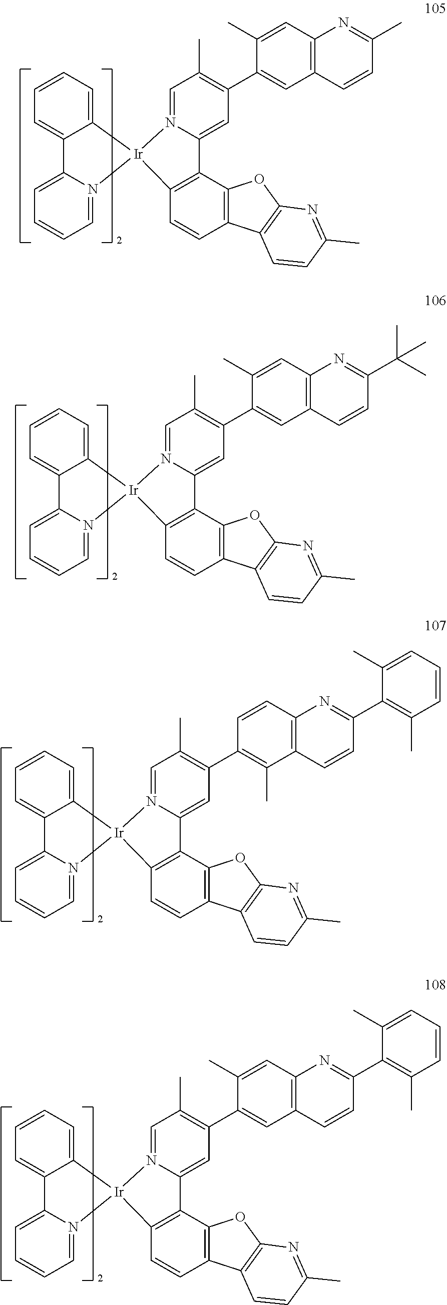

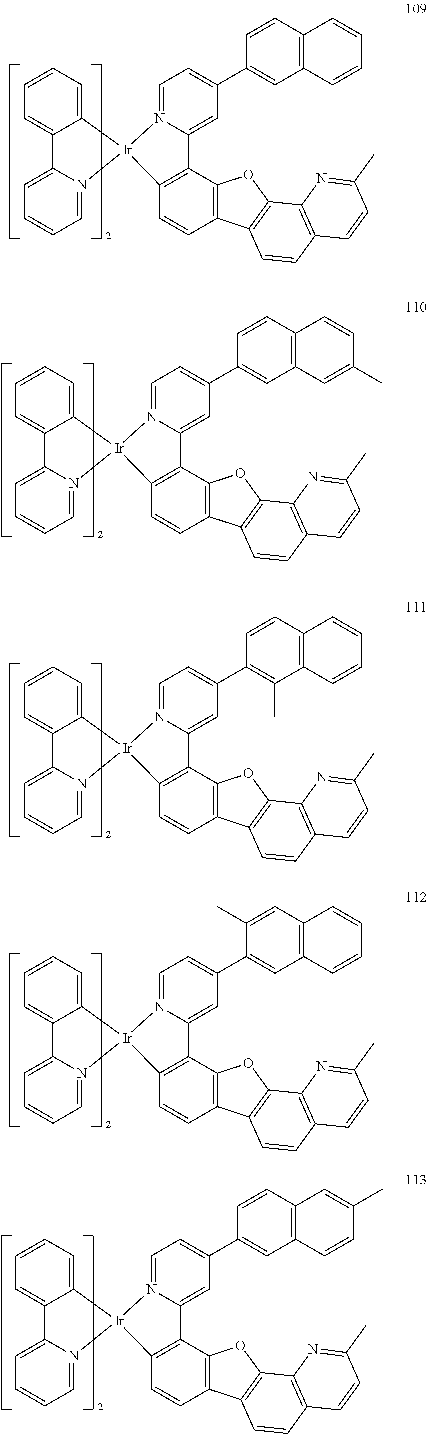

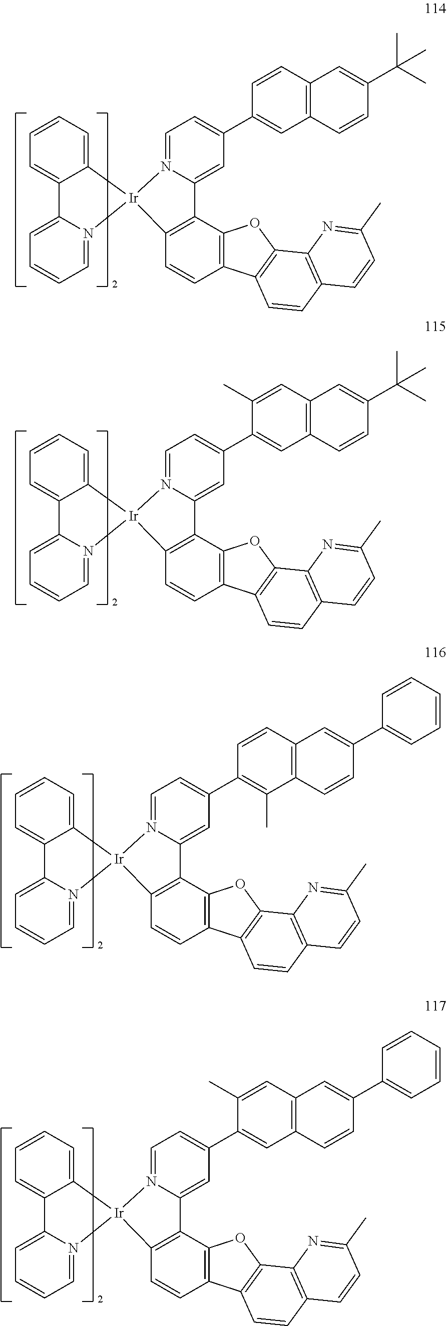

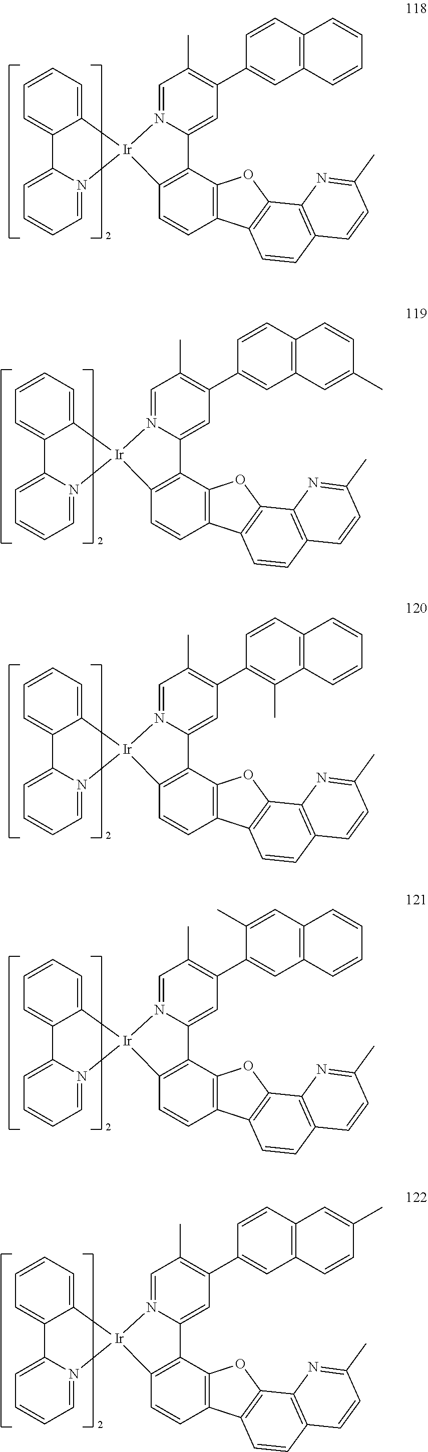

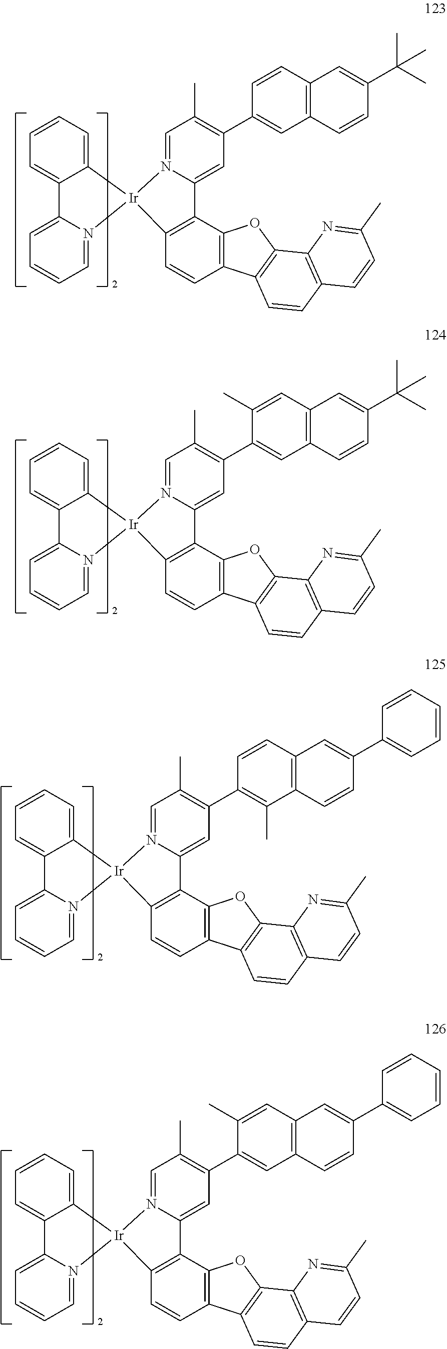

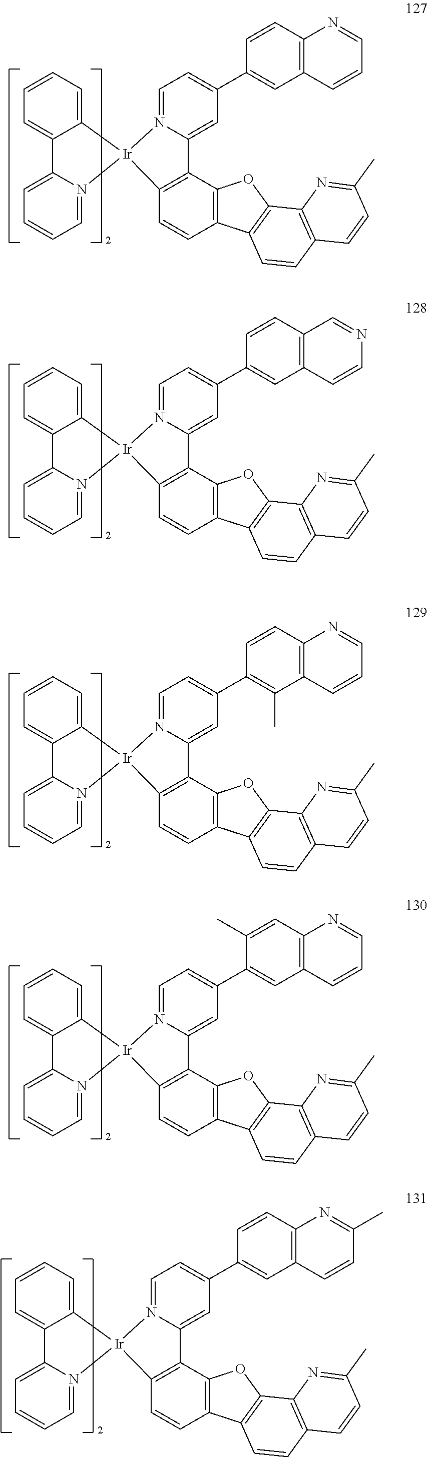

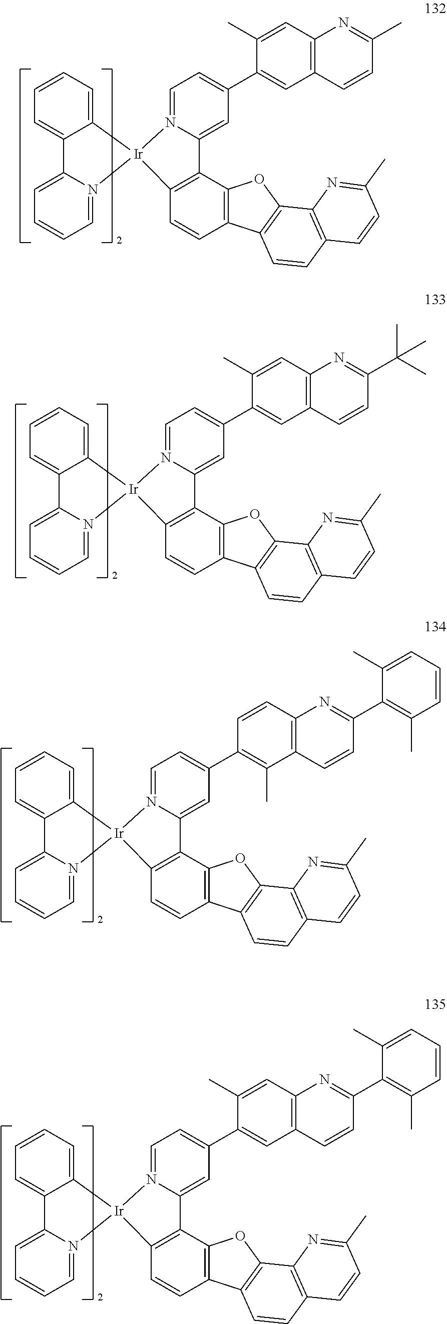

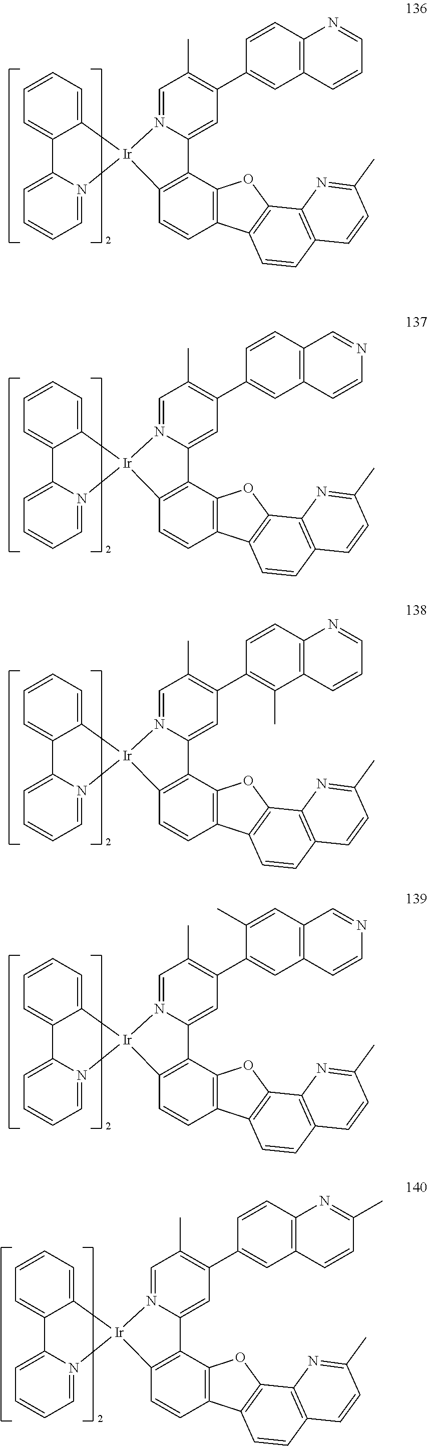

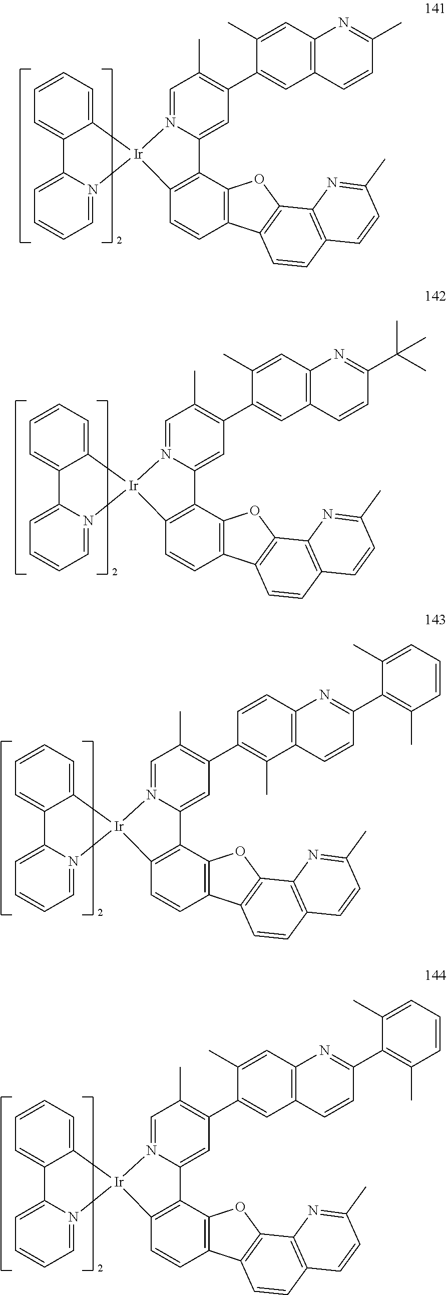

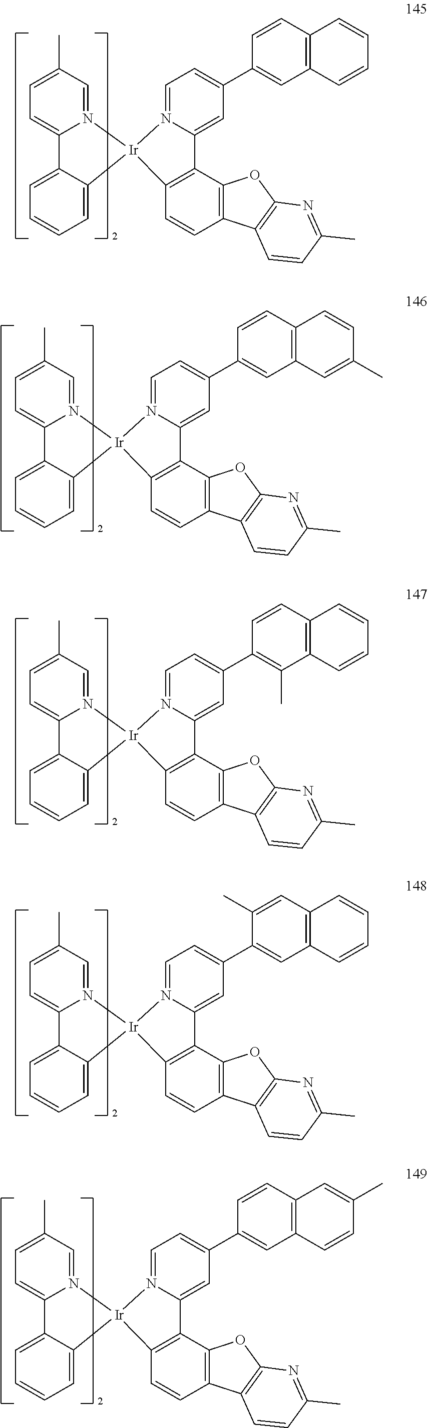

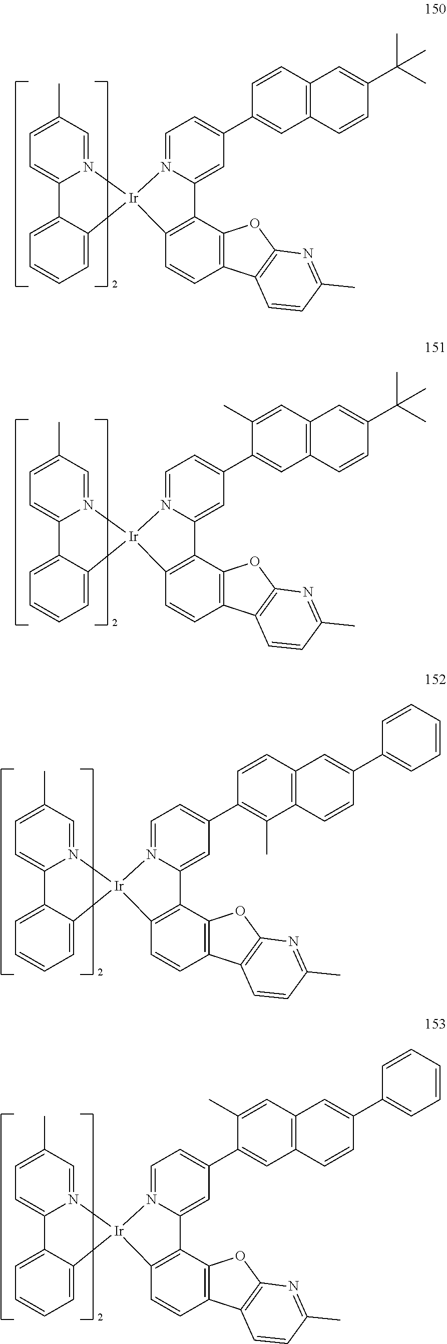

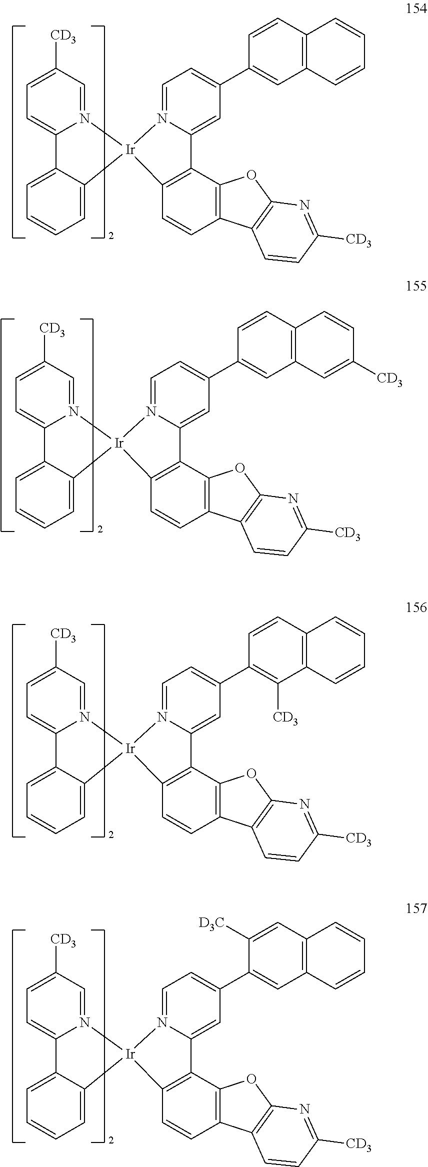

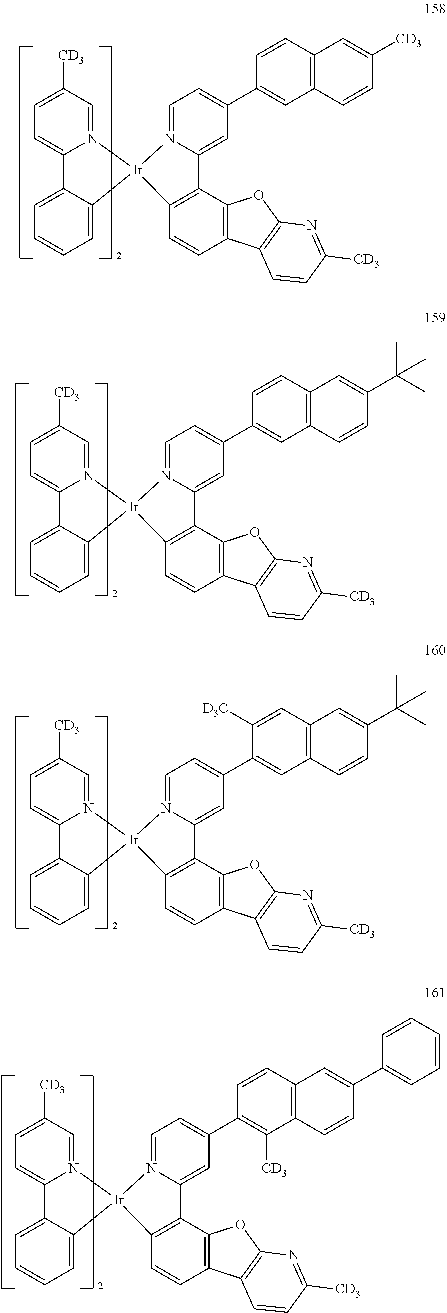

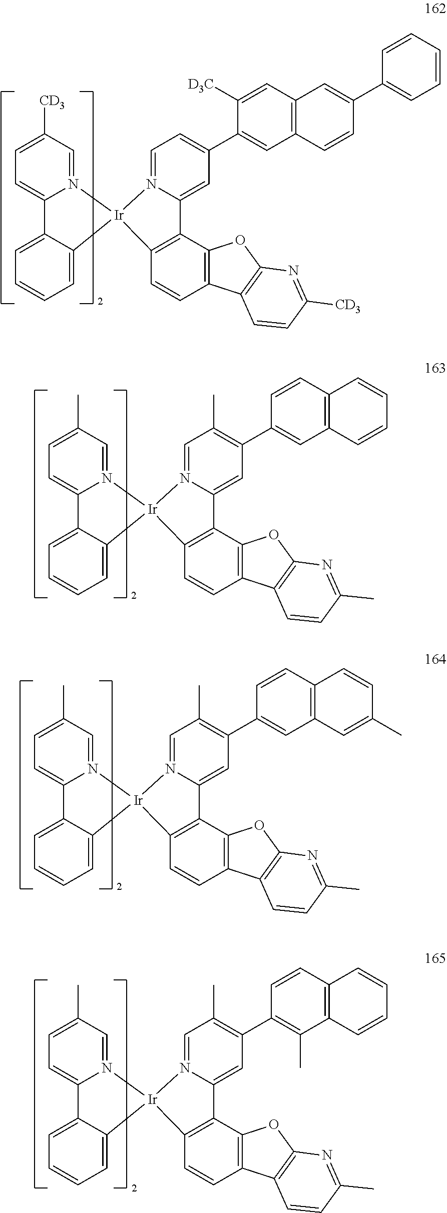

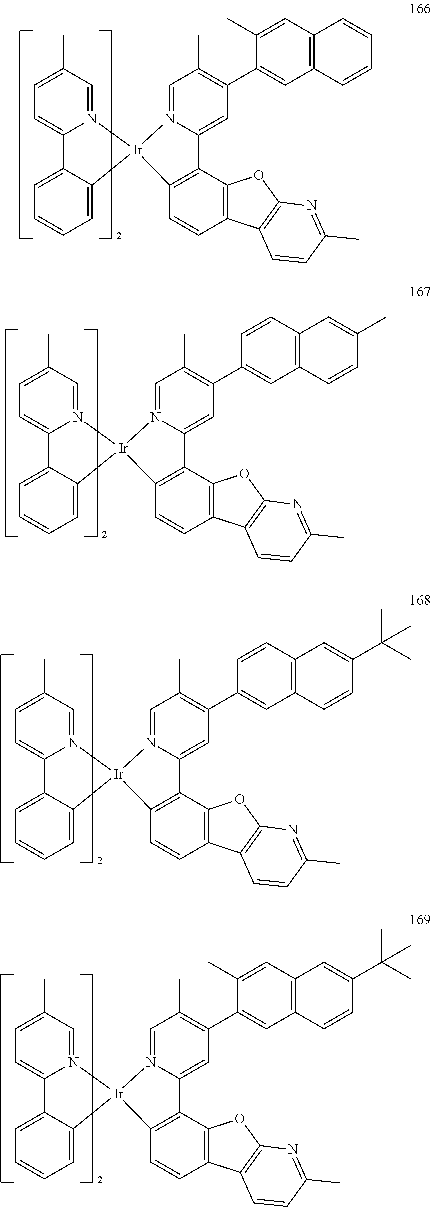

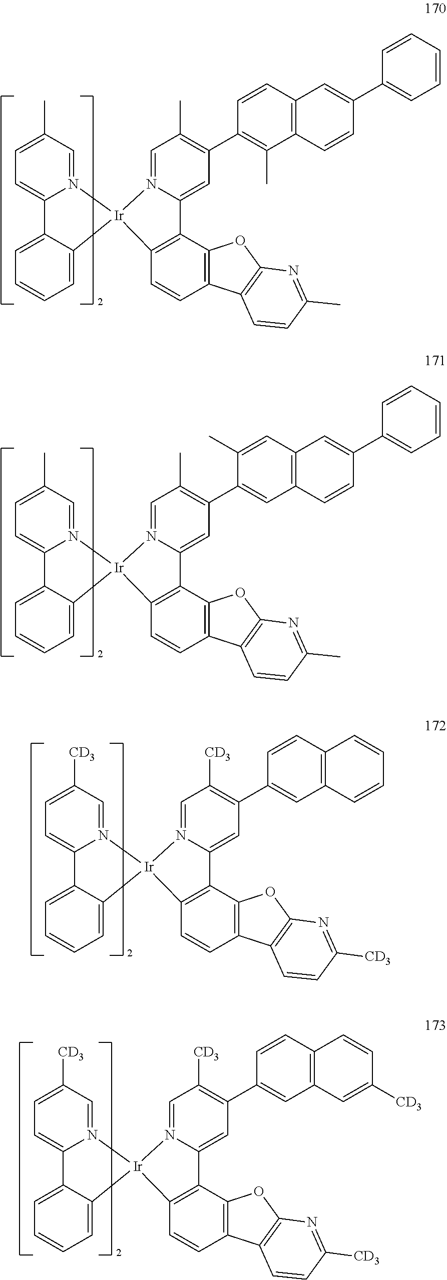

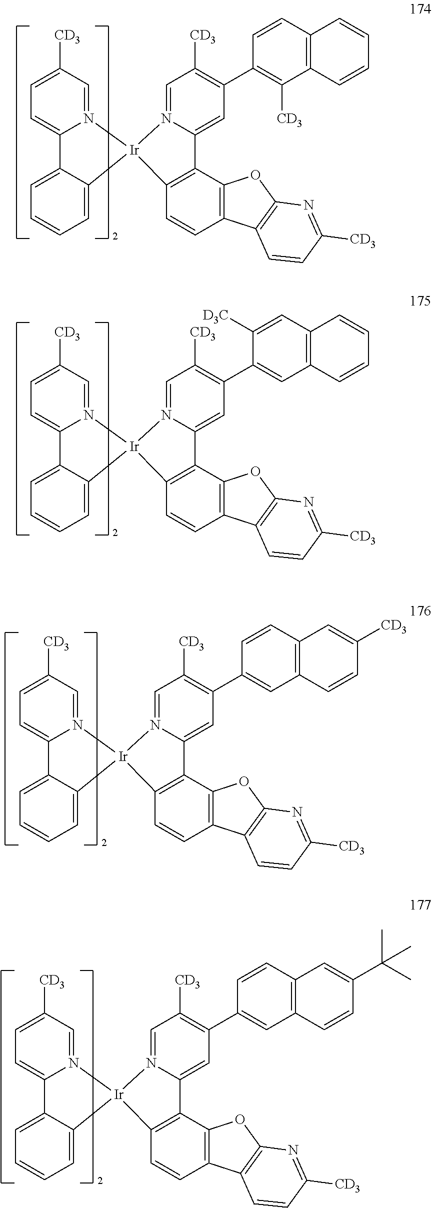

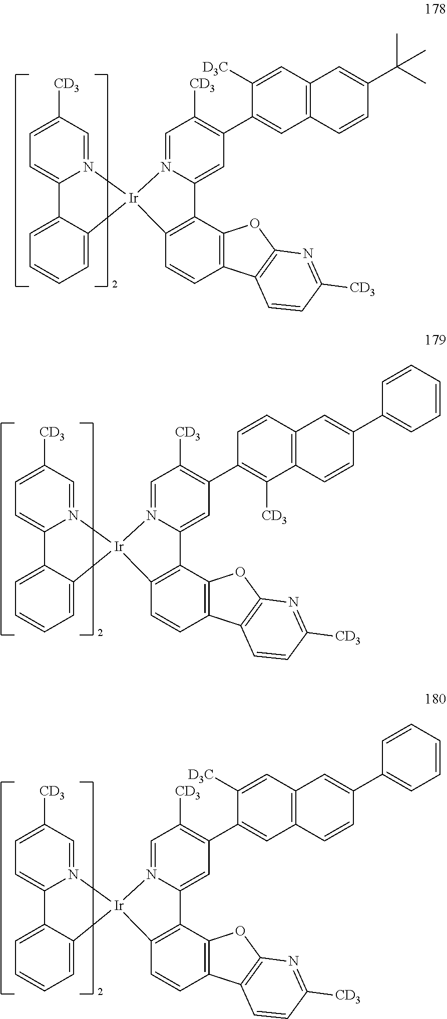

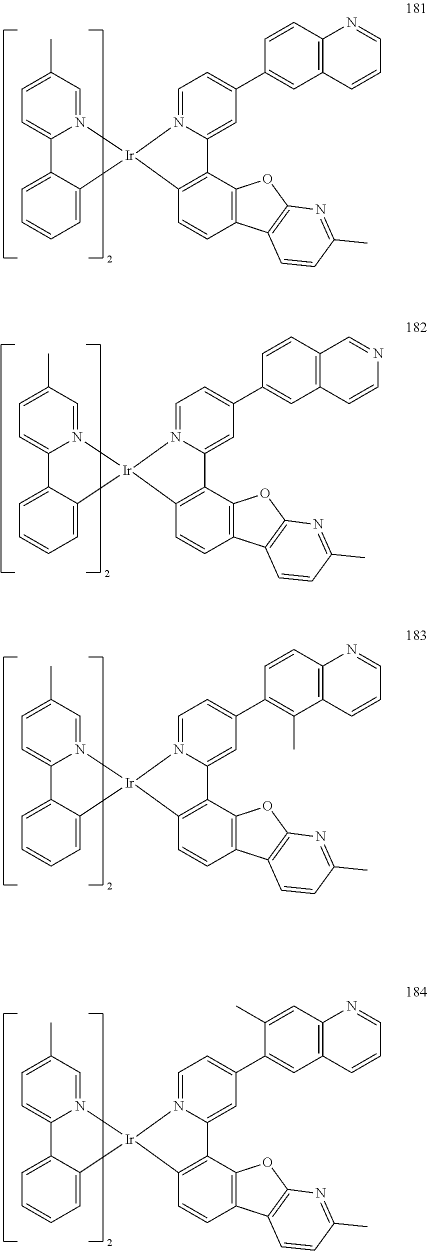

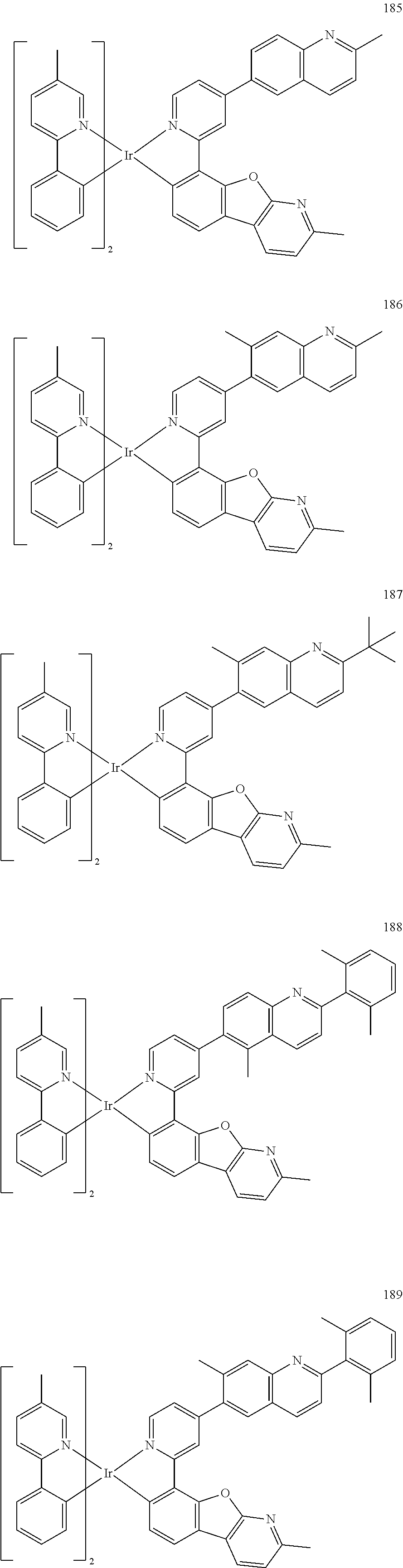

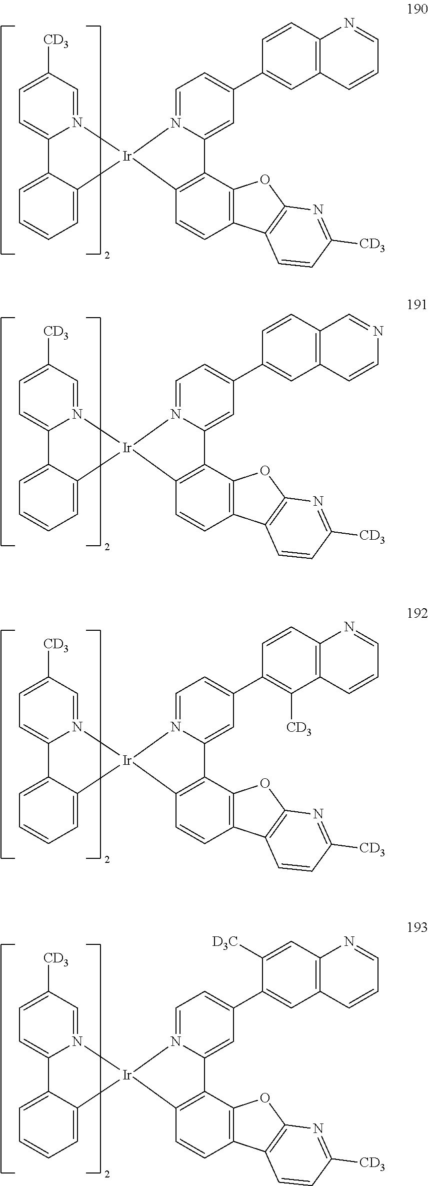

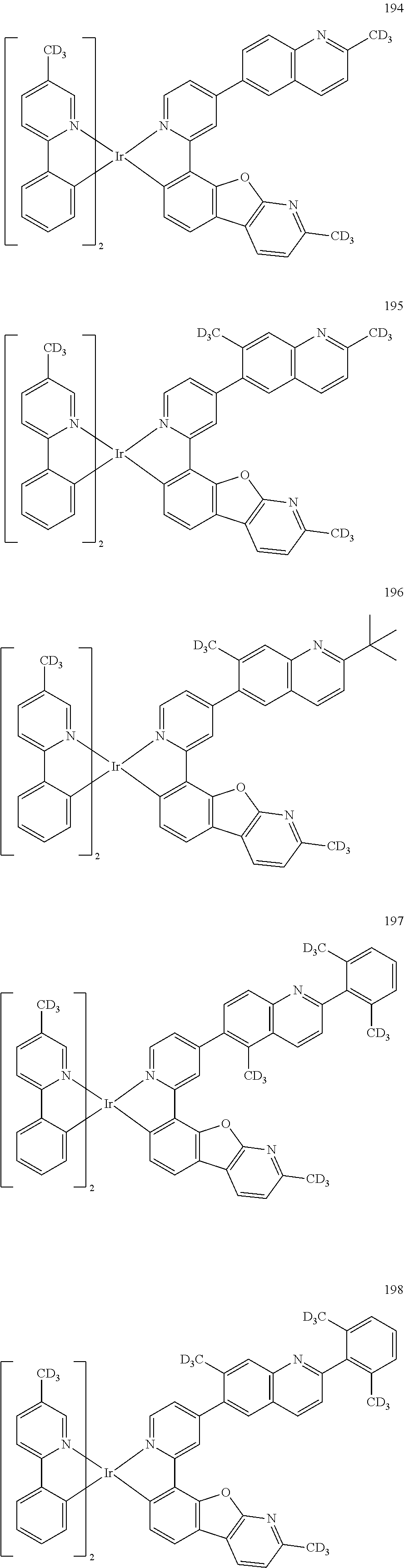

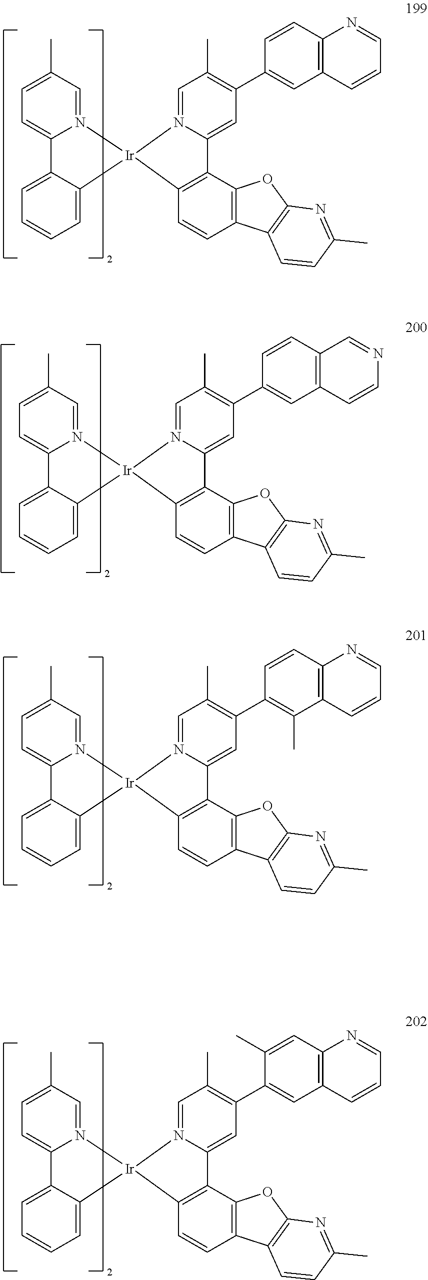

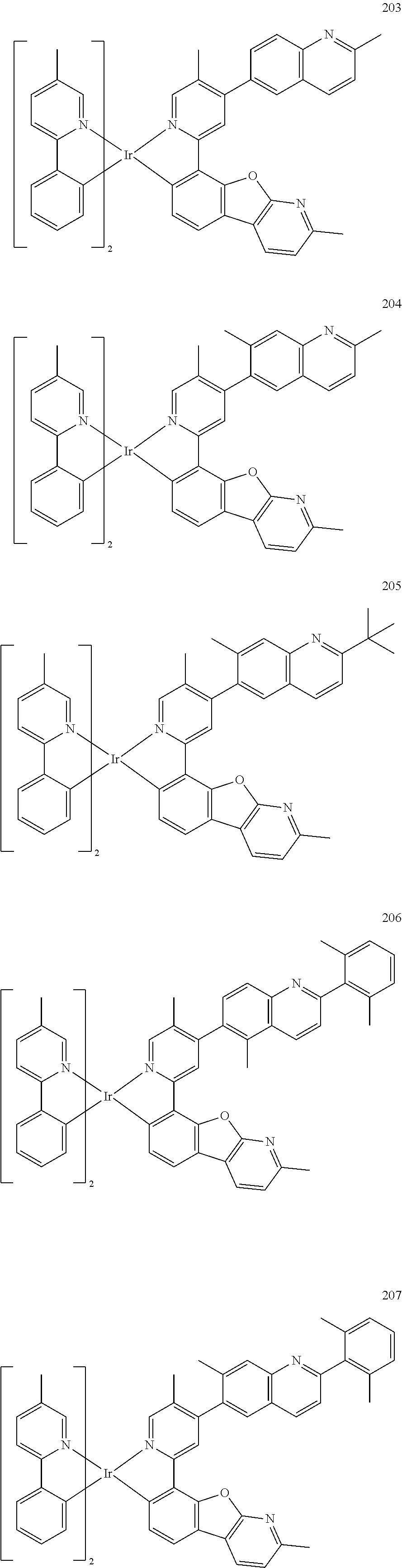

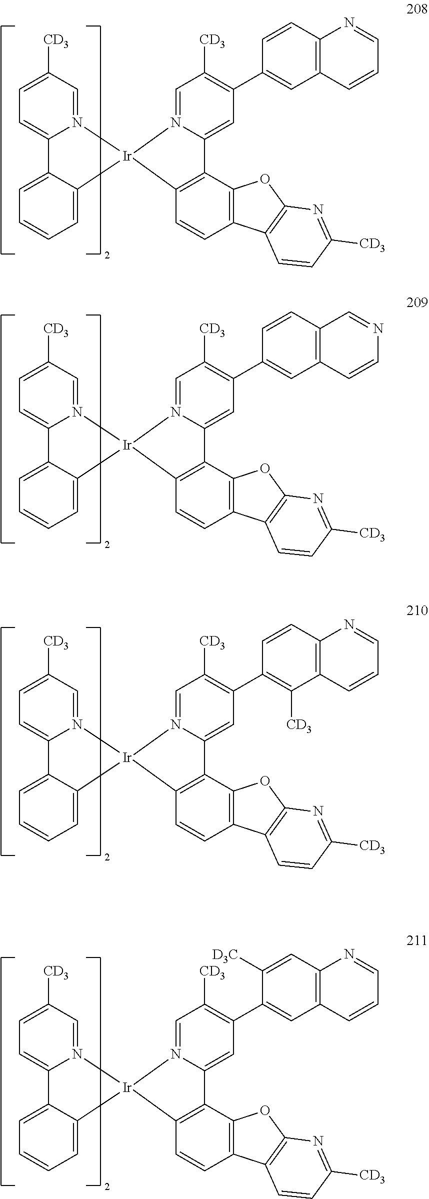

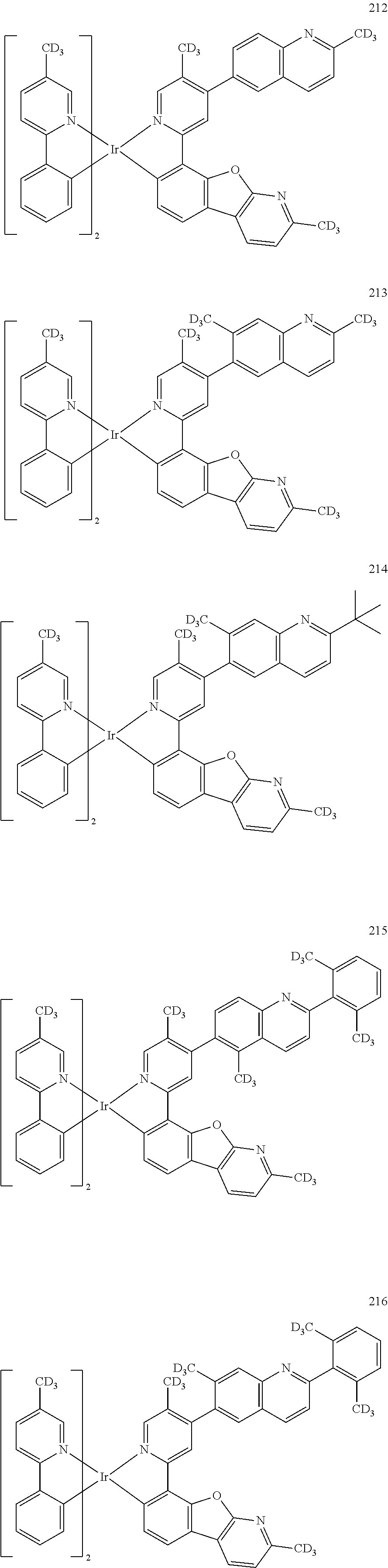

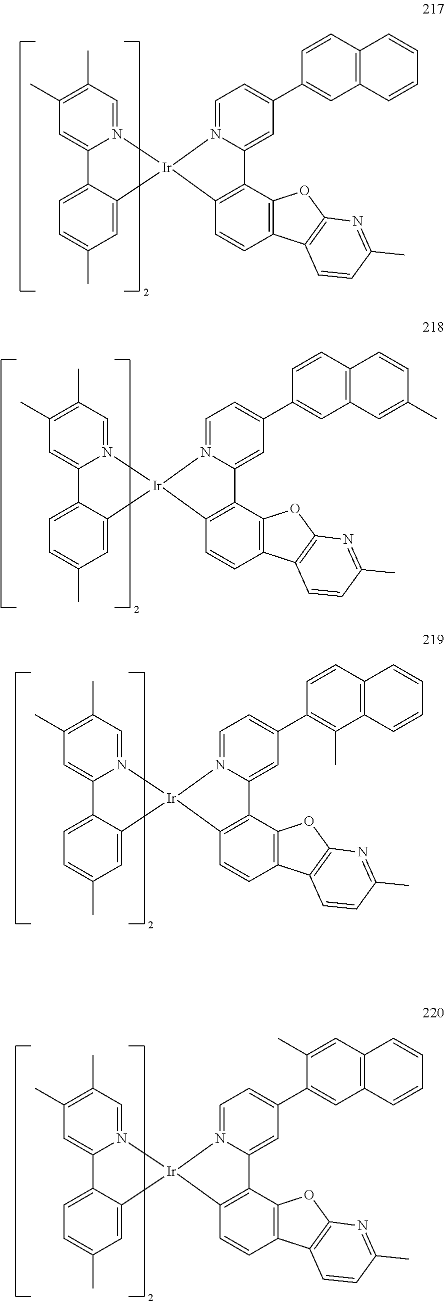

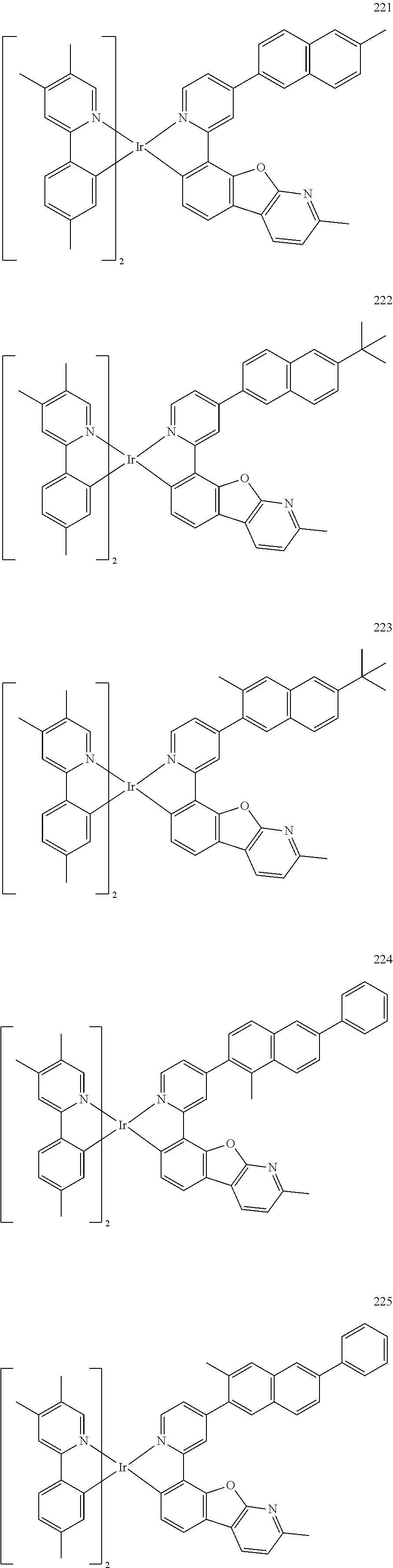

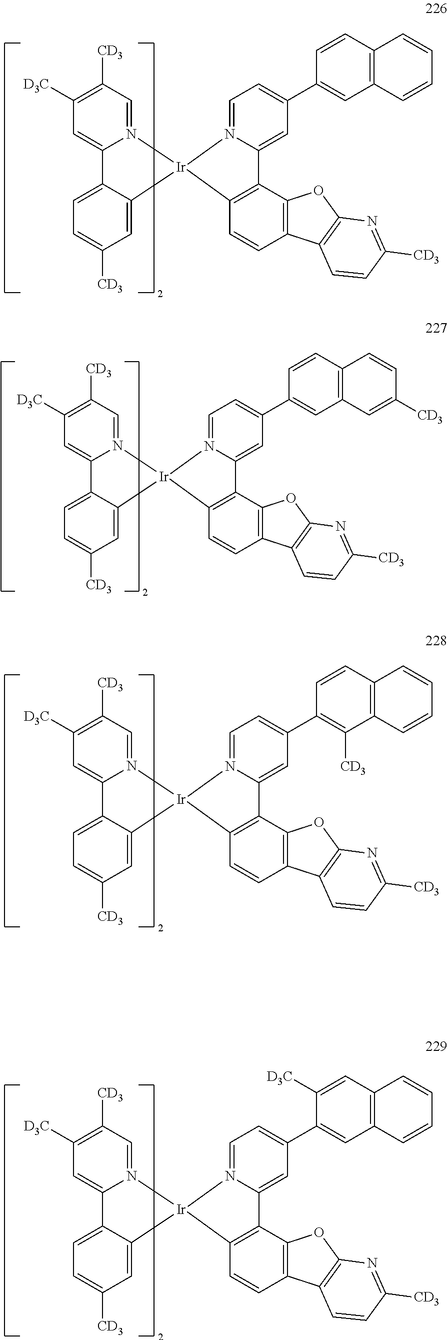

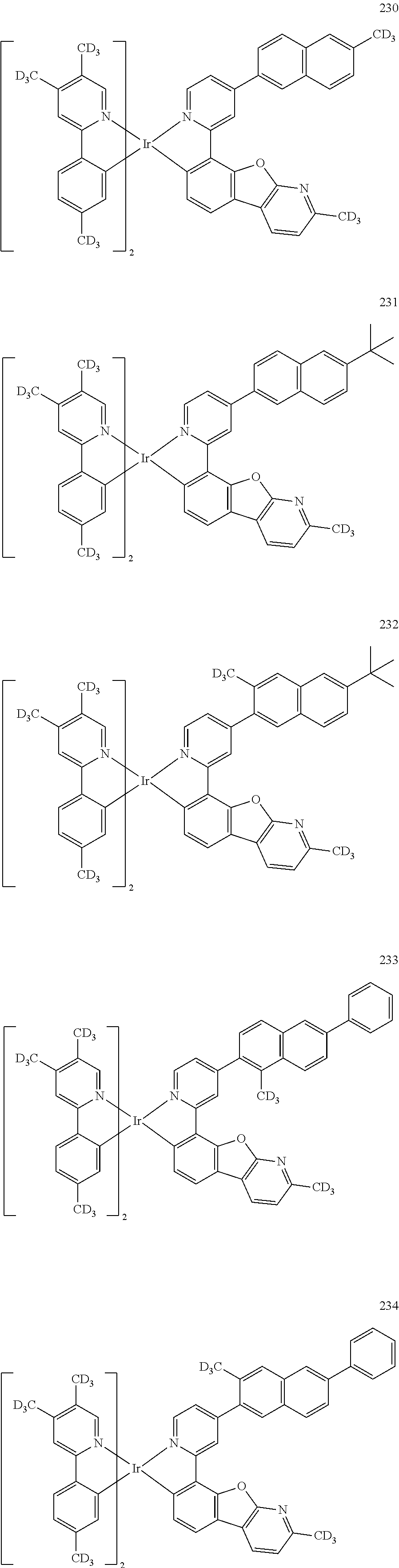

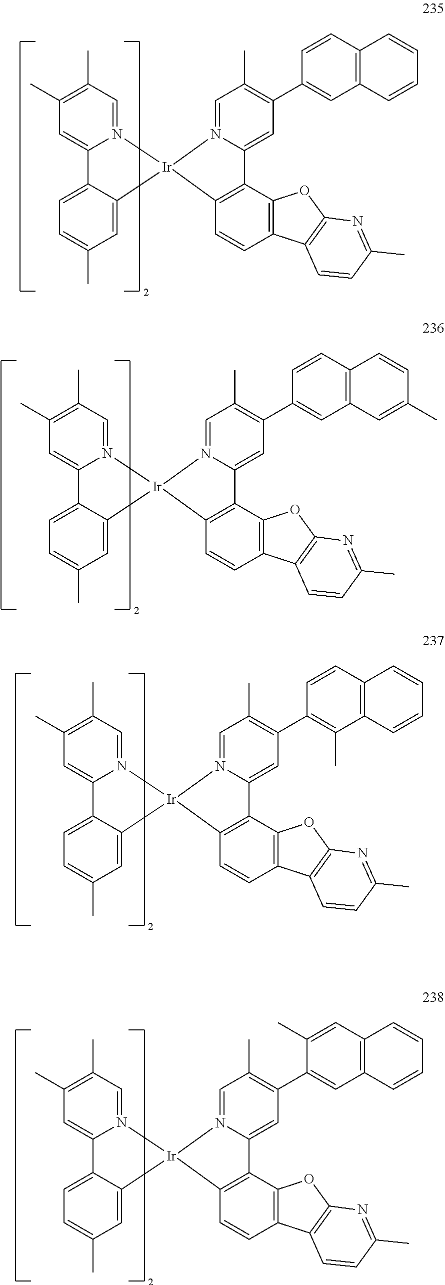

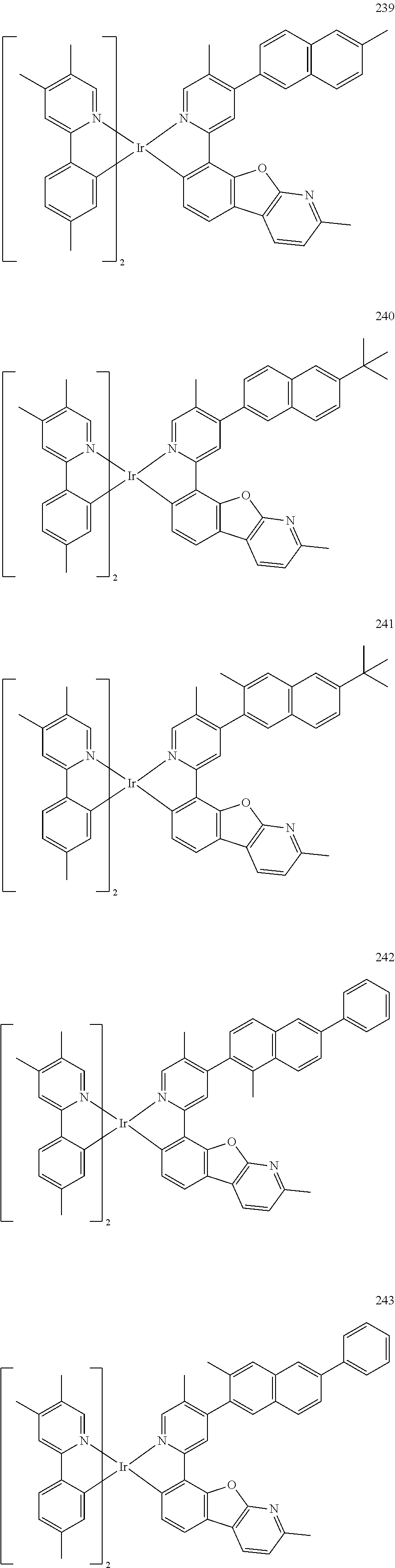

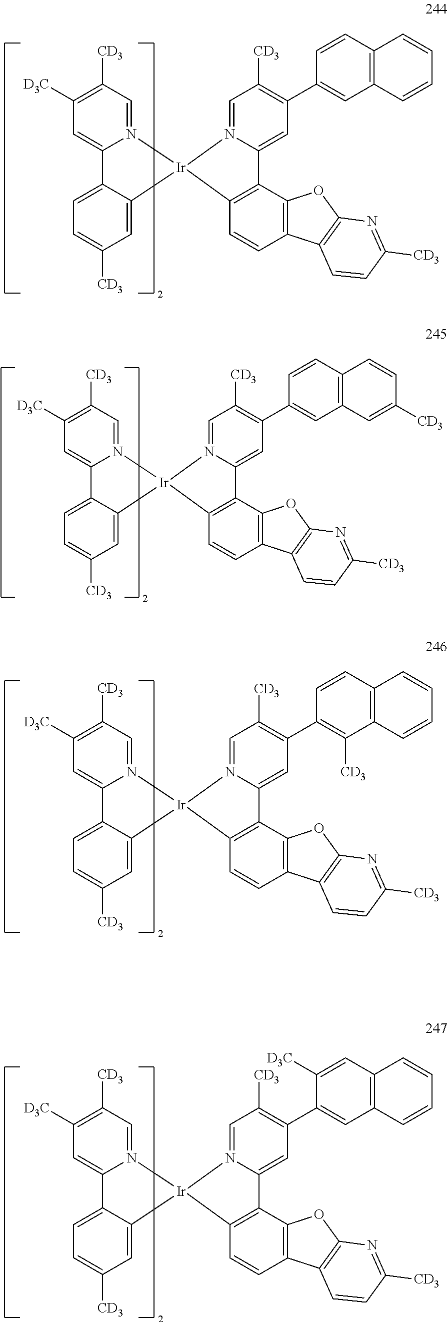

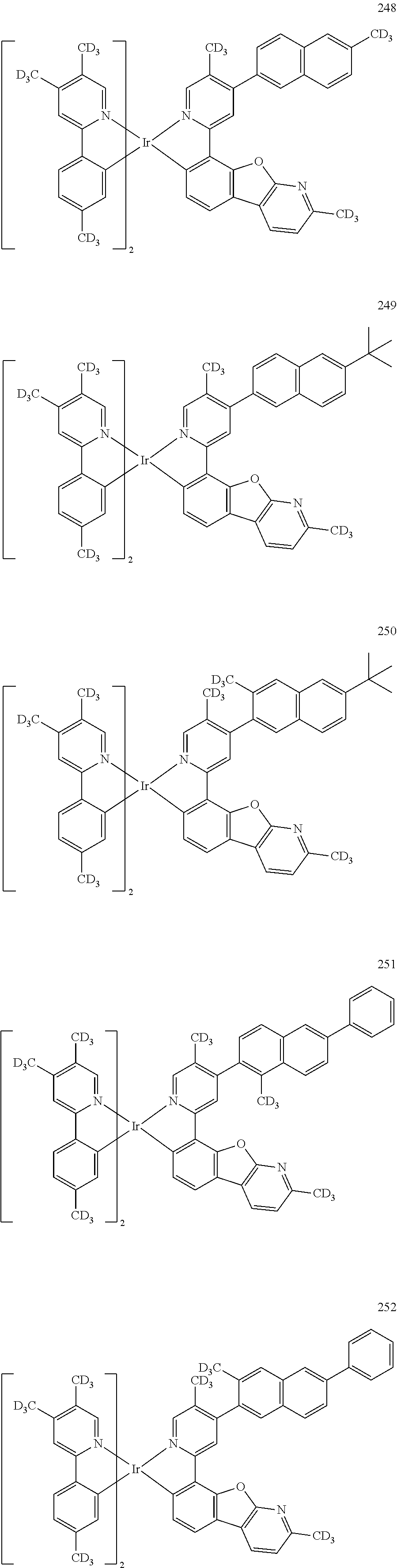

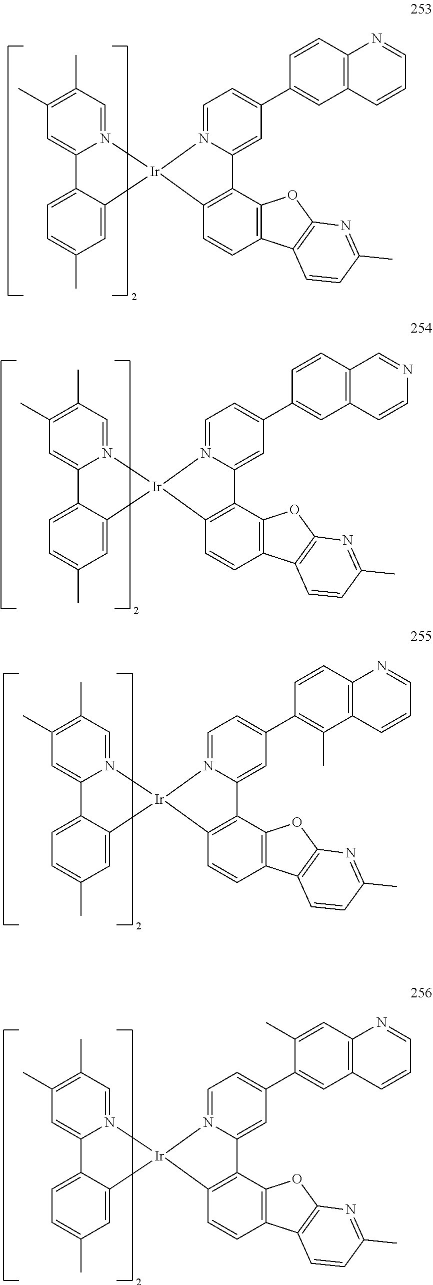

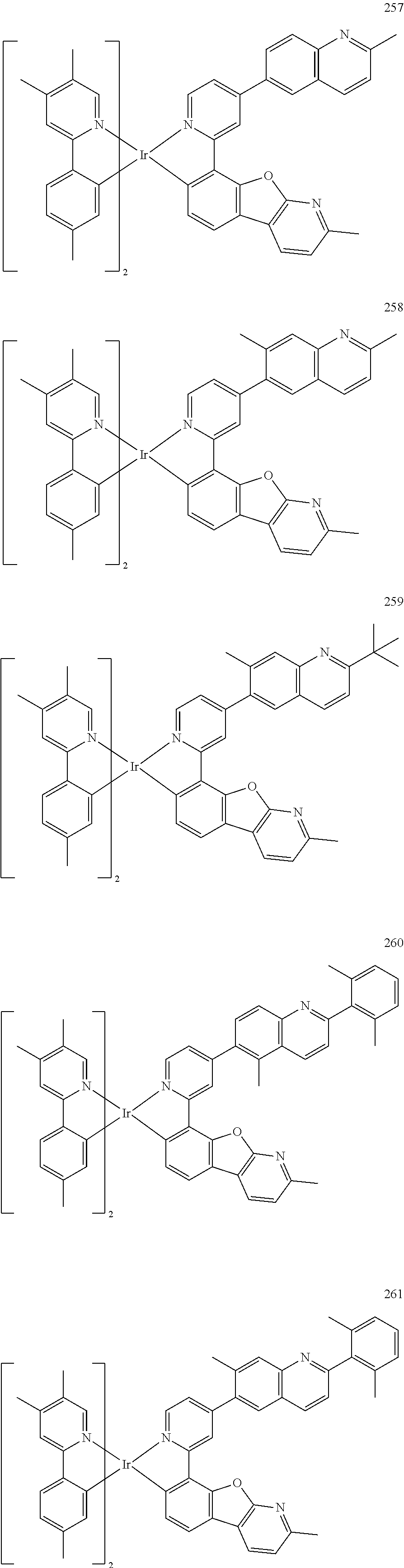

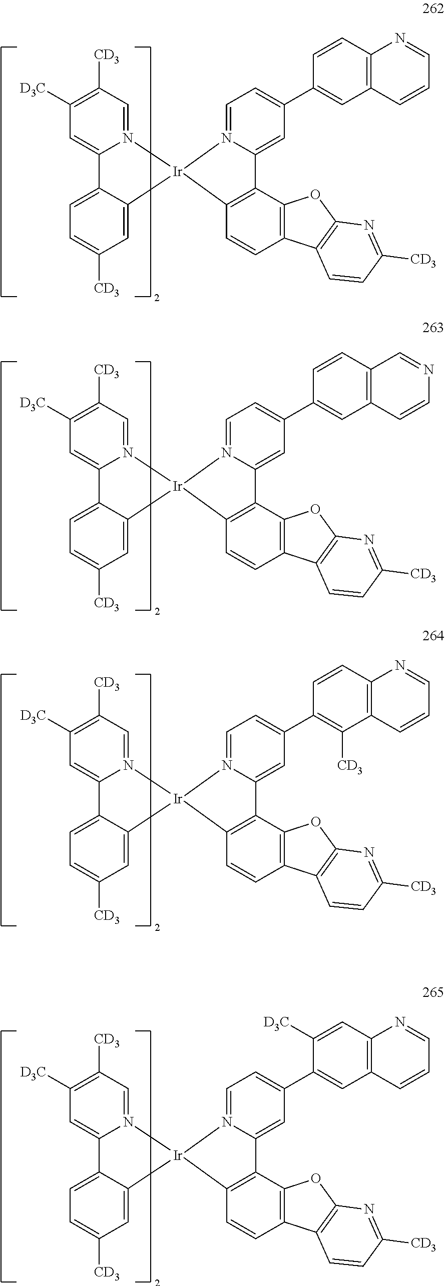

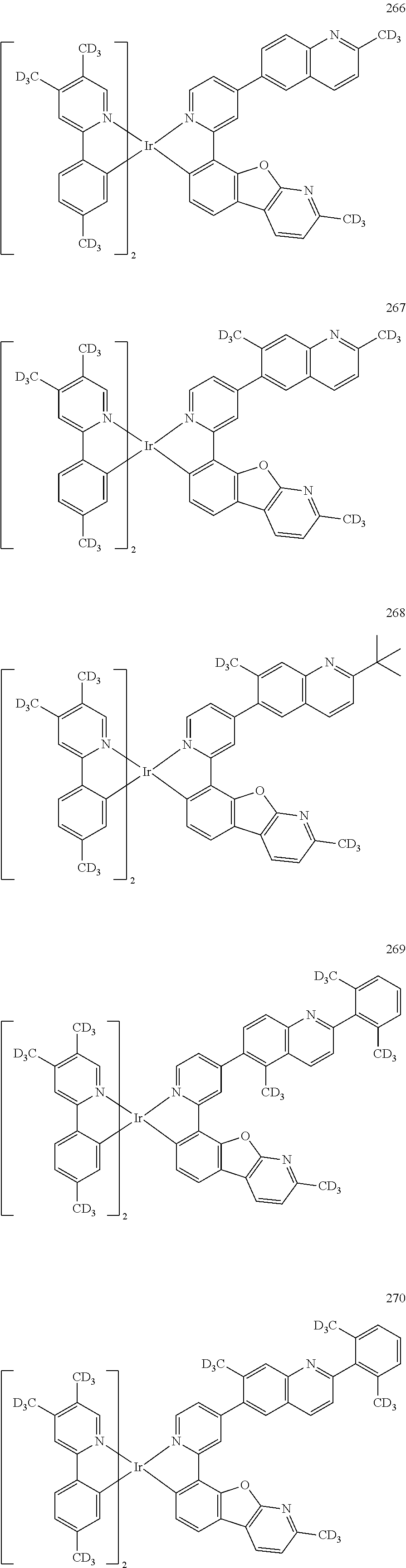

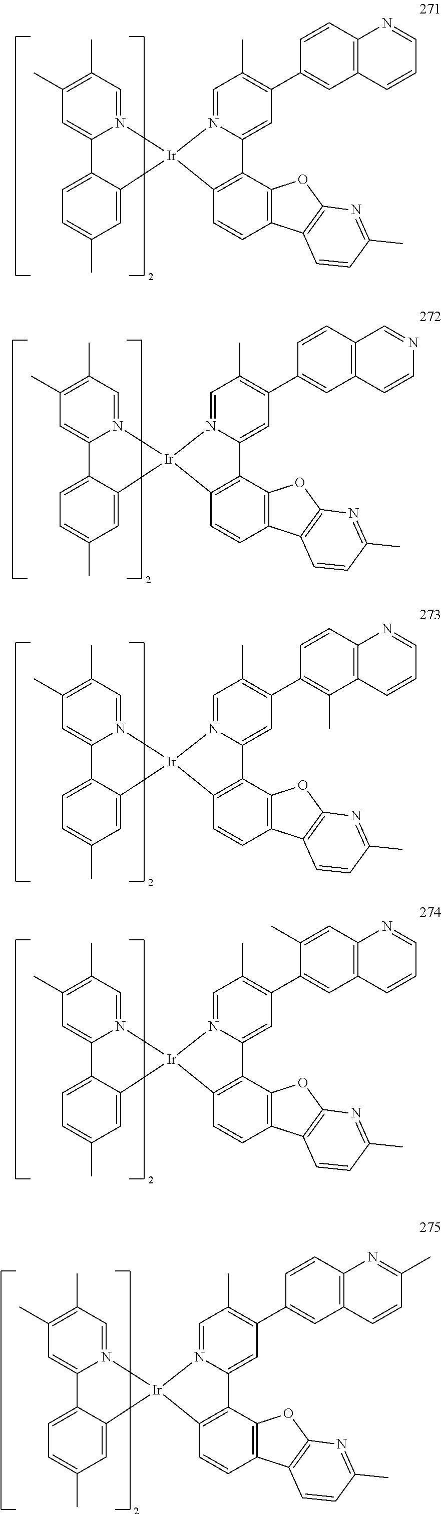

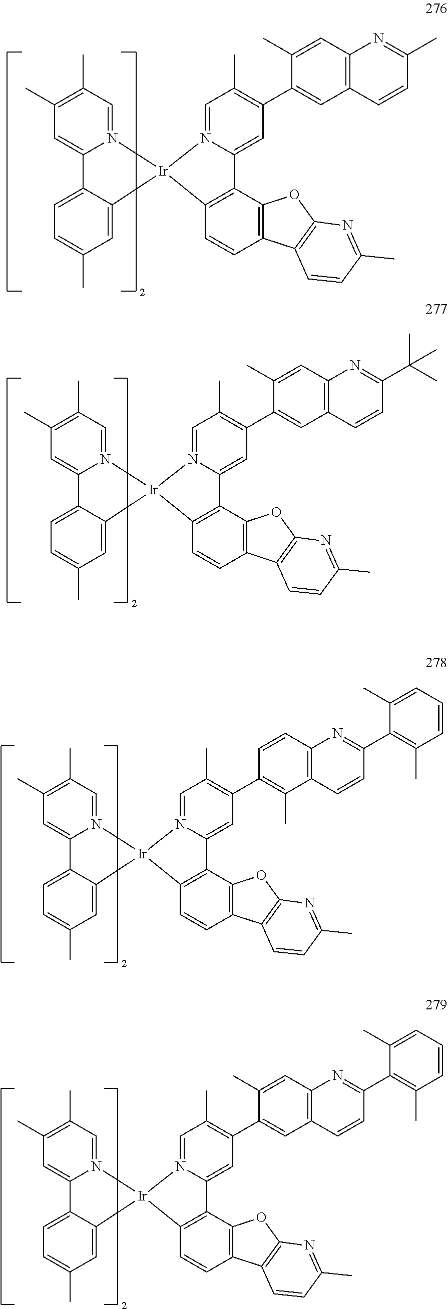

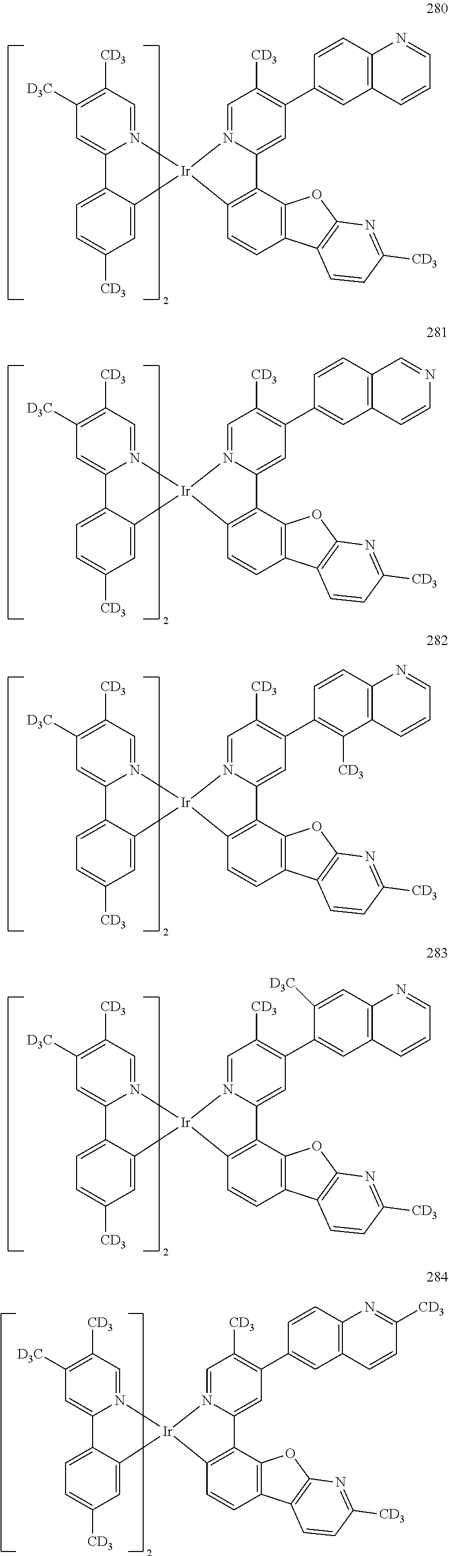

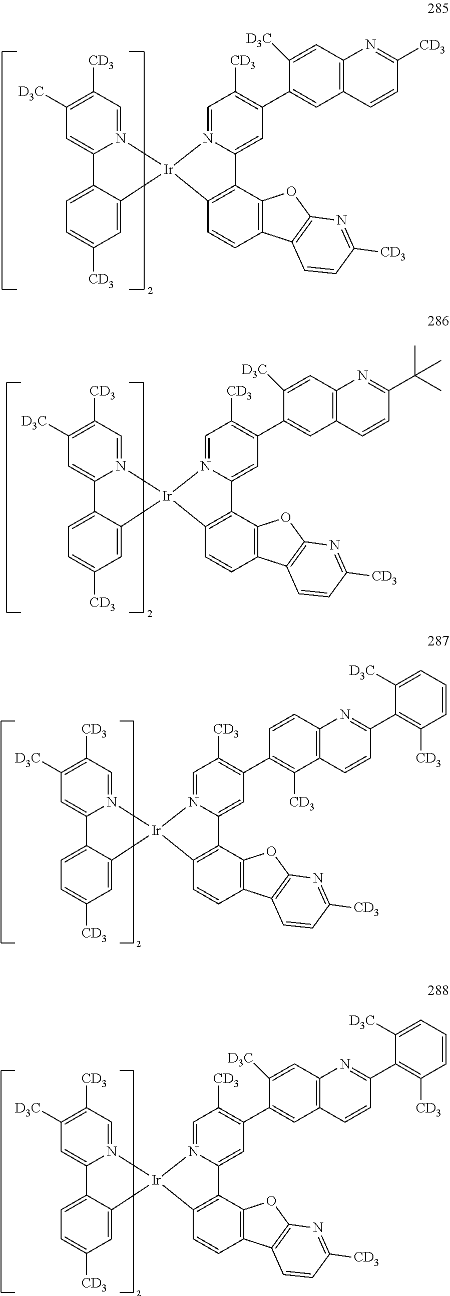

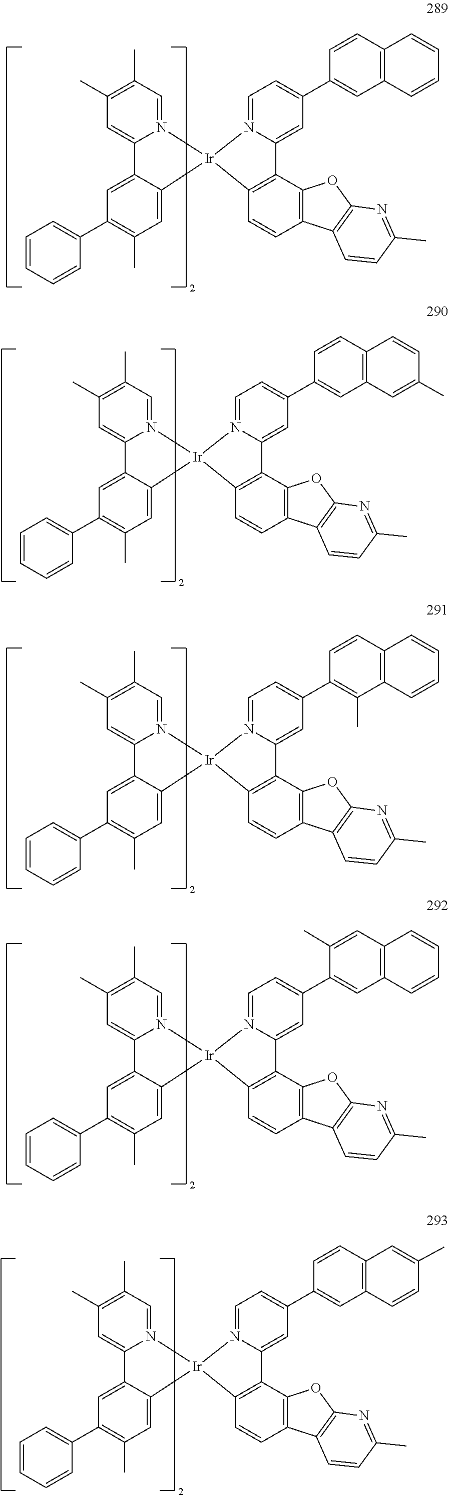

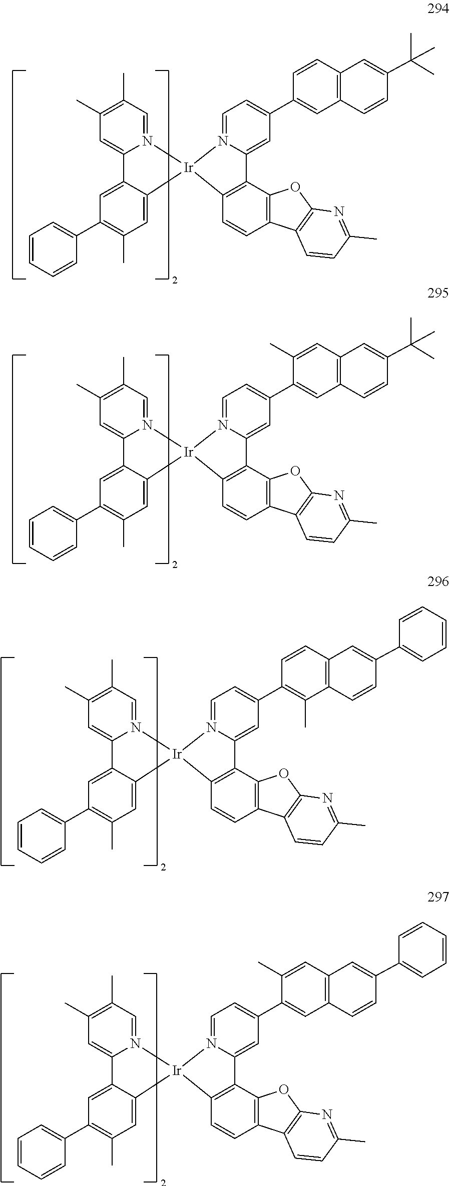

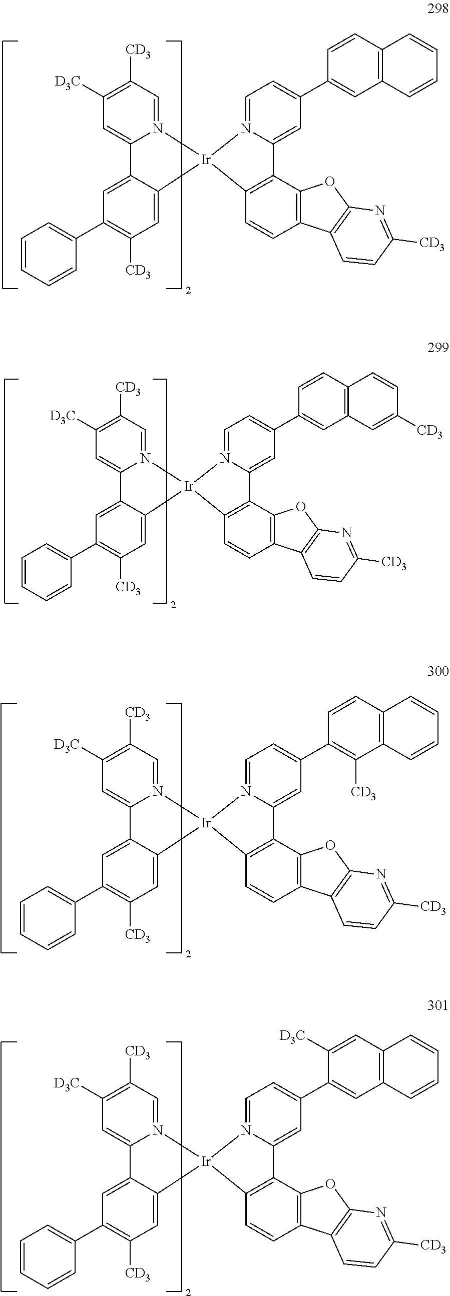

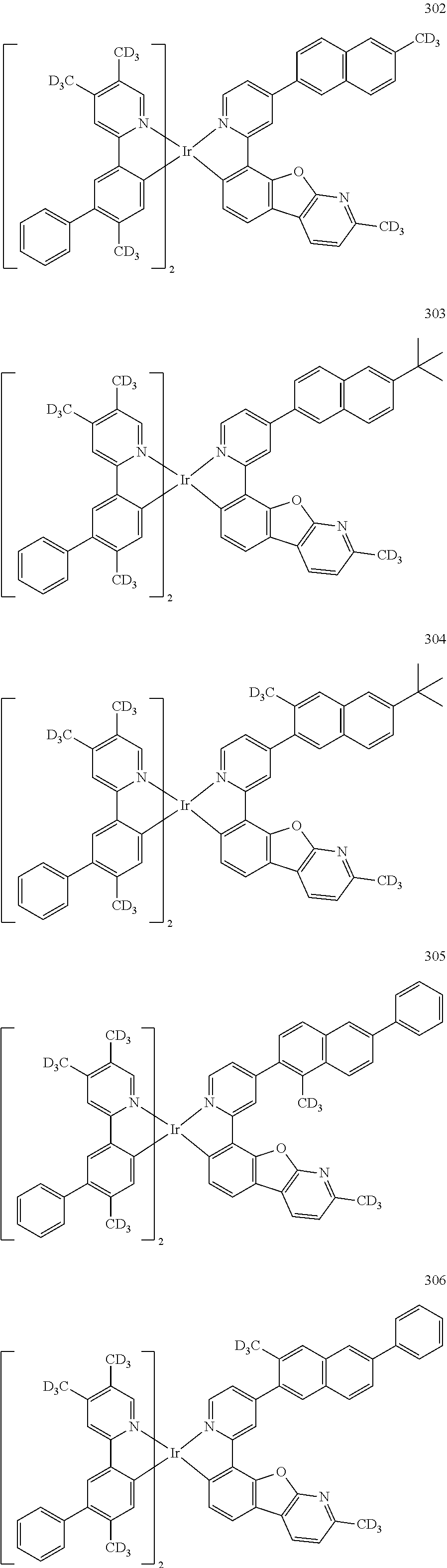

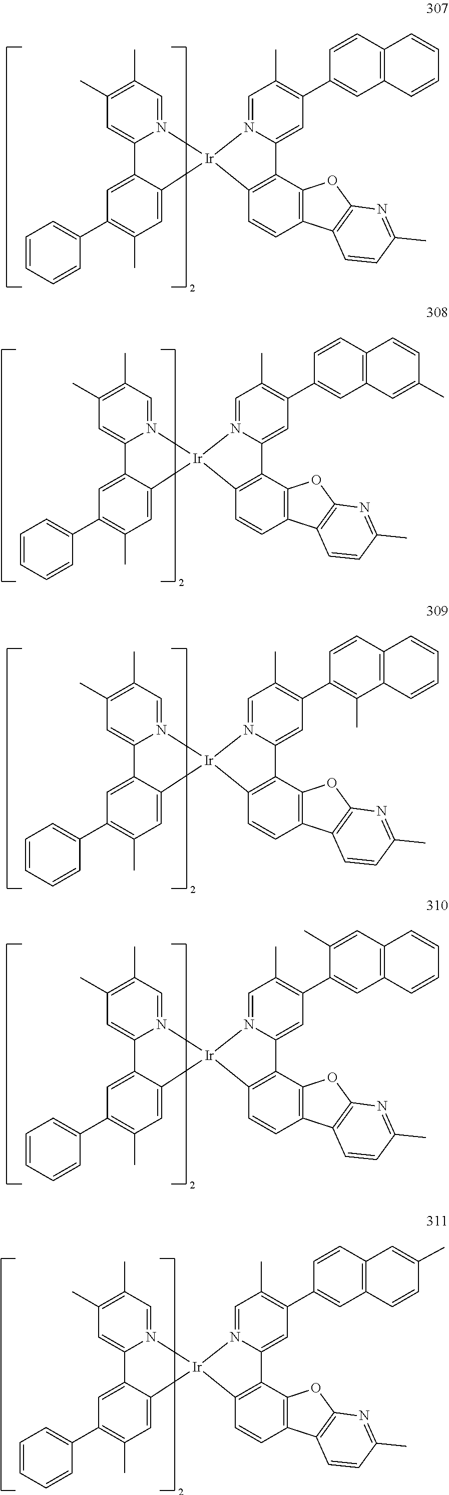

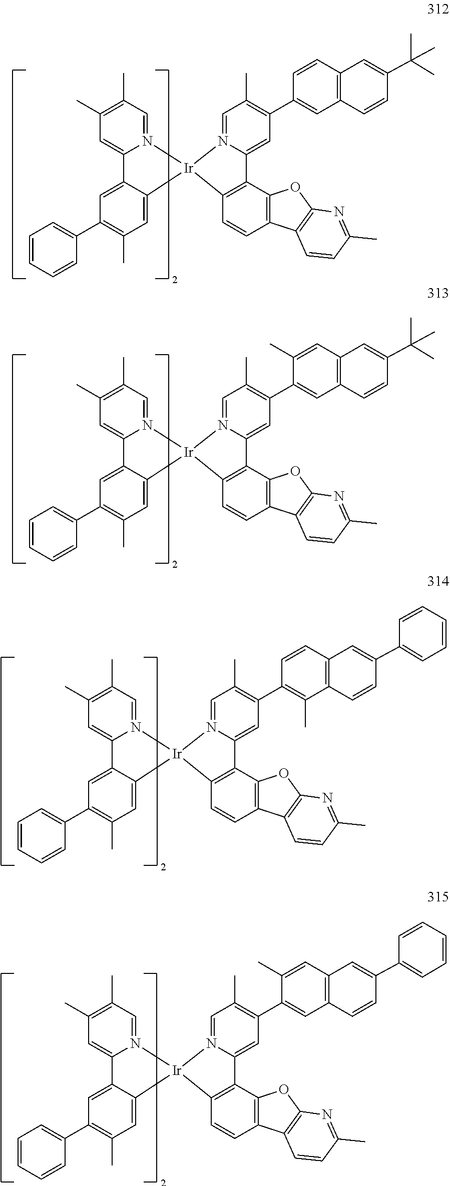

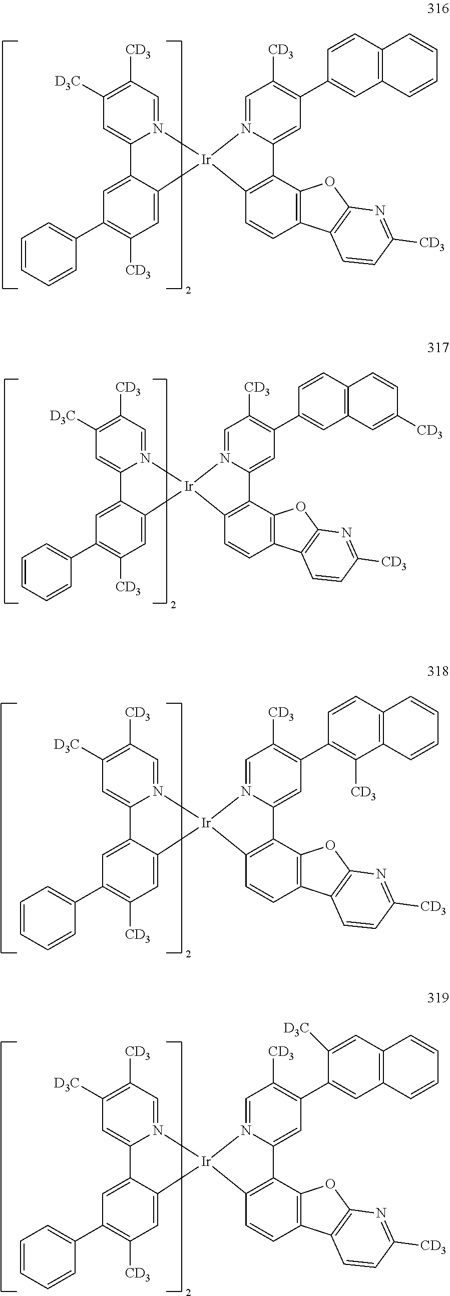

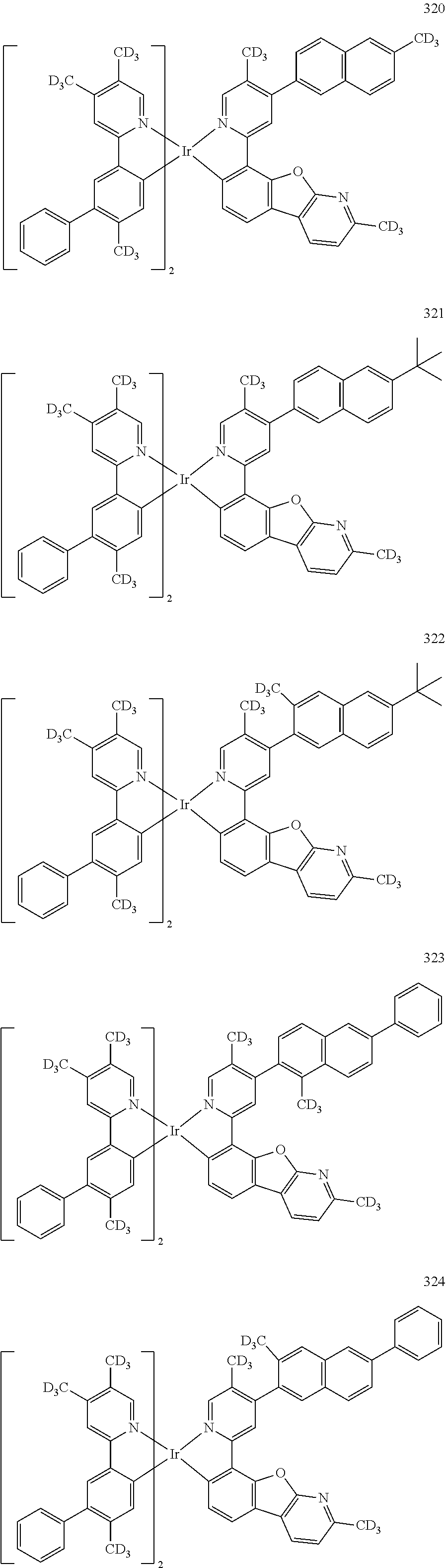

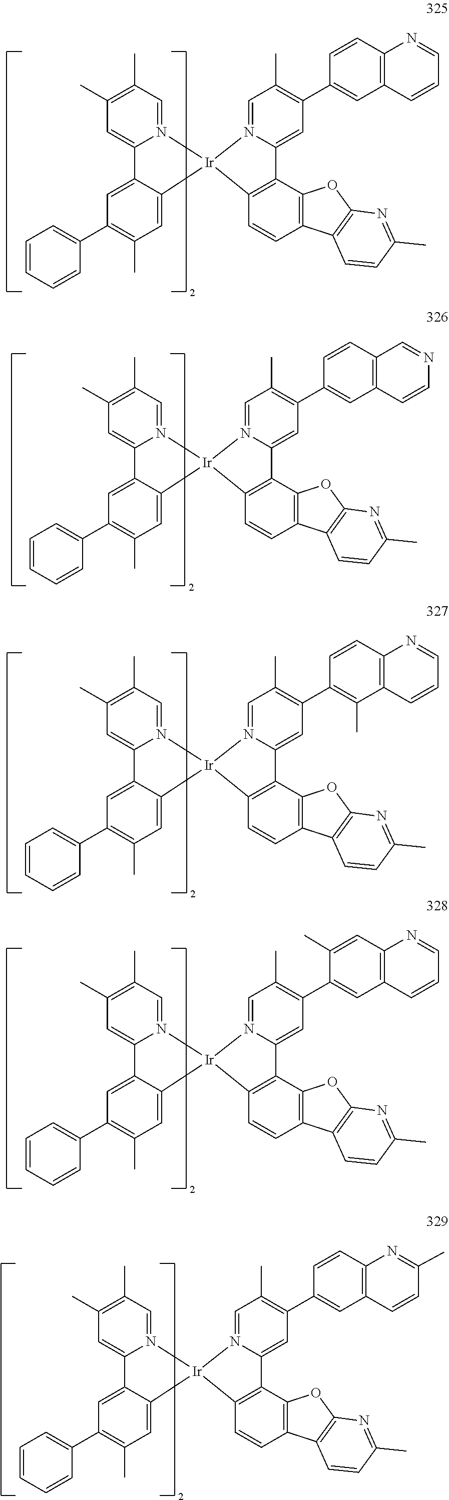

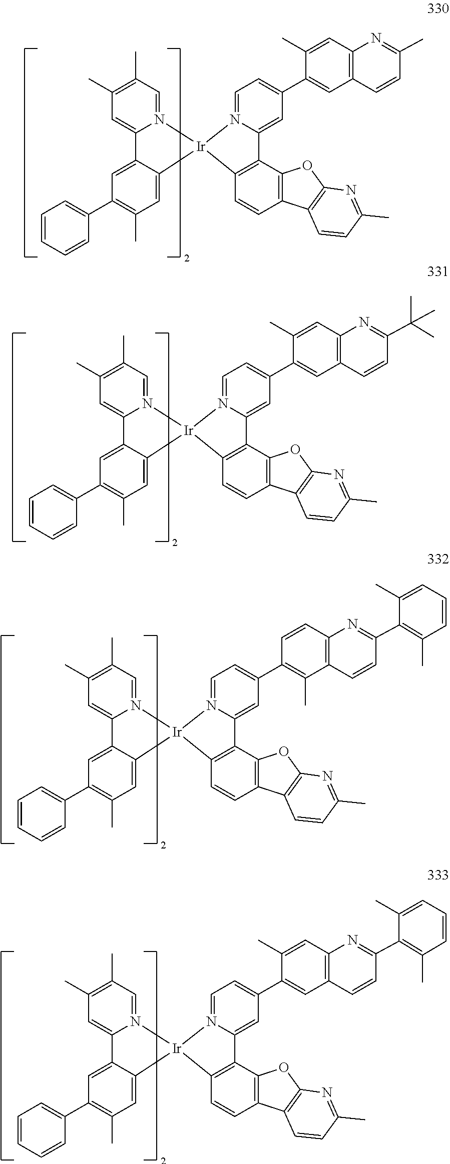

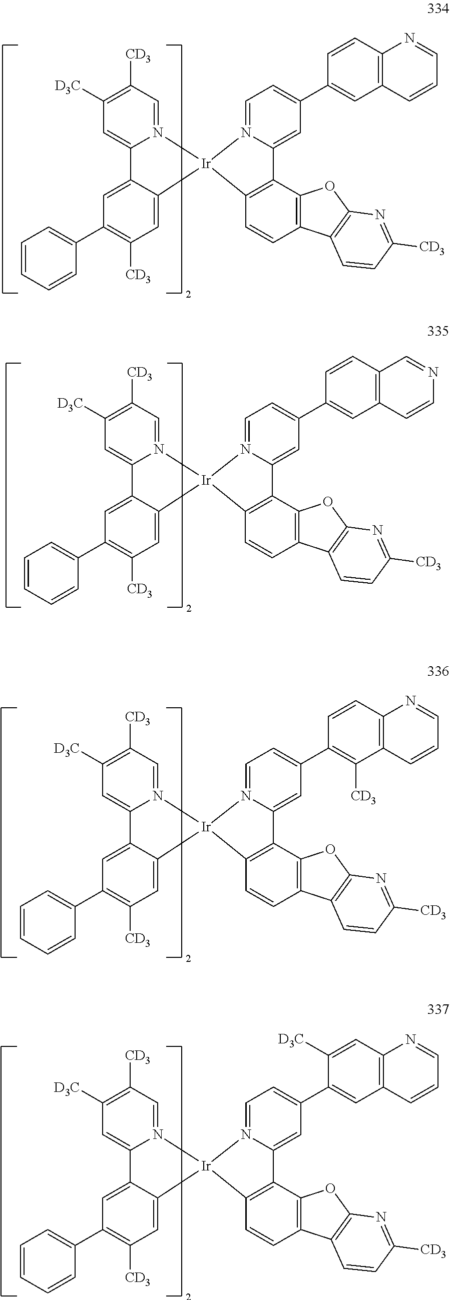

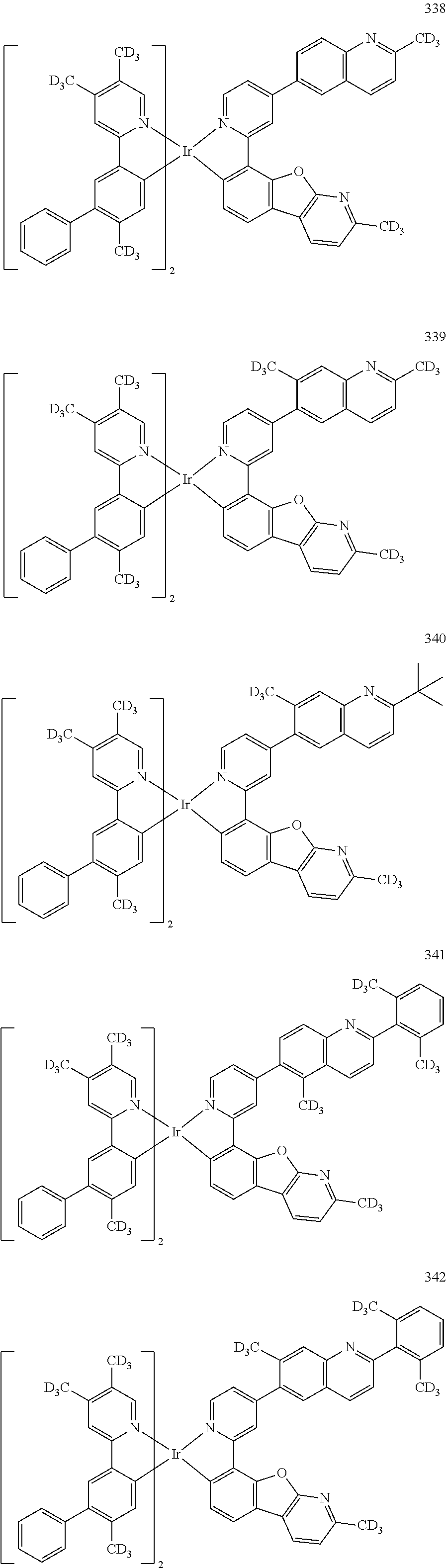

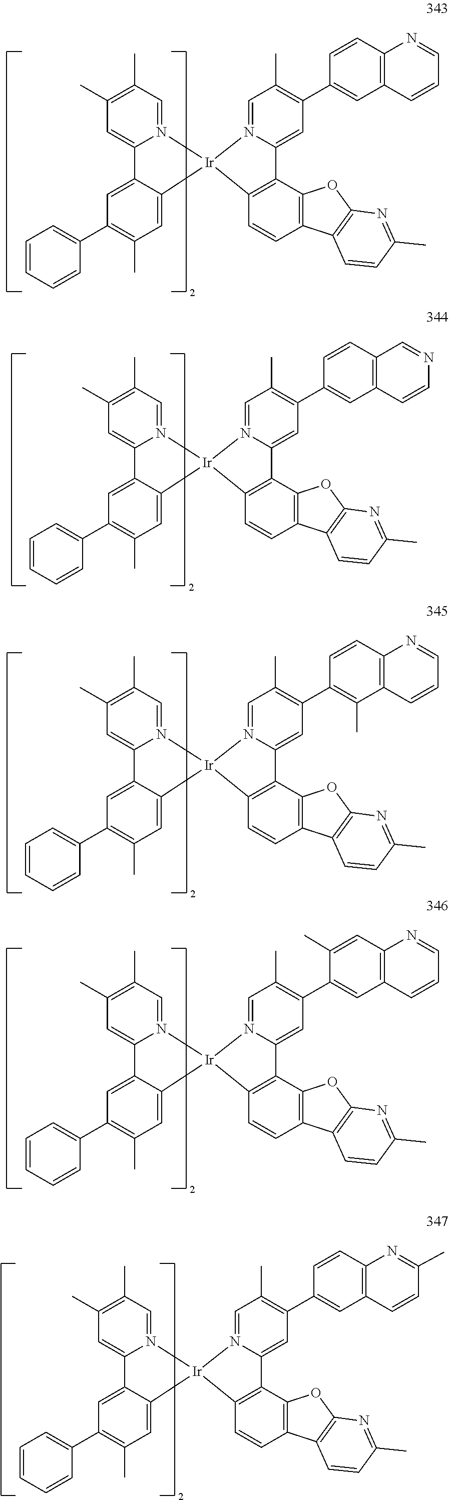

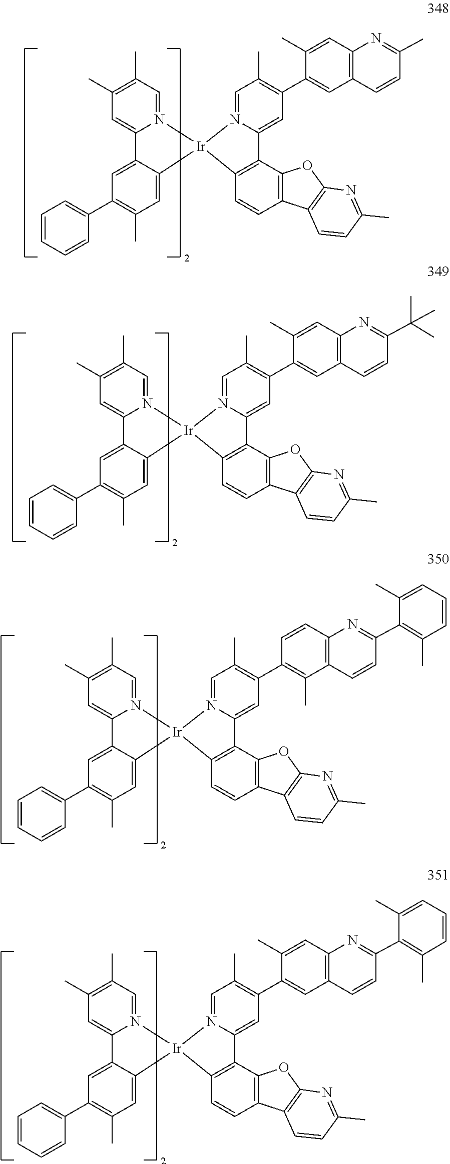

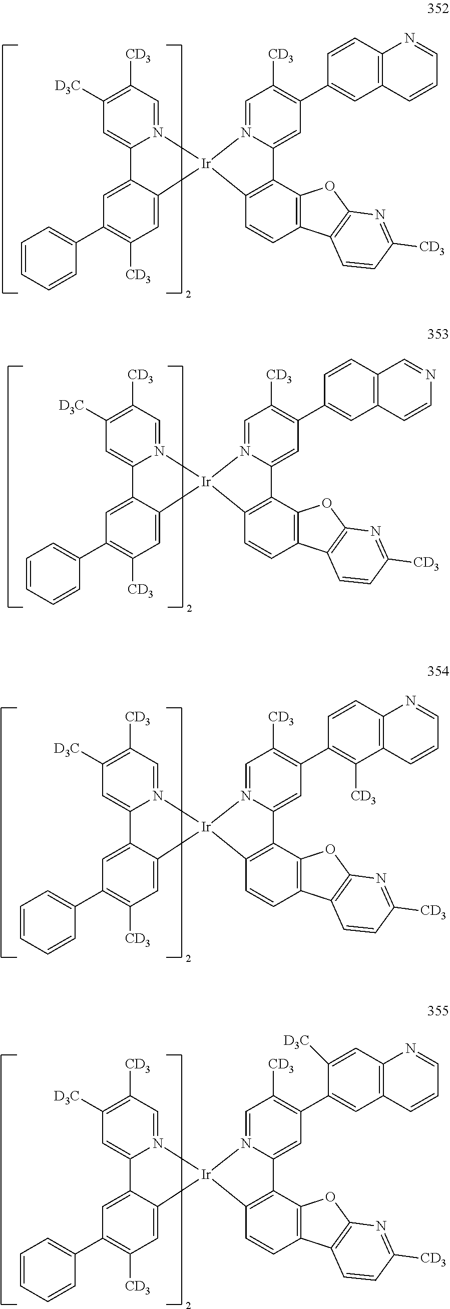

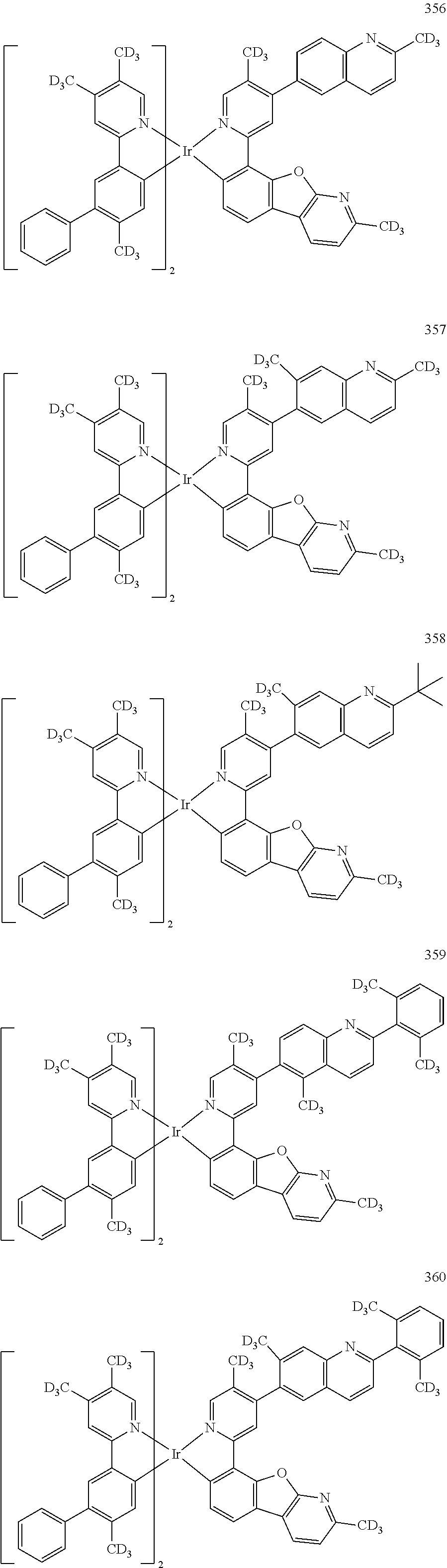

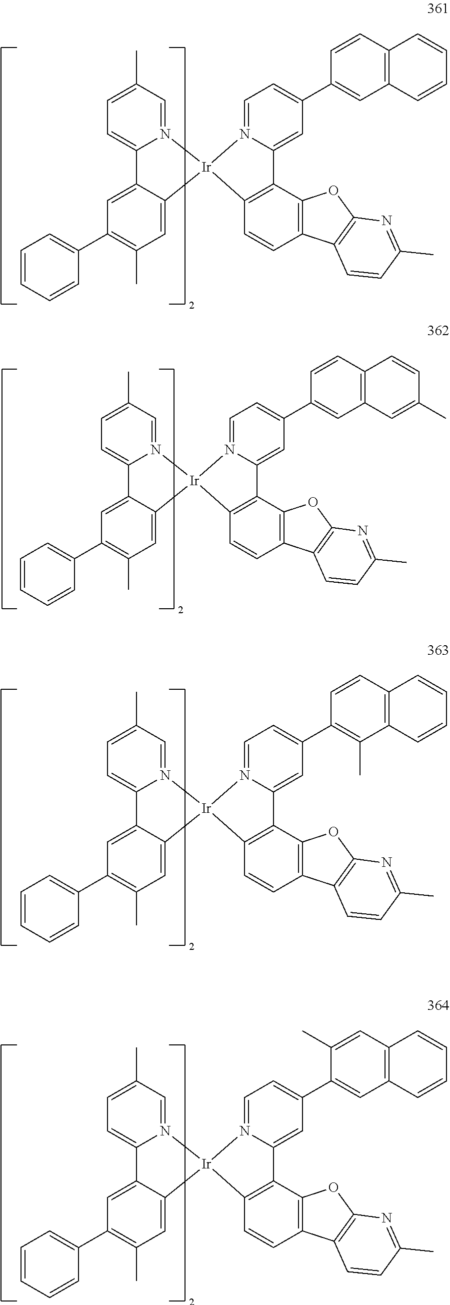

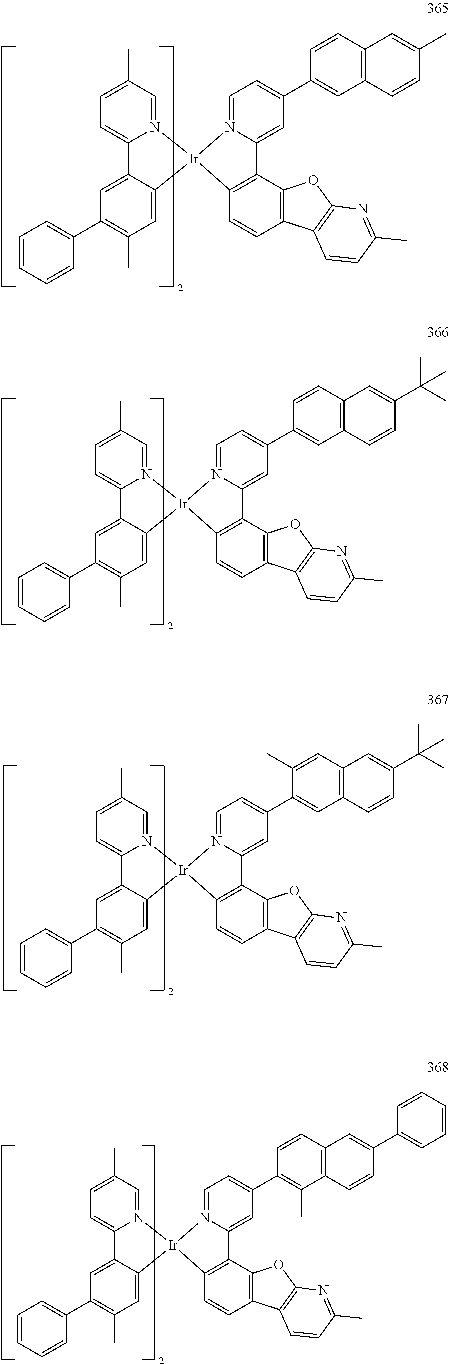

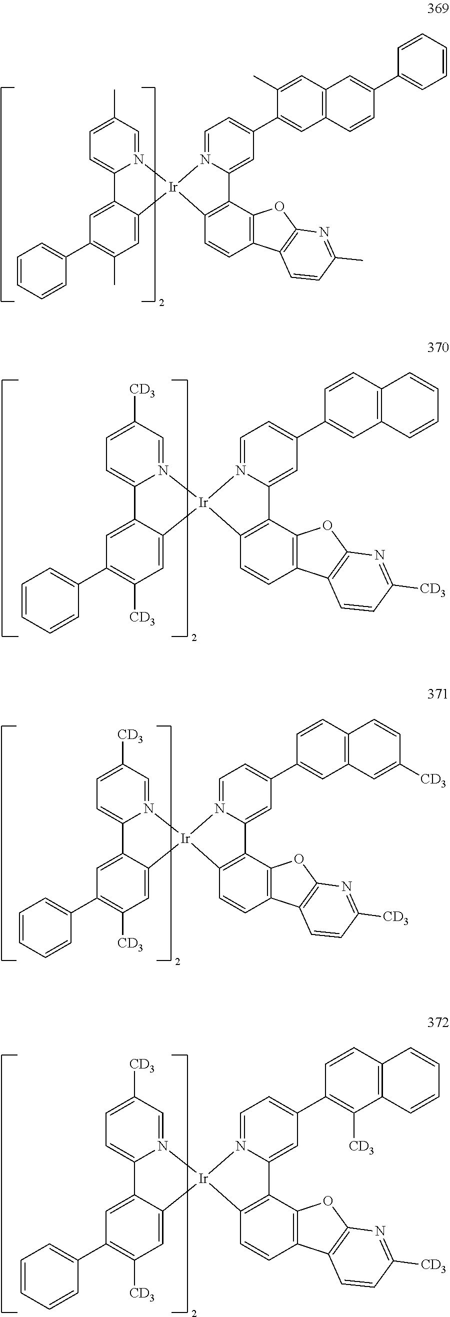

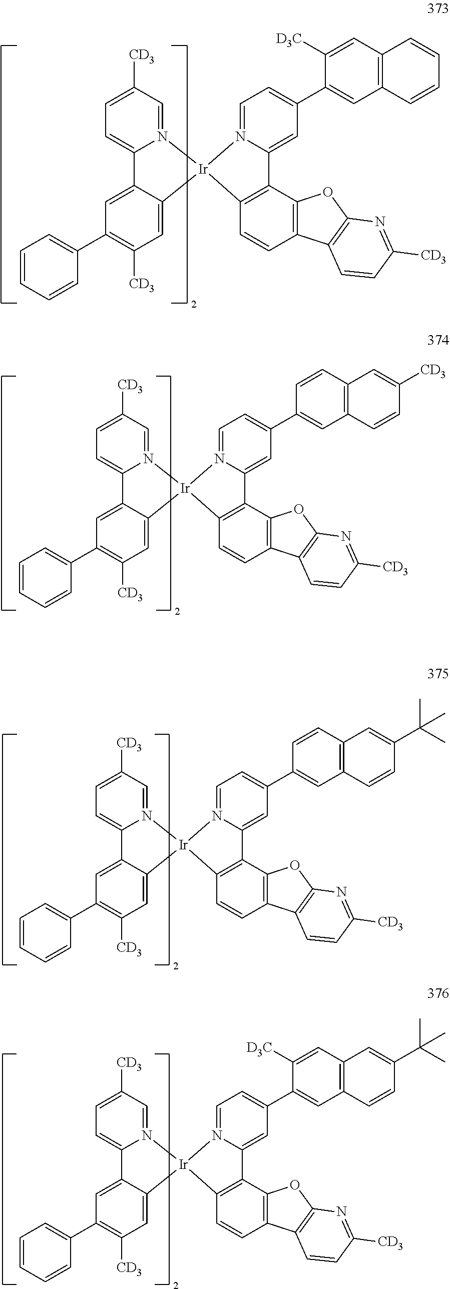

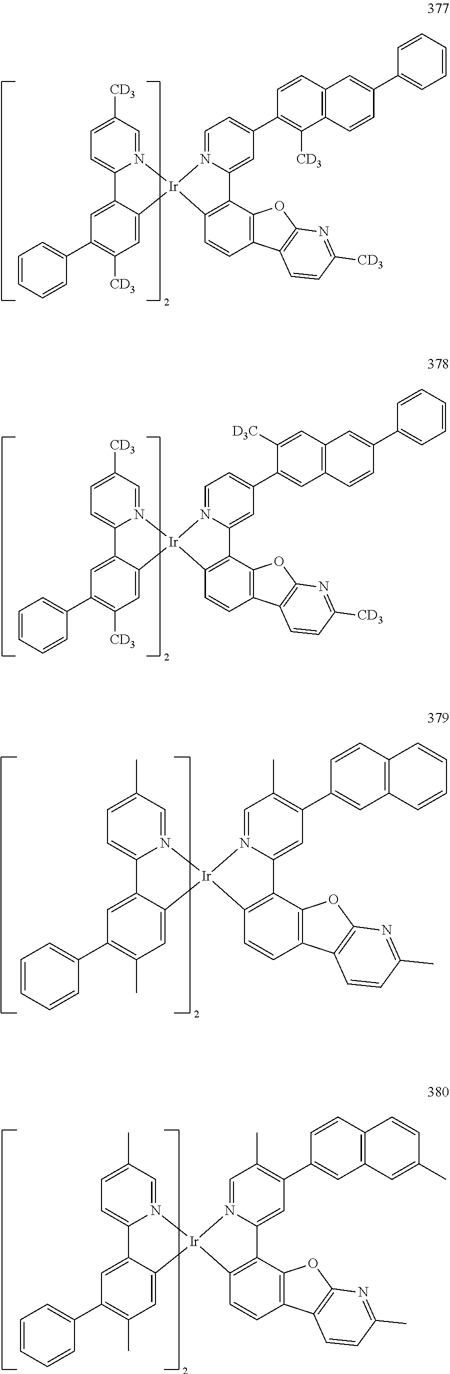

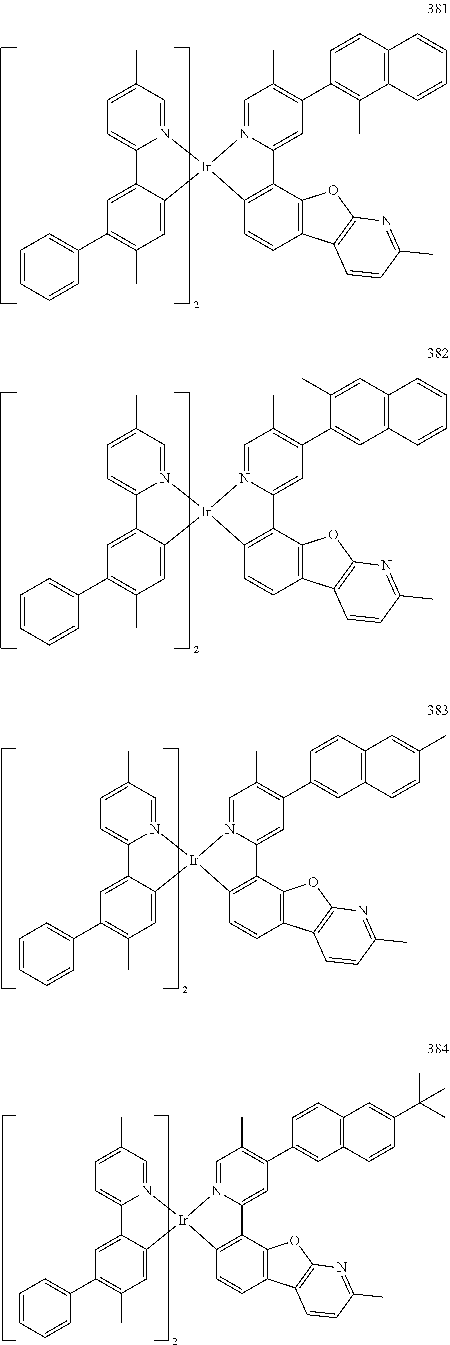

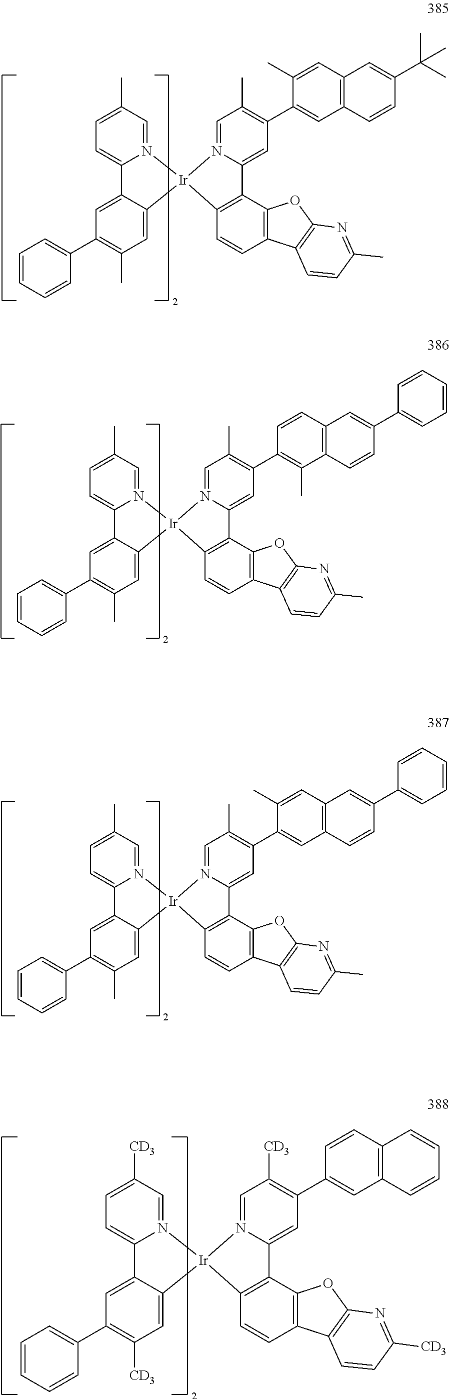

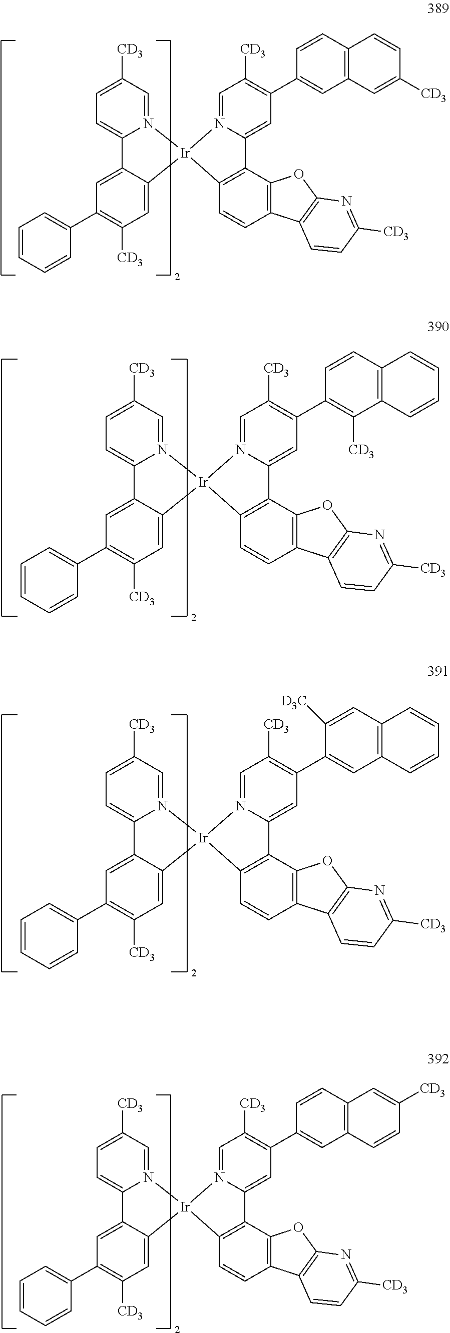

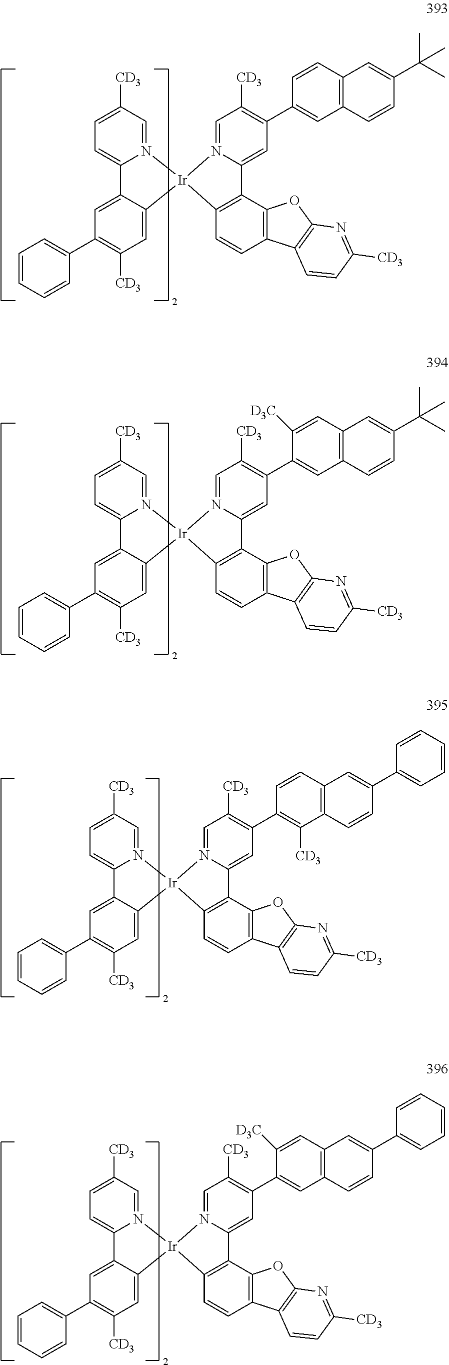

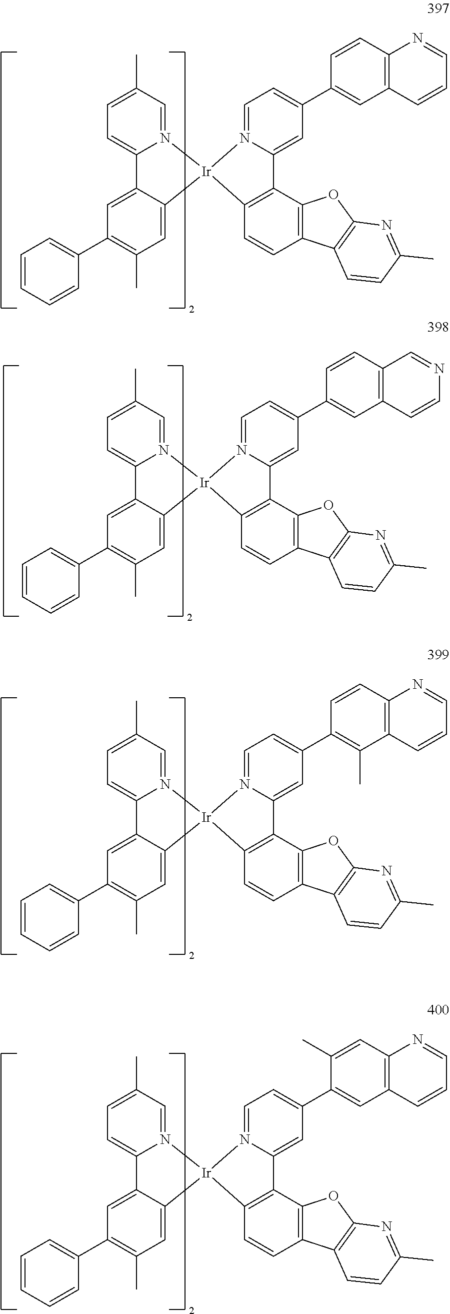

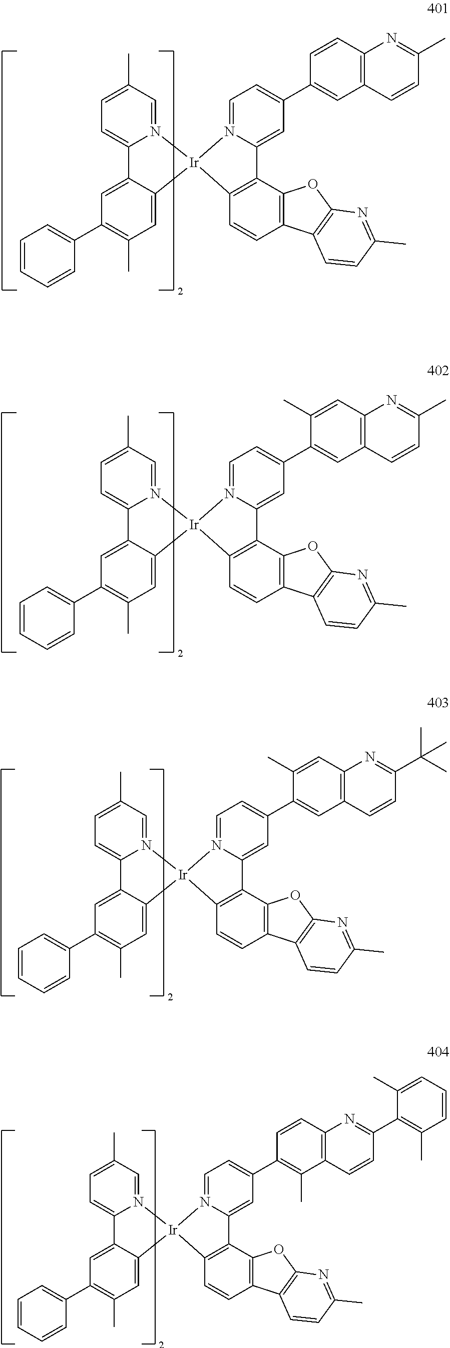

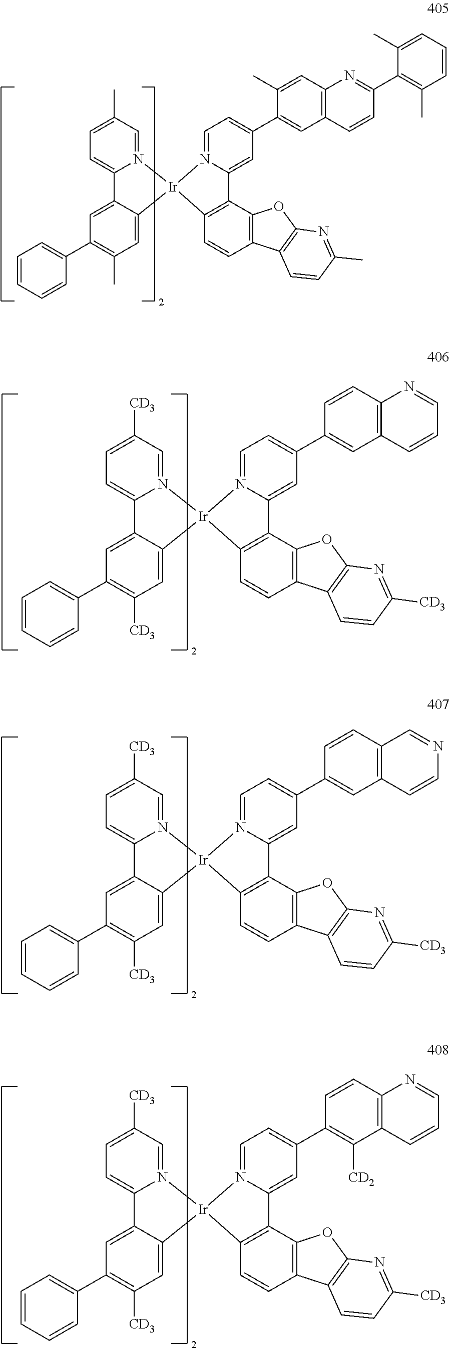

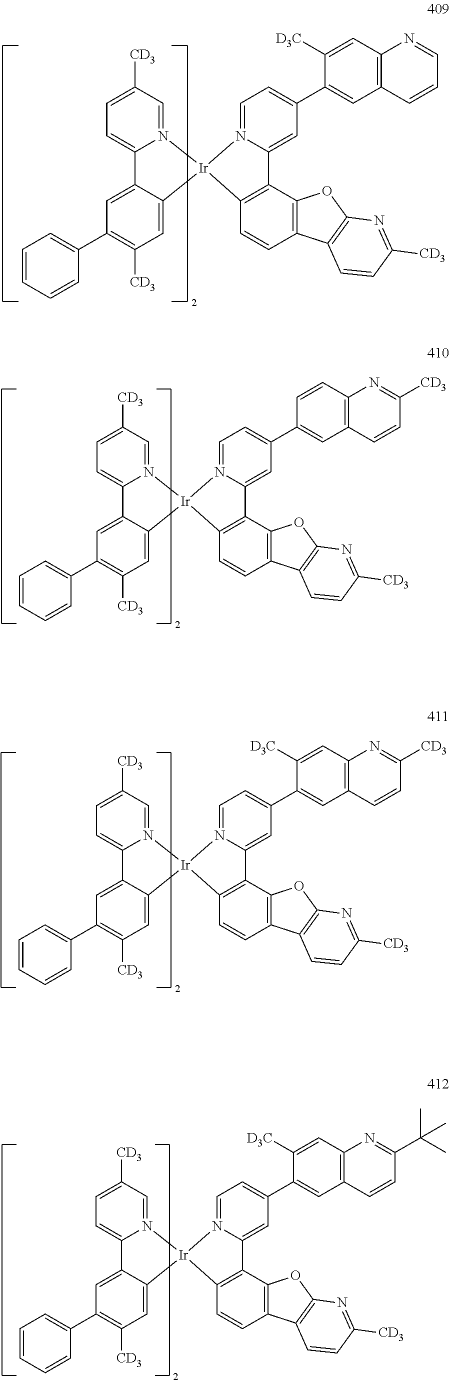

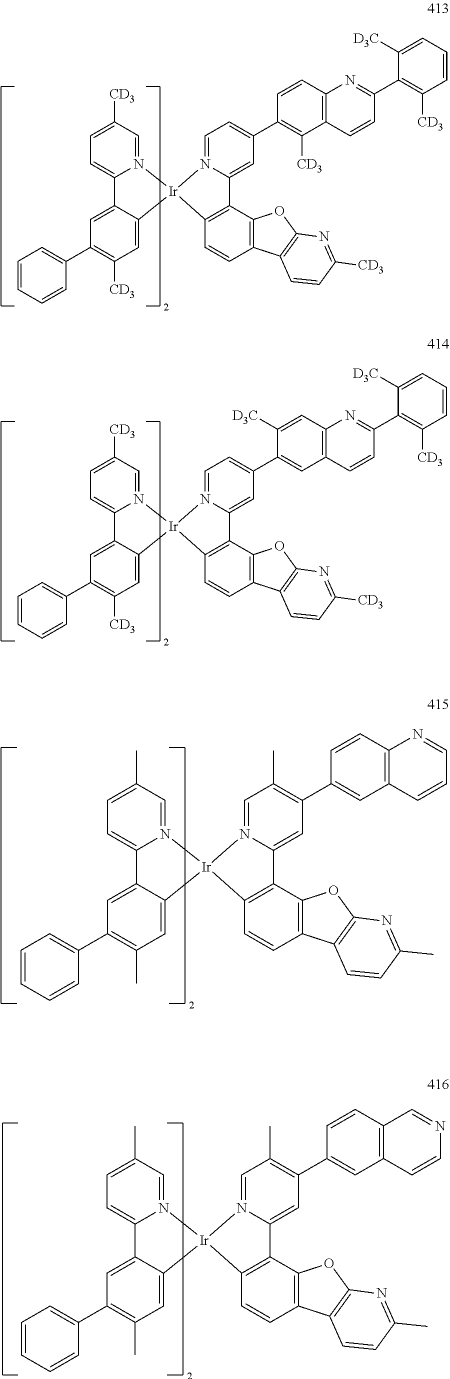

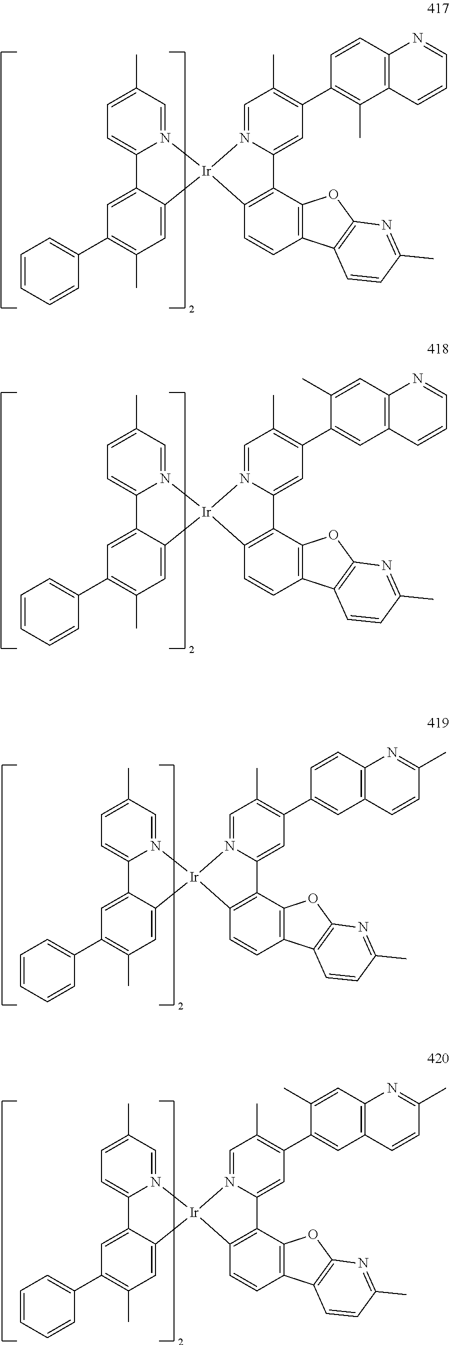

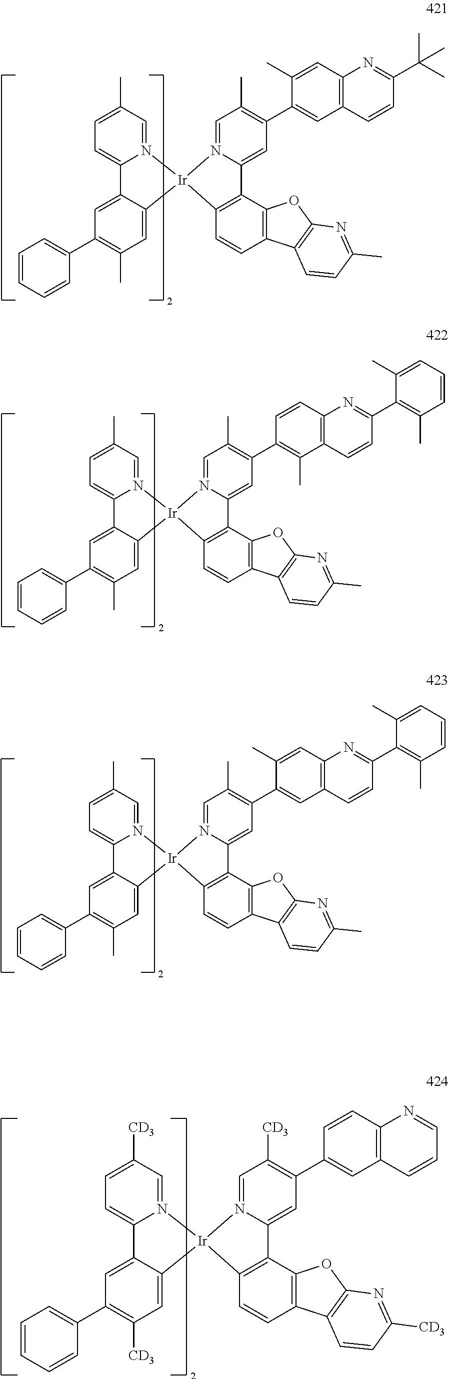

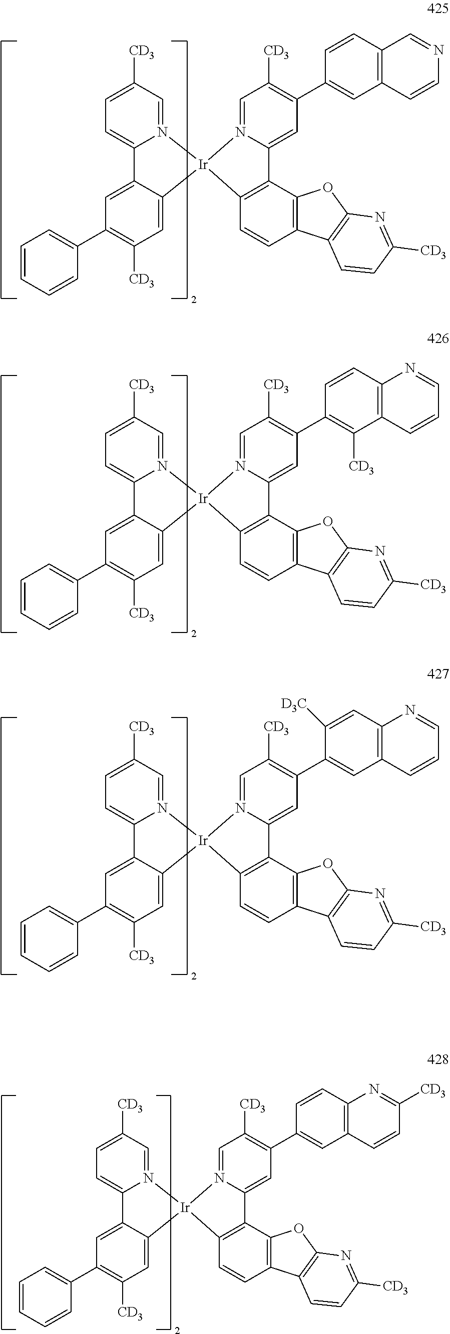

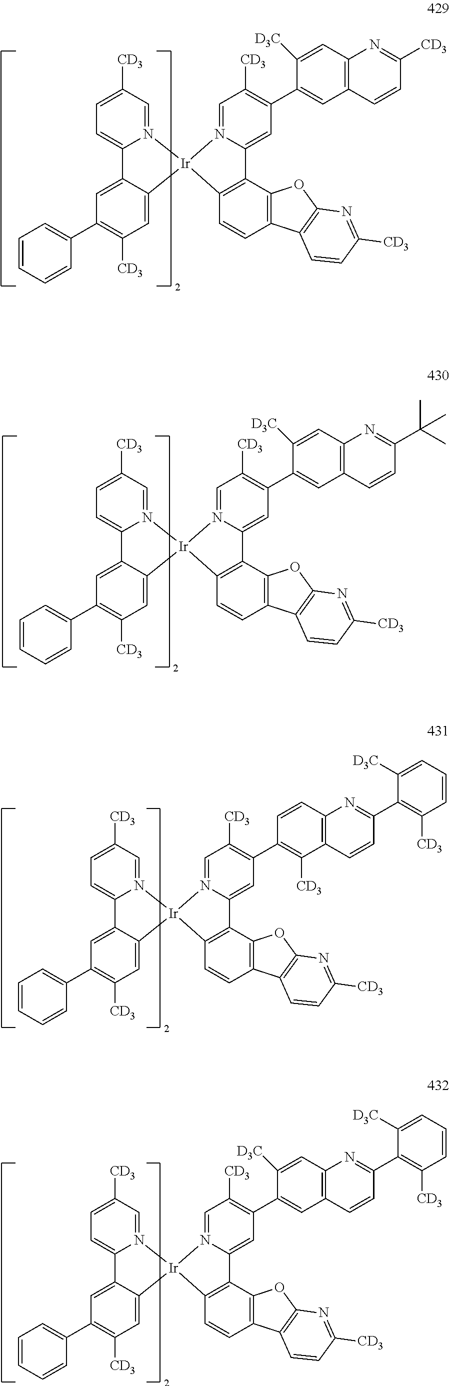

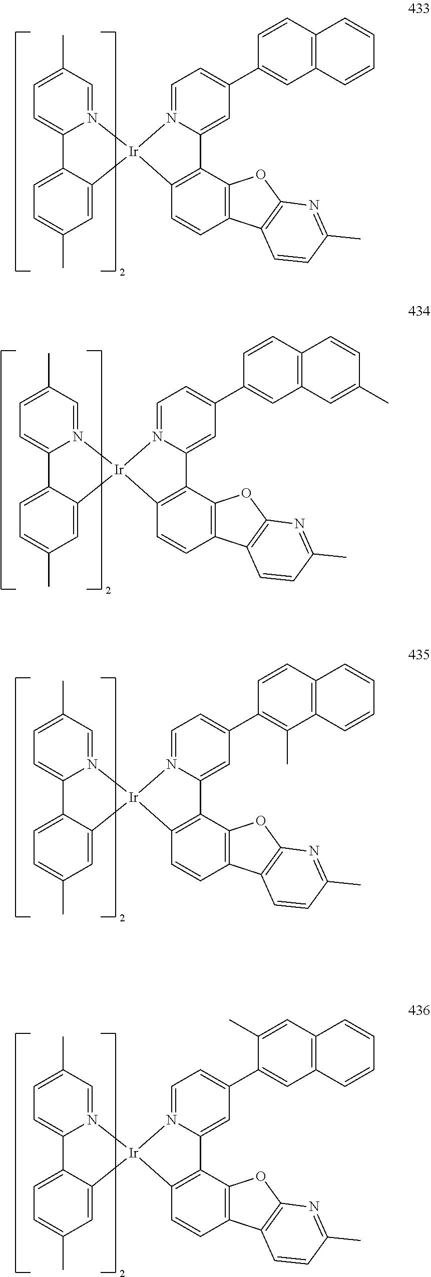

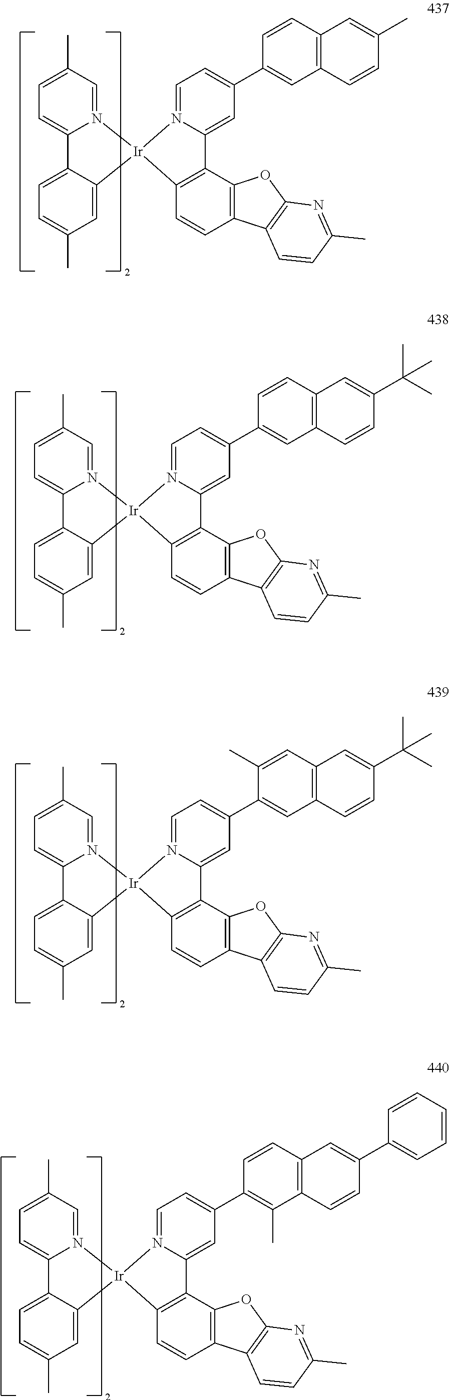

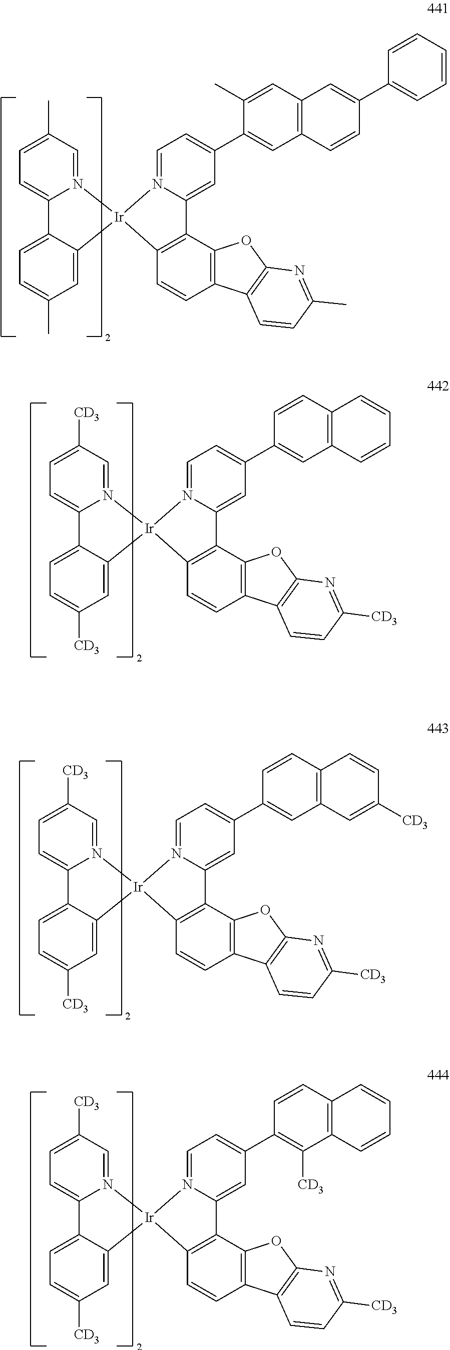

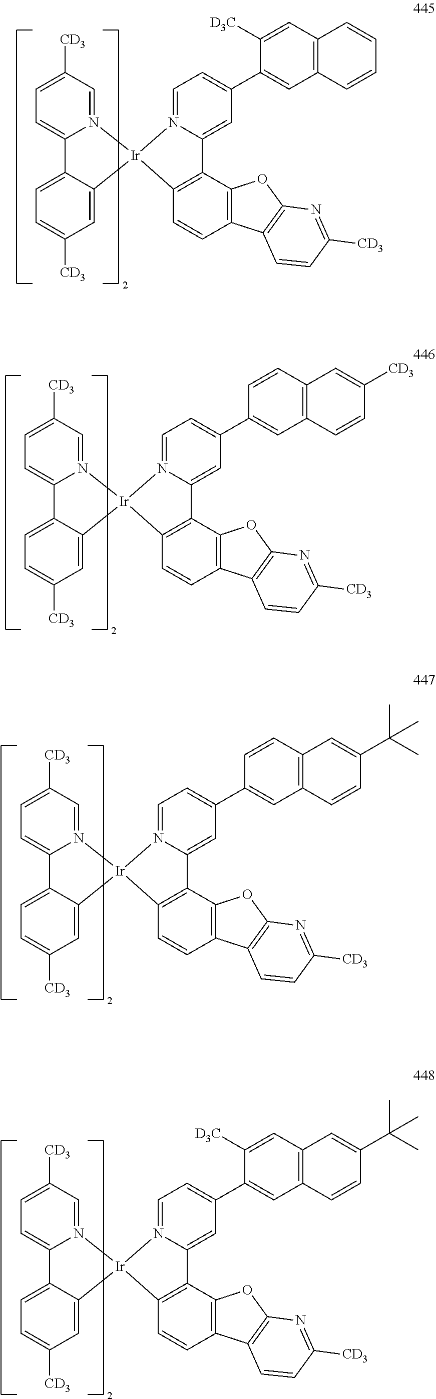

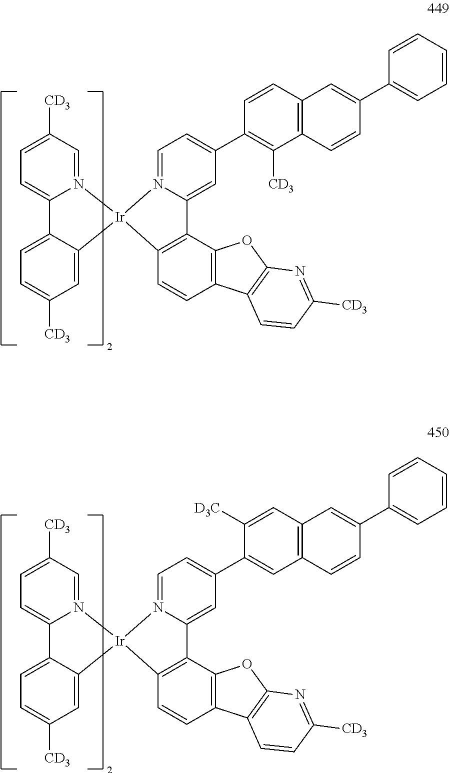

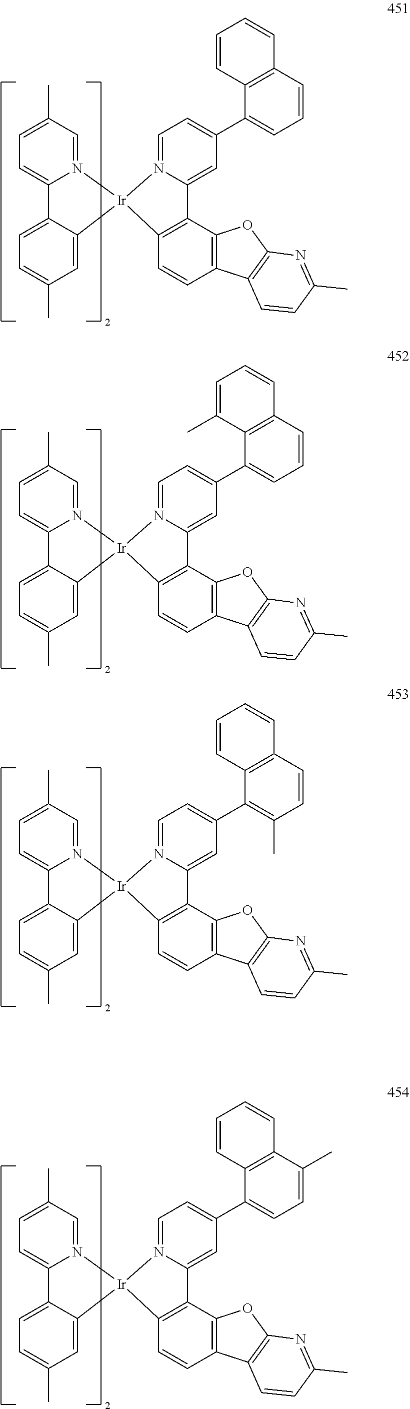

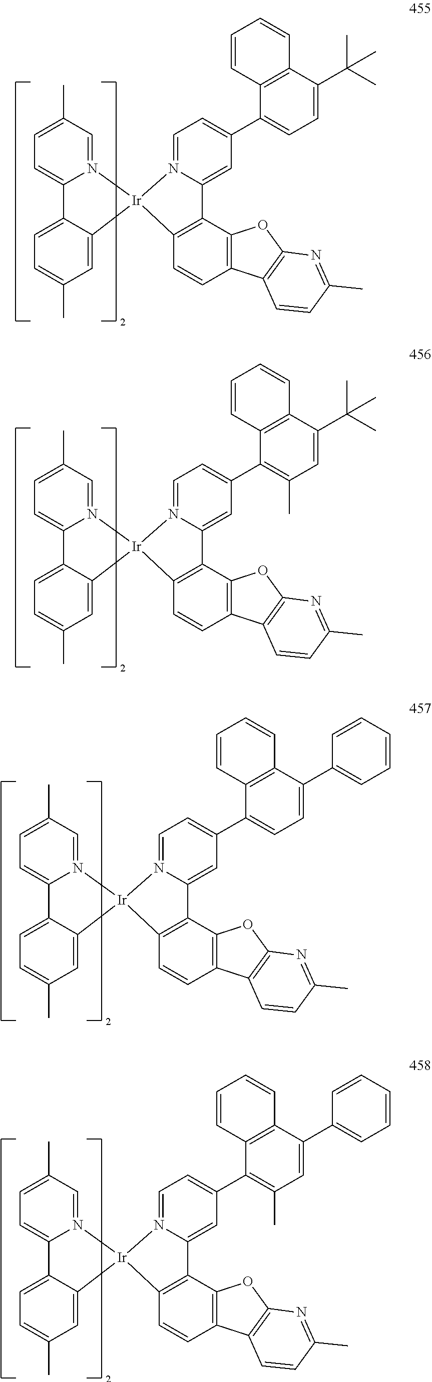

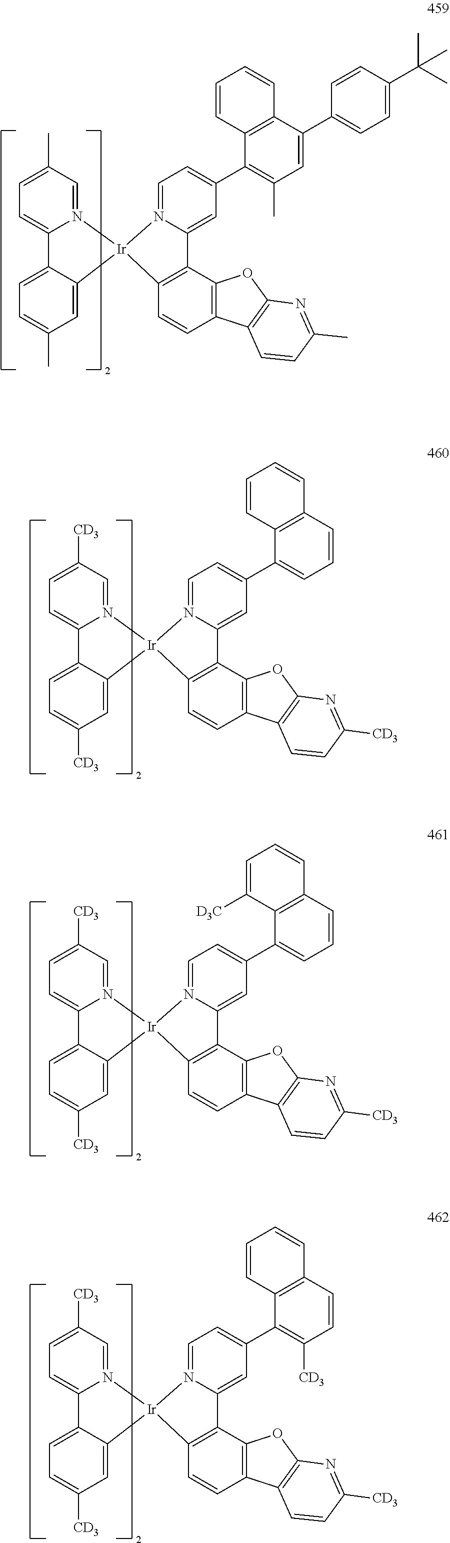

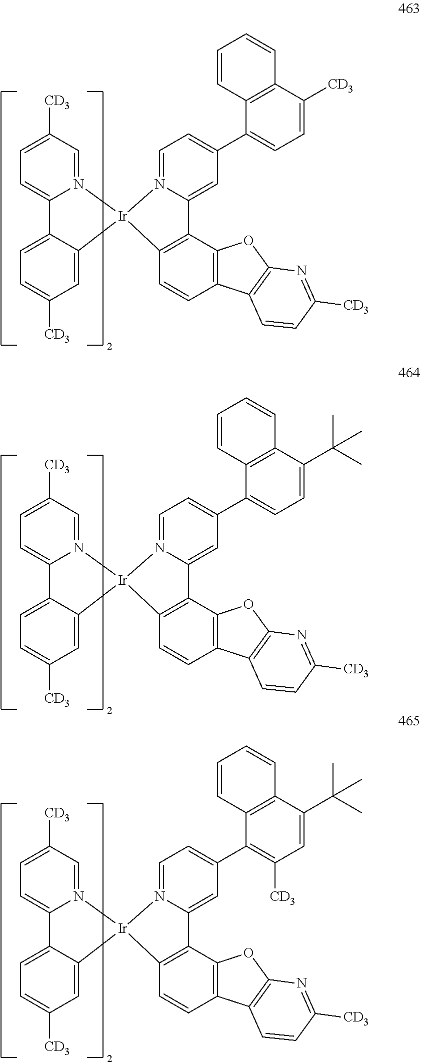

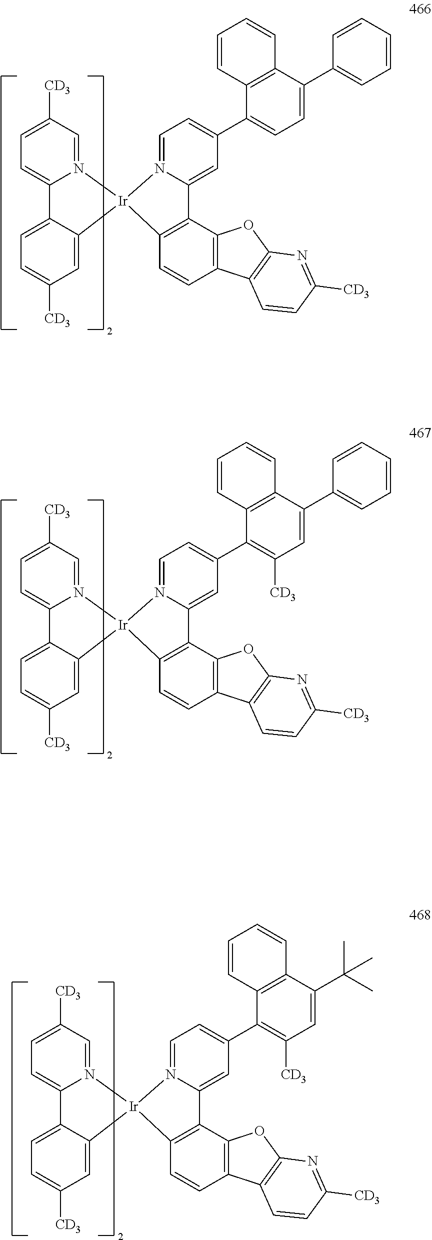

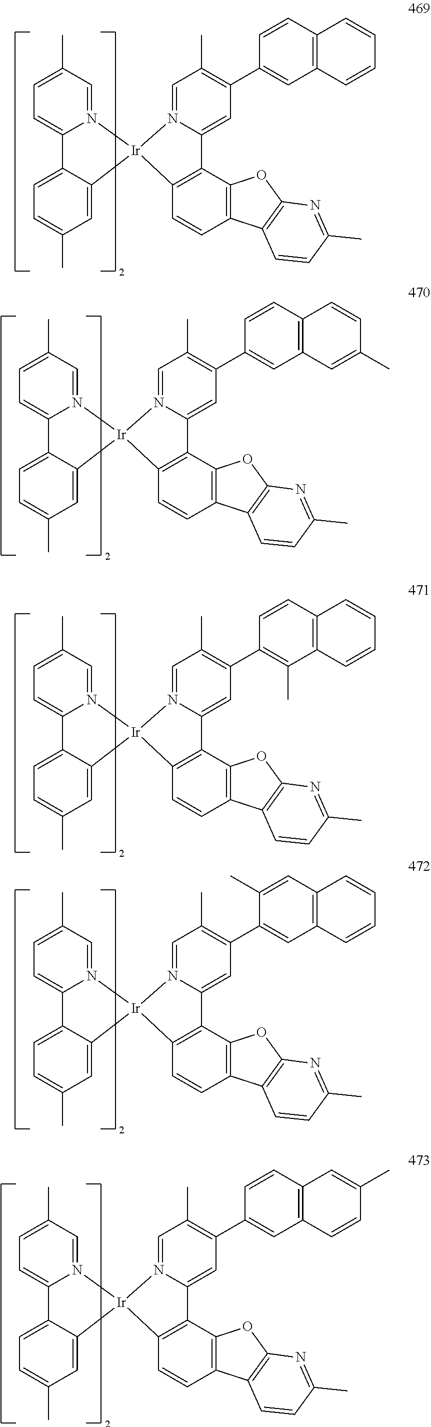

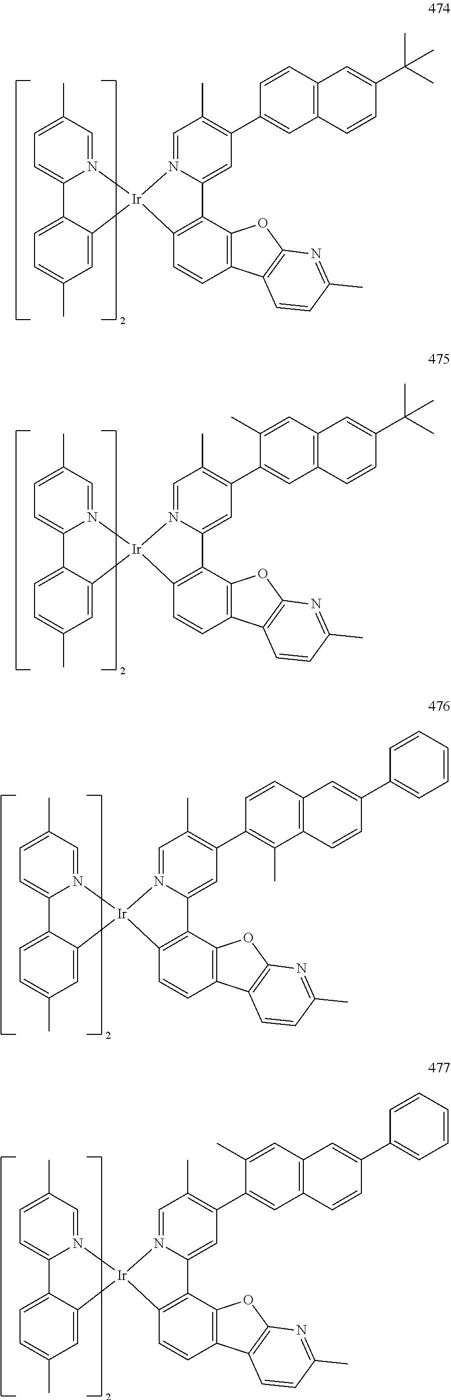

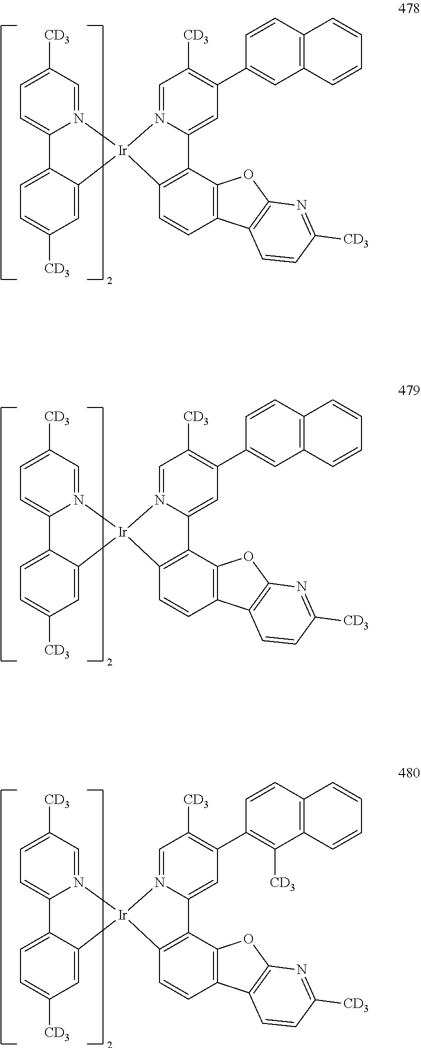

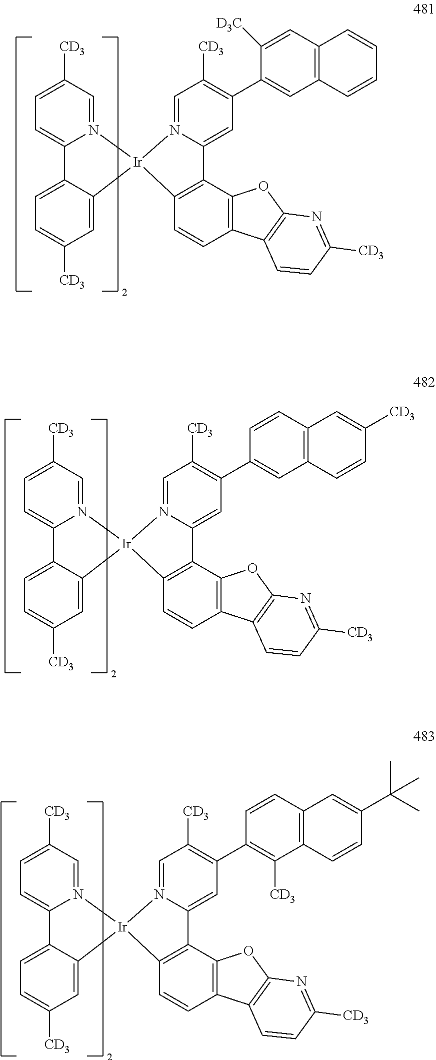

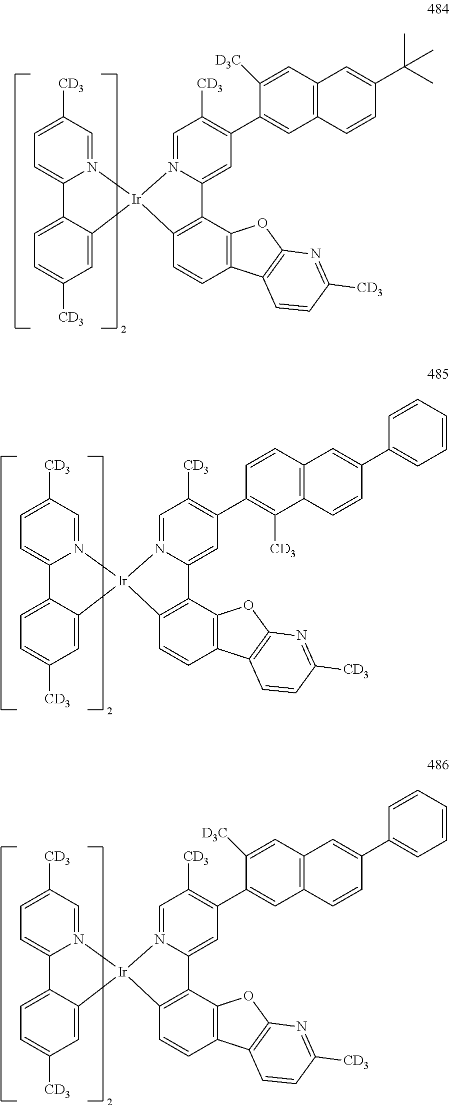

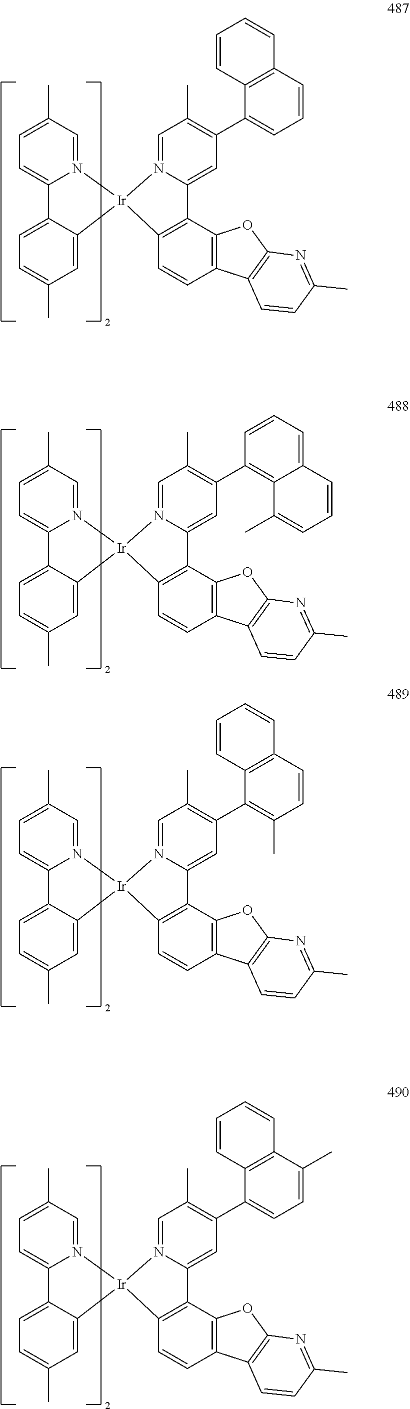

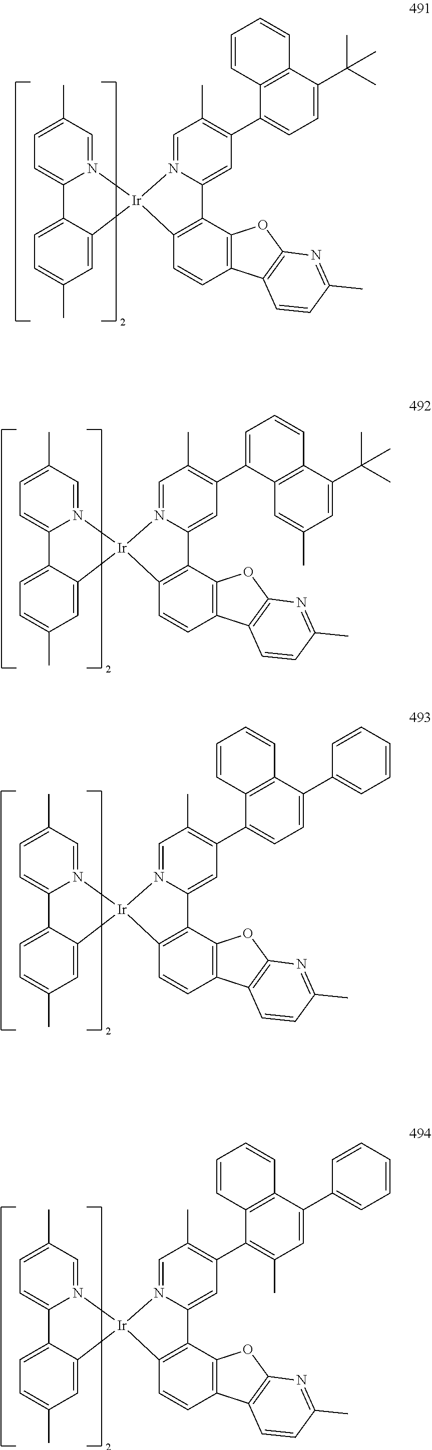

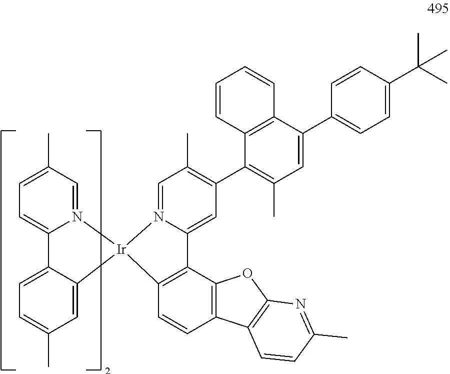

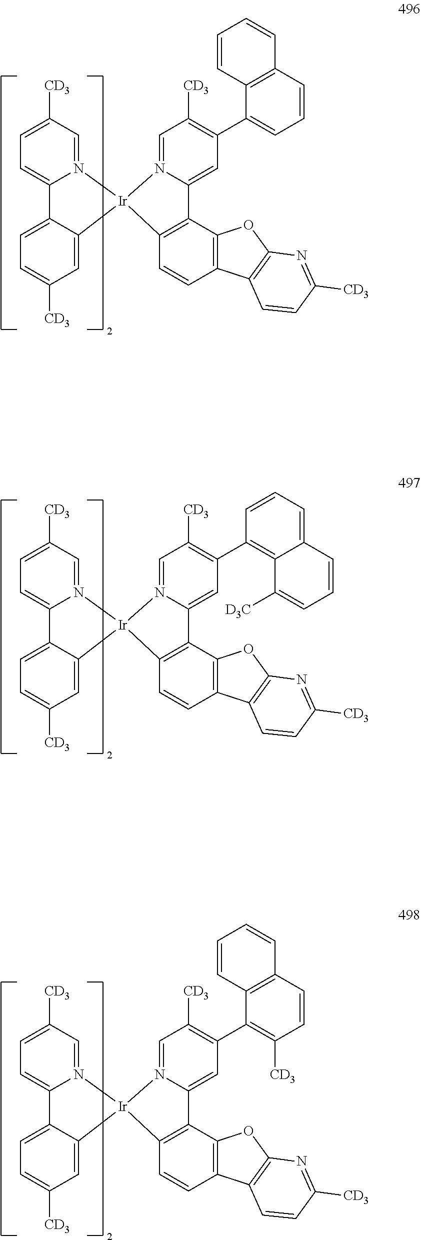

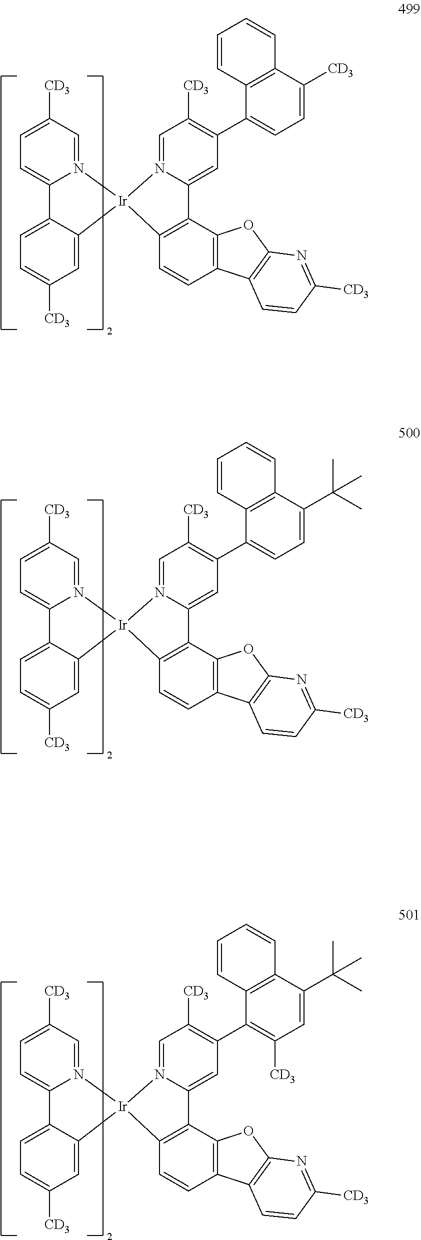

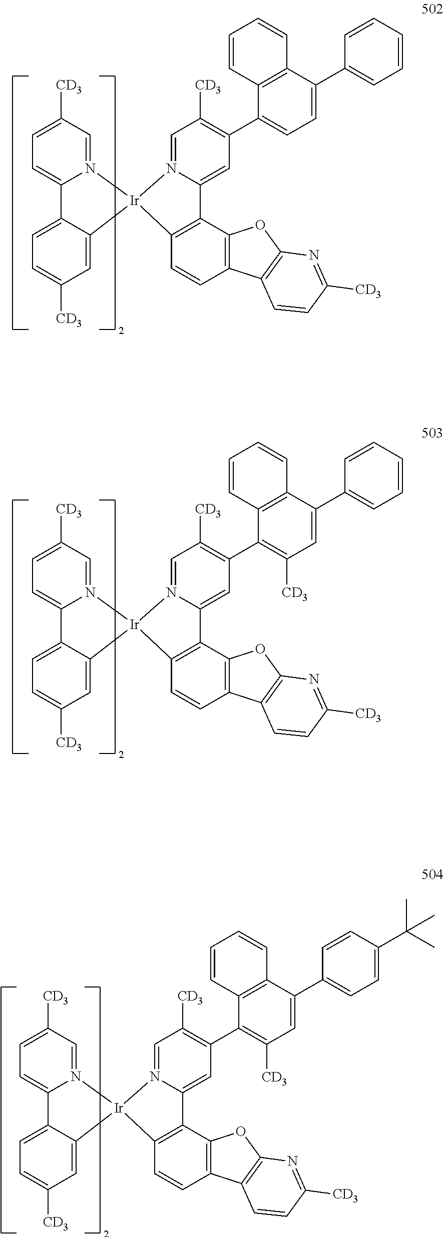

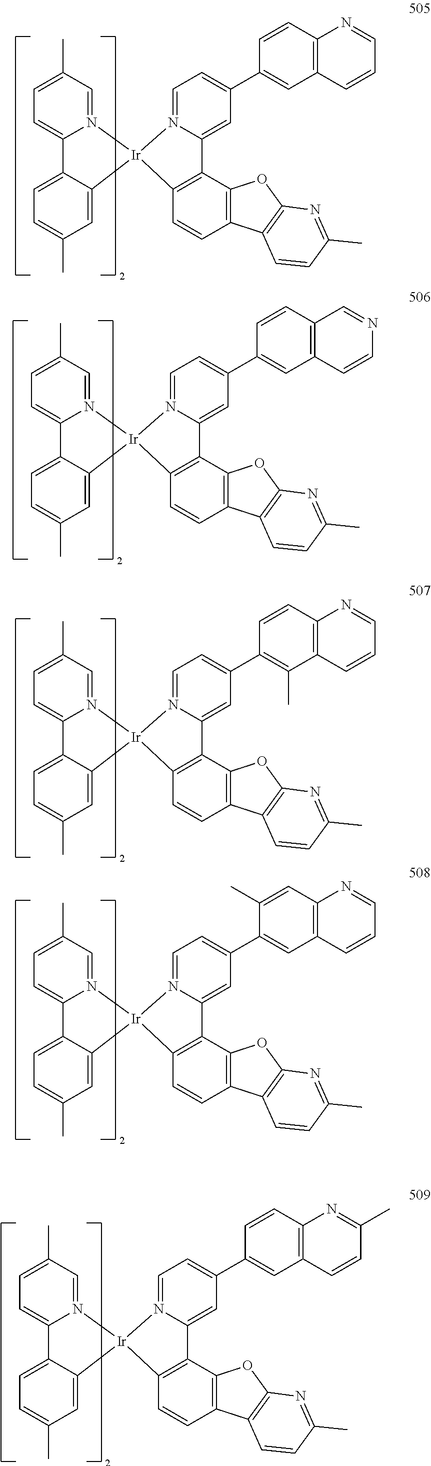

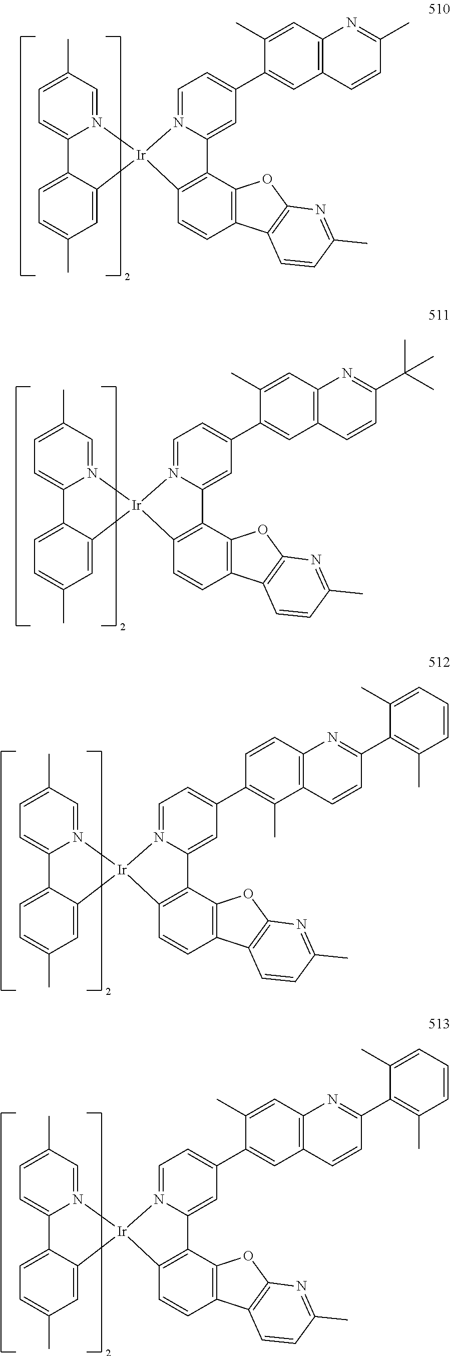

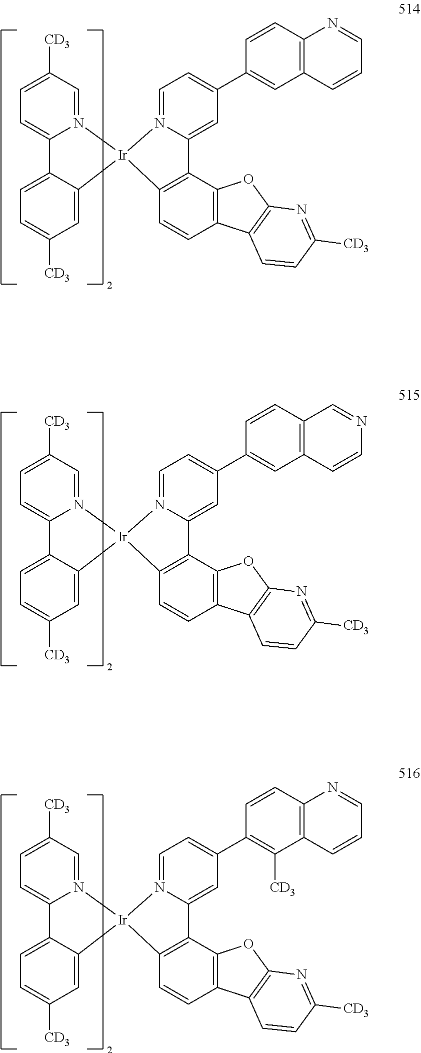

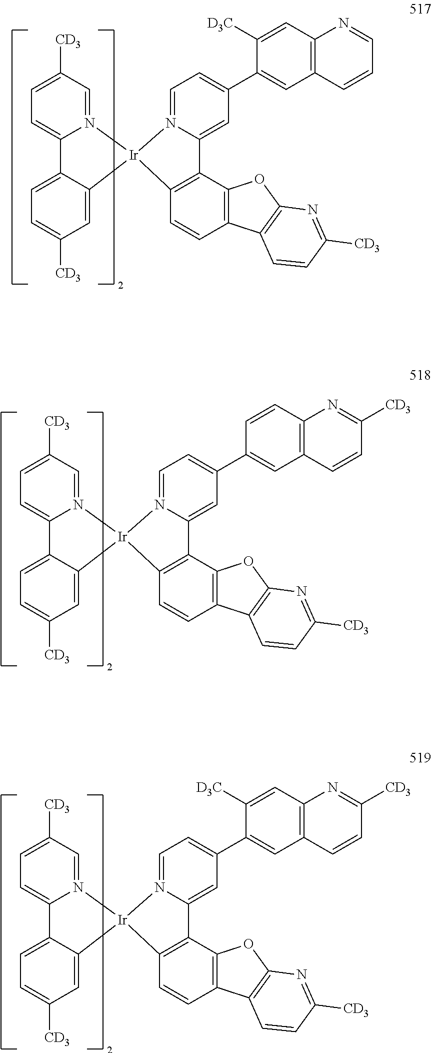

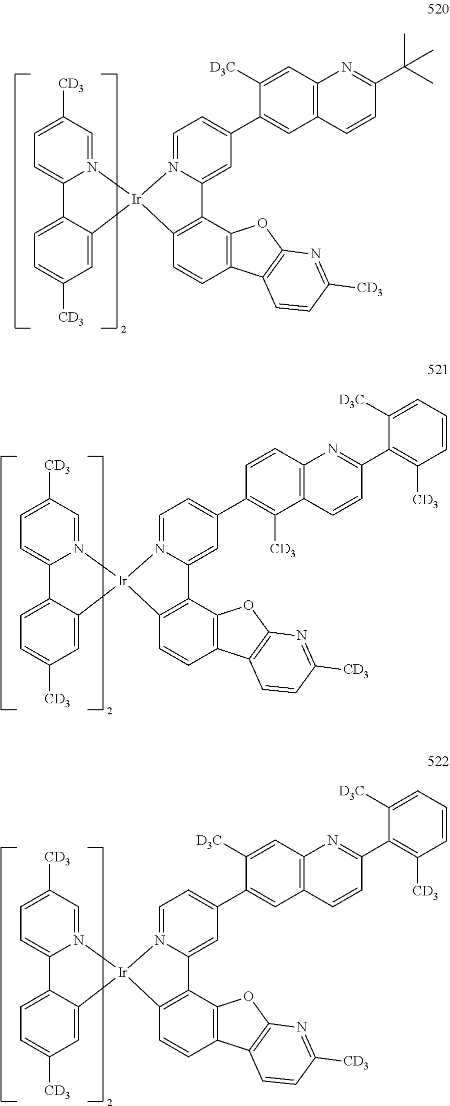

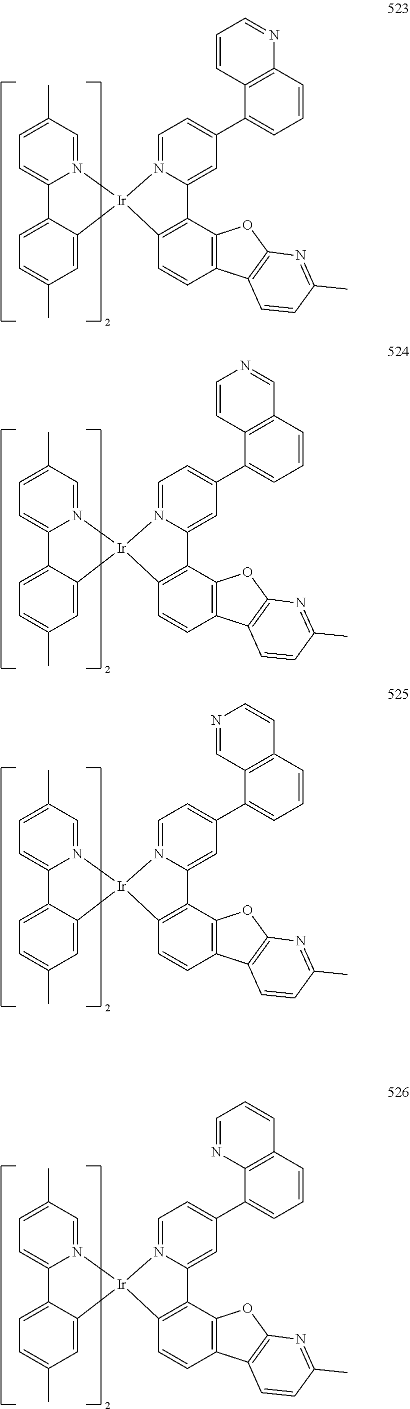

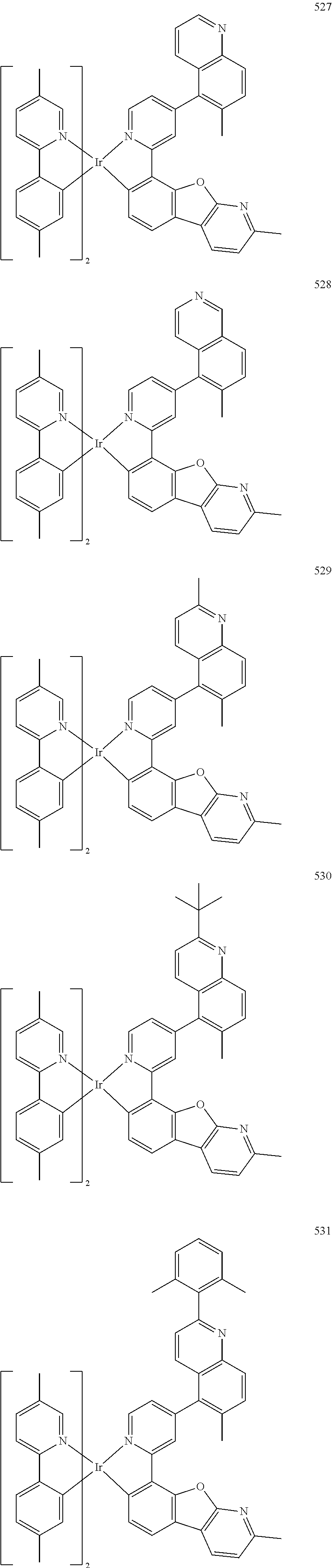

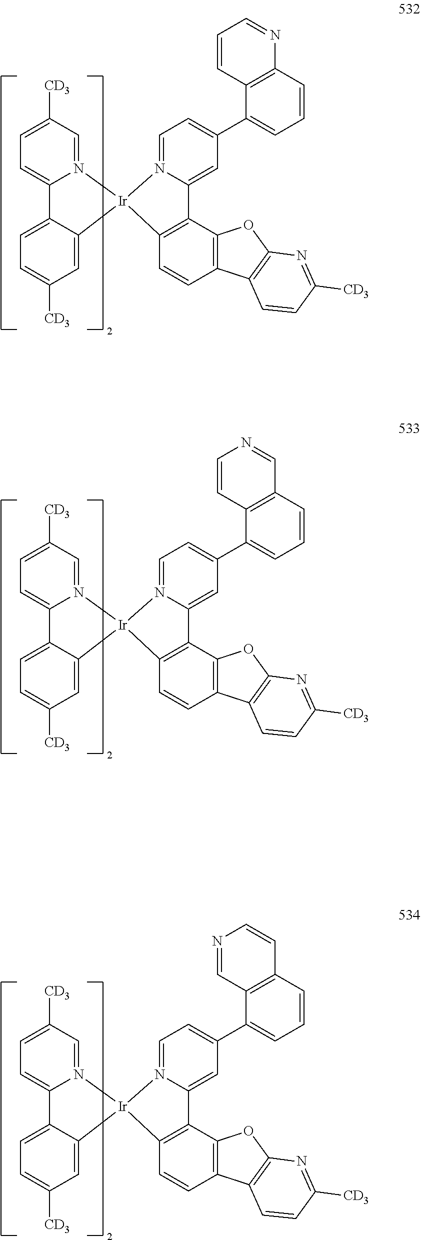

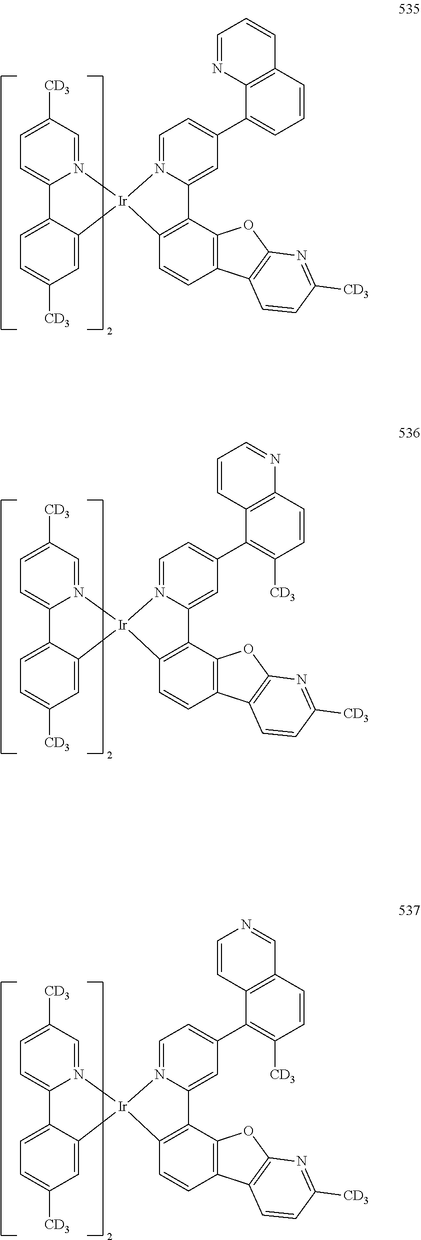

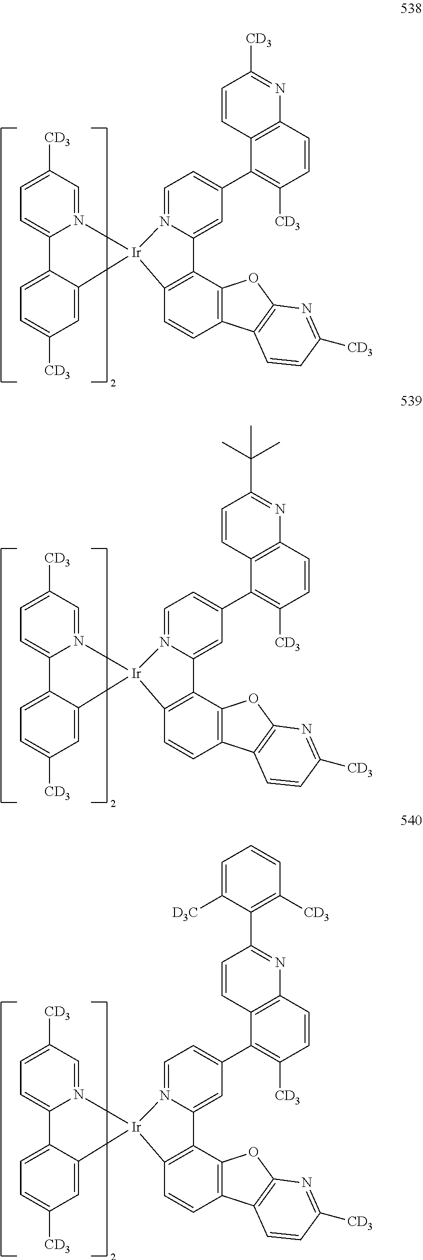

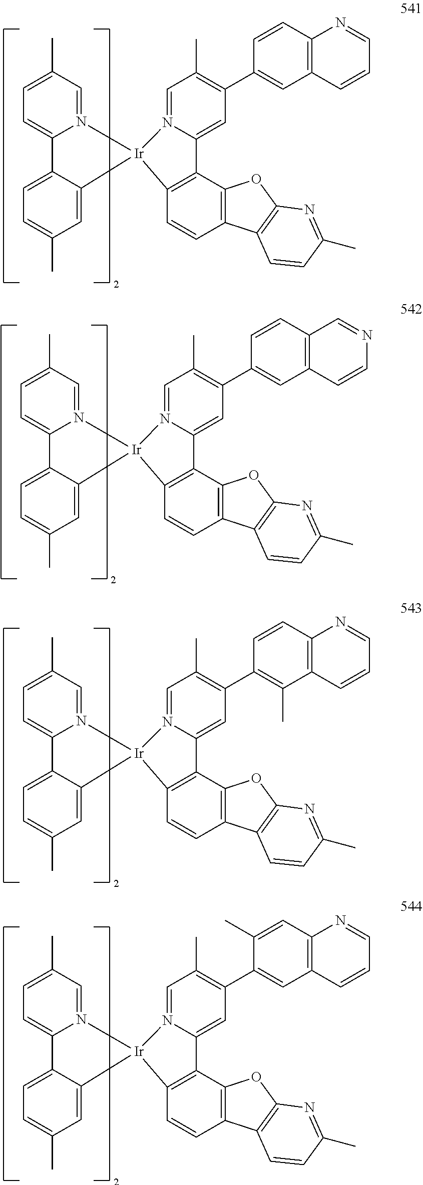

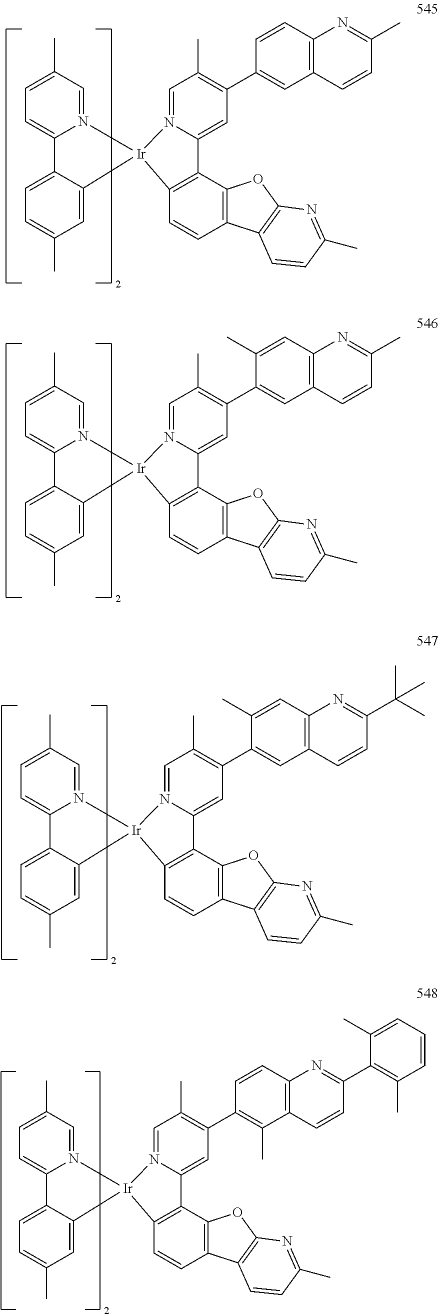

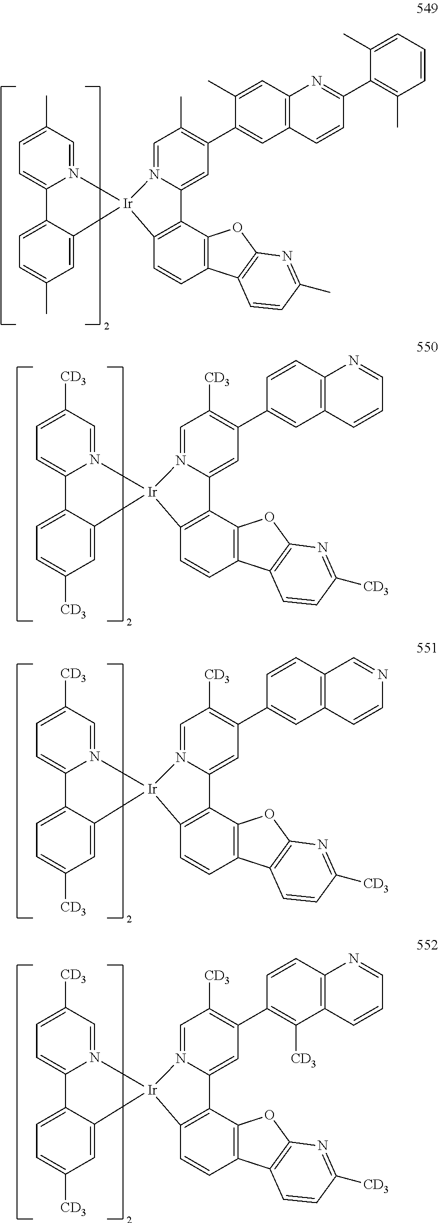

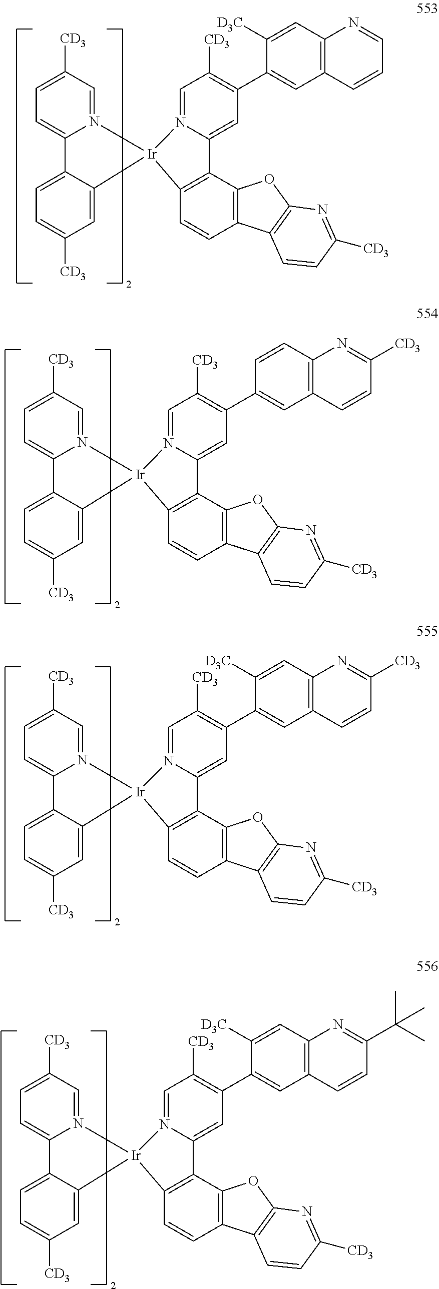

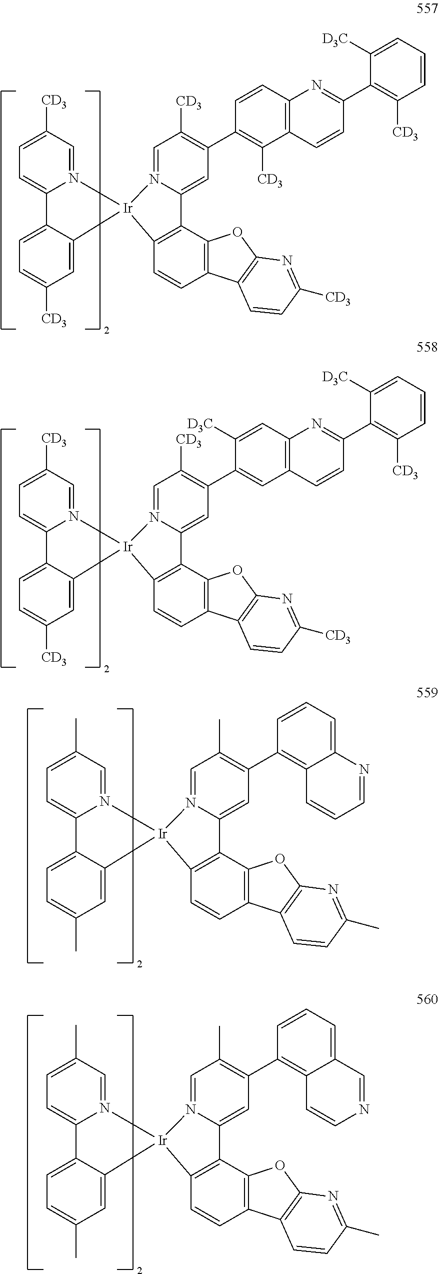

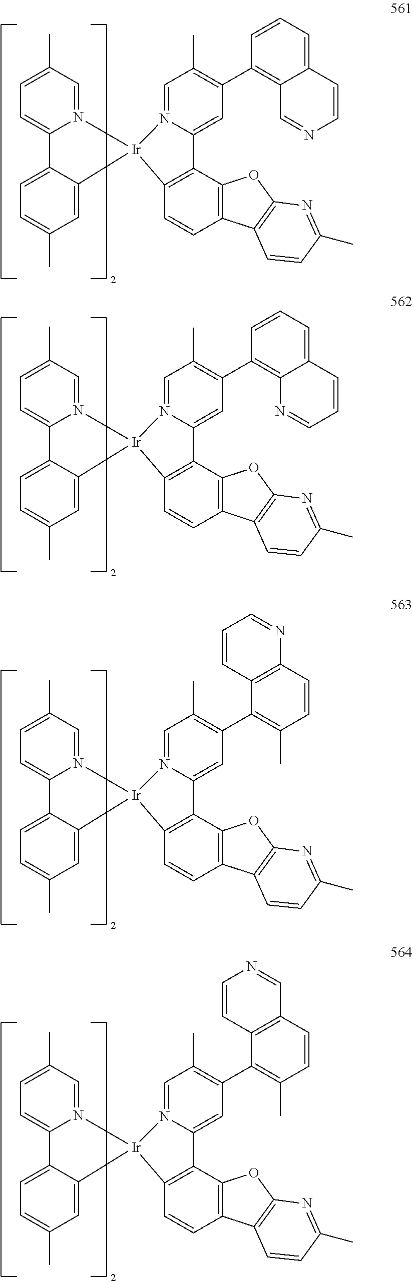

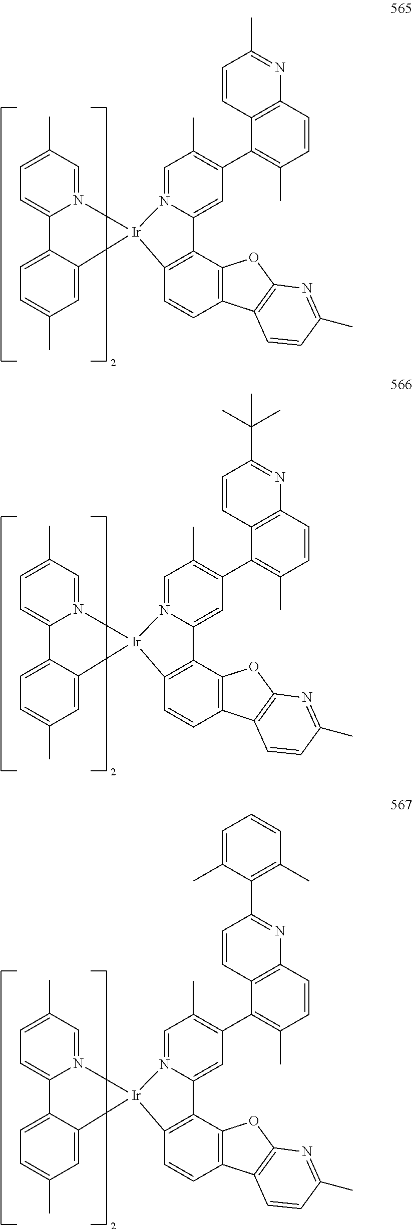

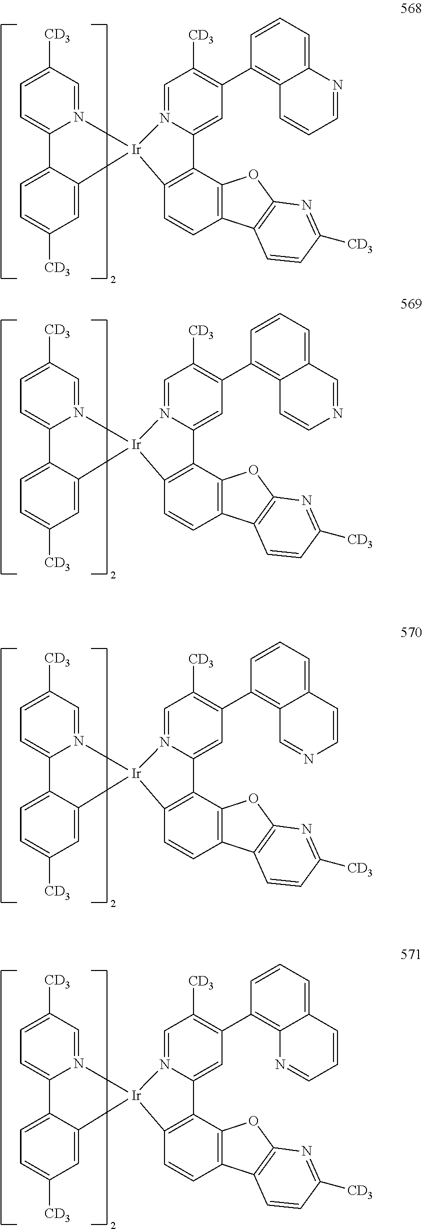

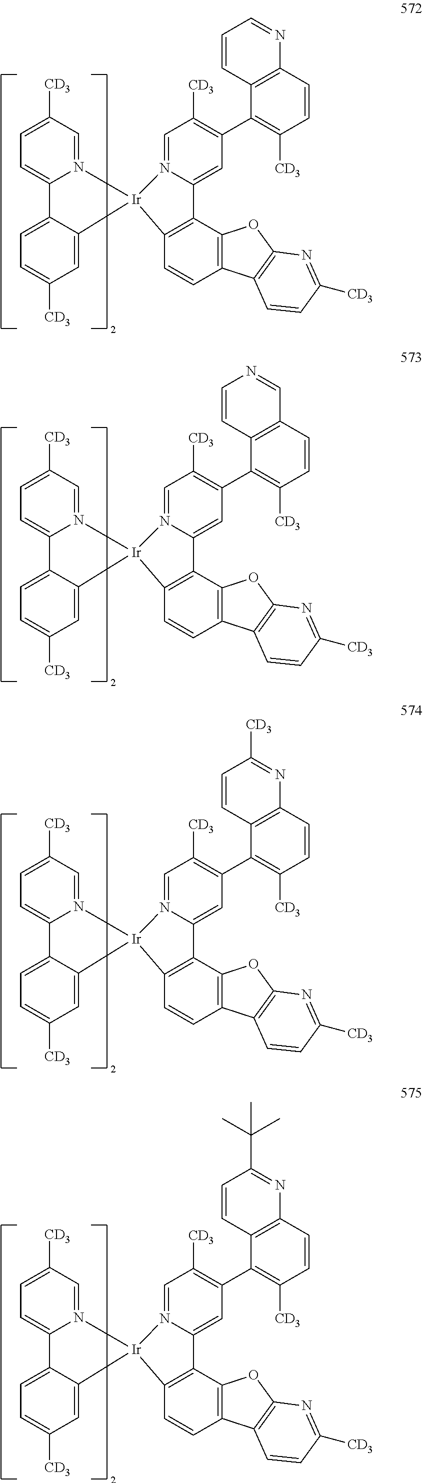

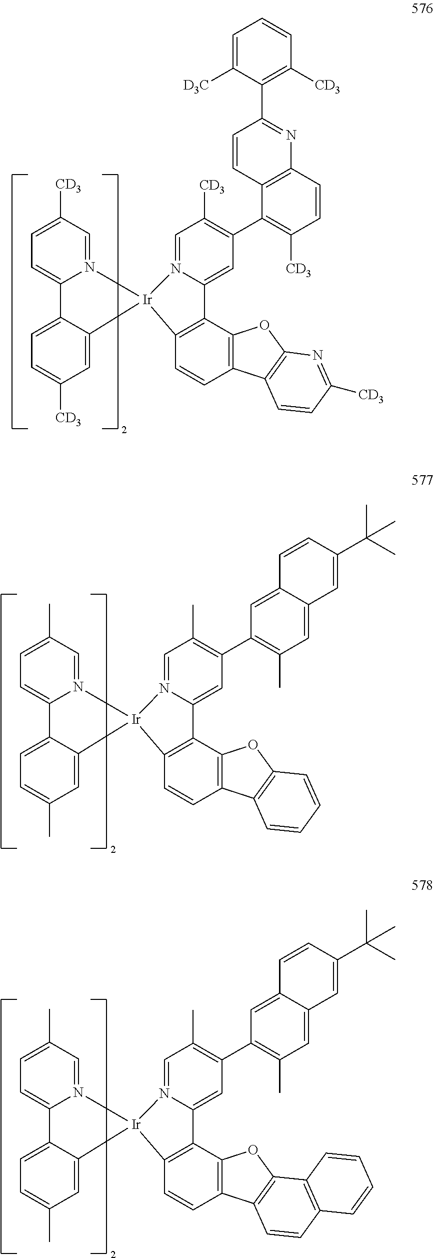

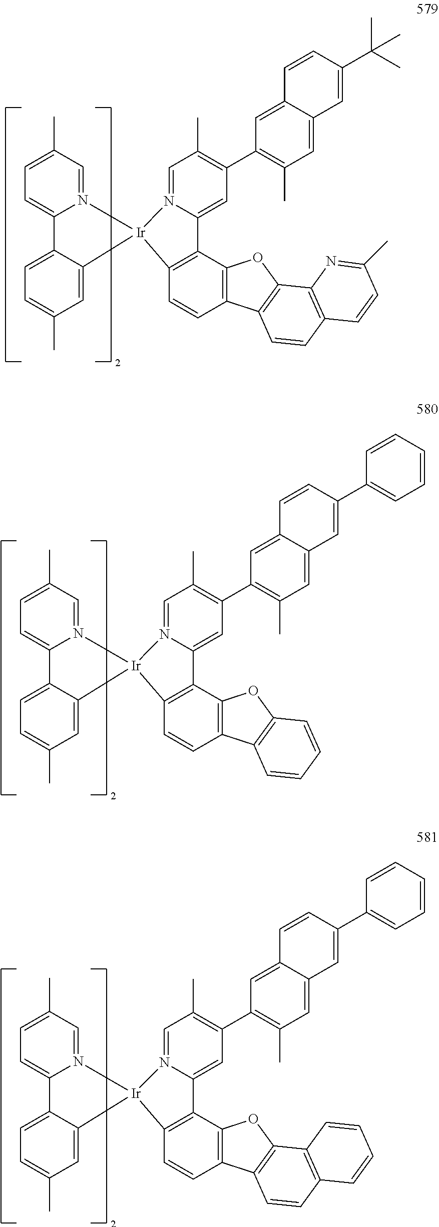

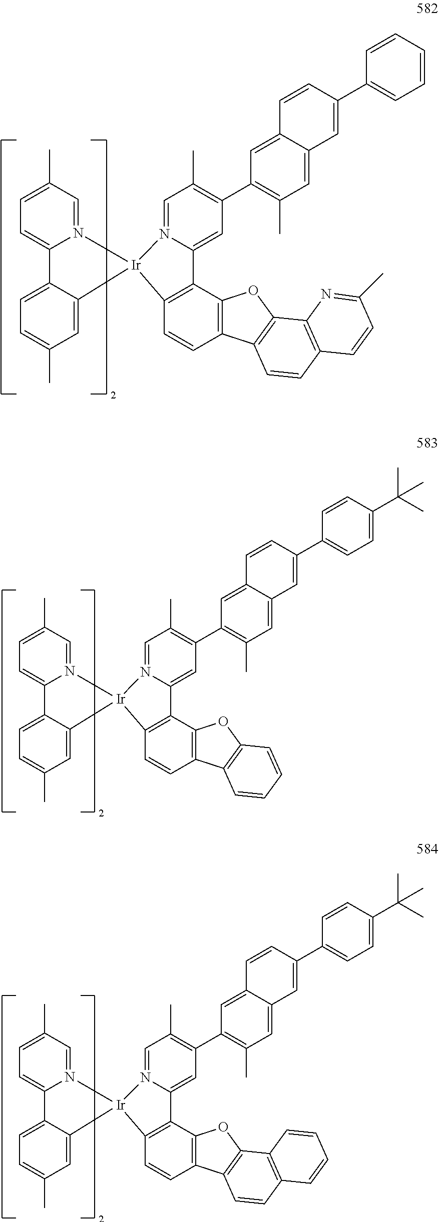

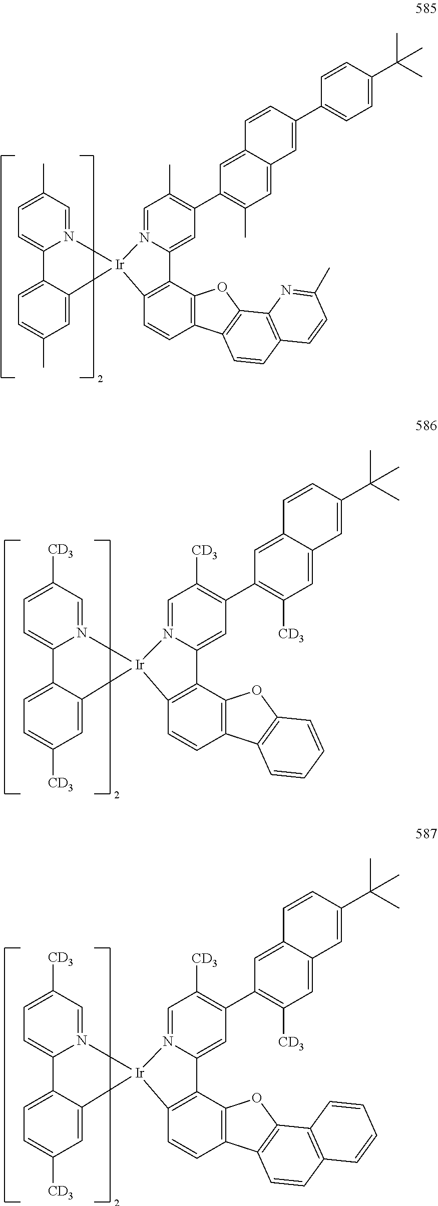

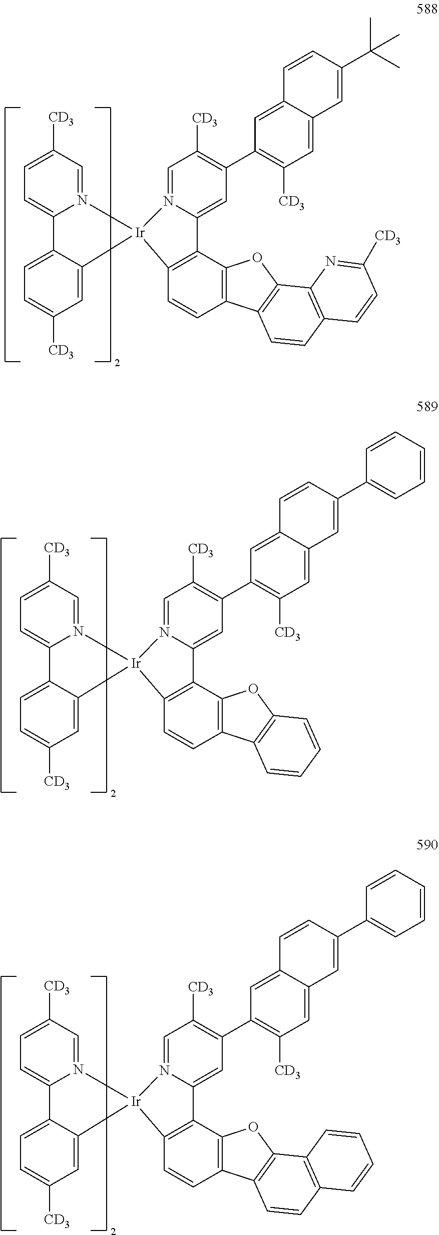

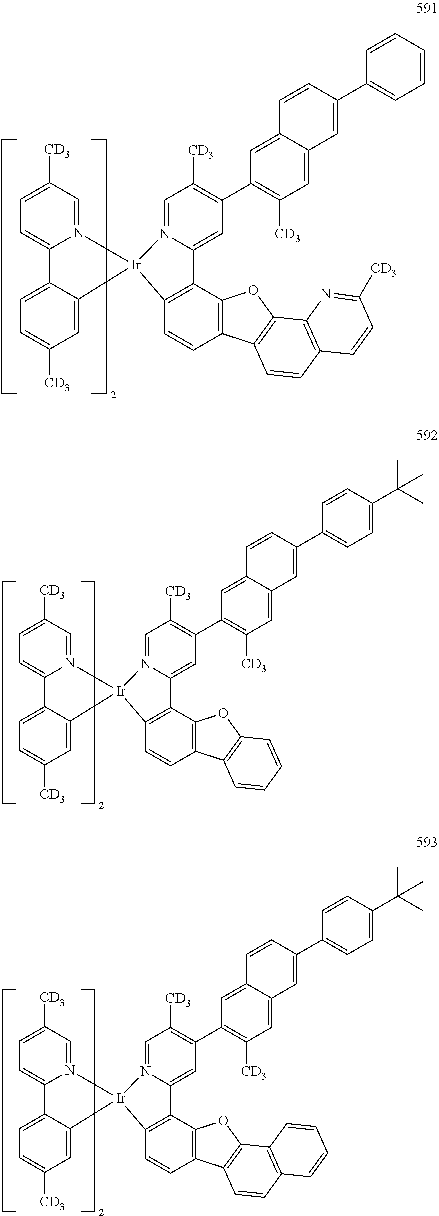

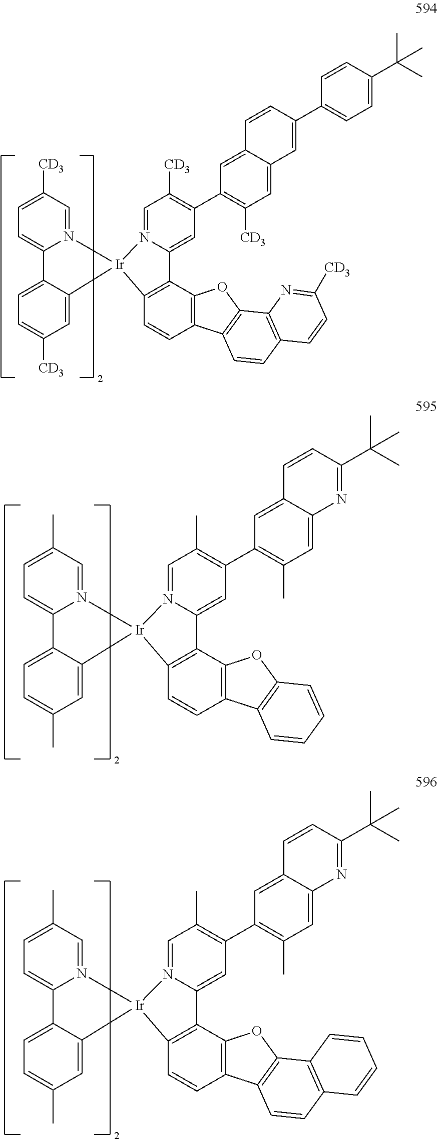

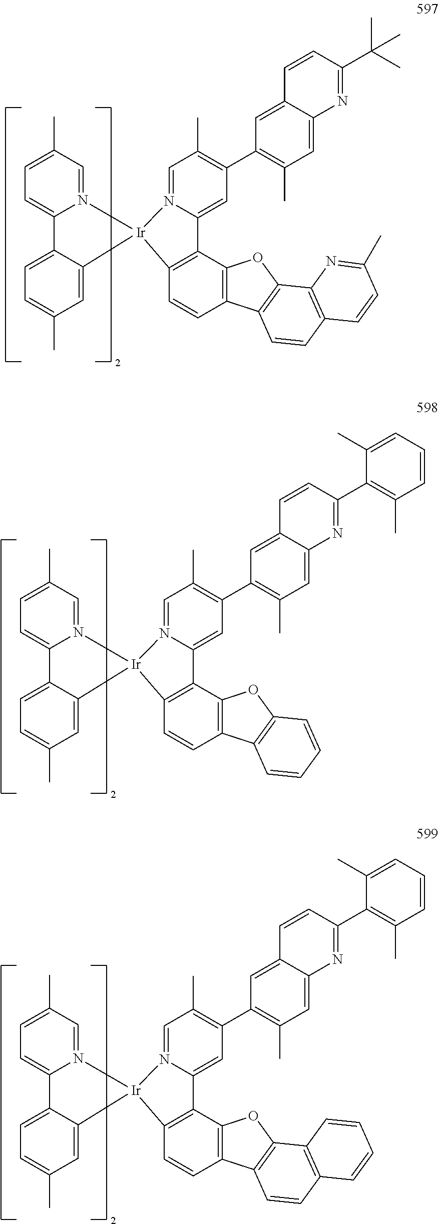

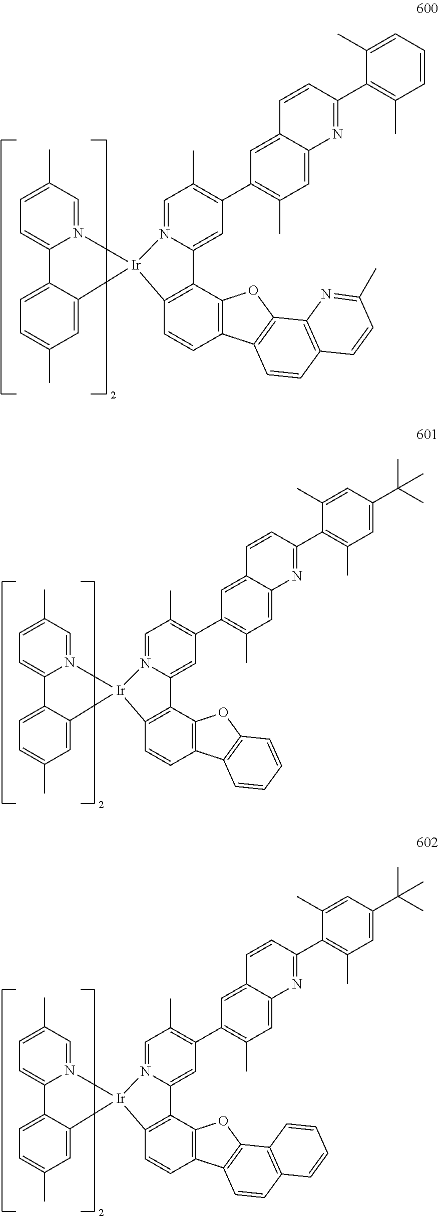

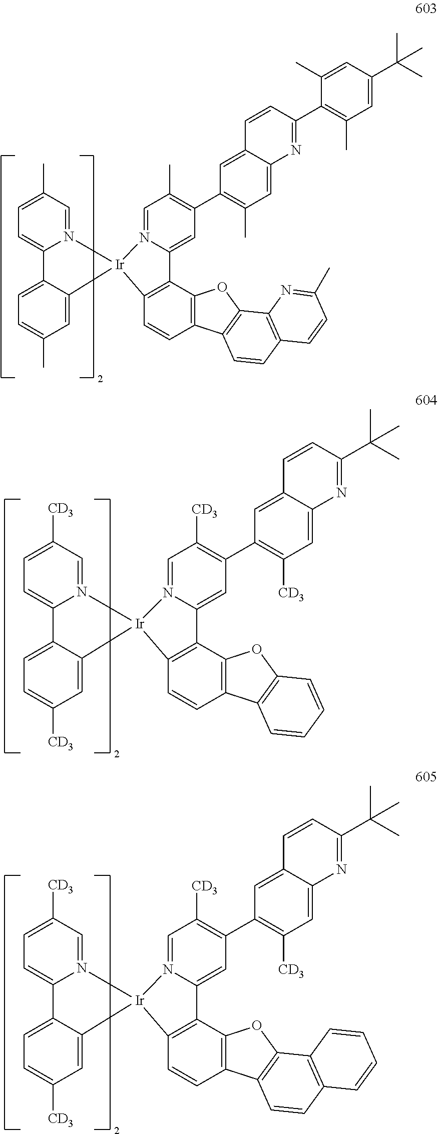

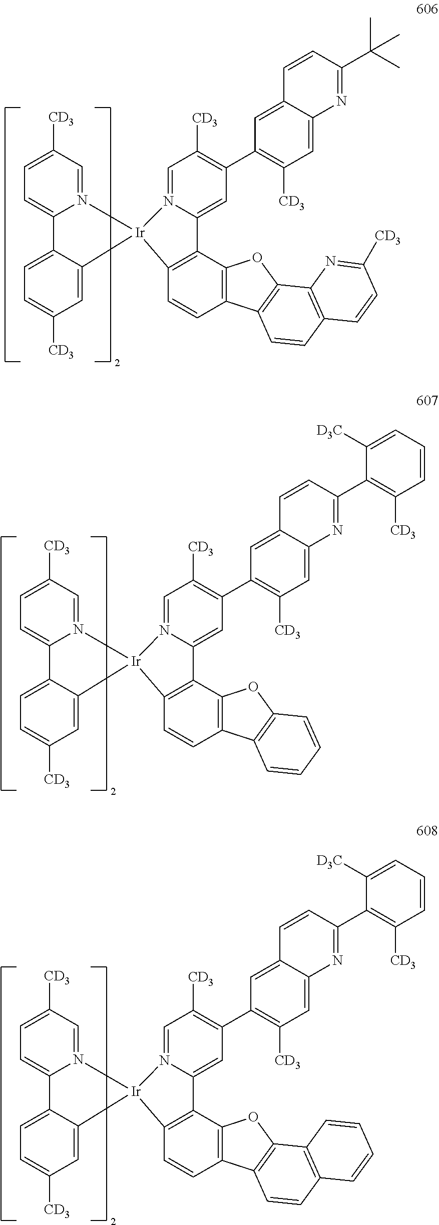

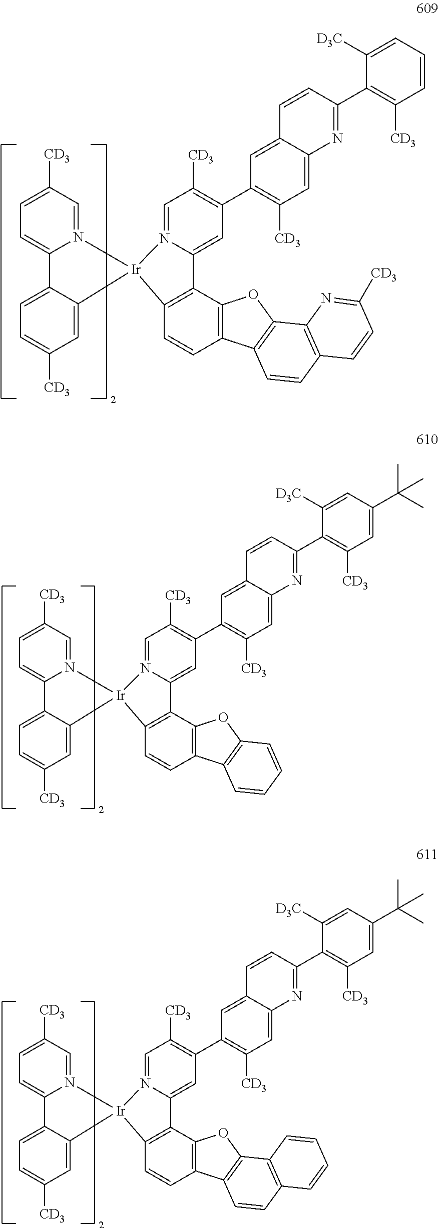

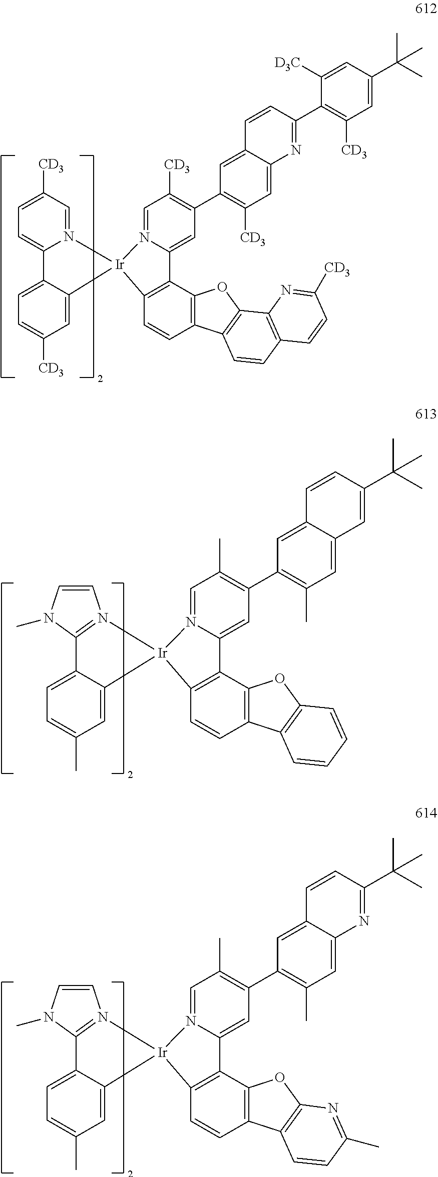

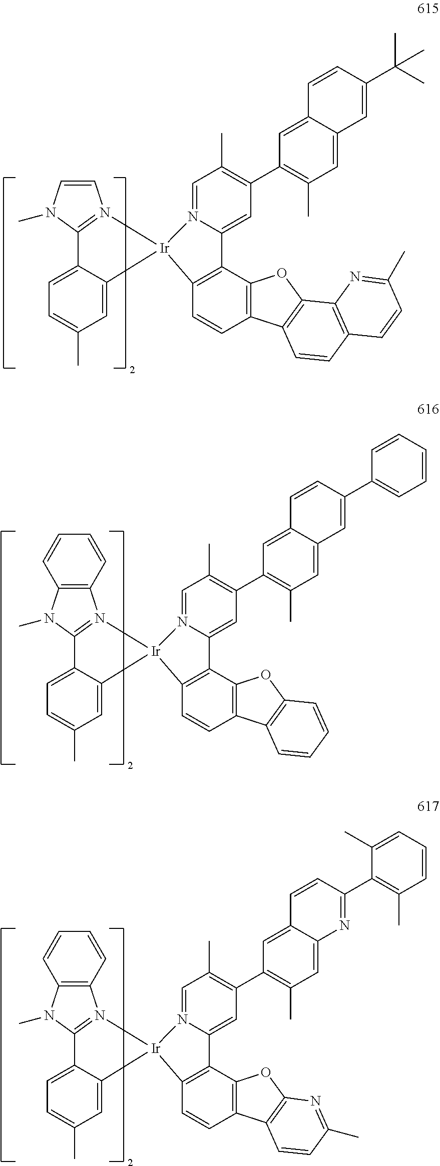

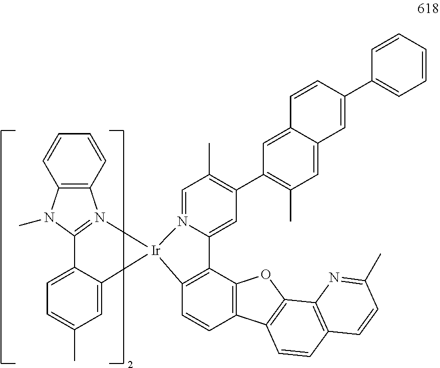

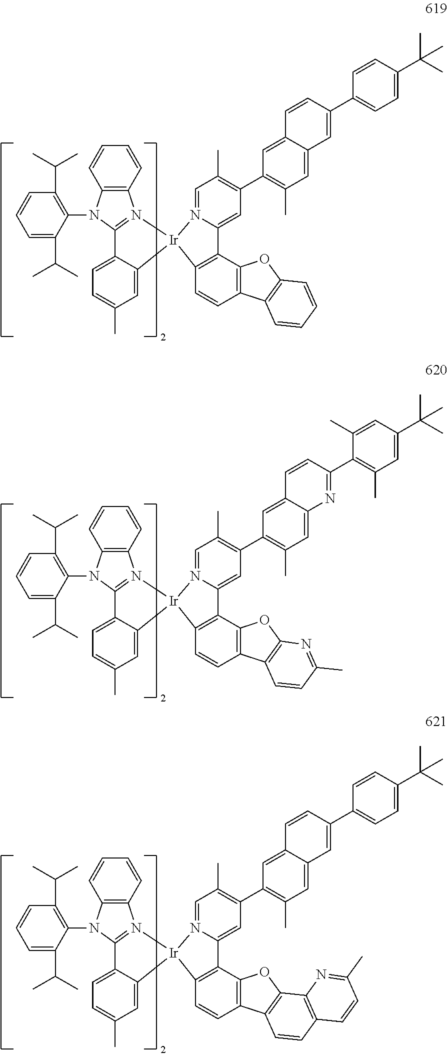

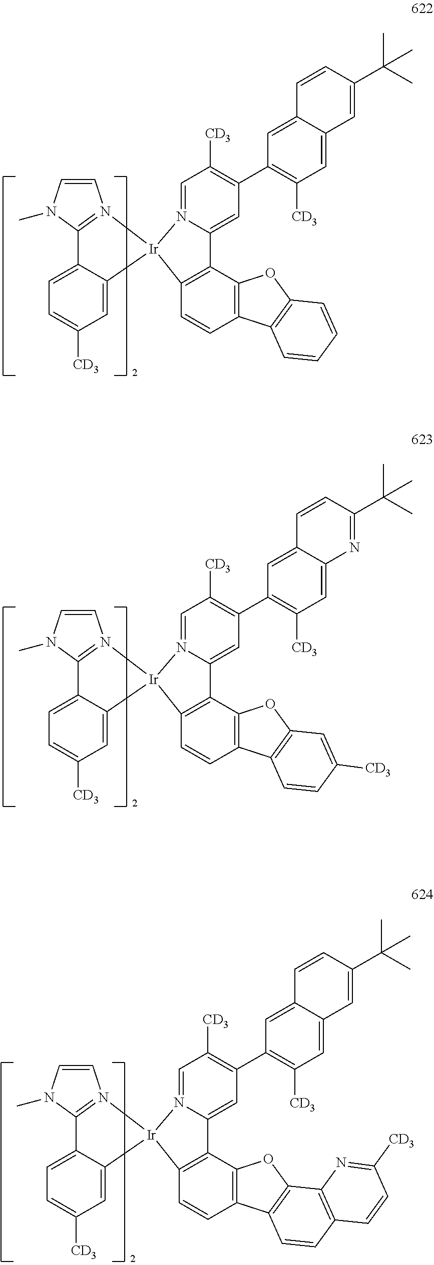

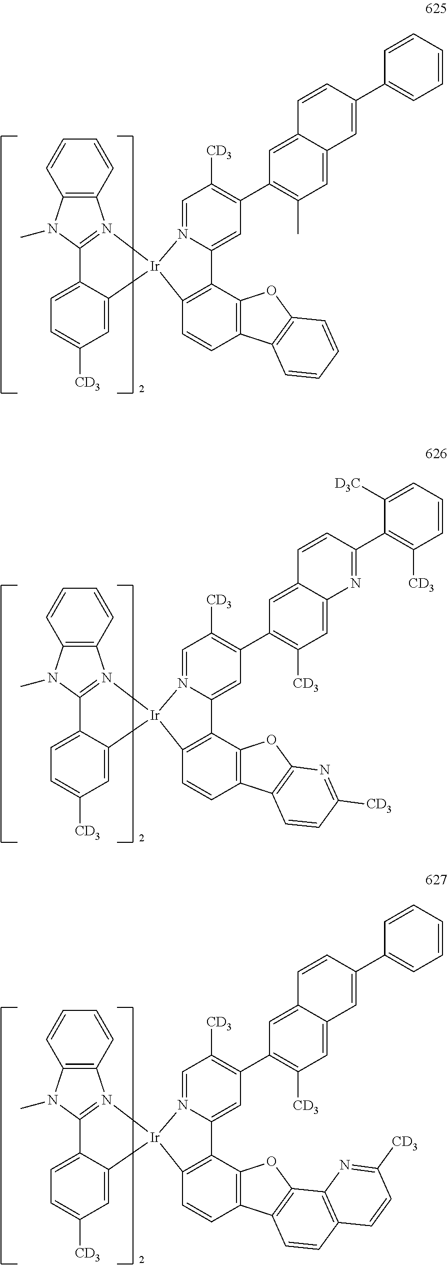

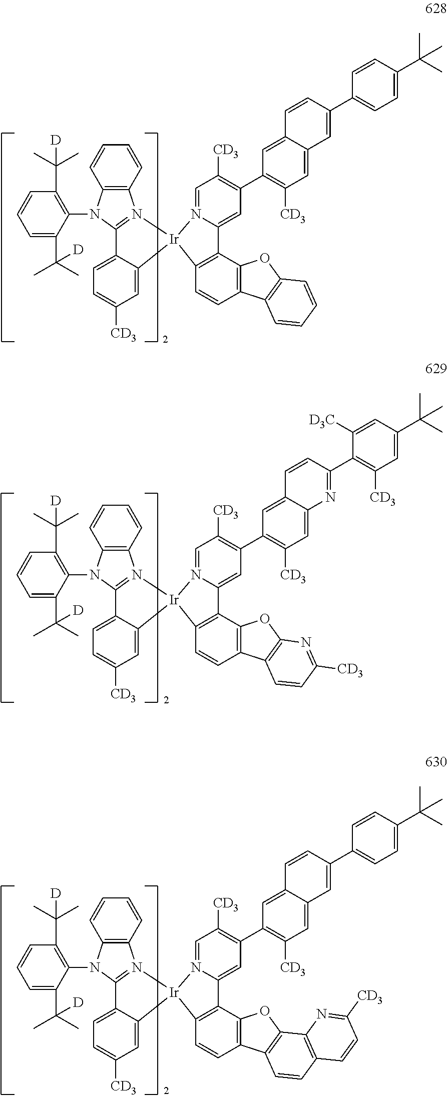

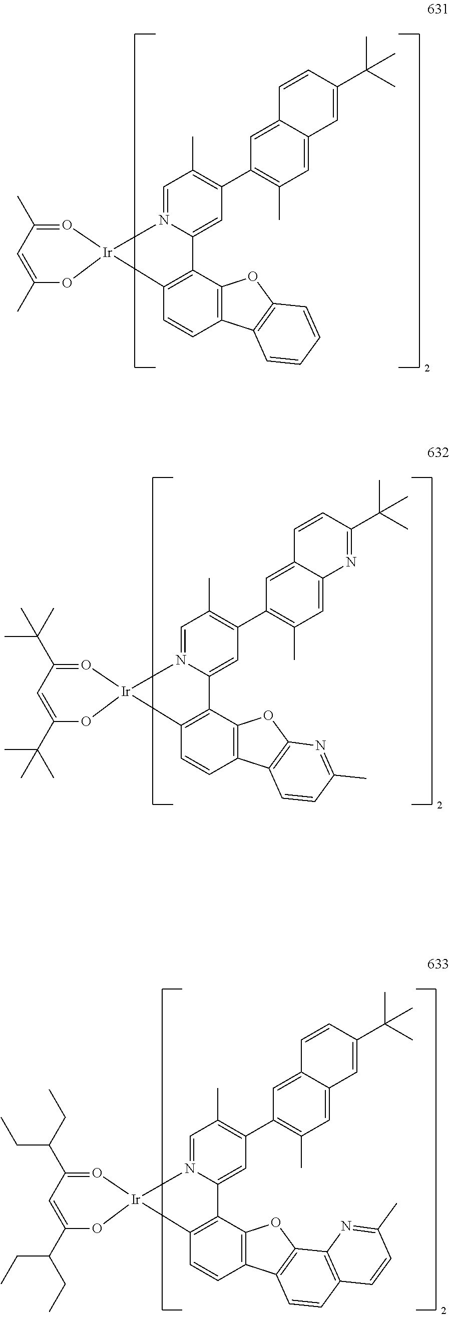

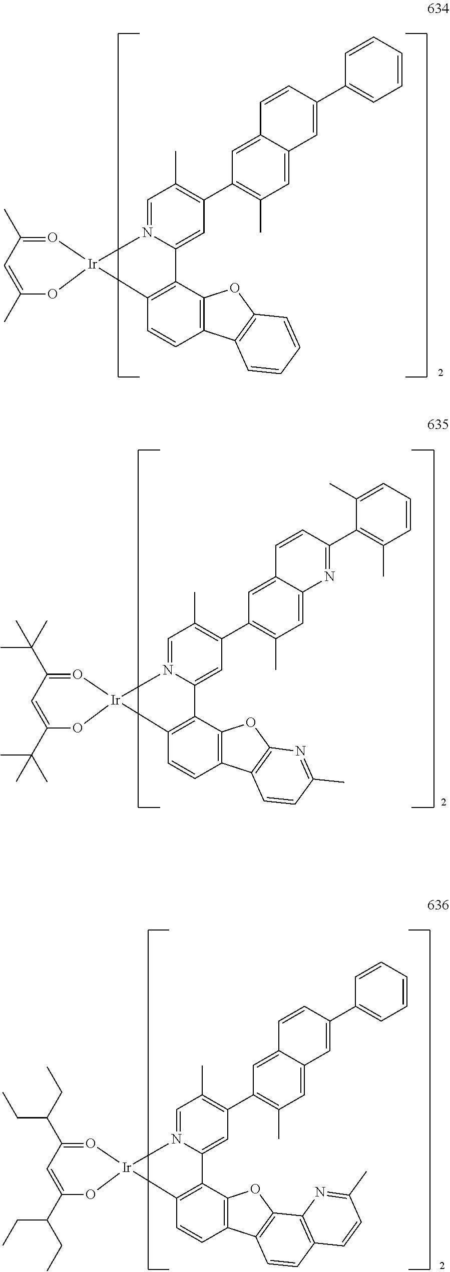

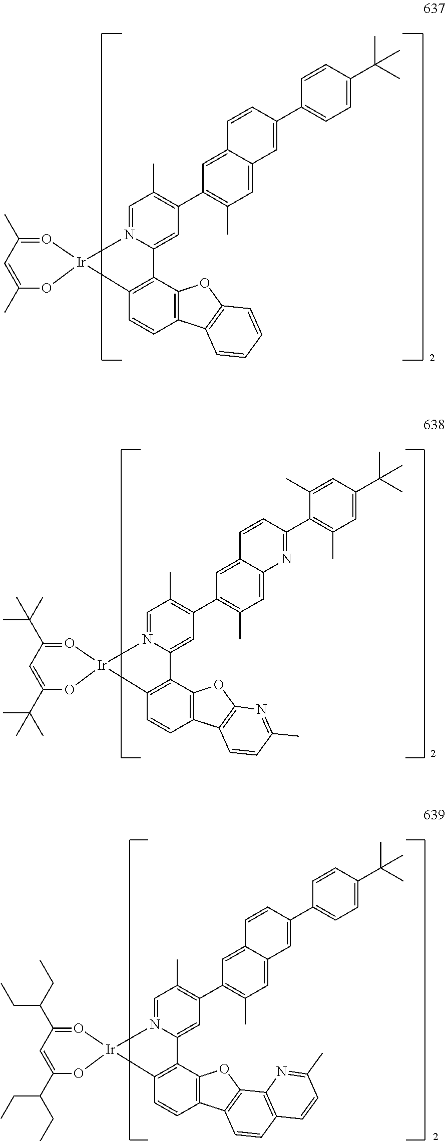

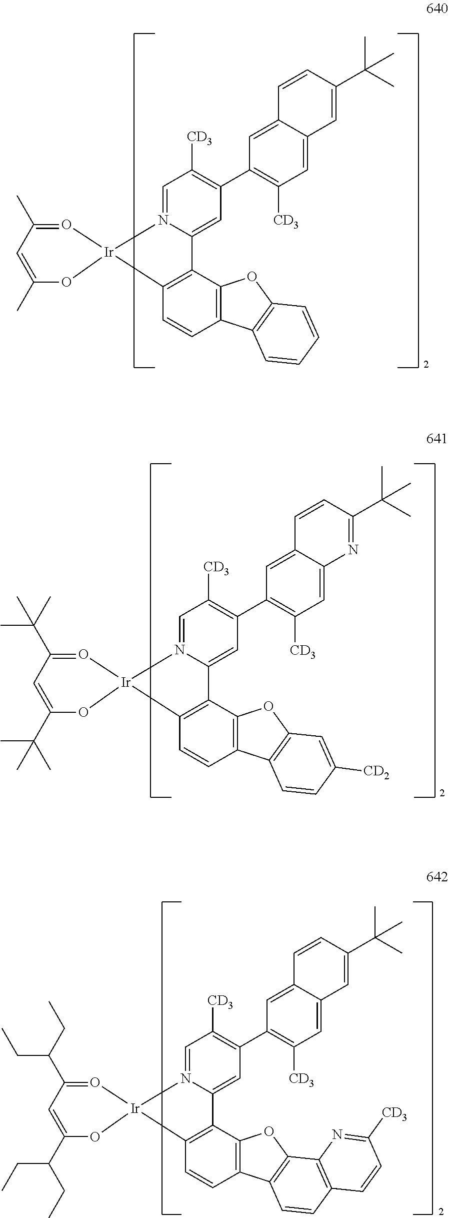

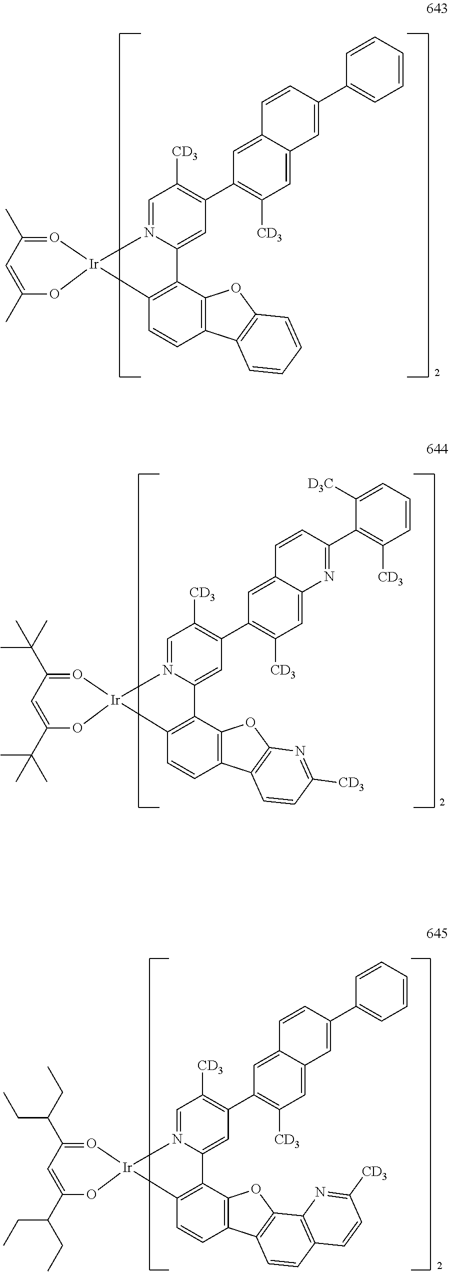

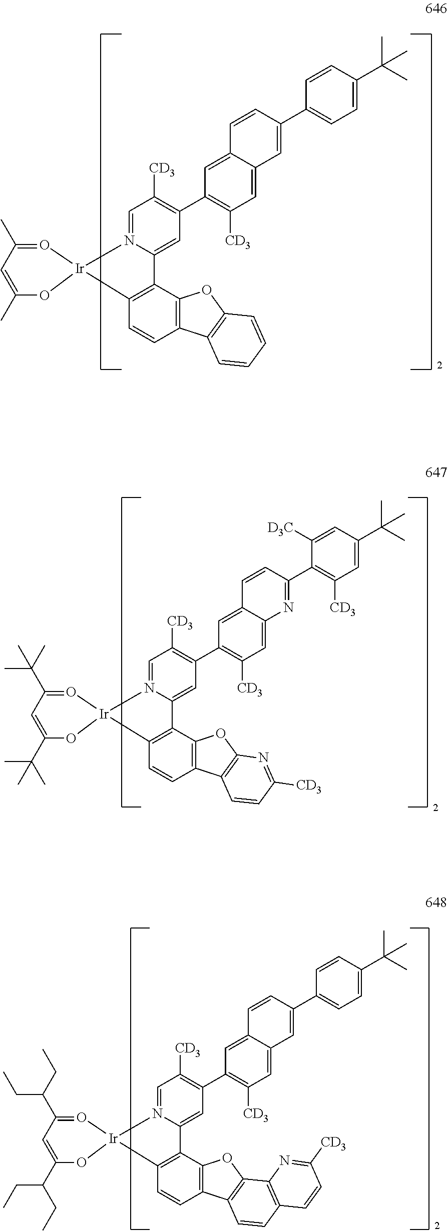

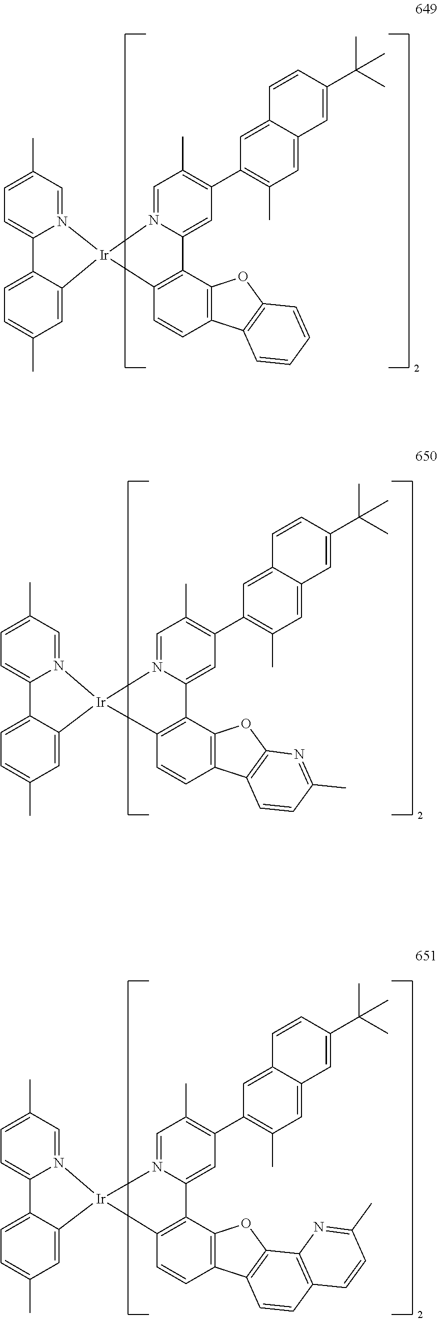

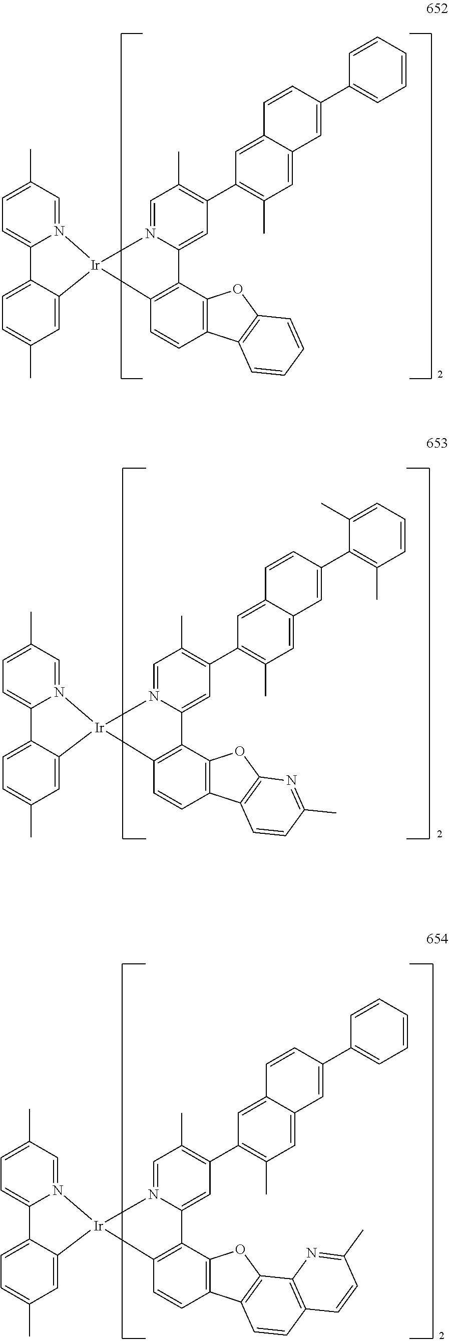

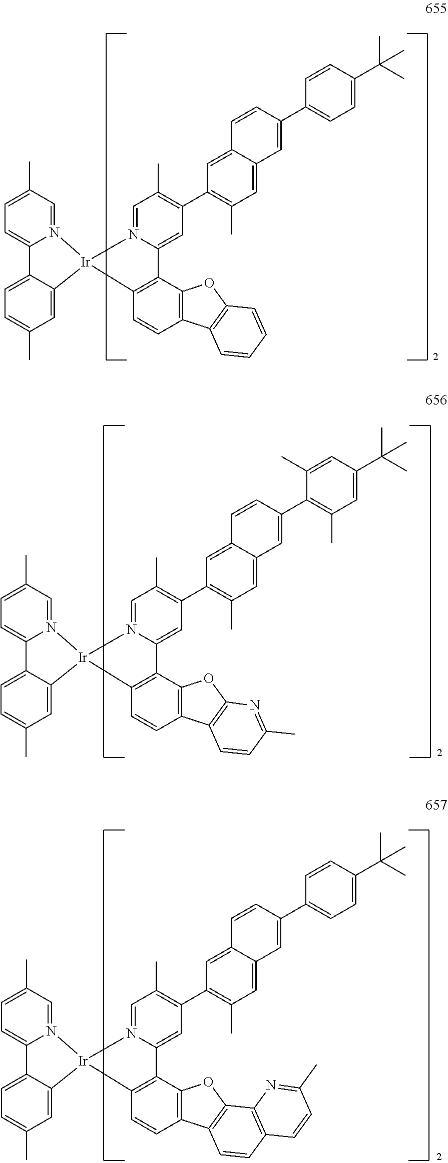

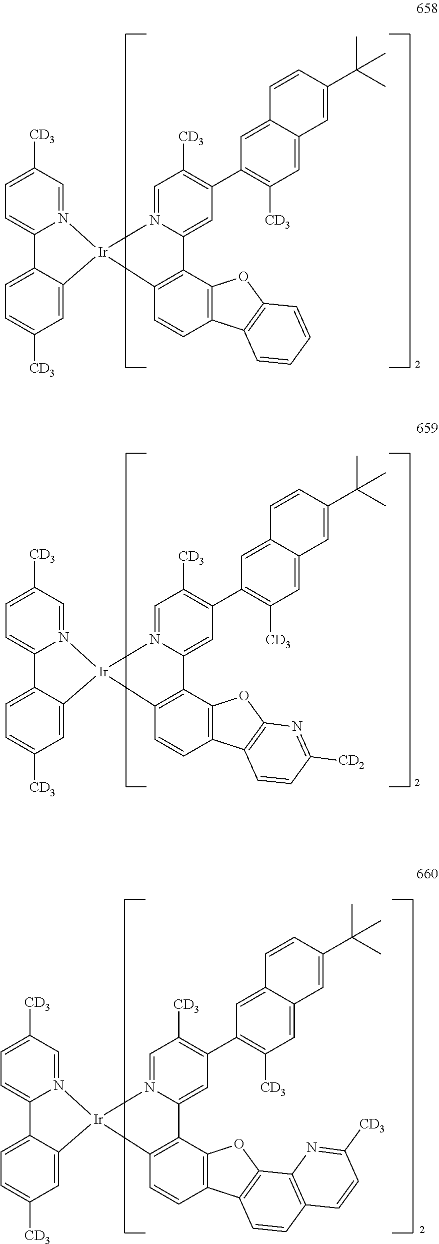

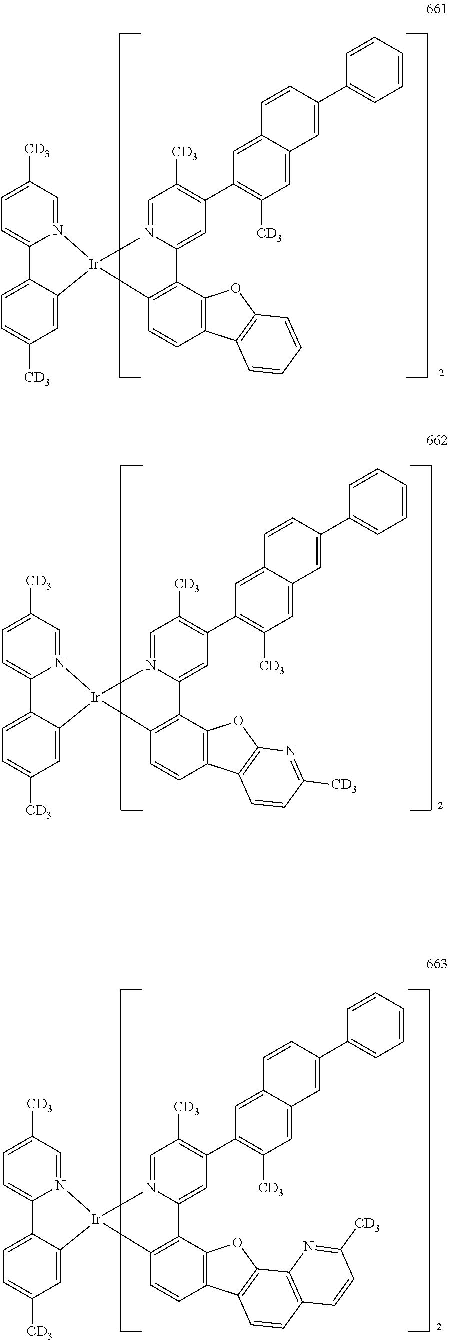

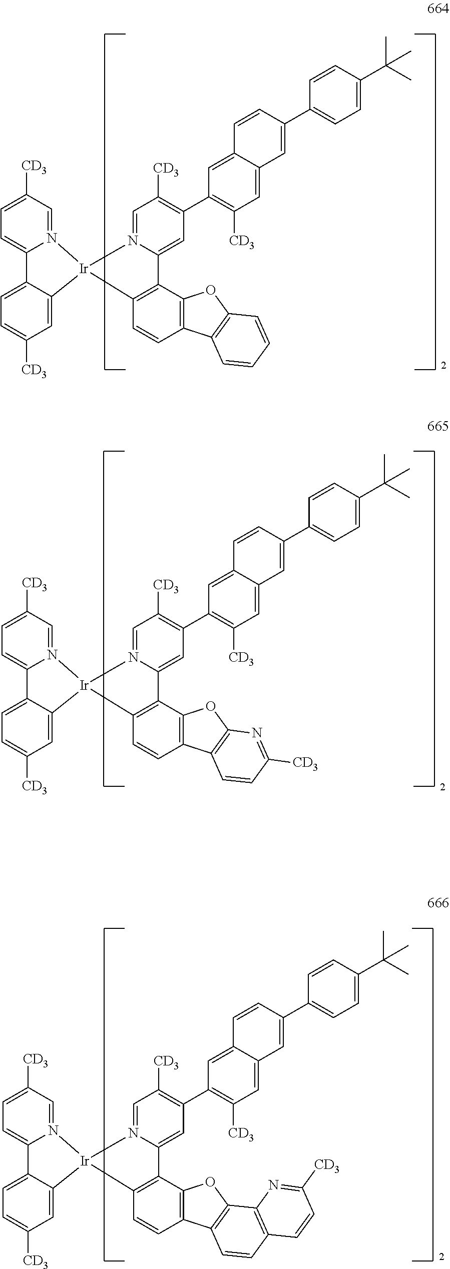

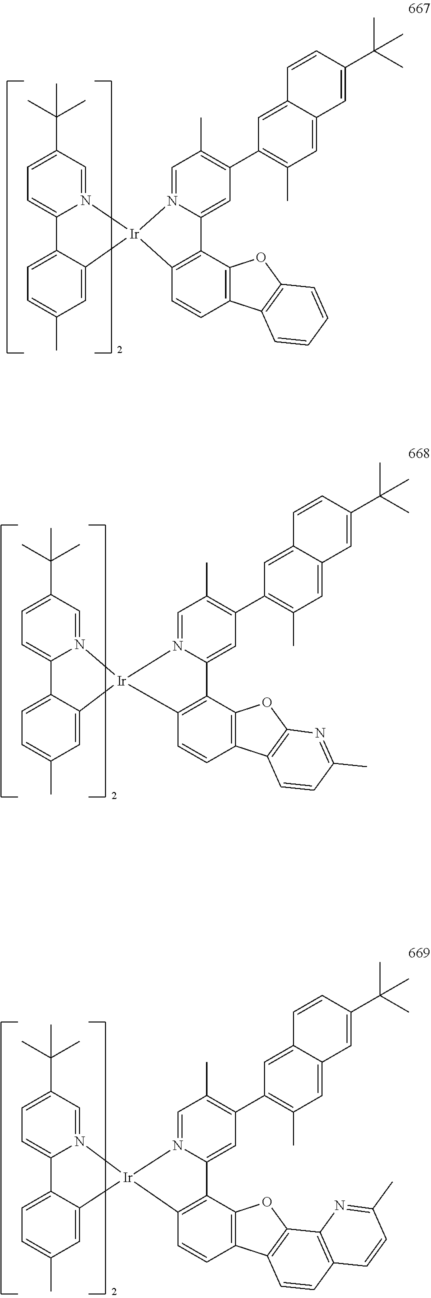

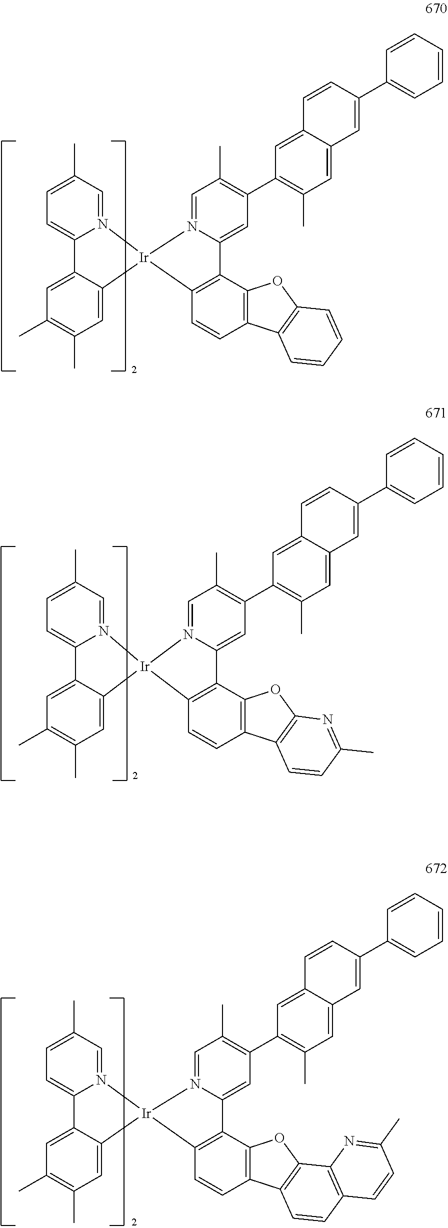

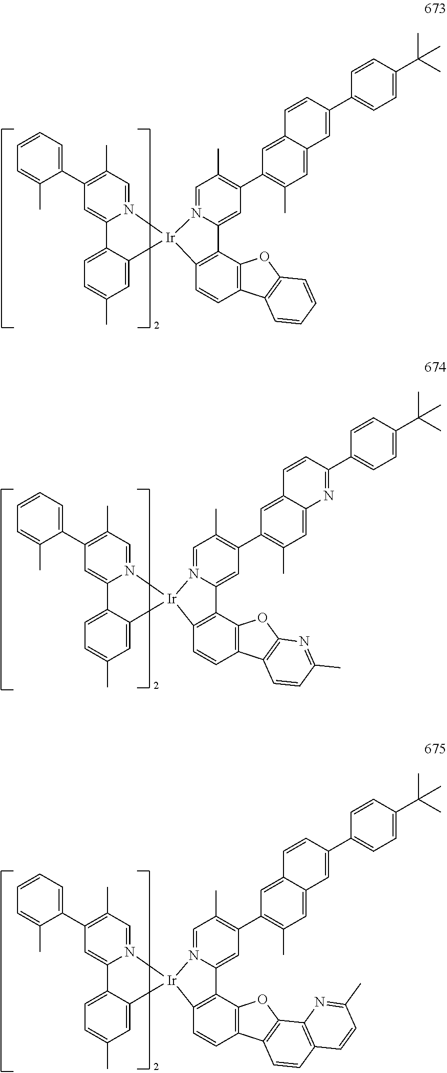

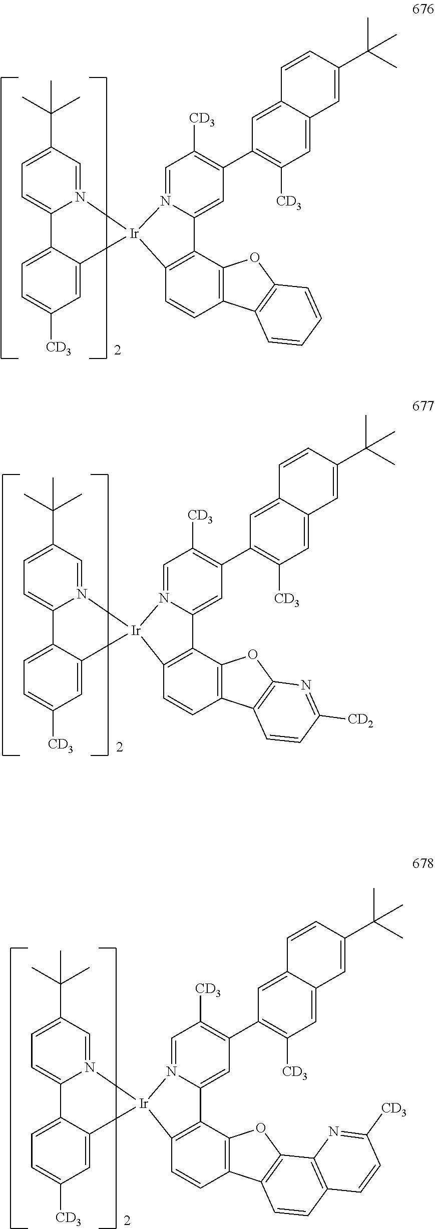

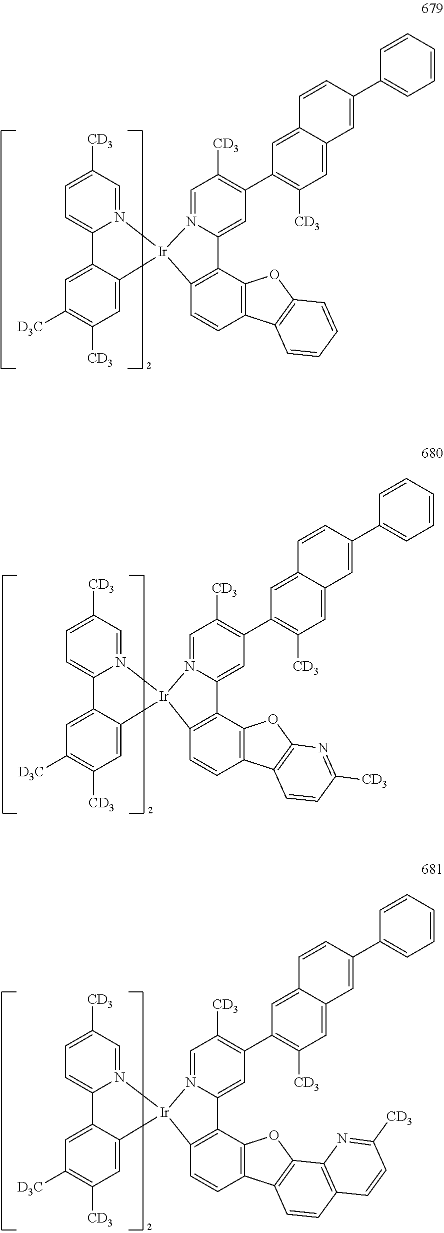

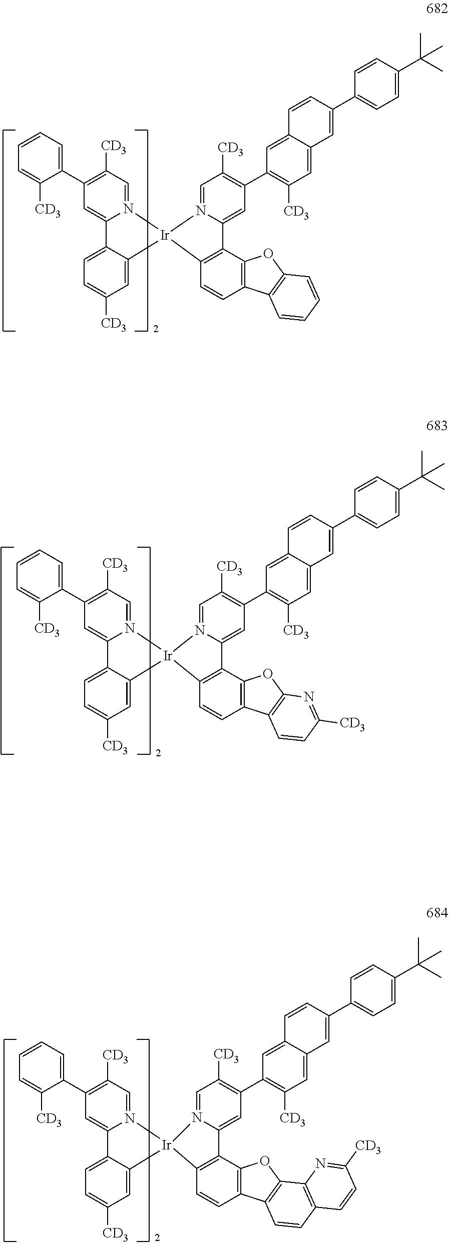

The organometallic compound having the structure of Formula 1 has a main ligand in which a plurality of aromatic rings and heteroaromatic rings are fused. Accordingly, the full-width at half maximum (FWHM) in the emission spectrum is narrow. In particular, since the organometallic compound has a solid chemical structure, the rotation of the chemical structure is not free during the light emission process, so that a good light emission lifespan can be stably maintained. Since the emission spectrum of the organometallic compound according to the present disclosure can be limited to a specific range, the color purity of the organometallic compound is improved.

In addition, the organometallic compound of the present disclosure can be a heteroleptic metal complex compound in which different main ligand and auxiliary ligand are bonded to a central metal (iridium). Therefore, the color purity and the emission wavelength range of the organometallic compound can be easily controlled.

The organometallic compound having the structure of Formula 1 can have an emission wavelength range of green to red. For example, the organometallic compound having the structure of Formula 1 can be used as at least one of a green dopant, a yellow-green dopant and a red dopant.

The organometallic compound of the present disclosure, which is represented by Formula 1 and one of the compounds in Formula 3, can have an emission wavelength range of green to red and is included in an emitting material layer of an OLED so that the emitting efficiency and the emission lifespan of the OLED can be increased.

The present disclosure relates to an OLED, in which the organometallic compound represented by Formula 1 is included in an emitting material layer, and an organic light emitting device including the OLED. As an example, an organic light emitting display device, which is a display device including the OLED of the present disclosure, will be mainly described. For instance, various display devices according to all embodiments of the present disclosure can include a plurality of pixels or subpixels including OLEDs having the configurations of FIGS. 2-8.

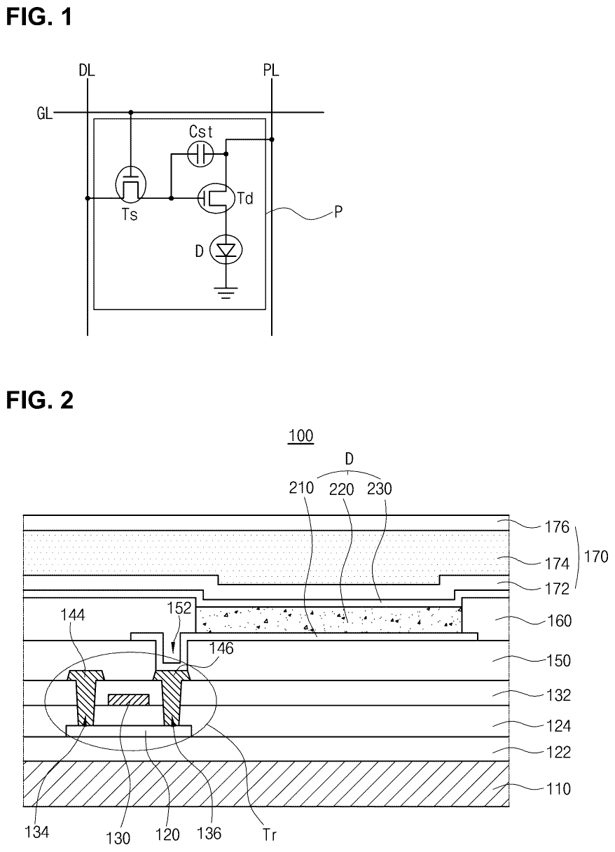

FIG. 1 is a schematic circuit diagram of an organic light emitting display device according to one or more embodiments of the present disclosure. A display device can include a plurality of such organic light emitting display device of FIG. 1, which can be arranged in a specific manner such as a matrix configuration or the like.

As shown in FIG. 1, the organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region can include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr and an OLED D connected to the TFT Tr.

The substrate 110 can be a glass substrate or a flexible substrate. For example, the substrate 110 can be one of a polyimide (PI) substrate, a polyethersulfone (PES) substrate, a polyethylenenaphthalate (PEN) substrate, a polyethylene Terephthalate (PET) substrate and a polycarbonate (PC) substrate.

A buffer layer 122 is formed on the substrate, and the TFT Tr is formed on the buffer layer 122. The buffer layer 122 can be omitted.

A semiconductor layer 120 is formed on the buffer layer 122 (or over the substrate 110 when the buffer layer 122 is not present). The semiconductor layer 120 can include an oxide semiconductor material or polycrystalline silicon.

When the semiconductor layer 120 includes the oxide semiconductor material, a light-shielding pattern can be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities can be doped into both sides of the semiconductor layer 120.

A gate insulating layer 124 is formed on the semiconductor layer 120. The gate insulating layer 124 can be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120.

In FIG. 2, the gate insulating layer 124 is formed on an entire surface of the substrate 110. Alternatively, the gate insulating layer 124 can be patterned to have the same shape as the gate electrode 130.

An interlayer insulating layer 132, which is formed of an insulating material, is formed on the gate electrode 130. The interlayer insulating layer 132 can be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first and second contact holes 134 and 136 are formed through the gate insulating layer 124. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132.

The source electrode 144 and the drain electrode 146 are spaced apart from each other with respect to the gate electrode 130 and respectively contact both sides of the semiconductor layer 120 through the first and second contact holes 134 and 136.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure.

Alternatively, in the TFT Tr, the gate electrode can be positioned under the semiconductor layer, and the source and drain electrodes can be positioned over the semiconductor layer such that the TFT Tr can have an inverted staggered structure. In this instance, the semiconductor layer can include amorphous silicon.

Although, the gate line and the data line cross each other to define the pixel region, and the switching TFT is formed to be connected to the gate and data lines. The switching TFT is connected to the TFT Tr as the driving element. In addition, the power line, which can be formed to be parallel to and spaced apart from one of the gate and data lines, and the storage capacitor for maintaining the voltage of the gate electrode of the TFT Tr in one frame can be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr.

The OLED D is disposed on the planarization layer 150 and includes a first electrode 210, which is connected to the drain electrode 146 of the TFT Tr, an light emitting layer 220 and a second electrode 230. The light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 can be an anode and can be formed of a conductive material, e.g., a transparent conductive oxide (TCO), having a relatively high work function. For example, the first electrode 210 can be formed of indium-tin-oxide (ITO), indium-zinc-oxide (IZO), indium-tin-zinc-oxide (ITZO), tin oxide (SnO), zinc oxide (ZnO), indium-copper-oxide (ICO) or aluminum-zinc-oxide (Al:ZnO, AZO).

When the organic light emitting display device 100 of the present disclosure is operated in a bottom-emission type, the first electrode 210 can have a single-layered structure of a transparent conductive oxide layer of the transparent conductive oxide. Alternatively, when the organic light emitting display device 100 of the present disclosure is operated in a top-emission type, the first electrode 210 can further include a reflection layer to have a double-layered structure or a triple-layered structure. For example, the reflection layer can be formed of silver (Ag) or aluminum-palladium-copper (APC) alloy. In the top-emission type OLED, the first electrode 210 can have a double-layered structure of Ag/ITO or APC/ITO or a triple-layered structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 is formed on the first electrode 210. The organic light emitting layer 220 can have a single-layered structure of an emitting material layer (EML) including an emitting material. Alternatively, the organic light emitting layer 220 can further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure. In addition, two or more organic light emitting layers can be disposed to be spaced apart from each other such that the OLED D can have a tandem structure.

In at least one of the red pixel region and the green pixel region, the organic light emitting layer 220 of the OLED D includes the organometallic compound of the present disclosure so that the emitting efficiency and the lifespan of the OLED D and the organic light emitting display device 100 are improved.

The second electrode 230 is formed over the substrate 110 where the organic light emitting layer 220 is formed. The second electrode 230 covers an entire surface of the display area and can be formed of a conductive material having a relatively low work function to serve as a cathode. For example, the second electrode 230 can be formed of a high reflective material, e.g., aluminum (Al), magnesium (Mg), calcium (Ca), silver (Ag), their alloy, or their combination. In the top-emission type organic light emitting display device 100, the second electrode 230 can be thin to be transparent (or semi-transparent).

An encapsulation layer (or an encapsulation film) 170 is formed on the second electrode 230 to prevent penetration of moisture into the OLED D. The encapsulation layer 170 includes a first inorganic insulating layer 172, an organic insulating layer 174 and a second inorganic insulating layer 176 sequentially stacked, but it is not limited thereto.

The organic light emitting display device 100 can include a color filter layer corresponding to the red, green and blue pixel regions. The color filter layer can include a red color filter, a green color filter and a blue color filter corresponding to the red, green and blue pixel regions, respectively. When the OLED includes the color filter layer, the color purity of the OLED can be further improved.

When the organic light emitting display device 100 is operated in a bottom-emission type, the color filter can be disposed between the OLED D and the substrate 110, e.g., between the interlayer insulating layer 132 and the planarization layer 150. Alternatively, the organic light emitting display device 100 is operated in a top-emission type, the color filter can be disposed over the OLED D, e.g., over the second electrode 230. For example, the color filter layer can be disposed on the encapsulation layer 170.

In the bottom-emission type organic light emitting display device 100, a metal plate can be further disposed on the encapsulation layer 170.

The organic light emitting display device 100 can further include a polarization plate for reducing an ambient light reflection. For example, the polarization plate can be a circular polarization plate. In the bottom-emission type organic light emitting display device 100, the polarization plate can be positioned under the substrate 110. Alternatively, in the top-emission type organic light emitting display device 100, the polarization plate can be positioned on or over the encapsulation layer 170.

In addition, in the top-emission type organic light emitting display device 100, a cover window can be attached to the encapsulation layer 170. In this instance, the substrate 110 and the cover window have a flexible property such that a flexible organic light emitting display device can be provided.

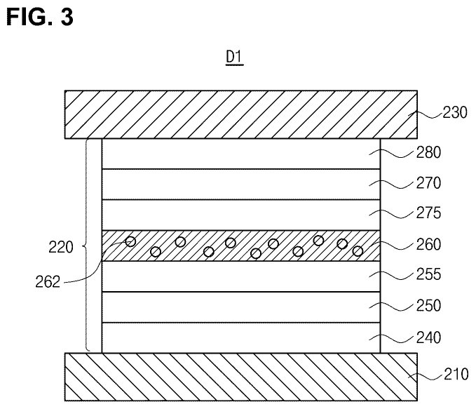

FIG. 3 is a schematic cross-sectional view of an OLED according to a second embodiment of the present disclosure.

As shown in FIG. 3, the OLED D1 includes the first and second electrodes 210 and 230, which face each other, and the organic light emitting layer 220 therebetween.

The organic light emitting display device 100 includes the red, green and blue pixel regions. In addition, the organic light emitting display device 100 can further include a white pixel region. The OLED D1 can be positioned in at least one of the red and green pixel regions. For example, the OLED D1 can be positioned in the green pixel region.

The first electrode 210 can be anode, and the second electrode 230 can be a cathode. One of the first and second electrodes 210 and 230 can be a transparent electrode (or a semi-transparent electrode), and the other one of the first and second electrodes 210 and 230 can be a reflection electrode.

The organic light emitting layer 220 includes an emitting material layer (EML) 260.

The organic light emitting layer 220 further include at least one of a hole transporting layer (HTL) 250 between the first electrode 210 and the EML 260 and an electron transporting layer (ETL) 270 between the second electrode 230 and the EML 260.

In addition, the organic light emitting layer 220 can further include at least one of a hole injection layer (HIL) 240 between the first electrode 210 and the HTL 250 and an electron injection layer (EIL) 280 between the second electrode 230 and the ETL 270.

Moreover, the organic light emitting layer 220 can further include at least one of an electron blocking layer (EBL) 255 between the HTL 250 and the EML 260 and a hole blocking layer (HBL) 275 between the EML 260 and the ETL 270.

Namely, the OLED D1 according to the second embodiment of the present disclosure has a single emitting part (unit).

For example, the HIL 240 can include a hole injection material selected from the group consisting of

4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile (HAT-CN), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine), and N,N′-diphenyl-N,N′-di[4-(N,N-diphenyl-amino)phenyl]benzidine (NPNPB), but it is not limited thereto. For example, the hole injection material of the HIL 240 can include a compound in Formula 4. The HIL 240 can have a thickness of 5 to 100 nm.

The HTL 250 can include a hole transporting material selected from the group consisting of N,N′-diphenyl-N,N′-bis(3-methylphenyl)-1,1′-biphenyl-4,4′-diamine (TPD), NPB (NPD), 4,4′-bis(N-carbazolyl)-1,1′-biphenyl (CBP), poly[N,N′-bis(4-butylpnehyl)-N,N′-bis(phenyl)-benzidine](poly-TPD), (poly[(9,9-dioctylfluorenyl-2,7-diyl)-co-(4,4′-(N-(4-sec-butylphenyl)diphenylamine))](TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, and N-([1,1′-biphenyl]-4-yl)-9,9-dimethyl-N-(4-(9-phenyl-9H-carbazol-3-yl)phenyl)-9H-fluoren-2-amine, but it is not limited thereto. For example, the hole transporting material of the HTL 250 can include a compound in Formula 5. The HTL 250 can have a thickness of 50 to 150 nm, preferably 50 to 120 nm.

The ETL 270 can include an electron transporting material selected from the group consisting of tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl)-4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), diphenyl-4-triphenylsilyl-phenylphosphine oxide (TSPO1), and 2-[4-(9,10-Di-2-naphthalen2-yl-2-anthracen-2-yl)phenyl]-1-phenyl-1H-benzimidazole (ZADN). The electron transporting material of the ETL 270 can include a compound in Formula 7 and a compound in Formula 8, but it is not limited thereto. The ETL 270 can have a thickness of 10 to 50 nm, preferably 15 to 40 nm.

The EIL 280 can include an electron injection material selected from the group consisting of LiF, CsF, NaF, BaF₂, Liq, lithium benzoate, and sodium stearate, but it is not limited thereto. The EIL 280 can have a thickness of 0.1 to 10 nm, preferably 0.5 to 5 nm.

In FIG. 3, the ETL 270 and the EIL 280 as separated elements are formed. Alternatively, an electron transporting-injection layer as a single layer having an electron transporting function and an electron injection function can be formed. In this case, the electron transporting-injection layer can include an electron transporting material and an electron injection material and can have a thickness of 10 to 50 nm. For example, the electron transporting-injection layer can include a compound in Formula 7 and a compound in Formula 8, and a weight % of the compound in Formula 7 and a weight % of the compound in Formula 8 can be same.

The EBL 255, which is positioned between the HTL 250 and the EML 260 to block the electron transfer from the EML 260 into the HTL 250, can include an electron blocking material selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene), but it is not limited thereto. The EBL 255 can have a thickness of 1 to 30 nm.

The HBL 275, which is positioned between the EML 260 and the ETL 270 to block the hole transfer from the EML 260 into the ETL 270, can include the above material of the ETL 270. For example, the HBL 275 can include a hole blocking material selected from the group consisting of BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole, and TSPO1, but it is not limited thereto. The HBL 275 can have a thickness of 1 to 30 nm.

The EML 260 can have a thickness of 10 to 100 nm, preferably 20 to 50 nm.

In at least one of the red and green pixel regions, the EML 260 includes a first compound 262 being the organometallic compound of the present disclosure. The first compound 262 serves as a dopant (e.g., an emitter or a light emitter). In addition, the EML 260 can further include a second compound as a host. In the EML 260, a weight % of the first compound 262 is smaller than that of the second compound. For example, in the EML 260, the first compound 262 can have a weight % of 1 to 40, preferably 1 to 20, more preferably 1 to 10.

When the EML 260 in the red and green pixel regions includes the organometallic compound of the present disclosure as the first compound 262, the first compound 262 (e.g., a red dopant) in the EML 260 in the red pixel region and the first compound 262 (e.g., a green dopant) in the EML 260 in the green pixel region have a difference in the auxiliary ligand in Formula 1 to have a difference in the emission wavelength.

For example, when the voltage is applied to the first and second electrodes 210 and 230, a hole from the first electrode 210 and an electron from the second electrode 230 are injected to the EML 260 so that an exciton is generated in the second compound. The generated exciton is transferred into the first compound 262, and thus the light is emitted from the first compound 262.

When the EML 260 in the green pixel region include the first compound 262 being the organometallic compound of Formula 1, the EML 260 in the green pixel region can further include a green host as the second compound.

For example, the second compound, i.e., the green host, can be one of 9-(3-(9H-carbazol-9-yl)phenyl)-9H-carbazole-3-carbonitrile (mCP-CN), CBP, 3,3′-bis(N-carbazolyl)-1,1′-biphenyl (mCBP), 1,3-bis(carbazol-9-yl)benzene (mCP), DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto.

When the EML 260 in the red pixel region include the first compound 262 being the organometallic compound of Formula 1, the EML 260 in the red pixel region can further include a red host as the second compound.

For example, the second compound, i.e., the red host, can be one of 9-(3-(9H-carbazol-9-yl)phenyl)-9H-carbazole-3-carbonitrile (mCP-CN), CBP, 3,3′-bis(N-carbazolyl)-1,1′-biphenyl (mCBP), 1,3-bis(carbazol-9-yl)benzene (mCP), DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbipheyl (CDBP), 2,7-bis(carbazole-9-yl)-9,9-dimethylfluorene (DMFL-CBP), 2,2′,7,7′-tetrakis(carbazole-9-yl)-9,9-spiorofluorene (Spiro-CBP), 3,6-bis(carbazole-9-yl)-9-(2-ethyl-hexyl)-9H-carbazole (TCz1), bis(2-hydroxylphenyl)-pyridine)beryllium (Bepp2), bis(10-hydroxylbenzo[h]quinolinato)beryllium (Bebg2), and 1,3,5-tris(1-pyrenyl)benzene (TPB3), but it is not limited thereto

Alternatively, the EML 260 in the red pixel region can include a red dopant being not the organometallic compound of Formula 1. In this instance, the red dopant can include at least one of a red phosphorescent material, a red fluorescent material and a red delayed fluorescent material. For example, the red dopant can be one of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)2(acac)), tris[2-(4-n-hexylphenyl)quinoline]iridium(III) (Hex-Ir(phq)3), tris[2-phenyl-4-methylquinoline]iridium(III) (Ir(Mphq)3), bis(2-phenylquinoline)(2,2,6,6-tetramethylheptene-3,5-dionate)iridium(III) (Ir(dpm)PQ2), bis(phenylisoquinoline)(2,2,6,6-tetramethylheptene-3,5-dionate)iridium(III) (Ir(dpm)(piq)2), bis[(4-n-hexylphenyl)isoquinoline](acetylacetonate)iridium(III) (Hex-Ir(piq)2(acac)), tris[2-(4-n-hexylphenyl)quinoline]iridium(III) (Hex-Ir(piq)3), tris(2-(3-methylphenyl)-7-methyl-quinolato)iridium (Ir(dmpq)3), bis[2-(2-methylphenyl)-7-methyl-quinoline](acetylacetonate)iridium(III) (Ir(dmpq)2(acac)), and bis[2-(3,5-dimethylphenyl)-4-methyl-quinoline](acetylacetonate)iridium(III) (Ir(mphmq)2(acac)).

The organometallic compound of the present disclosure is an iridium complex having a structure of Formula 1 and is included in the EML 260 of the OLED D1. As a result, the emitting efficiency and the lifespan of the OLED D1 and the organic light emitting display device 100 are improved.

### EXAMPLES

The following examples are exemplary and not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### [Synthesis]

### 1. Synthesis of an Intermediate a

### (1) An Intermediate A-2

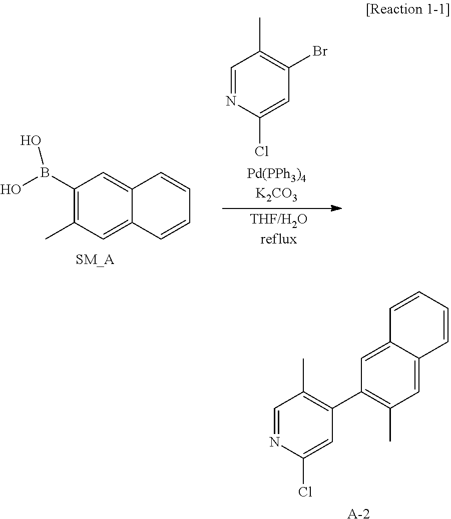

The mixture of the compound SM_A (13.0 g, 70.0 mmol), 4-bromo-2-chloro-5-methylpyridine (16.5 g, 80.0 mmol), Pd(PPh3)4 (2.3 g, 2.0 mmol) and calcium carbonate (22.1 g, 160.0 mmol) were added into the solvent (500 ml) of tetrahydrofuran and water and refluxed overnight. After removing the solvent of the crude mixture, the intermediate A-2 14.2 g (76%, 53.2 mmol) was obtained by silica gel column chromatography.

### (2) An Intermediate A-1

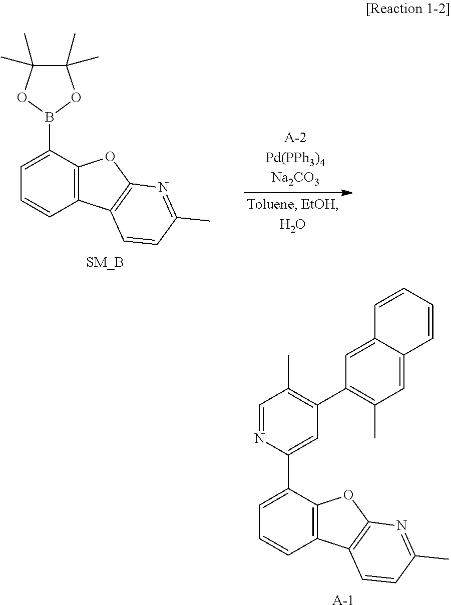

The mixture of the compound SM_B (15.5 g, 50.0 mmol), the intermediate A-2 (13.9 g, 52.0 mmol), Pd(PPh3)4 (1.2 g, 1.0 mmol) and sodium carbonate (15.9 g, 150.0 mmol) were added into the solvent (500 ml) of toluene, ethanol and water and refluxed overnight. After removing the solvent of the crude mixture, the intermediate A-1 13.8 g (64%, 33.3 mmol) was obtained by silica gel column chromatography.

### (3) An Intermediate A

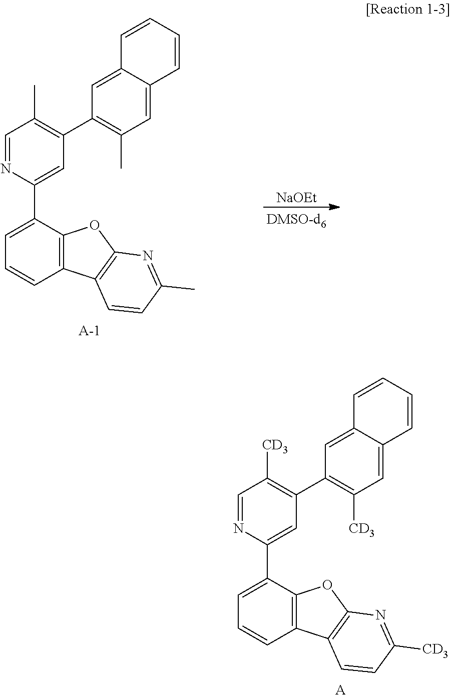

The mixture of the intermediate A-1 (12.4 g, 30.0 mmol) and sodium ethoxide (13.6 g, 200.0 mmol) was added to DMSO-d6 (300 ml) and stirred at 70° C. for 48 hours, and then the solvent was removed. After repeating this process, of the intermediate A 10.5 g (83%, 24.9 mmol) was obtained by silica gel column chromatography.

### 2. Synthesis of an Intermediate B

### (1) An Intermediate B-2

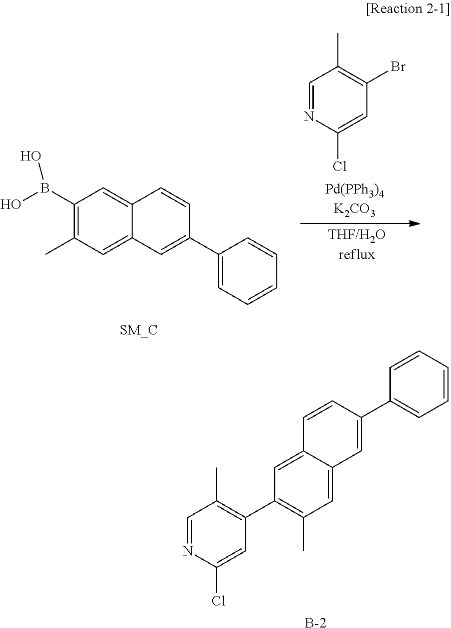

The mixture of the compound SM_C (18.3 g, 70.0 mmol), 4-bromo-2-chloro-5-methylpyridine (16.5 g, 80.0 mmol), Pd(PPh3)4 (2.3 g, 2.0 mmol), and calcium carbonate (22.1 g, 160.0 mmol) were added into the solvent (600 ml) of tetrahydrofuran and water and refluxed overnight. After removing the solvent of the crude mixture, the intermediate B-2 17.3 g (72%, 50.4 mmol) was obtained by silica gel column chromatography.

### (2) An Intermediate B-1

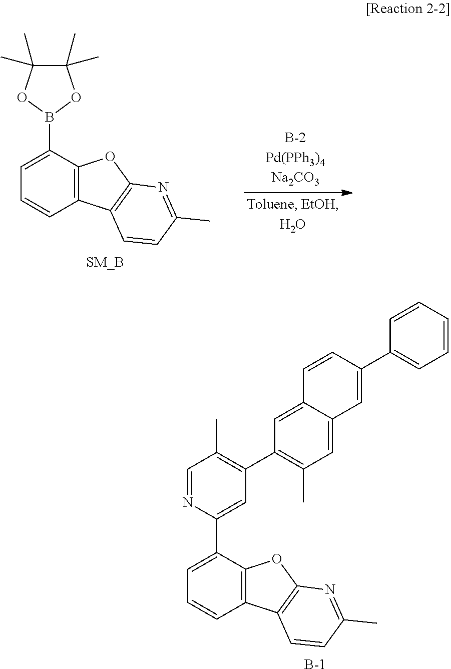

The mixture of the compound SM_B (13.9 g, 45.0 mmol), the intermediate B-2 (16.7 g, 48.5 mmol), Pd(PPh3)4 (1.2 g, 1.0 mmol), and sodium carbonate (14.8 g, 140.0 mmol) were added into the solvent (500 ml) of toluene, ethanol and water and refluxed overnight. After removing the solvent of the crude mixture, the intermediate B-1 15.7 g (66%, 32.0 mmol) was obtained by silica gel column chromatography.

### (3) An Intermediate B

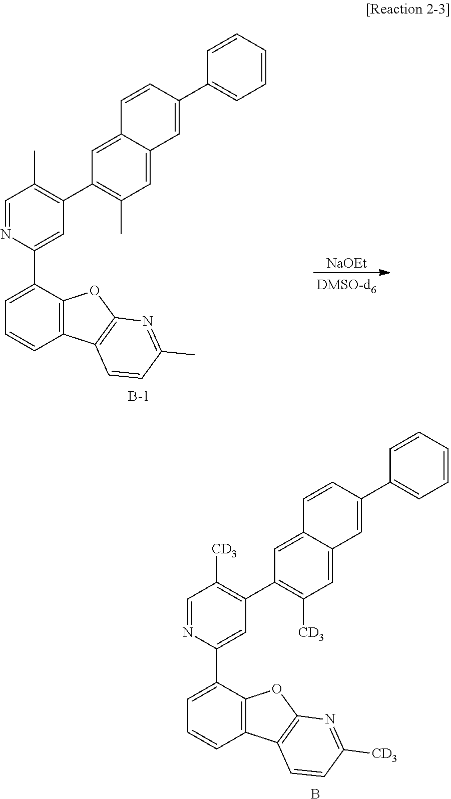

The mixture of the intermediate B-1 (14.7 g, 30.0 mmol) and sodium ethoxide (13.6 g, 200.0 mmol) was added to DMSO-d6 (300 ml) and stirred at 70° C. for 48 hours, and then the solvent was removed. After repeating this process, of the intermediate B 12.0 g (80%, 24.0 mmol) was obtained by silica gel column chromatography.

### 3. Synthesis of an Intermediate C

### (1) An Intermediate C-1

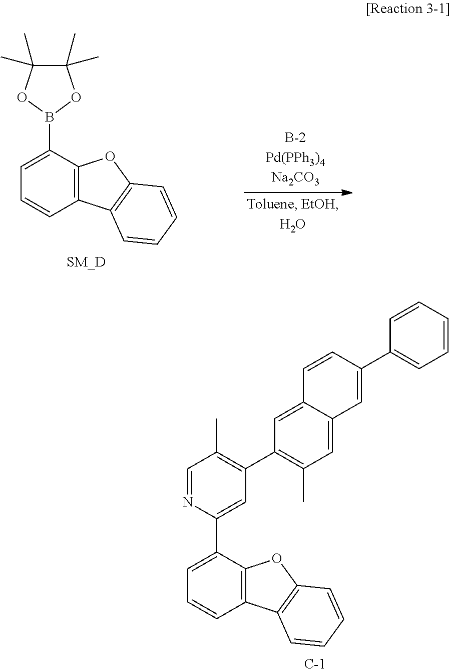

The mixture of the compound SM_D (13.2 g, 45.0 mmol), the intermediate B-2 (17.2 g, 50.0 mmol), Pd(PPh3)4 (1.2 g, 1.0 mmol), and sodium carbonate (14.8 g, 140.0 mmol) were added into the solvent (500 ml) of toluene, ethanol and water and refluxed overnight. After removing the solvent of the crude mixture, the intermediate C-1 16.6 g (70%, 35.0 mmol) was obtained by silica gel column chromatography.

### (2) An Intermediate C

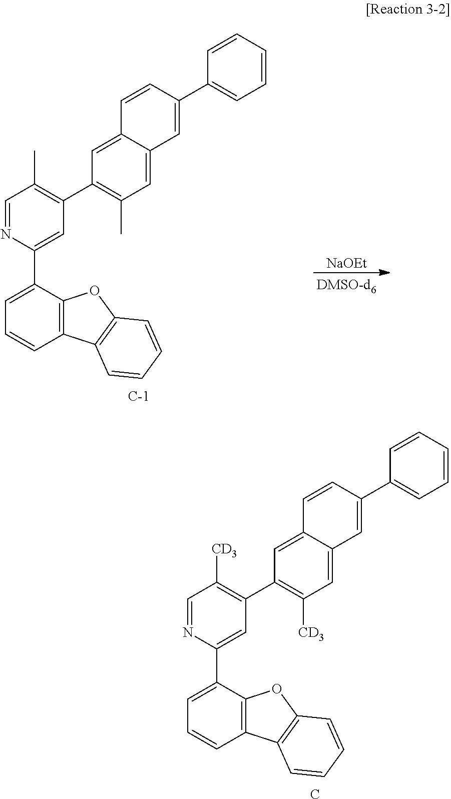

The mixture of the intermediate C-1 (14.3 g, 30.0 mmol) and sodium ethoxide (13.6 g, 200.0 mmol) was added to DMSO-d6 (300 ml) and stirred at 70° C. for 48 hours, and then the solvent was removed. After repeating this process, of the intermediate C 11.4 g (79%, 23.7 mmol) was obtained by silica gel column chromatography.

### 4. Synthesis of an Intermediate D

### (1) An Intermediate D-1

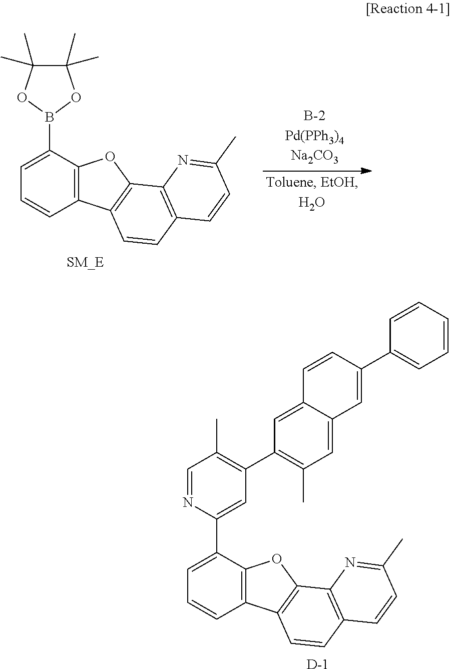

The mixture of the compound SM_E (16.2 g, 45.0 mmol), the intermediate B-2 (17.2 g, 50.0 mmol), Pd(PPh3)4 (1.2 g, 1.0 mmol), and sodium carbonate (14.8 g, 140.0 mmol) were added into the solvent (500 ml) of toluene, ethanol and water and refluxed overnight. After removing the solvent of the crude mixture, the intermediate D-1 16.5 g (61%, 30.5 mmol) was obtained by silica gel column chromatography.

### (2) An Intermediate D

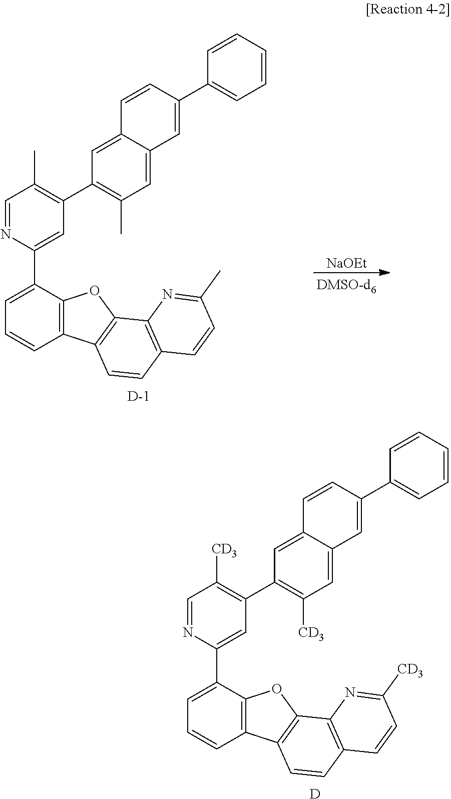

The mixture of the intermediate D-1 (15.7 g, 29.0 mmol) and sodium ethoxide (13.3 g, 195.0 mmol) was added to DMSO-d6 (300 ml) and stirred at 70° C. for 48 hours, and then the solvent was removed. After repeating this process, of the intermediate D 11.8 g (74%, 21.5 mmol) was obtained by silica gel column chromatography.

### 5. Synthesis of an Intermediate E

### (1) An Intermediate E-2

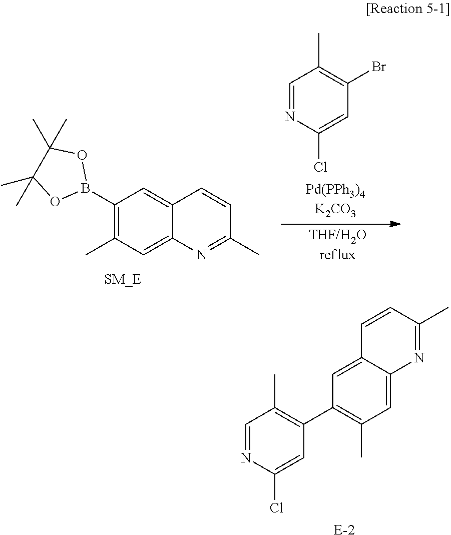

The mixture of the compound SM_E (19.8 g, 70.0 mmol), 4-bromo-2-chloro-5-methylpyridine (16.5 g, 80.0 mmol), Pd(PPh3)4 (2.3 g, 2.0 mmol), and calcium carbonate (22.1 g, 160.0 mmol) were added into the solvent (600 ml) of tetrahydrofuran and water and refluxed overnight. After removing the solvent of the crude mixture, the intermediate E-2 12.9 g (65%, 45.5 mmol) was obtained by silica gel column chromatography.

### (2) An Intermediate E-1

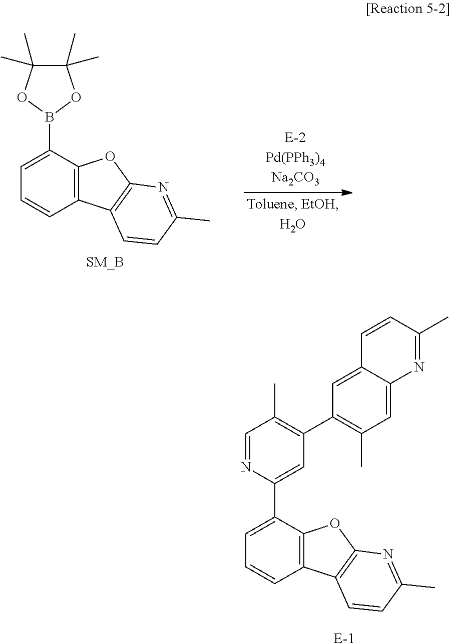

The mixture of the compound SM_B (13.9 g, 45.0 mmol), the intermediate E-2 (12.4 g, 44.0 mmol), Pd(PPh3)4 (1.2 g, 1.0 mmol), and sodium carbonate (14.8 g, 140.0 mmol) were added into the solvent (500 ml) of toluene, ethanol and water and refluxed overnight. After removing the solvent of the crude mixture, the intermediate E-1 13.0 g (69%, 30.4 mmol) was obtained by silica gel column chromatography.

### (3) An Intermediate E

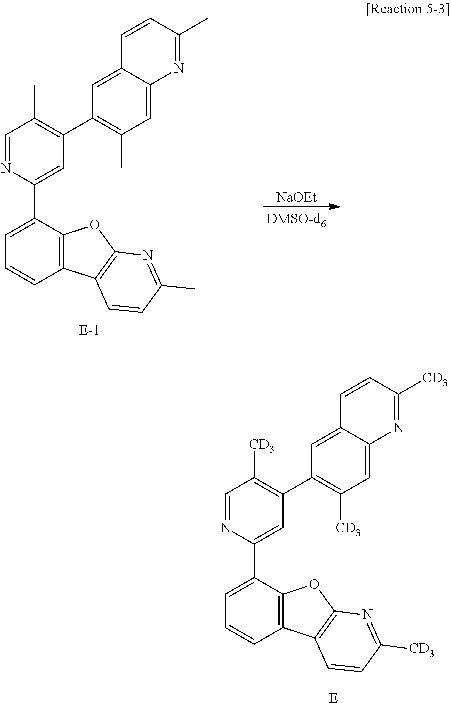

The mixture of the intermediate E-1 (12.9 g, 30.0 mmol) and sodium ethoxide (13.6 g, 200.0 mmol) was added to DMSO-d6 (300 ml) and stirred at 70° C. for 48 hours, and then the solvent was removed. After repeating this process, of the intermediate E 9.8 g (74%, 22.2 mmol) was obtained by silica gel column chromatography.

### 6. Synthesis of an Intermediate FF

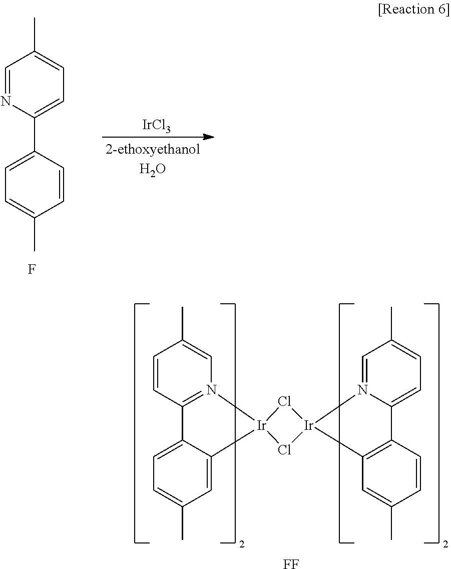

The solution of the compound F (7.3 g, 40.0 mmol) and IrCl3 (4.8 g, 16.0 mmol) was added to the mixed solution of ethoxyethanol (100 ml) and distilled water (30 ml). The mixture was stirred and refluxed for 24 hours. The temperature was lowered to room temperature, and the produced solid was separated by filtration under reduced pressure. The filtered solid filtered was washed with water and cold methanol, and the process of filtration under reduced pressure was repeated several times to obtain the intermediate FF 11.3 g (95%, 9.5 mmol).

### 7. Synthesis of an Intermediate GG

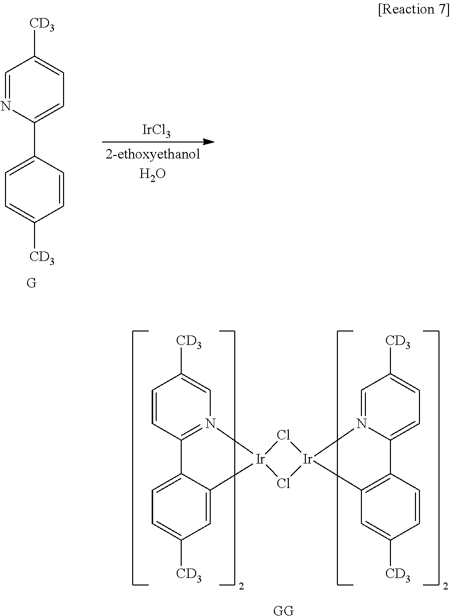

The solution of the compound G (7.6 g, 40.0 mmol) and IrCl3 (4.8 g, 16.0 mmol) was added to the mixed solution of ethoxyethanol (100 ml) and distilled water (30 ml). The mixture was stirred and refluxed for 24 hours. The temperature was lowered to room temperature, and the produced solid was separated by filtration under reduced pressure. The filtered solid filtered was washed with water and cold methanol, and the process of filtration under reduced pressure was repeated several times to obtain the intermediate GG 11.4 g (94%, 9.4 mmol).

### 8. Synthesis of an Intermediate HH

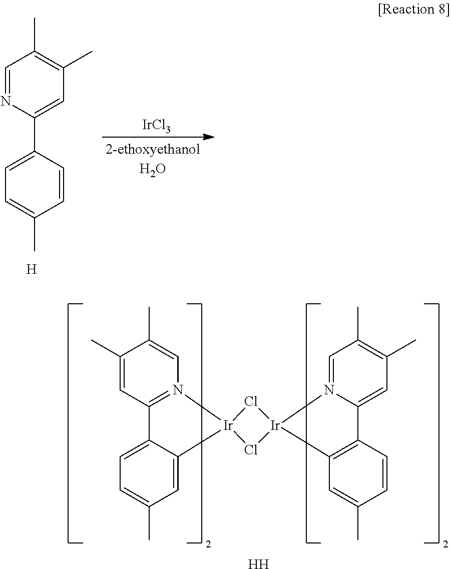

The solution of the compound H (7.9 g, 40.0 mmol) and IrCl3 (4.8 g, 16.0 mmol) was added to the mixed solution of ethoxyethanol (100 ml) and distilled water (30 ml). The mixture was stirred and refluxed for 24 hours. The temperature was lowered to room temperature, and the produced solid was separated by filtration under reduced pressure. The filtered solid filtered was washed with water and cold methanol, and the process of filtration under reduced pressure was repeated several times to obtain the intermediate HH 10.2 g (82%, 8.2 mmol).

### 9. Synthesis of an Intermediate II

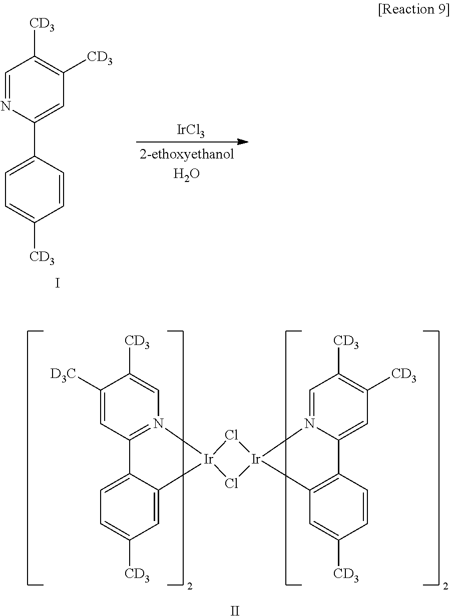

The solution of the compound I (8.3 g, 40 mmol) and IrCl3 (4.8 g, 16.0 mmol) was added to the mixed solution of ethoxyethanol (100 ml) and distilled water (30 ml). The mixture was stirred and refluxed for 24 hours. The temperature was lowered to room temperature, and the produced solid was separated by filtration under reduced pressure. The filtered solid filtered was washed with water and cold methanol, and the process of filtration under reduced pressure was repeated several times to obtain the intermediate 1110.6 g (83%, 8.3 mmol).

### 10. Synthesis of an Intermediate JJ

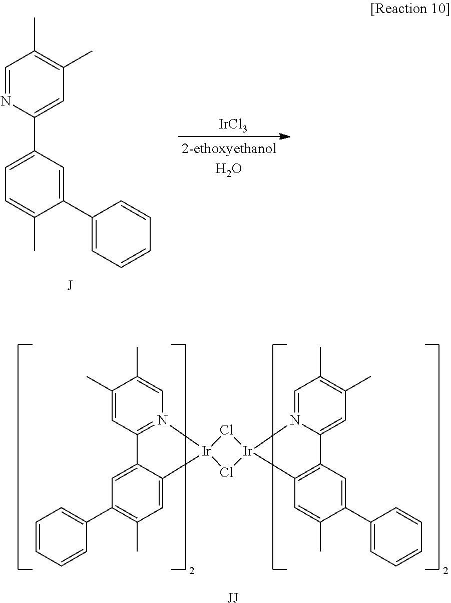

The solution of the compound J (10.9 g, 40.0 mmol) and IrCl3 (4.8 g, 16.0 mmol) was added to the mixed solution of ethoxyethanol (100 ml) and distilled water (30 ml). The mixture was stirred and refluxed for 24 hours. The temperature was lowered to room temperature, and the produced solid was separated by filtration under reduced pressure. The filtered solid filtered was washed with water and cold methanol, and the process of filtration under reduced pressure was repeated several times to obtain the intermediate JJ 12.5 g (81%, 8.1 mmol).

### 11. Synthesis of an Intermediate KK

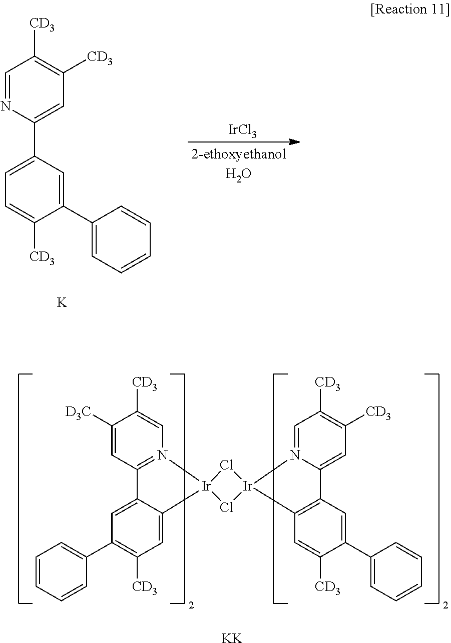

The solution of the compound K (11.3 g, 40 mmol) and IrCl3 (4.8 g, 16.0 mmol) was added to the mixed solution of ethoxyethanol (100 ml) and distilled water (30 ml). The mixture was stirred and refluxed for 24 hours. The temperature was lowered to room temperature, and the produced solid was separated by filtration under reduced pressure. The filtered solid filtered was washed with water and cold methanol, and the process of filtration under reduced pressure was repeated several times to obtain the intermediate KK 12.5 g (79%, 7.9 mmol).

### 12. Synthesis of an Intermediate FFF

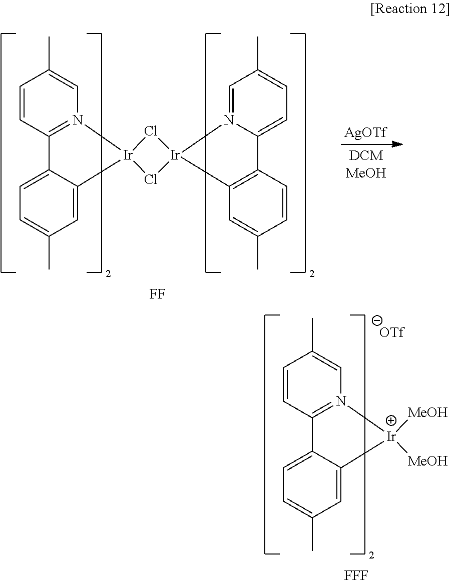

The solution of the compound FF (11.3 g, 9.5 mmol) and silver trifluoromethanesulfonate (6.9 g, 27.0 mmol) was added to the mixed solution of dichloromethane (150 ml) and methanol (150 ml), and the mixture was stirred at room temperature overnight. After completion of the reaction, the solid precipitate was removed by filtration through Celite. The process of vacuum filtration of the filtrate filtered through the filter was repeated several times to obtain the intermediate FFF 13.9 g (95%, 18.1 mmol).

### 13. Synthesis of an Intermediate GGG

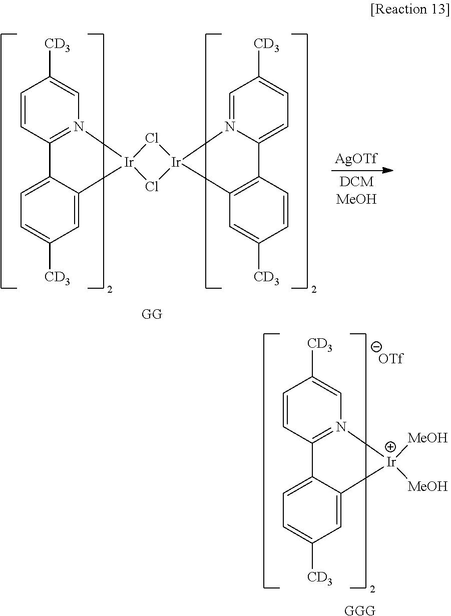

The solution of the compound GG (11.4 g, 9.4 mmol) and silver trifluoromethanesulfonate (6.9 g, 27.0 mmol) was added to the mixed solution of dichloromethane (150 ml) and methanol (150 ml), and the mixture was stirred at room temperature overnight. After completion of the reaction, the solid precipitate was removed by filtration through Celite. The process of vacuum filtration of the filtrate filtered through the filter was repeated several times to obtain the intermediate GGG 13.5 g (92%, 17.3 mmol).

### 14. Synthesis of an Intermediate HHH

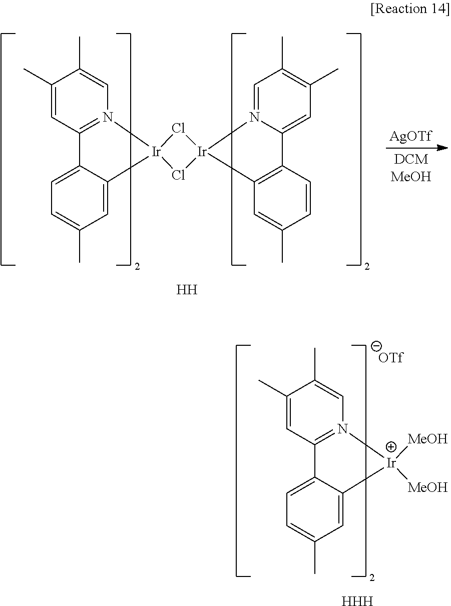

The solution of the compound HH (10.2 g, 8.2 mmol) and silver trifluoromethanesulfonate (6.9 g, 27.0 mmol) was added to the mixed solution of dichloromethane (150 ml) and methanol (150 ml), and the mixture was stirred at room temperature overnight. After completion of the reaction, the solid precipitate was removed by filtration through Celite. The process of vacuum filtration of the filtrate filtered through the filter was repeated several times to obtain the intermediate HHH 12.4 g (95%, 15.6 mmol).

### 15. Synthesis of an Intermediate III

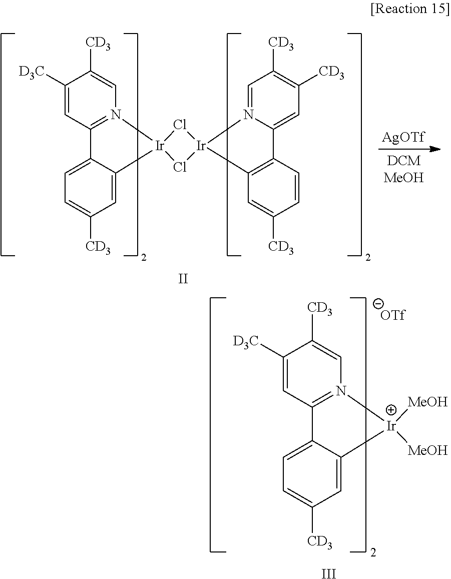

The solution of the compound II (10.6 g, 8.3 mmol) and silver trifluoromethanesulfonate (6.9 g, 27.0 mmol) was added to the mixed solution of dichloromethane (150 ml) and methanol (150 ml), and the mixture was stirred at room temperature overnight. After completion of the reaction, the solid precipitate was removed by filtration through Celite. The process of vacuum filtration of the filtrate filtered through the filter was repeated several times to obtain the intermediate III 12.9 g (95%, 15.8 mmol).

### 16. Synthesis of an Intermediate JJJ

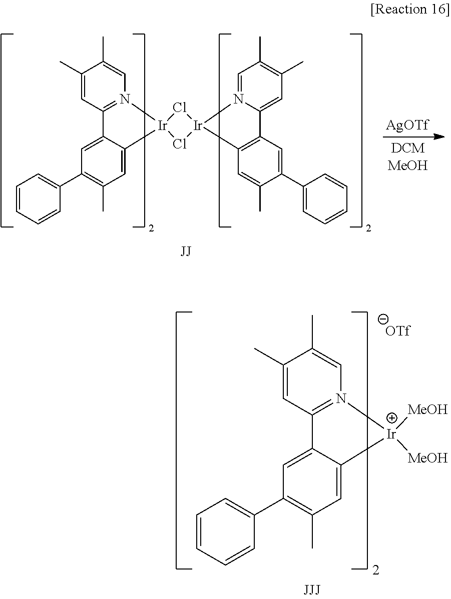

The solution of the compound JJ (12.5 g, 8.1 mmol) and silver trifluoromethanesulfonate (6.9 g, 27.0 mmol) was added to the mixed solution of dichloromethane (150 ml) and methanol (150 ml), and the mixture was stirred at room temperature overnight. After completion of the reaction, the solid precipitate was removed by filtration through Celite. The process of vacuum filtration of the filtrate filtered through the filter was repeated several times to obtain the intermediate JJJ 14.0 g (91%, 14.7 mmol).

### 17. Synthesis of an Intermediate KKK

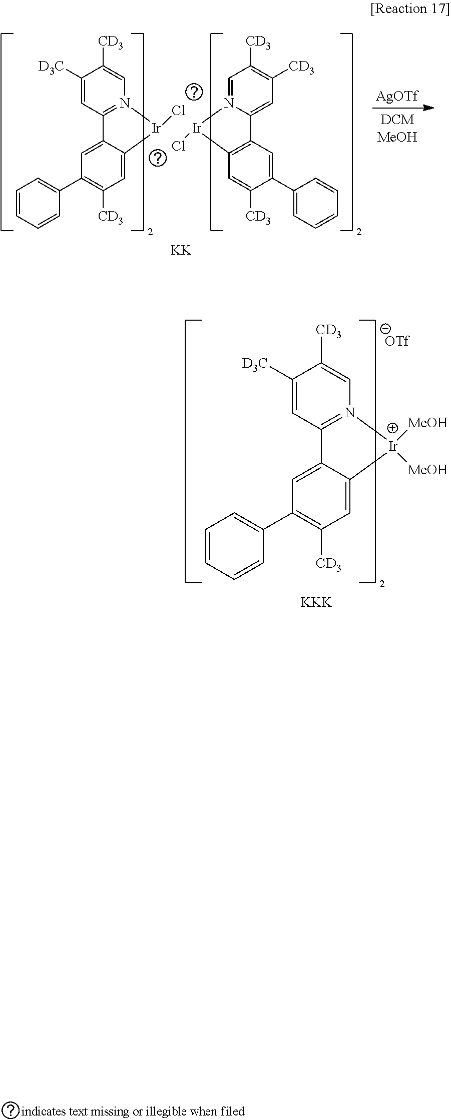

The solution of the compound KK (12.5 g, 7.9 mmol) and silver trifluoromethanesulfonate (6.9 g, 27.0 mmol) was added to the mixed solution of dichloromethane (150 ml) and methanol (150 ml), and the mixture was stirred at room temperature overnight. After completion of the reaction, the solid precipitate was removed by filtration through Celite. The process of vacuum filtration of the filtrate filtered through the filter was repeated several times to obtain the intermediate KKK 14.2 g (93%, 14.7 mmol).

### 18. Synthesis of the Compound 238

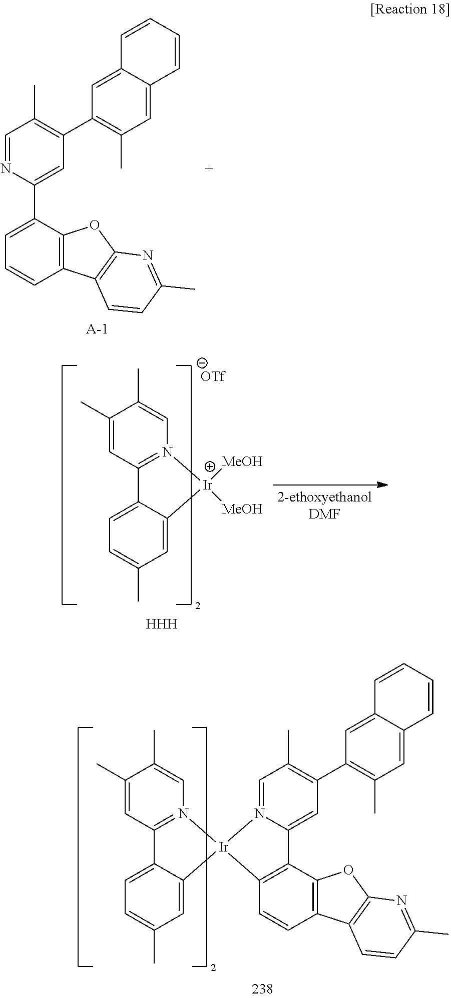

The intermediate A-1 (4.1 g, 10.0 mmol) and the intermediate HHH (9.6 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 238 6.5 g (65%, 6.7 mmol).

### 19. Synthesis of the Compound 247

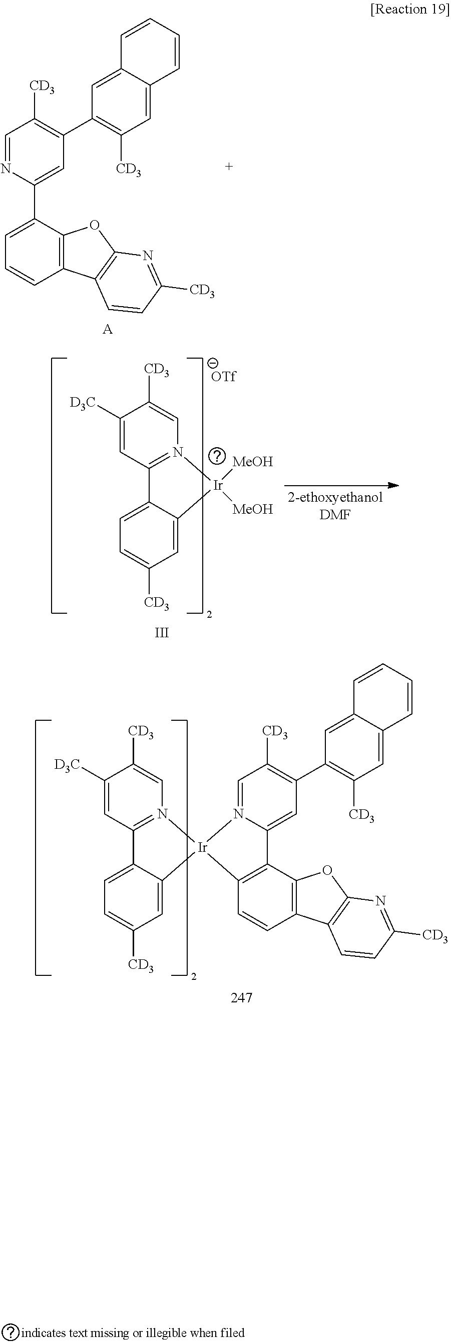

The intermediate A (4.2 g, 10.0 mmol) and the intermediate III (9.8 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 247 6.8 g (67%, 6.7 mmol).

### 20. Synthesis of the Compound 310

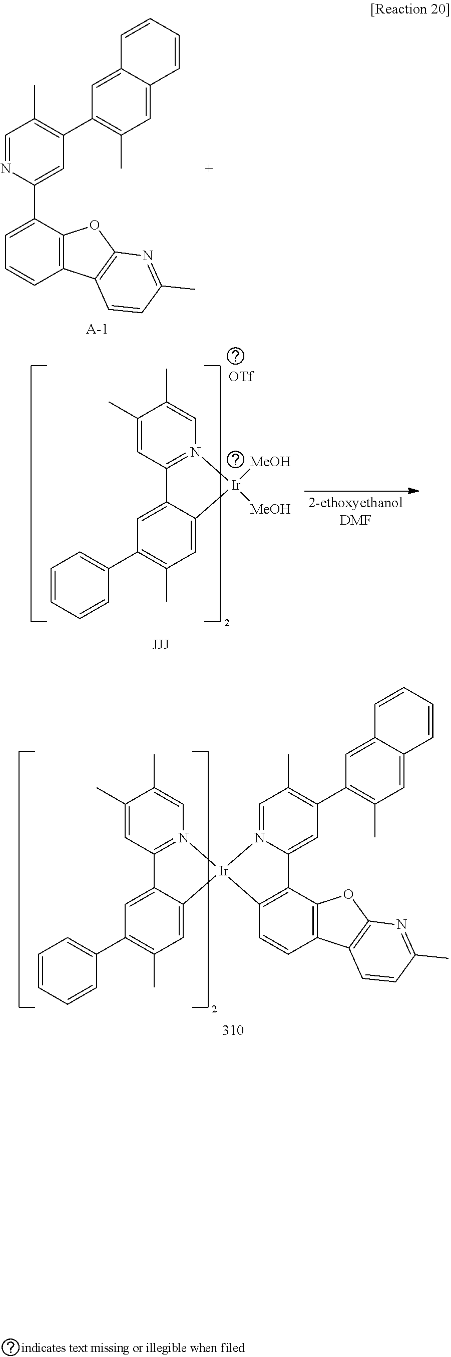

The intermediate A-1 (4.1 g, 10.0 mmol) and the intermediate JJJ (11.4 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 310 8.0 g (69%, 6.9 mmol).

### 21. Synthesis of the Compound 319

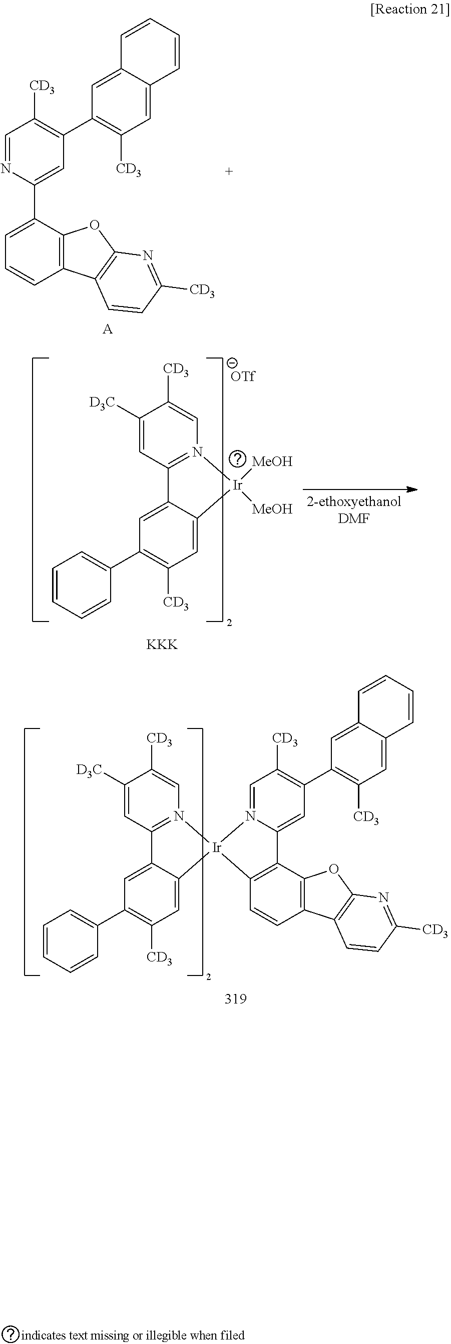

The intermediate A (4.2 g, 10.0 mmol) and the intermediate KKK (11.6 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 319 7.5 g (64%, 6.4 mmol).

### 22. Synthesis of the Compound 243

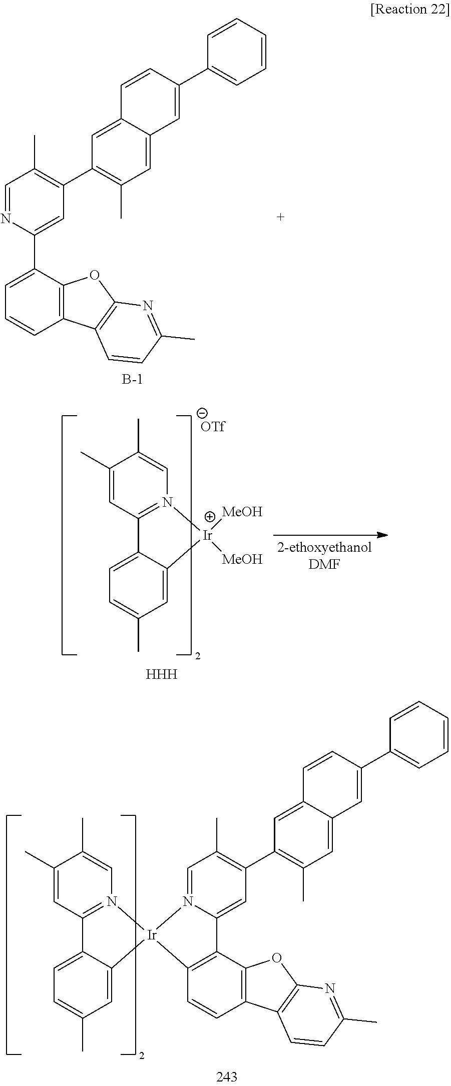

The intermediate B-1 (4.9 g, 10.0 mmol) and the intermediate HHH (9.6 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 243 7.1 g (66%, 6.6 mmol).

### 23. Synthesis of the Compound 252

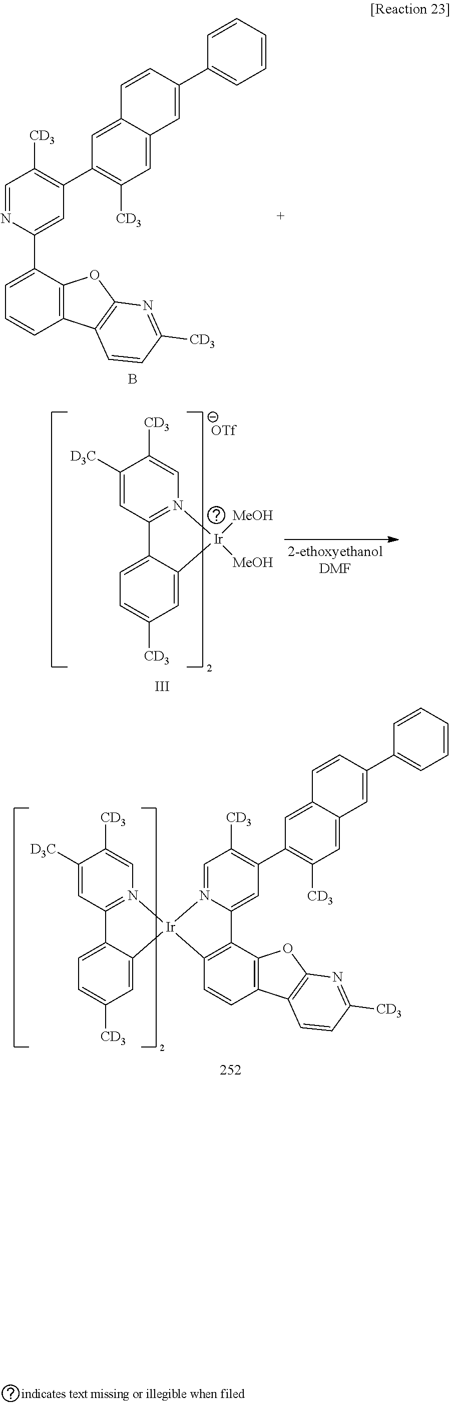

The intermediate B (5.0 g, 10.0 mmol) and the intermediate III (9.8 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 252 7.4 g (67%, 6.7 mmol).

### 24. Synthesis of the Compound 315

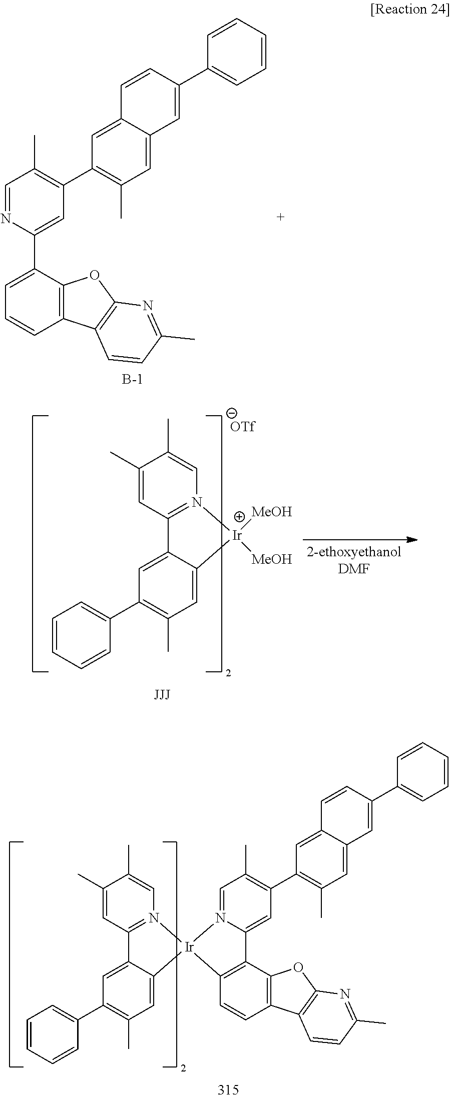

The intermediate B-1 (4.9 g, 10.0 mmol) and the intermediate JJJ (11.4 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 315 8.4 g (69%, 6.9 mmol).

### 25. Synthesis of the Compound 324

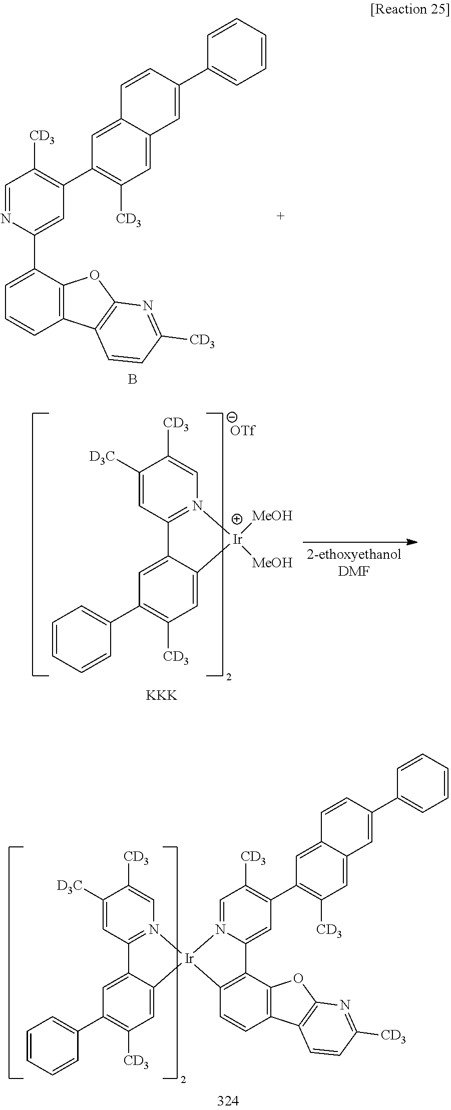

The intermediate B (5.0 g, 10.0 mmol) and the intermediate KKK (11.6 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 324 8.1 g (65%, 6.5 mmol).

### 26. Synthesis of the Compound 580

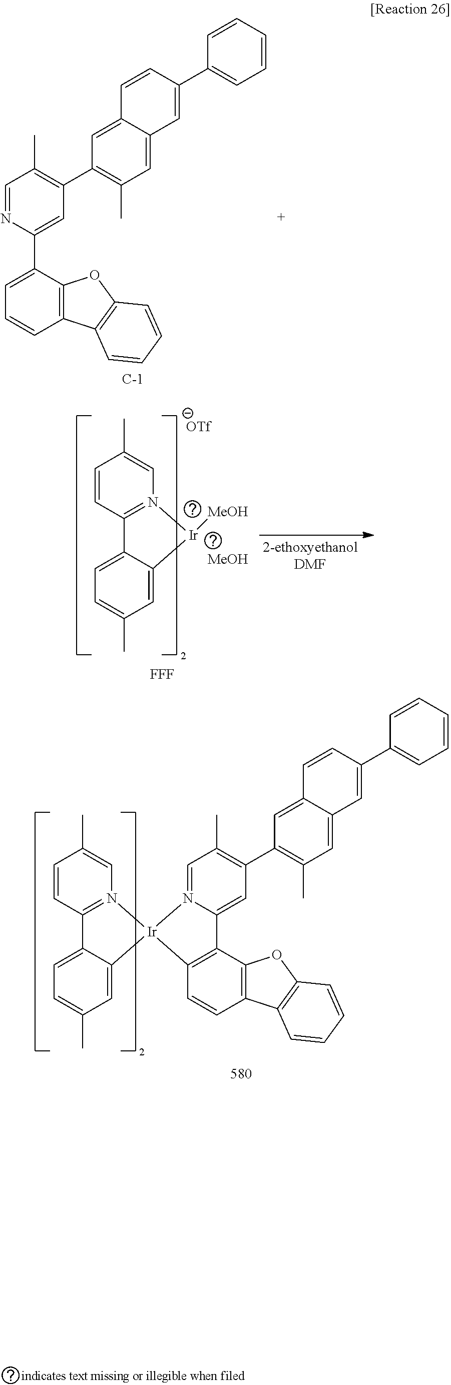

The intermediate C-1 (4.8 g, 10.0 mmol) and the intermediate FFF (9.2 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 580 6.7 g (65%, 6.5 mmol).

### 27. Synthesis of the Compound 589

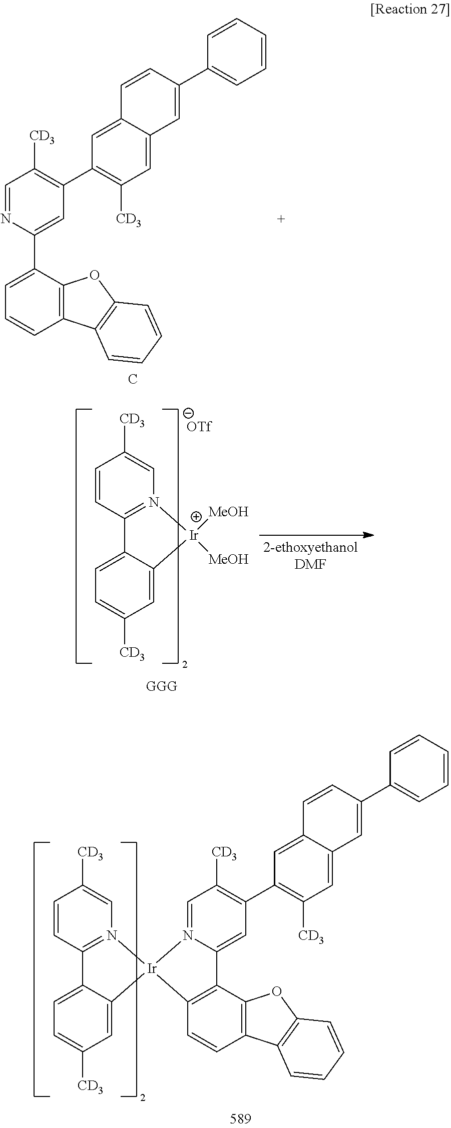

The intermediate C (4.8 g, 10.0 mmol) and the intermediate GGG (9.4 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 589 6.6 g (63%, 6.3 mmol).

### 28. Synthesis of the Compound 582

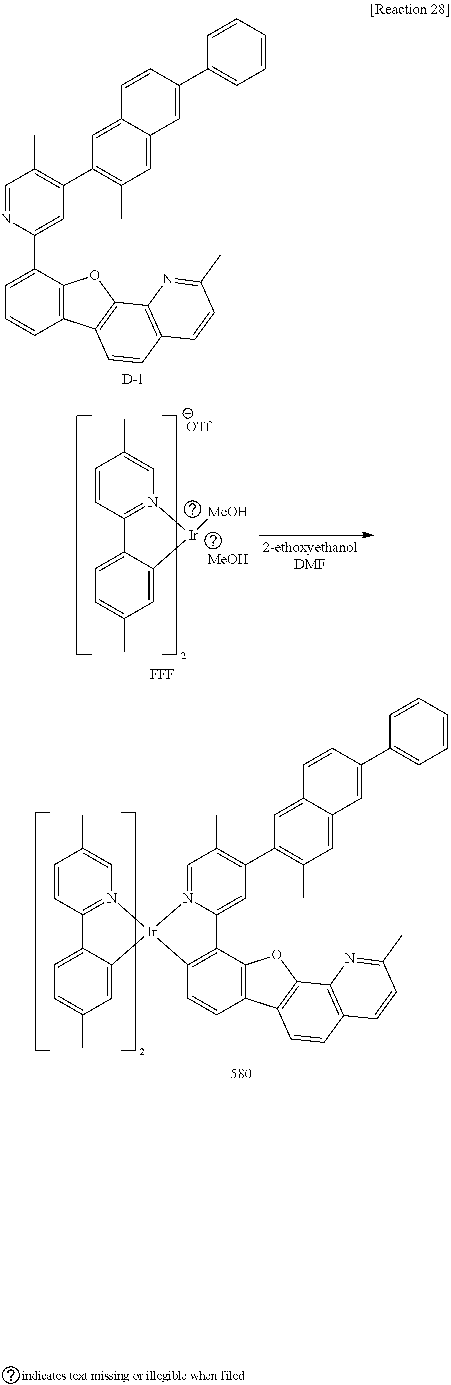

The intermediate D-1 (5.4 g, 10.0 mmol) and the intermediate FFF (9.2 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 582 7.0 g (64%, 6.4 mmol).

### 29. Synthesis of the Compound 591

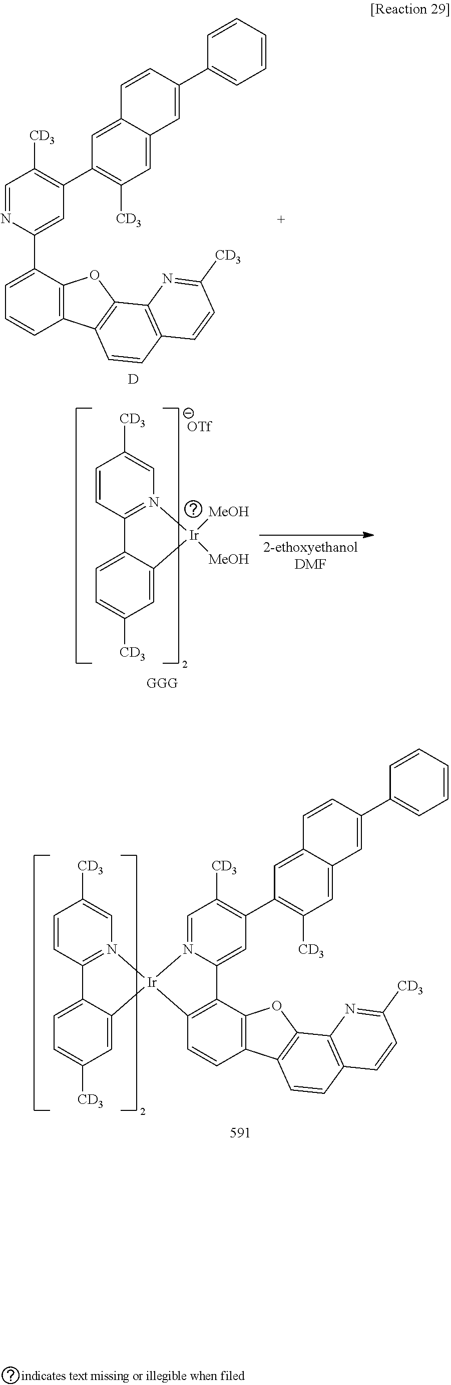

The intermediate D (5.5 g, 10.0 mmol) and the intermediate GGG (9.4 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 591 6.9 g (62%, 6.2 mmol).

### 30. Synthesis of the Compound 546

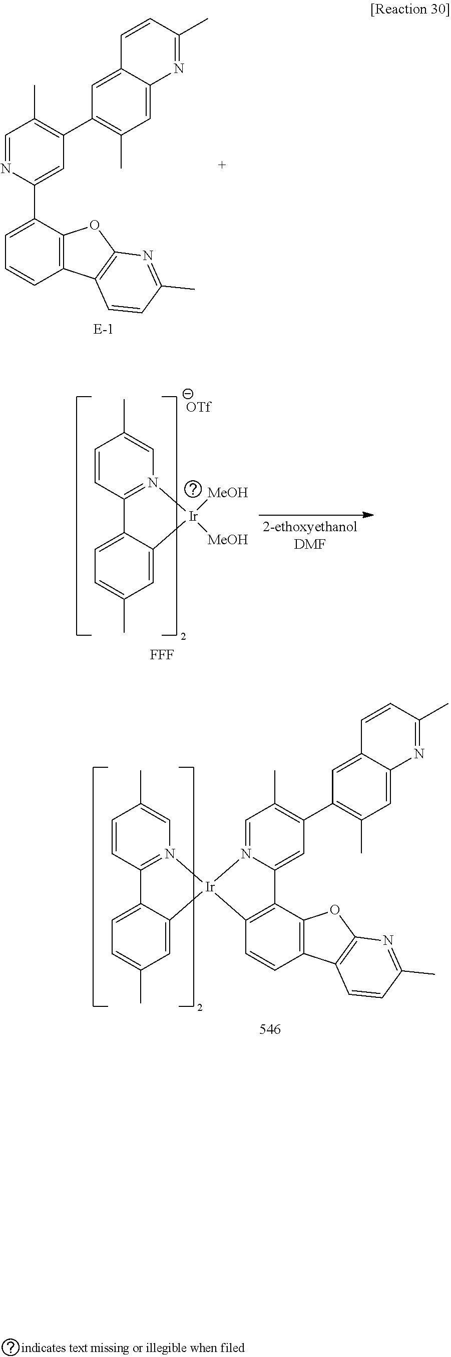

The intermediate E-1 (4.3 g, 10.0 mmol) and the intermediate FFF (9.2 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 546 6.8 g (69%, 6.9 mmol).

### 31. Synthesis of the Compound 555

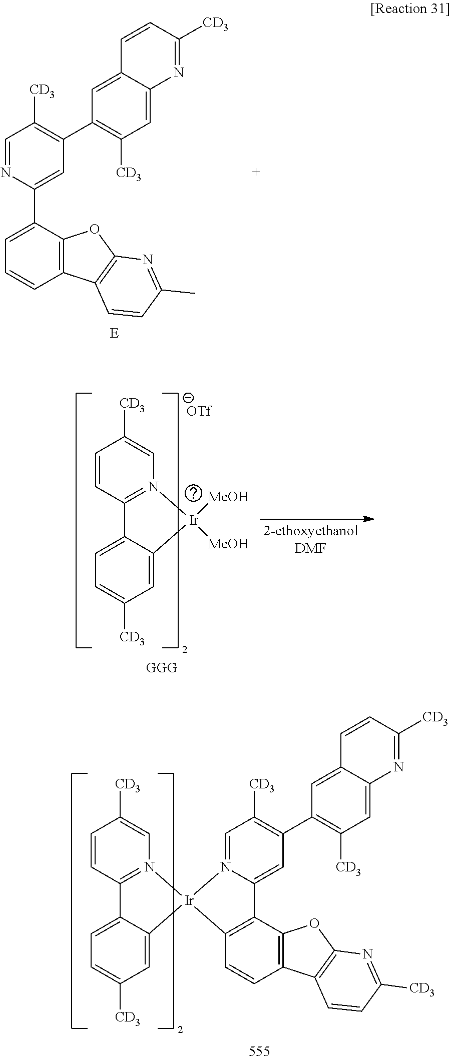

The intermediate E (4.4 g, 10.0 mmol) and the intermediate GGG (9.4 g, 12.0 mmol) were added to a mixed solution of 2-ethoxyethanol (180 ml) and DMF (180 ml), and the mixture was stirred at 135° C. for 24 hours. After the reaction was completed, the temperature was lowered to room temperature, and the organic phase was separated using dichloromethane and distilled water. The moisture was removed by adding anhydrous magnesium sulfate. The residue obtained by reducing the pressure of the solution, which was obtained through filtration, was purified by silica gel column chromatography to obtain the iridium compound 555 7.1 g (70%, 7.0 mmol).

### [OLED]

On a substrate, where an anode (ITO, 100 nm) is coated, an HIL (the compound HI-1 in Formula 4, 60 nm), an HTL (the compound NPB in Formula 5, 80 nm), an EML (a host (the compound CBP in Formula 6, 95 wt %) and a dopant (5 wt %), 30 nm), an electron transporting-injection layer (the compound ET-1 in Formula 7 and the compound Liq in Formula 8 (a weight ratio=1:1), 30 nm), and a cathode (Al, 15 nm) were sequentially stacked to form a green OLED.

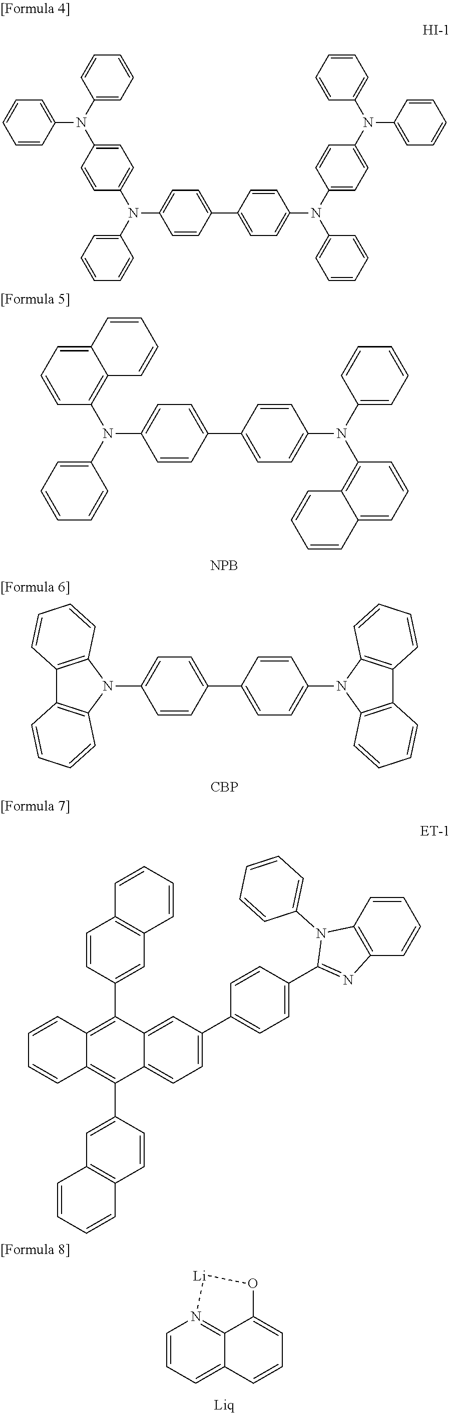

### 1. Comparative Examples

### (1) Comparative Example 1 (Ref1)

The compound Ref1 in Formula 9 was used as the dopant.

### (2) Comparative Example 2 (Ref2)

The compound Ref2 in Formula 9 was used as the dopant.

### (3) Comparative Example 3 (Ref3)

The compound Ref3 in Formula 9 was used as the dopant.

### (4) Comparative Example 4 (Ref4)

The compound Ref4 in Formula 9 was used as the dopant.

### (5) Comparative Example 5 (Ref5)

The compound Ref5 in Formula 9 was used as the dopant.

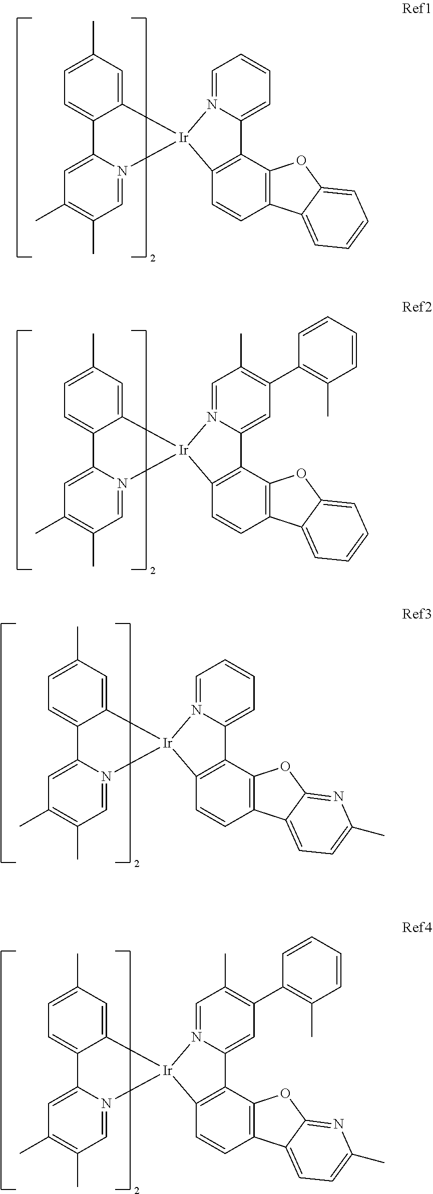

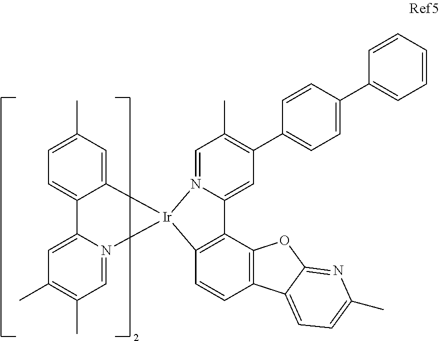

### 2. Examples

### (1) Example 1 (Ex1)

The compound 238 in Formula 3 was respectively used as the dopant.

### (2) Example 2 (Ex2)

The compound 247 in Formula 3 was respectively used as the dopant.

### (3) Example 3 (Ex3)

The compound 243 in Formula 3 was respectively used as the dopant.

### (4) Example 4 (Ex4)

The compound 252 in Formula 3 was respectively used as the dopant.

### (5) Example 5 (Ex5)

The compound 310 in Formula 3 was respectively used as the dopant.

### (6) Example 6 (Ex6)

The compound 319 in Formula 3 was respectively used as the dopant.

### (7) Example 7 (Ex7)

The compound 315 in Formula 3 was respectively used as the dopant.

### (8) Example 8 (Ex8)

The compound 324 in Formula 3 was respectively used as the dopant.

### (9) Example 9 (Ex9)

The compound 472 in Formula 3 was respectively used as the dopant.

### (10) Example 10 (Ex10)

The compound 481 in Formula 3 was respectively used as the dopant.

### (11) Example 11 (Ex11)

The compound 477 in Formula 3 was respectively used as the dopant.

### (12) Example 12 (Ex12)

The compound 486 in Formula 3 was respectively used as the dopant.

### (13) Example 13 (Ex13)

The compound 580 in Formula 3 was respectively used as the dopant.

### (14) Example 14 (Ex14)

The compound 589 in Formula 3 was respectively used as the dopant.

### (15) Example 15 (Ex15)

The compound 582 in Formula 3 was respectively used as the dopant.

### (16) Example 16 (Ex16)

The compound 591 in Formula 3 was respectively used as the dopant.

### (17) Example 17 (Ex17)

The compound 546 in Formula 3 was respectively used as the dopant.

### (18) Example 18 (Ex18)

The compound 555 in Formula 3 was respectively used as the dopant.

The emitting properties, i.e., a driving voltage (V), an external quantum efficiency (EQE, %) and a lifespan (LT95, %), of the OLED in Comparative Examples to 5 and Examples 1 to 18 were measured and listed in Table 1. The emitting properties of the OLED were measured at the room temperature using a current source (KEITHLEY) and a photometer (PR 650), and the external quantum efficiency and the lifespan are relative values with respect to Comparative Example 1.

TABLE 1

| | Dopant | V | EQE (%) | LT95 (%) |
|---|---|---|---|---|
| Ref1 | Compound Ref1 | 4.3 | 100 | 100 |
| Ref2 | Compound Ref2 | 4.3 | 109 | 84 |
| Ref3 | Compound Ref3 | 4.2 | 107 | 112 |
| Ref4 | Compound Ref4 | 4.2 | 115 | 95 |
| Ref5 | Compound Ref5 | 4.4 | 118 | 99 |
| Ex1 | Compound 238 | 4.3 | 132 | 147 |
| Ex2 | Compound 247 | 4.3 | 133 | 166 |
| Ex3 | Compound 243 | 4.4 | 136 | 145 |
| Ex4 | Compound 252 | 4.4 | 136 | 177 |
| Ex5 | Compound 310 | 4.3 | 134 | 143 |
| Ex6 | Compound 319 | 4.2 | 134 | 162 |
| Ex7 | Compound 315 | 4.4 | 138 | 141 |
| Ex8 | Compound 324 | 4.4 | 138 | 163 |
| Ex9 | Compound 472 | 4.2 | 134 | 143 |
| Ex10 | Compound 481 | 4.2 | 133 | 161 |
| Ex11 | Compound 477 | 4.2 | 137 | 140 |
| Ex12 | Compound 486 | 4.2 | 137 | 161 |
| Ex13 | Compound 580 | 4.3 | 129 | 158 |
| Ex14 | Compound 589 | 4.3 | 129 | 180 |
| Ex15 | Compound 582 | 4.3 | 134 | 145 |
| Ex16 | Compound 591 | 4.3 | 135 | 168 |
| Ex17 | Compound 546 | 4.2 | 128 | 188 |
| Ex18 | Compound 555 | 4.2 | 128 | 221 |

As shown in Table 1, in comparison to the OLED of Comparative Examples 1 to 5, in the OLED of Examples 1 to 18, the driving voltage is decreased, and the emitting efficiency and the lifespan are increased.

For example, in comparison to Comparative Example 1 using the compound Ref1, in which a pyridyl moiety in a pyridyl-dibenzothiophene ligand is not substituted, and Comparative Example 3 using the compound Ref3, in which a pyridyl moiety in a pyridyl-azadibenzothiophene ligand is not substituted, the OLED of Examples 1 to 18 each using the organometallic compound of the present disclosure, in which a pyridyl moiety in a pyridyl-dibenzothiophene ligand and a pyridyl moiety in a pyridyl-azadibenzothiophene ligand is substituted with an aryl group, provides improved emitting efficiency and lifespan.

In addition, in comparison to Comparative Example 2 using the compound Ref2, in which a pyridyl moiety in a pyridyl-dibenzothiophene ligand is substituted with a phenyl, Comparative Example 4 using the compound Ref4, in which a pyridyl moiety in a pyridyl-azadibenzothiophene ligand is substituted with a phenyl, and Comparative Example 5 using the compound Ref5, in which a pyridyl moiety in a pyridyl-azadibenzothiophene ligand is substituted with a biphenyl, the OLED of Examples 1 to 18 each using the organometallic compound of the present disclosure, in which a pyridyl moiety in a pyridyl-dibenzothiophene ligand and a pyridyl moiety in a pyridyl-azadibenzothiophene ligand is substituted with a naphthyl group, provides improved emitting efficiency and lifespan.

Moreover, in comparison to Examples 1, 3, 5, 7, 9, 11, 13, 15 and 17, the lifespan of the OLED of Examples 2, 4, 6, 8, 10, 12, 14, 16 and 18 respectively using the compounds 247, 252, 319, 324, 481, 486, 589, 591 and 555, each of which includes a CD3 substituent, is further improved.

Further, the lifespan of the OLED of Examples 13 and 14 respectively using the compounds 580 and 590, each of which satisfies n being 2, n1 being 0, X₁ to X₄ and X₁₀ being CH, R₁ and R₂₋₁ independent being a C1 to C20 alkyl group unsubstituted or substituted with deuterium, e.g., CH₃ or CD₃, and R₂₋₂ being a substituted or unsubstituted C6 to C30 aryl group, e.g., phenyl, is further improved.

Furthermore, the lifespan of the OLED of Examples 17 and 18 respectively using the compounds 546 and 555, each of which satisfies n being 2, n1 being 0, X₁ and X₁₀ being N, X₂ being CR₄ (R₄=CH₃ or CD₃), X₃ and X₄ being CH, and R₁, R₂₋₁ and R₂₋₂ independent being a C1 to C20 alkyl group unsubstituted or substituted with deuterium, e.g., CH₃ or CD₃, is further improved.

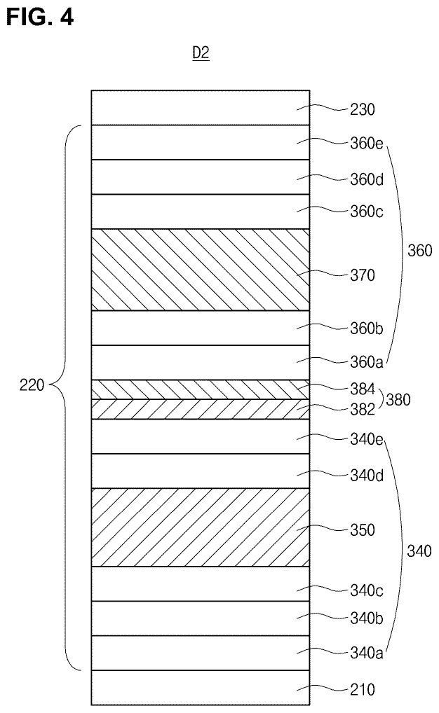

FIG. 4 is a schematic cross-sectional view of an OLED according to a third embodiment of the present disclosure.

As shown in FIG. 4, the OLED D2 includes the first and second electrodes 210 and 230, which face each other, and the emitting layer 220 therebetween.

The organic light emitting display device 100 (of FIG. 2) can include a red pixel region, a green pixel region and a blue pixel region. The organic light emitting display device 100 can further include a white pixel region. The OLED D2 can be positioned in at least one of the red and green pixel region. For example, the OLED D2 can be positioned in the green pixel region.

The first electrode 210 can be an anode, and the second electrode 230 can be a cathode. One of the first and second electrodes 210 and 230 can be a transparent electrode (or a semi-transparent electrode), and the other one of the first and second electrodes 210 and 230 can be a reflection electrode.

The organic light emitting layer 320 includes a first emitting part 340 including a first EML 350 and a second emitting part 360 including a second EML 370. In addition, the organic light emitting layer 320 can further include a charge generation layer (CGL) 380 between the first and second emitting parts 340 and 360.

The CGL 380 is positioned between the first and second emitting parts 340 and 360 such that the first emitting part 340, the CGL 380 and the second emitting part 360 are sequentially stacked on the first electrode 210. Namely, the first emitting part 340 is positioned between the first electrode 210 and the CGL 380, and the second emitting part 360 is positioned between the second electrode 230 and the CGL 380.

The first emitting part 340 can further include at least one of a first HTL 340b between the first electrode 210 and the first EML 350, an HIL 340a between the first electrode 210 and the first HTL 340b, and a first ETL 340e between the first EML 350 and the CGL 380.

Moreover, the first emitting part 340 can further include at least one of a first EBL 340c between the first HTL 340b and the first EML 350 and a first HBL 340d between the first EML 350 and the first ETL 340e.

The second emitting part 360 can further include at least one of a second HTL 360a between the CGL 380 and the second EML 370, a second ETL 360d between the second EML 370 and the second electrode 230, and an EIL 360e between the second ETL 360d and the second electrode 230.

Moreover, the second emitting part 360 can further include at least one of a second EBL 360b between the second HTL 360a and the second EML 370 and a second HBL 360c between the second EML 370 and the second ETL 360d.

The HIL 340a can include the above-mentioned hole injection material and can have a thickness of 10 to 100 nm.

Each of the first and second HTLs 340b and 360a can include the above-mentioned hole transporting material and can have a thickness of 30 to 150 nm, preferably 50 to 120 nm.

Each of the first and second ETLs 340e and 360d can include the above-mentioned electron transporting material and can have a thickness of 10 to 100 nm, preferably 10 to 50 nm.

The EIL 360e can include the above-mentioned electron injection material and can have a thickness of 0.1 to 10 nm, preferably 0.5 to 5 nm.

In FIG. 4, the ETL 360d and the EIL 360e as separated elements are formed. Alternatively, an electron transporting-injection layer as a single layer having an electron transporting function and an electron injection function can be formed. In this case, the electron transporting-injection layer can include an electron transporting material and an electron injection material and can have a thickness of 10 to 50 nm. For example, the electron transporting-injection layer can include a compound in Formula 7 and a compound in Formula 8, and a weight % of the compound in Formula 7 and a weight % of the compound in Formula 8 can be same.

Each of the first and second EBLs 340c and 360b can include the above-mentioned electron blocking material and can have a thickness of 1 to 30 nm.

Each of the first and second HBLs 340d and 360c can include the above-mentioned hole blocking material and can have a thickness of 1 to 30 nm.

The CGL 380 is positioned between the first and second emitting parts 340 and 360. Namely, the first and second emitting parts 340 and 360 are connected to each other through the CGL 380. The CGL 380 can be a P-N junction type CGL of an N-type CGL 382 and a P-type CGL 384.

The N-type CGL 382 is positioned between the first ETL 340e and the second HTL 360a, and the P-type CGL 384 is positioned between the N-type CGL 382 and the second HTL 360a. The N-type CGL 382 provides an electron into the first EML 350 of the first emitting part 340, and the P-type CGL 384 provides a hole into the second EML 370 of the second emitting part 360.

The N-type CGL 382 can be an organic layer doped with an alkali metal, e.g., Li, Na, K and Cs, and/or an alkali earth metal, e.g., Mg, Sr, Ba and Ra. For example, the N-type CGL 382 can be formed of an N-type charge generation material including a host being the organic material, e.g., 4,7-diphenyl-1,10-phenanthroline (Bphen) and MTDATA, a dopant being an alkali metal and/or an alkali earth metal, and the dopant can be doped with a weight % of 0.01 to 30.

The P-type CGL 384 can be formed of a P-type charge generation material including an inorganic material, e.g., tungsten oxide (WOx), molybdenum oxide (MoOx), beryllium oxide (Be2O3) and vanadium oxide (V2O5), an organic material, e.g., NPD, HAT-CN, F4TCNQ, TPD, TNB, TCTA and N,N′-dioctyl-3,4,9,10-perylenedicarboximide (PTCDI-C8).

The first and second EMLs 350 and 370 are a green EML. At least one of the first and second EMLs 350 and 370 includes a first compound being the organometallic compound represented by Formula 1. In addition, each of the first and second EMLs 350 and 370 can further include a second compound being a green host. The first compound can have a weight % of 1 to 40, preferably 1 to 20, more preferably 1 to 10.

The second compound as the green host can be the above-mentioned green host material.

In an aspect of the present disclosure, both the first EML 350 and the second EML 370 can include the first compound being the organometallic compound represented by Formula land the second compound being the green host. In this case, the first compound in the first EML 350 and the first compound in the second EML 370 can be same or different. In addition, the second compound in the first EML 350 and the second compound in the second EML 370 can be same or different.

In an aspect of the present disclosure, one of the first EML 350 and the second EML 370 can include the first compound being the organometallic compound represented by Formula 1 (e.g., a first green dopant) and the second compound being the green host (e.g., a first green host), and the other one of the first EML 350 and the second EML 370 can include a green dopant (e.g., a second green dopant), which is other than the organometallic compound represented by Formula 1, and a green host (e.g., a second green host). In this case, the second green dopant can include at least one of a green phosphorescent material, a green fluorescent material and a green delayed fluorescent material. For example, the second green dopant can be one of [bis(2-phenylpyridine)](pyridyl-2-benzofuro[2,3-b]pyridine)iridium), Ir(ppy)3, fac-Ir(ppy)3, Ir(ppy)2(acac), Ir(mppy)3, Ir(npy)2acac, Ir(3mppy)3 and TEG, but it is not limited thereto.

In an aspect of the present disclosure, the first and second EMLs 350 and 370 are a red EML. In this case, at least one of the first and second EMLs 350 and 370 includes a first compound being the organometallic compound represented by Formula 1. In addition, at least one of the first and second EMLs 350 and 370 can further include a second compound being a red host. The first compound can have a weight % of 1 to 40, preferably 1 to 20, more preferably 1 to 10.

The second compound as the red host can be the above-mentioned red host material.

In an aspect of the present disclosure, in the red pixel region, both the first EML 350 and the second EML 370 can include the first compound being the organometallic compound represented by Formula land the second compound being the red host. In this case, the first compound in the first EML 350 and the first compound in the second EML 370 can be same or different. In addition, the second compound in the first EML 350 and the second compound in the second EML 370 can be same or different.

In an aspect of the present disclosure, in the red pixel region, one of the first EML 350 and the second EML 370 can include the first compound being the organometallic compound represented by Formula 1 (e.g., a first red dopant) and the second compound being the red host (e.g., a first red host), and the other one of the first EML 350 and the second EML 370 can include a red dopant (e.g., a second red dopant), which is other than the organometallic compound represented by Formula 1, and a red host (e.g., a second red host). In this case, the second red dopant can include at least one of a red phosphorescent material, a red fluorescent material or a red delayed fluorescent material. For example, the red dopant can be one of the above-mentioned red dopant materials.

The organometallic compound of the present disclosure is an iridium complex having a structure of Formula 1 and is included in at least one of the first and second EMLs 350 and 370 of the OLED D2. As a result, the emitting efficiency and the lifespan of the OLED D2 and the organic light emitting display device 100 are improved.

In addition, since the OLED D2 has a double stack structure including two green EMLs or two red EMLs, the color sense of the OLED D2 is improved and/or the emitting efficiency of the OLED D2 is optimized.

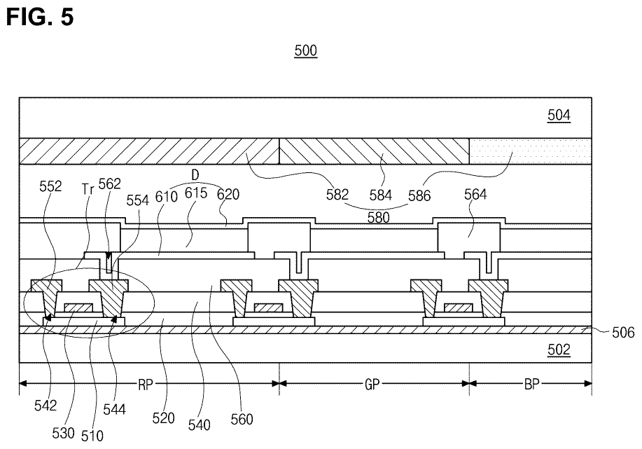

FIG. 5 is a schematic cross-sectional view illustrating an organic light emitting display device according to a fourth embodiment of the present disclosure.

As illustrated in FIG. 5, the organic light emitting display device 500 includes a first substrate 502, where a red pixel region RP, a green pixel region GP and a blue pixel region BP are defined, a second substrate 504 facing the first substrate 502, an OLED D, which is positioned between the first and second substrates 502 and 504 and providing white emission, and a color filter layer 580 between the OLED D and the second substrate 504.

Each of the first and second substrates 502 and 504 can be a glass substrate or a flexible substrate. For example, each of the first and second substrates 502 and 504 can be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 506 is formed on the substrate 502, and the TFT Tr corresponding to each of the red, green and blue pixel regions RP, GP and BP is formed on the buffer layer 506. The buffer layer 506 can be omitted. The TFT Tr can be a driving TFT.

A semiconductor layer 510 is formed on the buffer layer 506. The semiconductor layer 510 can include an oxide semiconductor material or polycrystalline silicon.

A gate insulating layer 520 is formed on the semiconductor layer 510. The gate insulating layer 520 can be formed of an inorganic insulating material such as silicon oxide or silicon nitride.

A gate electrode 530, which is formed of a conductive material, e.g., metal, is formed on the gate insulating layer 520 to correspond to a center of the semiconductor layer 510.

An interlayer insulating layer 540, which is formed of an insulating material, is formed on the gate electrode 530. The interlayer insulating layer 540 can be formed of an inorganic insulating material, e.g., silicon oxide or silicon nitride, or an organic insulating material, e.g., benzocyclobutene or photo-acryl.

The interlayer insulating layer 540 includes first and second contact holes 542 and 544 exposing both sides of the semiconductor layer 510. The first and second contact holes 542 and 544 are positioned at both sides of the gate electrode 530 to be spaced apart from the gate electrode 530.

A source electrode 552 and a drain electrode 554, which are formed of a conductive material, e.g., metal, are formed on the interlayer insulating layer 540. The source electrode 552 and the drain electrode 554 are spaced apart from each other with respect to the gate electrode 530 and respectively contact both sides of the semiconductor layer 510 through the first and second contact holes 542 and 544.

The semiconductor layer 510, the gate electrode 530, the source electrode 552 and the drain electrode 554 constitute the TFT Tr.

A planarization layer 560 is formed on the source and drain electrodes 552 and 554 to cover the TFT Tr. The planarization layer 560 includes a drain contact hole 562 exposing the drain electrode 554 of the TFT Tr.

An OLED D is disposed on the planarization layer 560. The OLED D includes a first electrode 610, which is connected to the drain electrode 554 of the TFT Tr through the drain contact hole 562, a second electrode 620 facing the first electrode 610 and an organic light emitting layer 615 between the first and second electrodes 610 and 620.

The first electrode 610 is separately formed in each pixel region and can be an anode. The first electrode 610 includes a transparent conductive oxide material layer.

A bank layer 564 is formed on the planarization layer 560 to cover an edge of the first electrode 610. Namely, the bank layer 564 is positioned at a boundary of the pixel region and exposes a center of the first electrode 610 in each of the red, green and blue pixel regions RP, GP and BP. Since the OLED D emits the white light in each of the red, green and blue pixel regions RP, GP and BP, the organic light emitting layer 615 can be formed as a common layer in the red, green and blue pixel regions RP, GP and BP without separation in the red, green and blue pixel regions RP, GP and BP. The bank layer 564 can be formed to prevent a current leakage at an edge of the first electrode 610 and can be omitted.

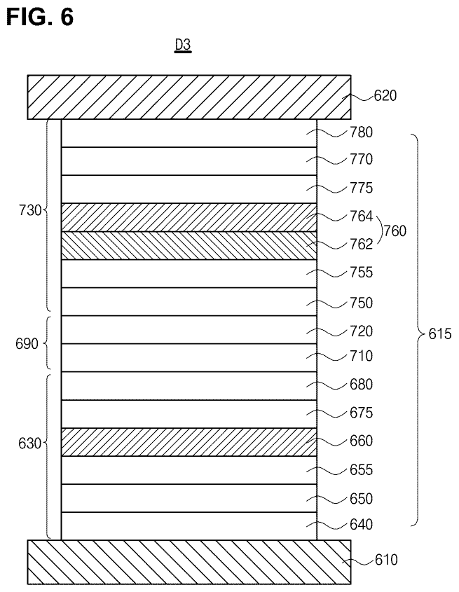

As described below, the organic light emitting layer 615 is formed on the first electrode 610 and includes two or more emitting parts (units). Namely, the OLED D has a tandem structure. For example, as shown in FIGS. 6 to 8, the organic light emitting layer 615 can include a plurality of emitting parts 630, 730, 830, 930, 1030, 1130, 1230 and 1330 and at least one CGLs 690, 890, 990, 1190 and 1290. Each of the emitting parts includes an EML, and the CGL is positioned between adjacent emitting parts.

The second electrode 620 is formed on the organic light emitting layer 615. The second electrode 620 can cover an entire of a display area and can be a cathode.

Since the light from the organic light emitting layer 615 passes through the second electrode 620 and is incident to the color filter layer 580, the second electrode 620 has a thin profile to be light-transparent. In addition, a reflection layer can be disposed under the first electrode 610.

The color filter layer 580 is disposed on or over the OLED D and includes a red color filter 582, a green color filter 584 and a blue color filter 586 respectively corresponding to the red pixel region RP, the green pixel region GP, and the blue pixel region BP. The red color filter 582 can include at least one of a red dye and a red pigment, the green color filter 584 can include at least one of a green dye and a green pigment, and the blue color filter 586 can include at least one of a blue dye and a blue pigment.

The color filter layer 580 can be attached to the OLED D using an adhesion layer. Alternatively, the color filter layer 580 can be formed directly on the OLED D.

In addition, an encapsulation layer can be formed to cover the OLED D, and the color filter layer 580 can be formed on the encapsulation layer.

In FIG. 5, the light from the organic light emitting layer 615 passes through the second electrode 620, and the color filter layer 580 is disposed over the OLED D. Alternatively, the light from the organic light emitting layer 615 can pass through the first electrode 610, and the color filter layer 580 can be disposed between the OLED D and the first substrate 502.

In addition, a color conversion layer can be disposed between the OLED D and the color filter layer 580. The color conversion layer can include red, green and blue color conversion layers respectively corresponding to the red, green and blue pixel regions RP, GP and BP. The white light from the OLED D can be converted into red, green and blue light by the red, green and blue color conversion layers.

As described above, the white light from the OLED D passes through the red, green and blue color filters 582, 584 and 586 in the red, green and blue pixel regions RP, GP and BP, so that the red, green and blue light are respectively displayed in the red, green and blue pixel regions RP, GP and BP.

FIG. 6 is a schematic cross-sectional view of an OLED according to a fifth embodiment of the present disclosure.

As shown in FIG. 6, the OLED D3 according to the fifth embodiment of the present disclosure includes the first and second electrodes 610 and 620 facing each other and an organic light emitting layer 615 therebetween, and the organic light emitting layer 615 includes a first emitting part 630 between the first and second electrodes 610 and 620 and a second emitting part 730 between the first emitting part 630 and the second electrode 620. In addition, the organic light emitting layer 615 can further include a CGL 690 between the first and second emitting parts 630 and 730.

The organic light emitting display device 500 includes the red, green and blue pixel regions RP, GP and BP, and the OLED D3 is positioned in the red, green and blue pixel regions RP, GP and BP.

The first electrode 610 can be an anode, and the second electrode 620 can be a cathode. The first electrode 610 can be a reflective electrode, and the second electrode 620 can be a transparent electrode.

The first emitting part 630 includes a first EML 660.

The first emitting part 630 can further include at least one of a first HTL (e.g., a lower HTL) 650 under the first EML 660 and a first ETL (e.g., a lower ETL) 670 on the first EML 660.

In addition, the first emitting part 630 can further include an HIL 640 under the first HTL 650. Moreover, the first emitting part 630 can further include at least one of a first EBL (e.g., a lower EBL) 655 between the first HTL 650 and the first EML 660 and a first HBL (e.g., a lower HBL) 675 between the first EML 660 and the first ETL 670.

The second emitting part 730 includes a second EML 760, and the second EML 760 includes a lower EML 762 and an upper EML 764 between the lower EML 762 and the second electrode 620. One of the lower and upper EMLs 762 and 764 is a red EML, and the other one of the lower and upper EMLs 762 and 764 is a green EML. For example, the upper EML 764 can be a red EML.

The second emitting part 730 can further include at least one of a second HTL (e.g., an upper HTL) 750 under the second EML 760 and a second ETL (e.g., an upper ETL) 770 on the second EML 760.

In addition, the second emitting part 730 can further include an EIL 780 on the second ETL 770. Moreover, the second emitting part 730 can further include at least one of a second EBL (e.g., an upper EBL) 755 between the second HTL 750 and the second EML 760 and a second HBL (e.g., an upper HBL) 775 between the second EML 760 and the second ETL 770.

The HIL 640 can include the above-mentioned hole injection material and can have a thickness of 10 to 100 nm. Each of the first and second HTLs 650 and 750 can include the above-mentioned hole transporting material and can have a thickness of 30 to 150 nm, preferably 50 to 120 nm.

Each of the first and second ETLs 680 and 770 can include the above-mentioned electron transporting material and can have a thickness of 10 to 100 nm, preferably 10 to 50 nm.

The EIL 780 can include the above-mentioned electron injection material and can have a thickness of 0.1 to 10 nm, preferably 0.5 to 5 nm.

In FIG. 6, the ETL 770 and the EIL 780 as separated elements are formed. Alternatively, an electron transporting-injection layer as a single layer having an electron transporting function and an electron injection function can be formed. In this case, the electron transporting-injection layer can include an electron transporting material and an electron injection material and can have a thickness of 10 to 50 nm. For example, the electron transporting-injection layer can include a compound in Formula 7 and a compound in Formula 8, and a weight % of the compound in Formula 7 and a weight % of the compound in Formula 8 can be same.

Each of the first and second EBLs 655 and 755 can include the above-mentioned electron blocking material, and each of the first and second HBLs 675 and 775 can include the above-mentioned hole blocking material.

The CGL 690 is positioned between the first and second emitting parts 630 and 730. The CGL 690 includes an N-type CGL 710 positioned to be closer to the first emitting part 630 and a P-type CGL 720 positioned to be closer to the second emitting part 730. The N-type CGL 710 provides an electron into the first emitting part 630, and the P-type CGL 720 provides a hole into the second emitting part 730.

The N-type CGL 710 can include the above-mentioned N-type charge generation material, and the P-type CGL 720 can include the above-mentioned P-type charge generation material.

The first EML 660 can be a blue EML. The first EML 660 can include a blue host and a blue dopant. For example, in the first EML 660, the blue dopant can have a weight % of 1 to 40, preferably 1 to 20, more preferably 1 to 10.

The blue host can include a blue host material being one of mCP, mCP-CN, mCBP, CBP-CN, CBP, 9-(3-(9H-Carbazol-9-yl)phenyl)-3-(diphenylphosphoryl)-9H-carbazole (mCPPO1), 3,5-di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spirobifluoren-2-yl-diphenyl-phosphine oxide (SPPO1), and 9,9′-(5-(triphenylsilyl)-1,3-phenylene)bis(9H-carbazole) (SimCP), but it is not limited thereto.

The blue dopant can include a blue dopant material being one of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,5,8,11-Tetra-tert-butylperylene (TBPe), Bepp2, 9-(9-phenylcarbazole-3-yl)-10-(naphthalene-1-yl)anthracene (PCAN), mer-tris(1-phenyl-3-methylimidazolin-2-ylidene-C,C(2)′iridium(III) (mer-Ir(pmi)₃), fac-tris(1,3-diphenyl-benzimidazolin-2-ylidene-C,C(2)′iridium(III) (fac-Ir(dpbic)₃), bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃), and bis[2-(4,6-difluorophenyl)pyridinato-C²,N](picolinato)iridium(III); Flrpic), but it is not limited thereto.

In an aspect to the present disclosure, the first EML 660 can include an anthracene derivative as a blue host and a boron derivative as a blue dopant.

At least one of the lower EML 762 and the upper EML 764 includes the organometallic compound represented by Formula 1 as a first compound.

For example, the upper EML 764 being the red EML can include the organometallic compound represented by Formula 1 as the first compound, i.e., a red dopant. In addition, the upper EML 764 can further include a second compound as a red host. In the upper EML 764 being the red EML, a weight % of the first compound is smaller than that of the second compound. For example, in the upper EML 764 being the red EML, the first compound can have a weight % of 1 to 40, preferably 1 to 20, more preferably 1 to 10.

The second compound, i.e., the red host, can include the above-mentioned red host material, but it is not limited thereto.

For example, the lower EML 762 being the green EML can include the organometallic compound represented by Formula 1 as the first compound, i.e., a green dopant. In addition, the lower EML 762 can further include a second compound as a green host. In the lower EML 762 being the green EML, a weight % of the first compound is smaller than that of the second compound. For example, in the lower EML 762 being the green EML, the first compound can have a weight % of 1 to 40, preferably 1 to 20, more preferably 1 to 10.

The second compound, i.e., the green host, can include the above-mentioned green host material, but it is not limited thereto.

When both the lower EML 762 being the green EML and the upper EML 764 being the red EML include the organometallic compound represented by Formula 1 as a first compound, the first compound, i.e., the green dopant, in the lower EML 762 and the first compound, i.e., the red dopant, in the upper EML 764 can have a difference in the auxiliary ligand in Formula 1 and emit light having different wavelength ranges.

Alternatively, the upper EML 764 being the red EML can include a red dopant other than the organometallic compound represented by Formula 1. In this case, the red dopant can include at least one of a red phosphorescent material, a red fluorescent material and a red delayed fluorescent material. For example, the red dopant can be the above-mentioned red dopant material, but it is not limited thereto.

In FIG. 6, the first emitting part 630 includes the blue EML, and the second emitting part 730 includes the red and green EMLs. Alternatively, the first emitting part 630 can include the red and green EMLs, and the second emitting part 730 can include the blue EML.

In FIG. 6, the second EML 760 has a double-layered structure including the lower EML 762, which is one of the red and green EMLs, and the upper EML 764, which is the other one of the red and green EMLs. Alternatively, the second EML 760 can further include a yellow-green EML between the red and green EMLs 762 and 764 to have a triple-layered structure.

In FIG. 6, the organic light emitting layer 615 includes the first emitting part 630 including the first EML 660 and the second emitting part 730 including the second EML 760 so that the OLED D3 has a two-stack structure. Alternatively, the organic light emitting layer 615 can further include a third emitting part including a blue EML and positioned between the second emitting part 730 and the second electrode 620 so that the OLED D3 can have a triple-layered structure. In this case, a CGL can be disposed between the second emitting part 730 and the third emitting part. In addition, the second EML 760 can further include a yellow-green EML between the lower EML 762, which is one of the red and green EMLs, and the upper EML 764, which is the other one of the red and green EMLs, to have a triple-layered structure.

As described above, the OLED D3 includes the first emitting part 630 including the first EML 660 being the blue EML and the second emitting part 730 including the red and green EMLs 762 and 764. As a result, the OLED D3 provides white emission. The OLED D3 is applied to the organic light emitting display device 500 including the color filter layer 580 so that the organic light emitting display device 500 can provide a full-color image.

In the OLED D3 of the present disclosure, at least one of the lower and upper EMLs 762 and 764 of the second EML 760 includes the organometallic compound of the present disclosure. As a result, the emitting efficiency and the lifespan of the OLED D3 are improved.

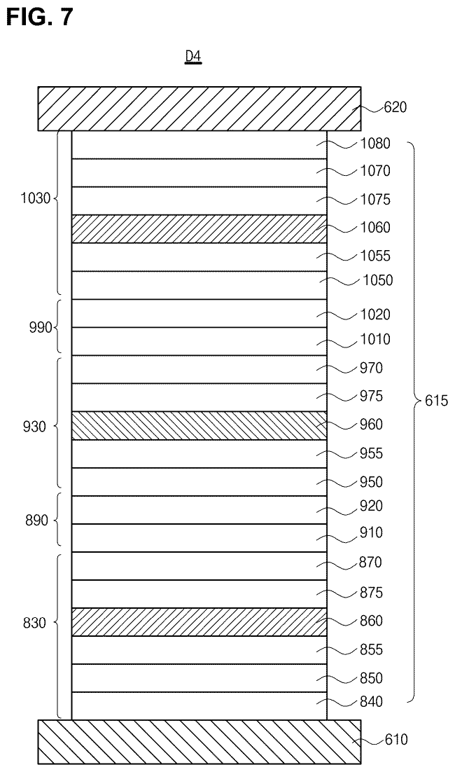

FIG. 7 is a schematic cross-sectional view of an OLED according to a sixth embodiment of the present disclosure.

As shown in FIG. 7, the OLED D4 according to the sixth embodiment of the present disclosure includes the first and second electrodes 610 and 620 facing each other and an organic light emitting layer 615 therebetween, and the organic light emitting layer 615 includes a first emitting part 830 between the first and second electrodes 610 and 620, a second emitting part 930 between the first emitting part 830 and the second electrode 620 and a third emitting part 1030 between the second emitting part 930 and the second electrode 620. In addition, the organic light emitting layer 615 can further include a first CGL 890 between the first and second emitting parts 830 and 930 and a second CGL 990 between the second and third emitting parts 930 and 1030.

The organic light emitting display device 500 includes the red, green and blue pixel regions RP, GP and BP, and the OLED D4 is positioned in the red, green and blue pixel regions RP, GP and BP.

The first electrode 610 can be an anode, and the second electrode 620 can be a cathode. The first electrode 610 can be a reflective electrode, and the second electrode 620 can be a transparent electrode.

The first emitting part 830 includes a first EML 860.

The first emitting part 830 can further include at least one of a first HTL 850 under the first EML 860 and a first ETL 870 on the first EML 860.

In addition, the first emitting part 830 can further include an HIL 840 under the first HTL 850. Moreover, the first emitting part 830 can further include at least one of a first EBL 855 between the first HTL 850 and the first EML 860 and a first HBL 875 between the first EML 860 and the first ETL 870.

The second emitting part 930 includes a second EML 960.

In addition, the second emitting part 930 can further include at least one of a second HTL 950 under the second EML 960 and a second ETL 970 on the second EML 960.

Moreover, the second emitting part 930 can further include at least one of a second EBL 955 between the second HTL 950 and the second EML 960 and a second HBL 975 between the second EML 960 and the second ETL 970.

The third emitting part 1030 includes a third EML 1060.

In addition, the third emitting part 1030 can further include an EIL 1080 on the second ETL 1070. Moreover, the third emitting part 1030 can further include at least one of a third EBL 1055 between the third HTL 1050 and the third EML 1060 and a third HBL 1075 between the third EML 1060 and the third ETL 1070.

The HIL 840 can include the above-mentioned hole injection material, and each of the first to third HTLs 850, 950 and 1050 can include the above-mentioned hole transporting material.

Each of the first to third ETLs 870, 970 and 1070 can include the above-mentioned electron transporting material, and the EIL 1080 can include the above-mentioned electron injection material.

Each of the first to third EBLs 855, 955 and 1055 can include the above-mentioned electron blocking material, and each of the first to third HBLs 875, 975 and 1075 can include the above-mentioned hole blocking material.

The first CGL 890 is positioned between the first and second emitting parts 830 and 930, and the second CGL 990 is positioned between the second and third emitting parts 930 and 1030. The first CGL 890 includes a first N-type CGL 910 positioned to be closer to the first emitting part 830 and a first P-type CGL 920 positioned to be closer to the second emitting part 930. The second CGL 990 includes a second N-type CGL 1010 positioned to be closer to the second emitting part 930 and a second P-type CGL 1020 positioned to be closer to the third emitting part 1030. The first and second N-type CGLs 910 and 1010 respectively provide an electron into the first and second emitting parts 830 and 930, and the first and second P-type CGL 920 and 1020 respectively provide a hole into the second and third emitting parts 930 and 1030.

Each of the first and second N-type CGLs 910 and 1010 can include the above-mentioned N-type charge generation material, and each of the first and second P-type CGL 920 and 1020 can include the above-mentioned P-type charge generation material.

One of the first to third EMLs 860, 960 and 1060 is a red EML, another one of the first to third EMLs 860, 960 and 1060 is a green EML, and the other one of the first to third EMLs 860, 960 and 1060 is a blue EML. Accordingly, the OLED 500 can provide white emission.

For example, the first EML 860 can be a red EML, the second EML 960 can be a green EML, and the third EML 1060 can be a blue EML.

In this case, the first EML 860 being the red EML can include the organometallic compound represented by Formula 1 as the first compound, i.e., a red dopant. In addition, the first EML 860 can further include a second compound as a red host. In the first EML 860, a weight % of the first compound is smaller than that of the second compound. For example, in the first EML 860, the first compound can have a weight % of 1 to 40, preferably 1 to 20, more preferably 1 to 10.

The second compound, i.e., the red host, can include the above-mentioned red host material.

The second EML 960 being the green EML can include the organometallic compound represented by Formula 1 as the first compound, i.e., a green dopant. In addition, the second EML 960 can further include a second compound as a green host. In the second EML 960, a weight % of the first compound is smaller than that of the second compound. For example, in the second EML 960, the first compound can have a weight % of 1 to 40, preferably 1 to 20, more preferably 1 to 10.

The second compound, i.e., the green host, can include the above-mentioned green host material.

When both the first EML 860 being the red EML and the second EML 960 being the green EML include the organometallic compound represented by Formula 1 as a first compound, the first compound, i.e., the red dopant, in the first EML 860 and the first compound, i.e., the green dopant, in the second EML 960 can have a difference in the auxiliary ligand in Formula 1 and emit light having different wavelength ranges.

Alternatively, the first EML 860 being the red EML can include a red dopant other than the organometallic compound represented by Formula 1. In this case, the red dopant can include at least one of a red phosphorescent material, a red fluorescent material and a red delayed fluorescent material. For example, the red dopant can be the above-mentioned red dopant material.

The third EML 1060 can be a blue EML. The third EML 1060 can include a blue host and a blue dopant. For example, in the third EML 1060, the blue dopant can have a weight % of 1 to 40, preferably 1 to 20, more preferably 1 to 10.

The blue host can be the above-mentioned blue host material, and the blue dopant can be the above-mentioned blue dopant material.

As described above, the OLED D4 includes the first emitting part 830 including the first EML 860, which can be the red EML, the second emitting part 930 including the second EML 960, which can be the green EML, and the third emitting part 1030 including the third EML 1060, which can be the blue EML. As a result, the OLED D4 provides white emission. The OLED D4 is applied to the organic light emitting display device 500 including the color filter layer 580 so that the organic light emitting display device 500 can provide a full-color image.

In the OLED D4 of the present disclosure, at least one of the first and second EMLs 860 and 960 includes the organometallic compound of the present disclosure. As a result, the emitting efficiency and the lifespan of the OLED D4 are improved.

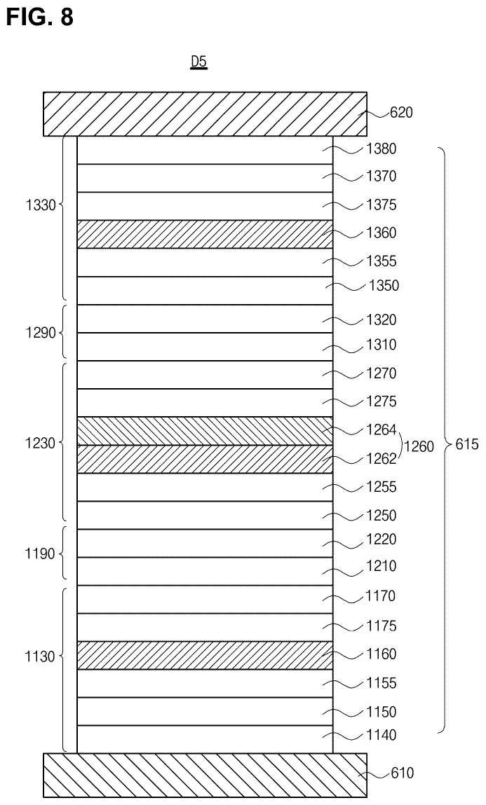

FIG. 8 is a schematic cross-sectional view of an OLED according to a seventh embodiment of the present disclosure.

As shown in FIG. 8, the OLED D5 according to the seventh embodiment of the present disclosure includes the first and second electrodes 610 and 620 facing each other and an organic light emitting layer 615 therebetween, and the organic light emitting layer 615 includes a first emitting part 1130 between the first and second electrodes 610 and 620, a second emitting part 1230 between the first emitting part 1130 and the second electrode 620 and a third emitting part 1330 between the second emitting part 1230 and the second electrode 620. In addition, the organic light emitting layer 615 can further include a first CGL 1190 between the first and second emitting parts 1130 and 1230 and a second CGL 1290 between the second and third emitting parts 1230 and 1330.

The organic light emitting display device 500 includes the red, green and blue pixel regions RP, GP and BP, and the OLED D5 is positioned in the red, green and blue pixel regions RP, GP and BP.

The first electrode 610 can be an anode, and the second electrode 620 can be a cathode. The first electrode 610 can be a reflective electrode, and the second electrode 620 can be a transparent electrode.

The first emitting part 1130 includes a first EML 1160.

The first emitting part 1130 can further include at least one of a first HTL 1150 under the first EML 1160 and a first ETL 1170 on the first EML 1160.

In addition, the first emitting part 1130 can further include an HIL 1140 under the first HTL 1150. Moreover, the first emitting part 1130 can further include at least one of a first EBL 1155 between the first HTL 1150 and the first EML 1160 and a first HBL 1175 between the first EML 1160 and the first ETL 1170.

The second emitting part 1230 includes a second EML 1260.

In addition, the second emitting part 1230 can further include at least one of a second HTL 1250 under the second EML 1260 and a second ETL 1270 on the second EML 1260.

Moreover, the second emitting part 1230 can further include at least one of a second EBL 1255 between the second HTL 1250 and the second EML 1260 and a second HBL 1275 between the second EML 1260 and the second ETL 1270.

The third emitting part 1330 includes a third EML 1360.

In addition, the third emitting part 1330 can further include an EIL 1380 on the second ETL 1370. Moreover, the third emitting part 1330 can further include at least one of a third EBL 1355 between the third HTL 1350 and the third EML 1360 and a third HBL 1375 between the third EML 1360 and the third ETL 1370.

The HIL 1140 can include the above-mentioned hole injection material, and each of the first to third HTLs 1150, 1250 and 1350 can include the above-mentioned hole transporting material.

Each of the first to third ETLs 1170, 1270 and 1370 can include the above-mentioned electron transporting material, and the EIL 1380 can include the above-mentioned electron injection material.

Each of the first to third EBLs 1155, 1255 and 1355 can include the above-mentioned electron blocking material, and each of the first to third HBLs 1175, 1275 and 1375 can include the above-mentioned hole blocking material.

The first CGL 1190 is positioned between the first and second emitting parts 1130 and 1230, and the second CGL 1290 is positioned between the second and third emitting parts 1230 and 1330. The first CGL 1190 includes a first N-type CGL 1210 positioned to be closer to the first emitting part 1130 and a first P-type CGL 1220 positioned to be closer to the second emitting part 1230. The second CGL 1290 includes a second N-type CGL 1310 positioned to be closer to the second emitting part 1230 and a second P-type CGL 1320 positioned to be closer to the third emitting part 1330. The first and second N-type CGLs 1210 and 1310 respectively provide an electron into the first and second emitting parts 1130 and 1230, and the first and second P-type CGL 1220 and 1320 respectively provide a hole into the second and third emitting parts 1230 and 1330.

Each of the first and second N-type CGLs 1210 and 1310 can include the above-mentioned N-type charge generation material, and each of the first and second P-type CGL 1220 and 1320 can include the above-mentioned P-type charge generation material.

Each of the first and third EMLs 1160 and 1360 can be a blue EML. Each of the first and third EMLs 1160 and 1360 can include a blue host and a blue dopant. The blue host in the first EML 1160 and the blue host in the third EML 1360 can be same or different, and the blue dopant in the first EML 1160 and the blue dopant in the third EML 1360 can be same or different. For example, in each of the first and third EMLs 1160 and 1360, the blue dopant can have a weight % of 1 to 40, preferably 1 to 20, more preferably 1 to 10.

The blue host can be the above-mentioned blue host material, and the blue dopant can be the above-mentioned blue dopant material.

The second EML 1260 includes a lower EML 122 between the second EBL 1255 and the second HBL 1275 and an upper EML 1264 between the lower EML 1262 and the second HBL 1275. One of the lower and upper EMLs 1262 and 1264 is a red EML, and the other one of the lower and upper EMLs 1262 and 1264 is a green EML. For example, the lower EML 1262 can be a red EML.

At least one of the lower EML 1262 and the upper EML 1264 includes the organometallic compound represented by Formula 1 as a first compound.

For example, the lower EML 1262 being the red EML can include the organometallic compound represented by Formula 1 as the first compound, i.e., a red dopant. In addition, the lower EML 1262 can further include a second compound as a red host. In the lower EML 1262 being the red EML, a weight % of the first compound is smaller than that of the second compound. For example, in the lower EML 1262 being the red EML, the first compound can have a weight % of 1 to 40, preferably 1 to 20, more preferably 1 to 10.

The second compound, i.e., the red host, can include the above-mentioned red host material.

For example, the upper EML 1264 being the green EML can include the organometallic compound represented by Formula 1 as the first compound, i.e., a green dopant. In addition, the upper EML 1264 can further include a second compound as a green host. In the upper EML 1264 being the green EML, a weight % of the first compound is smaller than that of the second compound. For example, in the upper EML 1264 being the green EML, the first compound can have a weight % of 1 to 40, preferably 1 to 20, more preferably 1 to 10.

The second compound, i.e., the green host, can include the above-mentioned green host material.

When both the lower EML 1262 being the red EML and the upper EML 1264 being the green EML include the organometallic compound represented by Formula 1 as a first compound, the first compound, i.e., the red dopant, in the lower EML 1262 and the first compound, i.e., the green dopant, in the upper EML 1264 can have a difference in the auxiliary ligand in Formula 1 and emit light having different wavelength ranges.

Alternatively, the lower EML 1262 being the red EML can include a red dopant other than the organometallic compound represented by Formula 1. In this case, the red dopant can include at least one of a red phosphorescent material, a red fluorescent material and a red delayed fluorescent material. For example, the red dopant can be the above-mentioned red dopant material.

In FIG. 8, the second EML 1260 has a double-layered structure of the lower EML 1262 being the red EML and the upper EML 1264 being the green EML.

Alternatively, the second EML 1260 can further include a yellow-green EML between the lower and upper EMLs 1262 and 1264 to have a triple-layered structure.

The yellow-green EML can include the organometallic compound represented by Formula 1 as a yellow-green dopant. In addition, the yellow-green EML can further include a yellow-green host. For example, in the yellow-green EML, the yellow-green dopant can have a weight % of 1 to 40, preferably 1 to 20, more preferably 1 to 10.

Alternatively, the yellow-green EML can include a yellow-green dopant other than the organometallic compound represented by Formula 1. In this case, the yellow-green dopant can include at least one of a yellow-green phosphorescent material, a yellow-green fluorescent material and a yellow-green delayed fluorescent material.

For example, the yellow-green dopant can be one of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)iridium(III) (Ir(BT)2(acac)), bis(2-(9,9-diethyl-fluoren-2-yl)-1-phenyl-1H-benzo[d]imdiazolato)(acetylacetonate)iridium(III) (Ir(fbi)2(acac)), bis(2-phenylpyridine)(3-(pyridine-2-yl)-2H-chromen-2-onate)iridium(III) (fac-Ir(ppy)₂Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(III) (PO-01).

As described above, the OLED D5 includes the first and third emitting parts 1130 and 1330 respectively including the first and third EMLs 1160 and 1360, each of which is the blue EML, and the second emitting part 1230 including the red and green EMLs. As a result, the OLED D5 provides white emission. The OLED D5 is applied to the organic light emitting display device 500 including the color filter layer 580 so that the organic light emitting display device 500 can provide a full-color image.

In the OLED D5 of the present disclosure, at least one of the lower and upper EMLs 1262 and 1264 of the second EML 1260 includes the organometallic compound of the present disclosure. As a result, the emitting efficiency and the lifespan of the OLED D5 are improved.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organometallic compound represented by Formula 1: 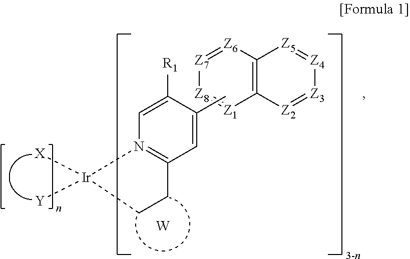
wherein in the Formula 1,
n is an integer of 0 to 2,
each of Z₁, Z₂, Z₃, Z₄, Z₅, Z₆, Z₇ and Z₈ is independently C, CR₂ or N, one of Z₁, Z₂, Z₃, Z₄, Z₅, Z₆, Z₇ and Z₈ is C,
R₁ is selected from the group consisting of hydrogen, deuterium and a substituted or unsubstituted C1 to C20 alkyl group,
R₂ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X and Y is independently selected from the group consisting of C, N and O, and
a W ring is represented by one of Formulas 1a-1, 1a-2 and 1a-3, 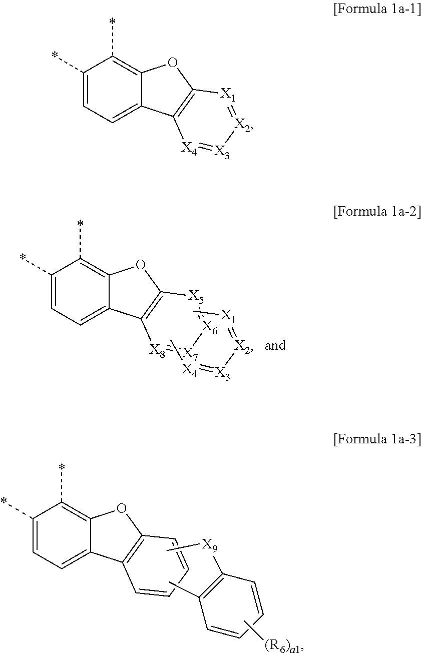
wherein in each of the Formulas 1a-1 and 1a-2,
each of X₁, X₂, X₃ and X₄ is independently CR₄ or N, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
wherein in the Formula 1a-2,
each of X₅, X₆, X₇ and X₈ is independently CR₅ or N, at least two of X₅, X₆, X₇ and X₈ are CR₅, and
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group, and
wherein in the Formula 1a-3,
X₉ is O or S, a1 is an integer of 0 to 4, and
R₆ is selected from the group consisting of deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group.

2. The organometallic compound according to claim 1, wherein an “X-Y” ligand in the Formula 1 is represented by one of Formulas 1b-1, 1b-2 and 1b-3: 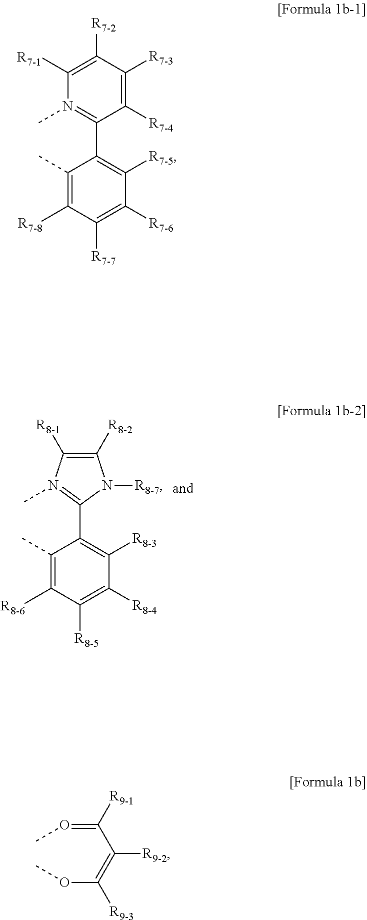
wherein in the Formula 1b-1,
each of R₇₋₁, R₇₋₂, R₇₋₃, R₇₋₄, R₇₋₅, R₇₋₆, R₇₋₇, and R₇₋₈ is independently selected from the group consisting of hydrogen, deuterium, halide, a substituted or unsubstituted C1 to C5 alkyl group and a substituted or unsubstituted C6 to C30 aryl group, or optionally, adjacent two of R₇₋₁, R₇₋₂, R₇₋₃ and R₇₋₄ or adjacent two of R₇₋₅, R₇₋₆, R₇₋₇, and R₇₋₈ are combined to form a ring,
wherein in the Formula 1b-2,
each of R₈₋₁, R₈₋₂, R₈₋₃, R₈₋₄, R₈₋₅ and R₈₋₆ is independently selected from the group consisting of hydrogen, deuterium, halide, a substituted or unsubstituted C1 to C5 alkyl group and a substituted or unsubstituted C6 to C30 aryl group, or optionally, adjacent two of R₈₋₁, R₈₋₂, R₈₋₃, R₈₋₄, R₈₋₅ and R₈₋₆ are combined to form a ring, and
R₈₋₇ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group, and
wherein in the Formula 1b-3,
each of R₉₋₁, R₉₋₂ and R₉₋₃ is independently selected from the group consisting of hydrogen, deuterium, halide, a substituted or unsubstituted C1 to C5 alkyl group and a substituted or unsubstituted C6 to C30 aryl group, or optionally, adjacent two of R₉₋₁, R₉₋₂ and R₈₋₃ are combined to form a ring.

3. The organometallic compound according to claim 1, wherein the Formula 1 is represented by one of Formulas 2-1, 2-2 and 2-3: 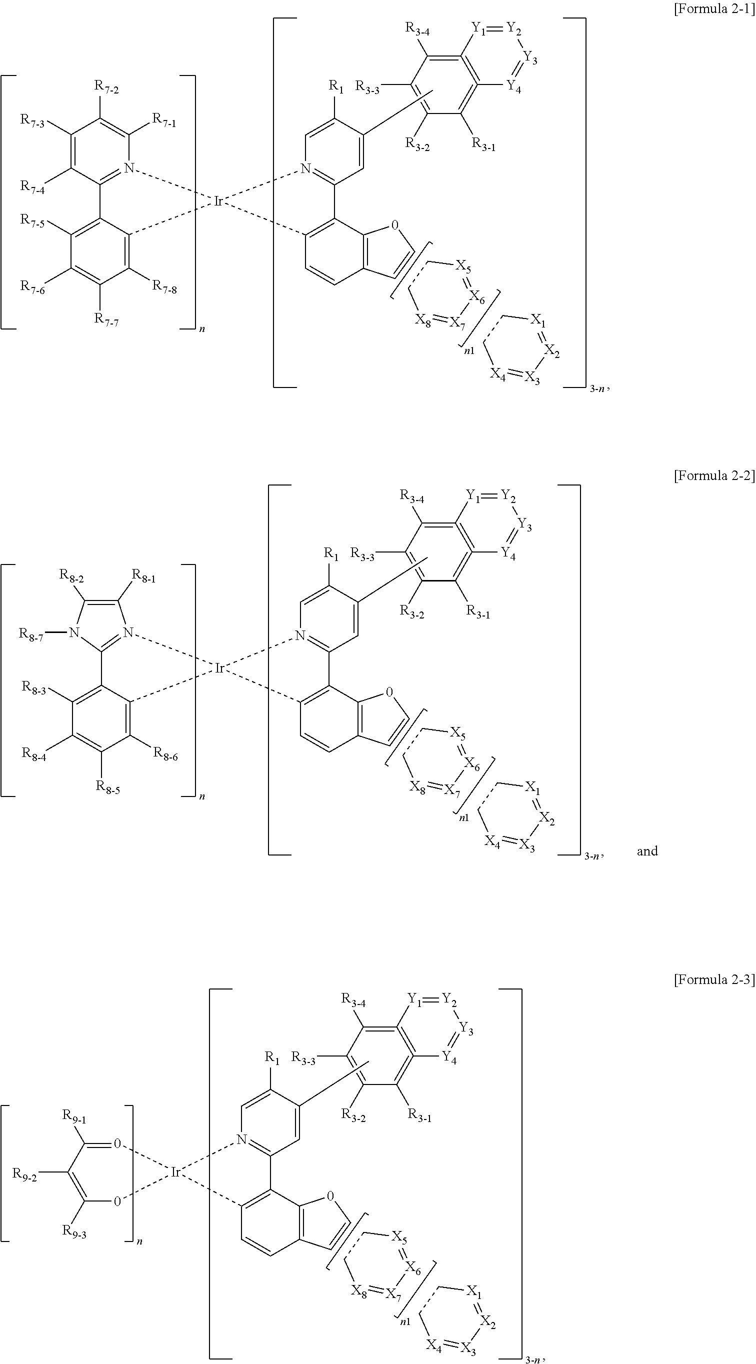
each of the Formulas 2-1 to 2-3,
n is an integer of 0 to 2, and n1 is 0 or 1,
R₁ is selected from the group consisting of hydrogen, deuterium and a C1 to C20 alkyl group unsubstituted or substituted with deuterium,
i) each of Y₁ to Y₄ is independently CR₂ or N, or ii) one of Y₁ to Y₄ is N, and the rest of Y₁ to Y₄ is CR₂,
one of R₃₋₁ to R₃₋₄ is a connecting group,
each of R₂ and the rest of R₃₋₁ to R₃₋₄ is independently selected from the group consisting of hydrogen, a C1 to C20 alkyl group unsubstituted or substituted with deuterium and a substituted or unsubstituted C6 to C30 aryl group,
each of X₁, X₂, X₃ and X₄ is independently CR₄ or N, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X₅, X₆, X₇ and X₈ is independently CR₅ or N, and two of X₅, X₆, X₇ and X₈ are CR₅, and
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
wherein in the Formula 2-1,
each of R₇₋₂, R₇₋₃, R₇₋₆ and R₇₋₇ is independently selected from the group consisting of hydrogen, deuterium, a C1 to C5 alkyl group unsubstituted or substituted with deuterium and a substituted or unsubstituted C6 to C30 aryl group,
wherein in the Formula 2-2,
each of R₈₋₁ and R₈₋₂ is independently selected from the group consisting of hydrogen and a C1 to C20 alkyl group unsubstituted or substituted with deuterium, or optionally R₈₋₁ and R₈₋₂ are combined to form a ring,
R₈₋₅ is selected from the group consisting of hydrogen and a C1 to C20 alkyl group unsubstituted or substituted with deuterium, and
R₈₋₇ is selected from the group consisting of hydrogen, a C1 to C20 alkyl group unsubstituted or substituted with deuterium and a C6 to C30 aryl group unsubstituted or substituted with at least one of a C1 to C20 alkyl group and a deuterated C1 to C20 alkyl group, and
wherein in the Formula 2-3,
each of R₉₋₁ and R₉₋₃ is independently selected from the group consisting of hydrogen and a C1 to C20 alkyl group unsubstituted or substituted with deuterium.

4. The organometallic compound according to claim 1, wherein the Formula 1 is represented by one of Formulas 2-4, 2-5 and 2-6: 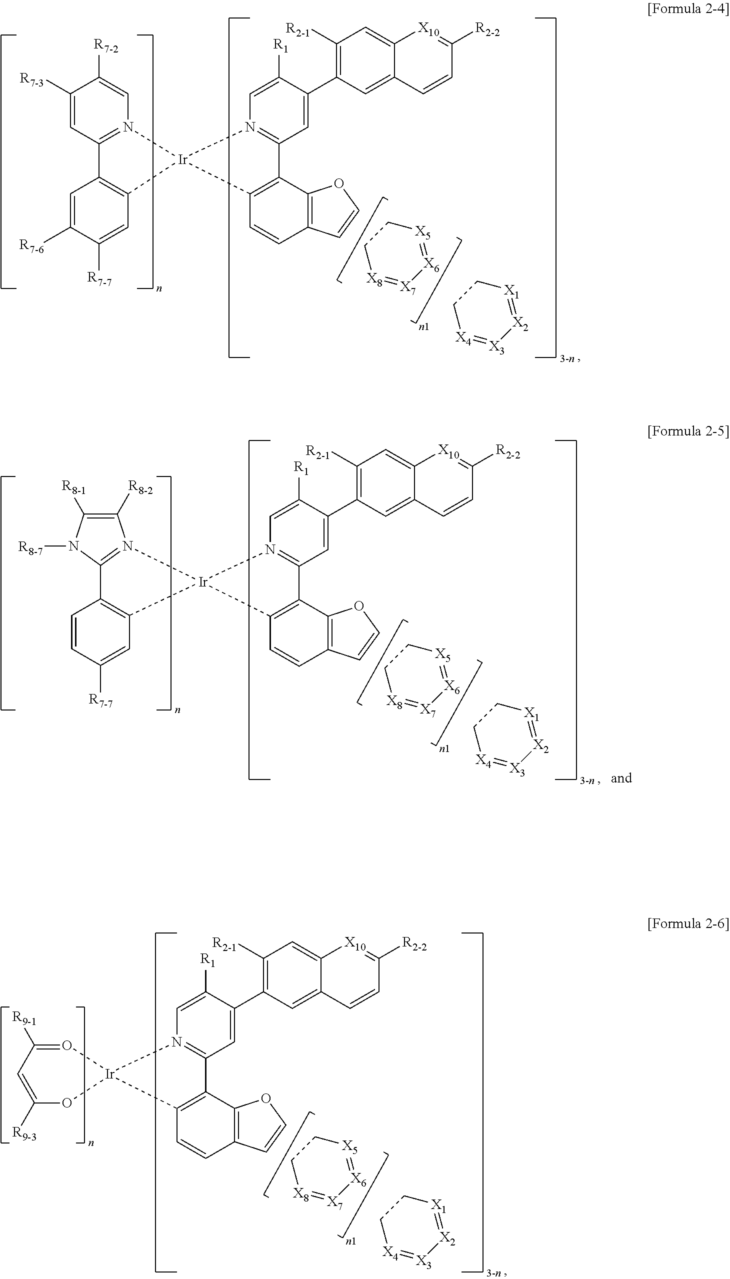
wherein in each of the Formula Formulas 2-4 to 2-6,
n is an integer of 0 to 2, and n1 is 0 or 1,
X₁₀ is CR₁₀ or N,
R₁ is selected from the group consisting of hydrogen, deuterium and a C1 to C20 alkyl group unsubstituted or substituted with deuterium,
each of R₂₋₁, R₂₋₂ and R₁₀ is independently selected from the group consisting of hydrogen, deuterium, a C1 to C20 alkyl group unsubstituted or substituted with deuterium and a substituted or unsubstituted C6 to C30 aryl group,
each of X₁, X₂, X₃ and X₄ is independently CR₄ or N, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X₅, X₆, X₇ and X₈ is independently CR₅ or N, and two of X₅, X₆, X₇ and X₈ are CR₅, and
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
wherein in the Formula 2-4,
each of R₇₋₂, R₇₃, R₇₋₆ and R₇₋₇ is independently selected from the group consisting of hydrogen, deuterium, a C1 to C5 alkyl group unsubstituted or substituted with deuterium and a substituted or unsubstituted C6 to C30 aryl group,
wherein in the Formula 2-5,
each of R₈₋₁ and R₈₋₂ is independently selected from the group consisting of hydrogen and a C1 to C20 alkyl group unsubstituted or substituted with deuterium, or optionally R₈₋₁ and R₈₋₂ are combined to form a ring,
R₈₋₅ is selected from the group consisting of hydrogen and a C1 to C20 alkyl group unsubstituted or substituted with deuterium, and
R₈₋₇ is selected from the group consisting of hydrogen, a C1 to C20 alkyl group unsubstituted or substituted with deuterium and a C6 to C30 aryl group unsubstituted or substituted with at least one of a C1 to C20 alkyl group and a deuterated C1 to C20 alkyl group,
wherein in the Formula 2-6,
each of R₉₋₁ and R₉₋₃ is independently selected from the group consisting of hydrogen and a C1 to C20 alkyl group unsubstituted or substituted with deuterium.

5. The organometallic compound according to claim 1, wherein the Formula 1 is represented by Formula 2-4: 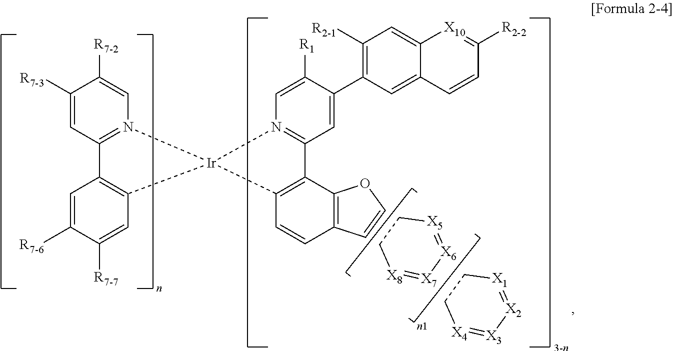
wherein:
n is an integer of 1 to 2, and n1 is 0 or 1,
X₁₀ is CR₁₀ or N,
R₁ is selected from the group consisting of hydrogen, deuterium and a C1 to C20 alkyl group unsubstituted or substituted with deuterium,
each of R₂₋₁, R₂₋₂ and R₁₀ is independently selected from the group consisting of hydrogen, deuterium, methyl, ethyl and propyl,
wherein one of X₁, X₂, X₃ and X₄ is N and the rest are CR₄, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X₅, X₆, X₇ and X₈ is independently CR₅ or N, wherein at least two of X₅, X₆, X₇ and X₈ are CR₅,
R₅ is a bonding site selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and
each of R₇₋₂, R₇₋₃, R₇₋₆ and R₇₋₇ is independently selected from the group consisting of hydrogen, deuterium, a C1 to C5 alkyl group unsubstituted or substituted with deuterium and a substituted or unsubstituted C6 to C30 aryl group.

6. The organometallic compound according to claim 1, wherein the Formula 1 is represented by Formula 2-5: 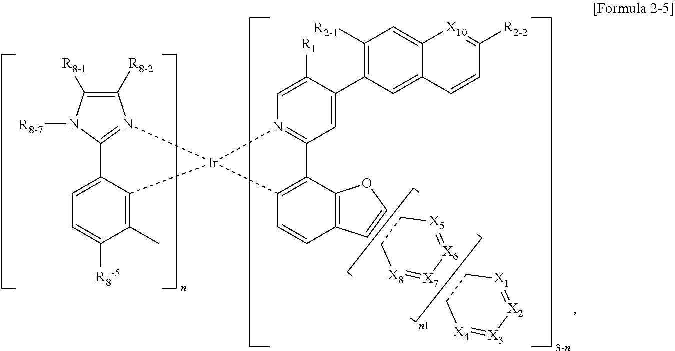
wherein:
n is an integer of 1 to 2, and n1 is 0 or 1,
X₁₀ is CR₁₀ or N,
R₁ is selected from the group consisting of hydrogen, deuterium and a C1 to C20 alkyl group unsubstituted or substituted with deuterium,
each of R₂₋₁, R₂₋₂ and R₁₀ is independently selected from the group consisting of hydrogen, deuterium, methyl, ethyl and propyl,
wherein one of X₁, X₂, X₃ and X₄ is N and the rest are CR₄, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X₅, X₆, X₇ and X₈ is independently CR₅ or N, wherein at least two of X₅, X₆, X₇ and X₈ are CR₅,
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
each of R₈₋₁ and R₈₋₂ is independently selected from the group consisting of hydrogen and a C1 to C20 alkyl group unsubstituted or substituted with deuterium,
R₈₋₅ is selected from the group consisting of hydrogen and a C1 to C20 alkyl group unsubstituted or substituted with deuterium, and
R₈₋₇ is selected from the group consisting of hydrogen, a C1 to C20 alkyl group unsubstituted or substituted with deuterium and a C6 to C30 aryl group unsubstituted or substituted with at least one of a C1 to C20 alkyl group and a deuterated C1 to C20 alkyl group.

7. The organometallic compound according to claim 1, wherein the Formula 1 is represented by Formula 2-6: 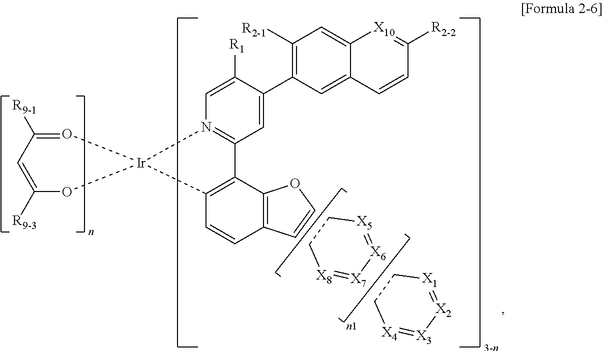
wherein:
n is an integer of 1 to 2, and n1 is 0 or 1,
X₁₀ is CR₁₀ or N,
R₁ is selected from the group consisting of hydrogen, deuterium and a C1 to C20 alkyl group unsubstituted or substituted with deuterium,
each of R₂₋₁, R₂₋₂ and R₁₀ is independently selected from the group consisting of hydrogen, deuterium, methyl, ethyl, and propyl,
wherein one of X₁, X₂, X₃ and X₄ is N and the rest are CR₄, R₄ is selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group, a substituted or unsubstituted C3 to C30 heteroaryl group, an acyl group, a carbonyl group, a carboxyl group, an ester group, a nitrile group, an isonitrile group, a sulfanyl group, a sulfinyl group, a sulfonyl group and a phosphino group,
each of X₅, X₆, X₇ and X₈ is independently CR₅ or N, wherein at least two of X₅, X₆, X₇ and X₈ are CR₅,
R₅ is a bonding site or selected from the group consisting of hydrogen, deuterium, halide, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C1 to C20 alkylsilyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and
each of R₉₋₁ and R₉₋₃ is independently selected from the group consisting of hydrogen and a C1 to C20 alkyl group unsubstituted or substituted with deuterium.

8. The organometallic compound according to claim 1, wherein the organometallic compound is one of compounds in Formula 3:

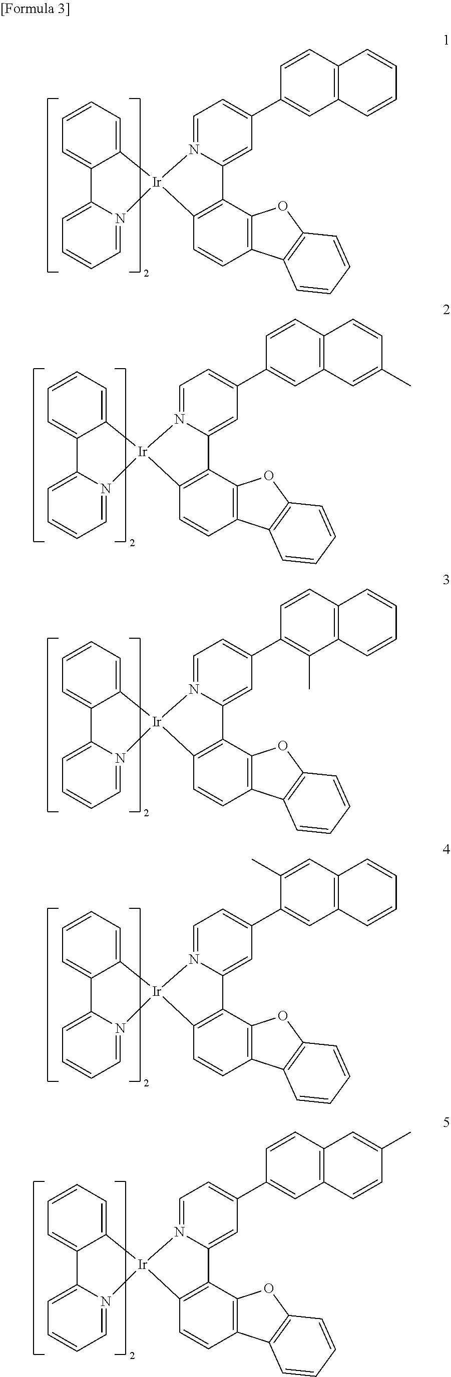

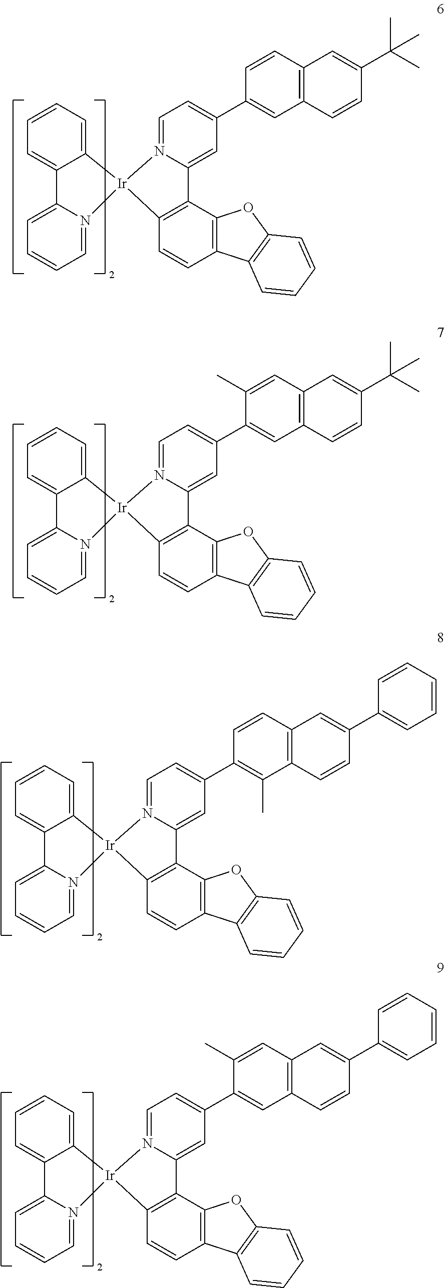

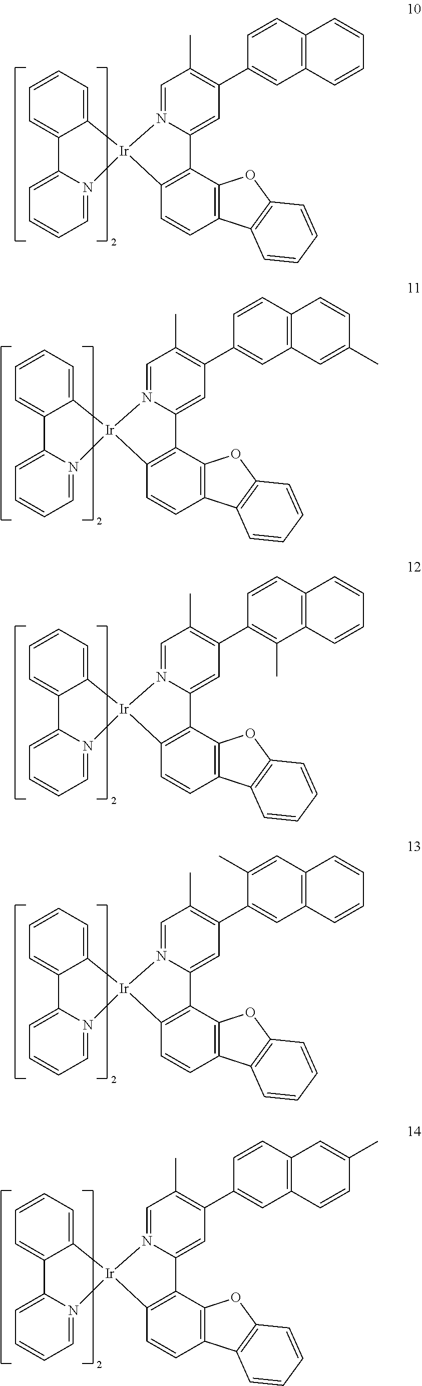

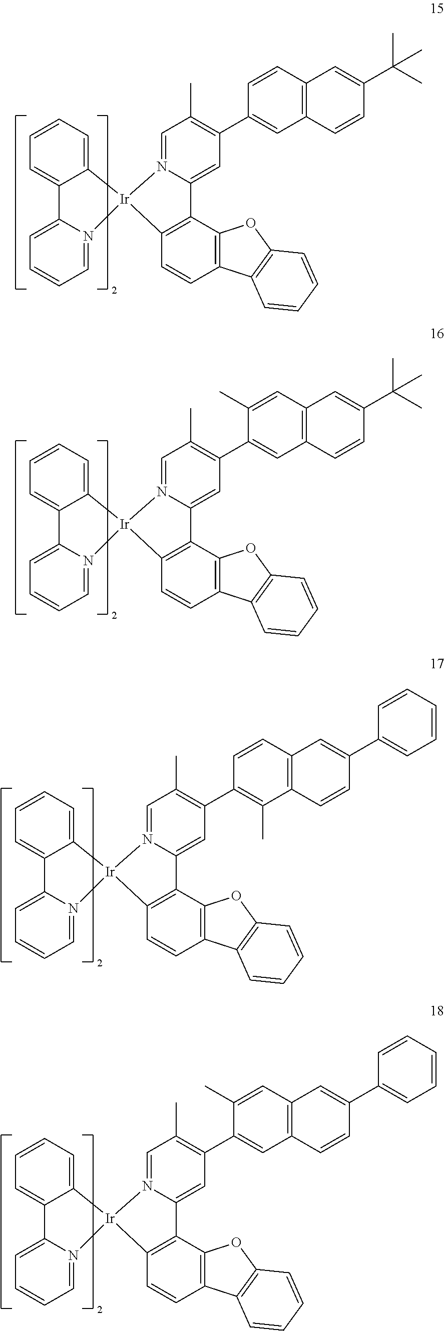

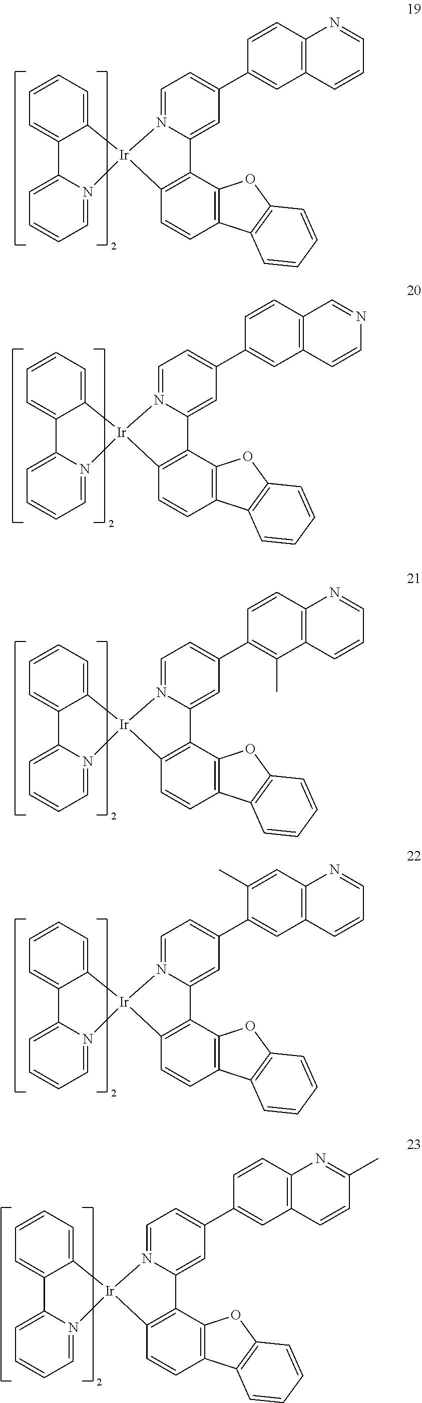

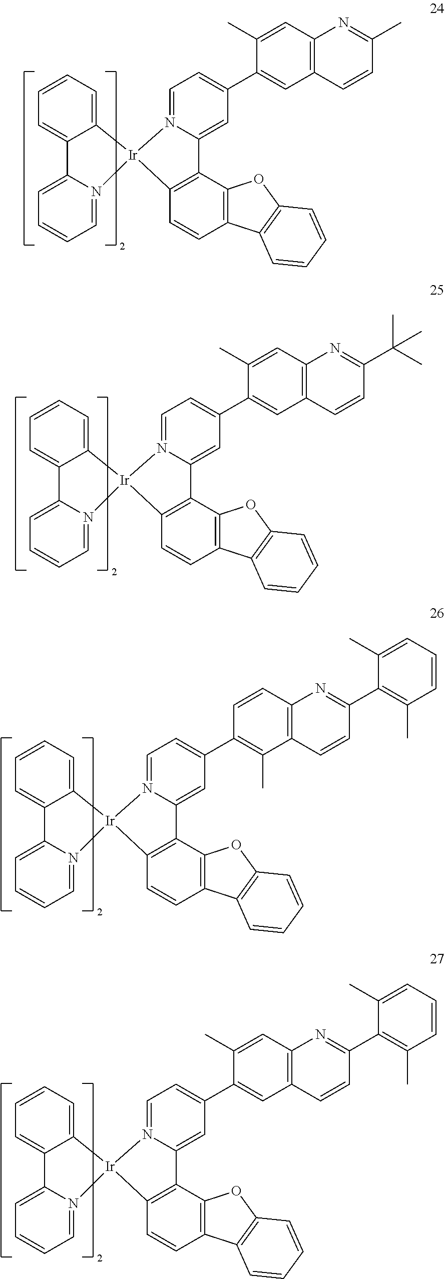

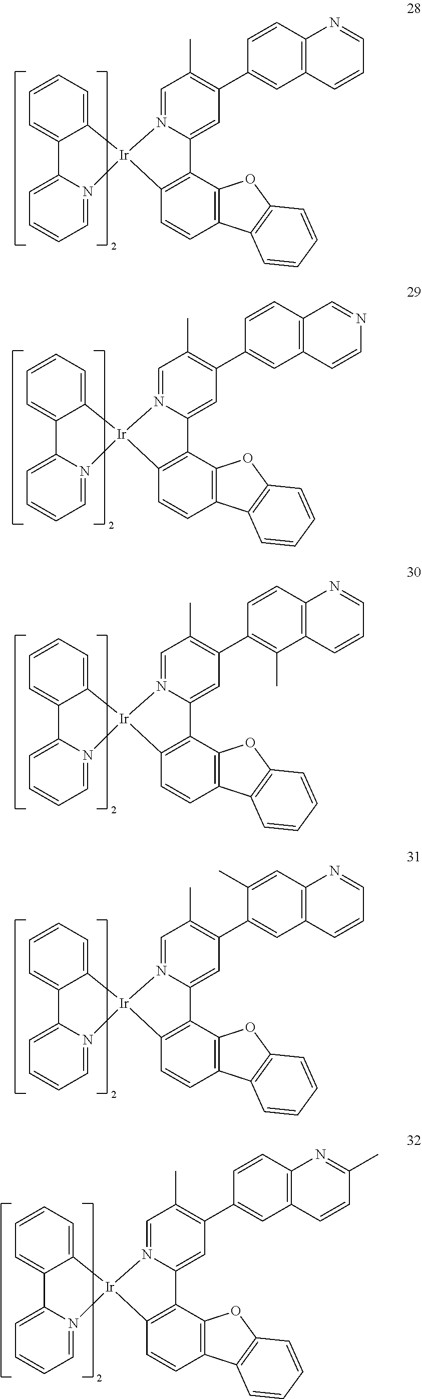

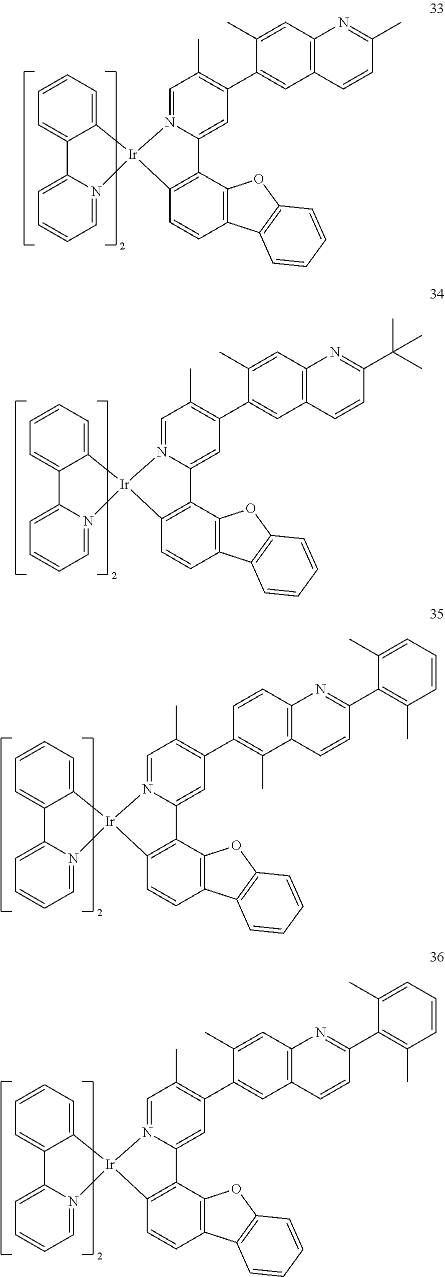

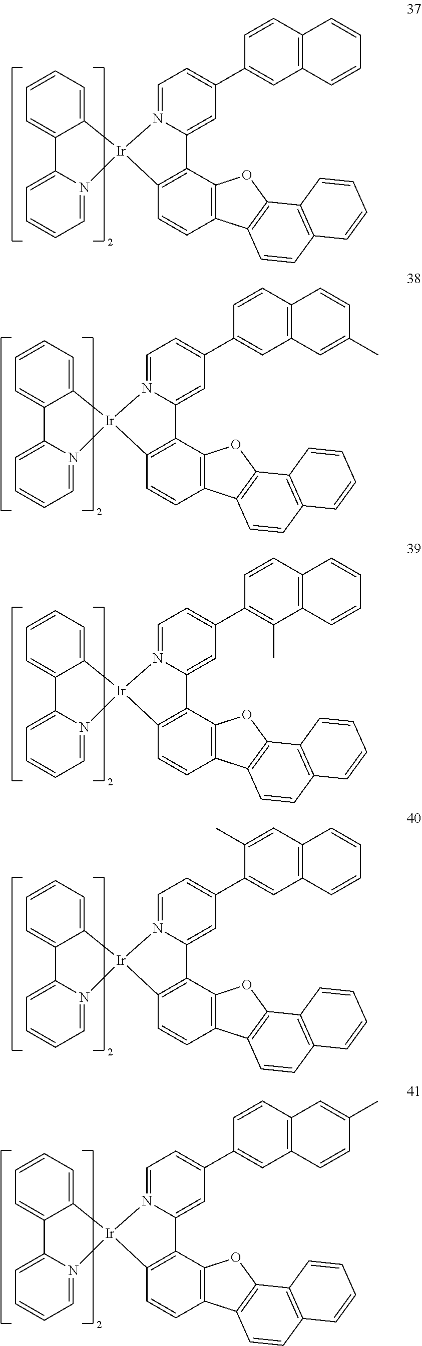

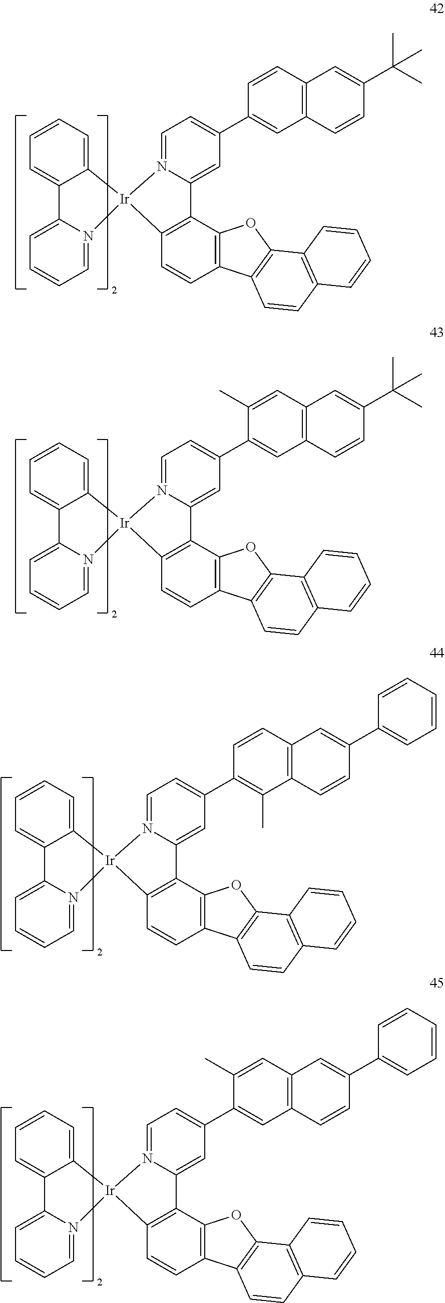

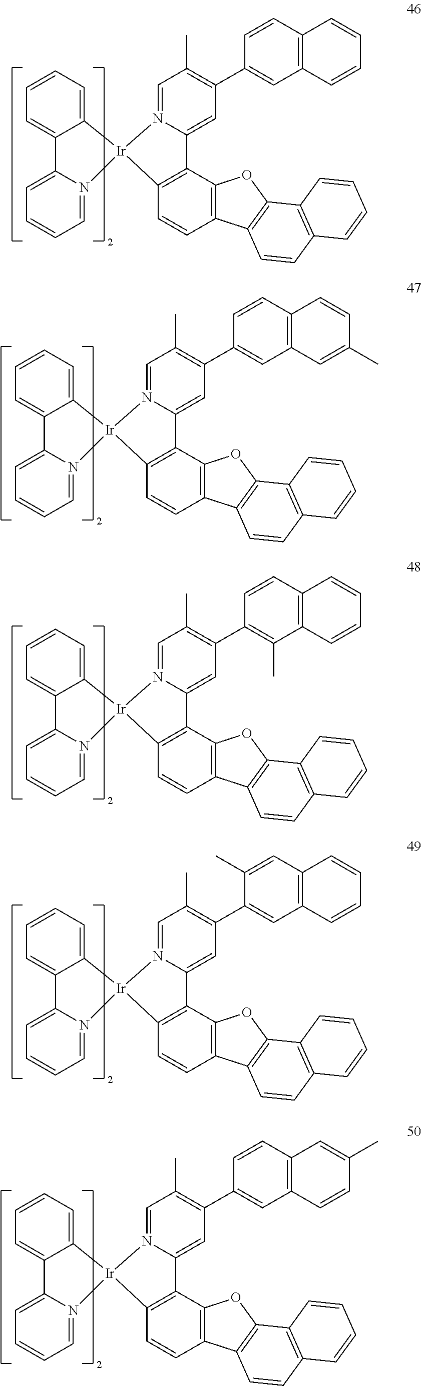

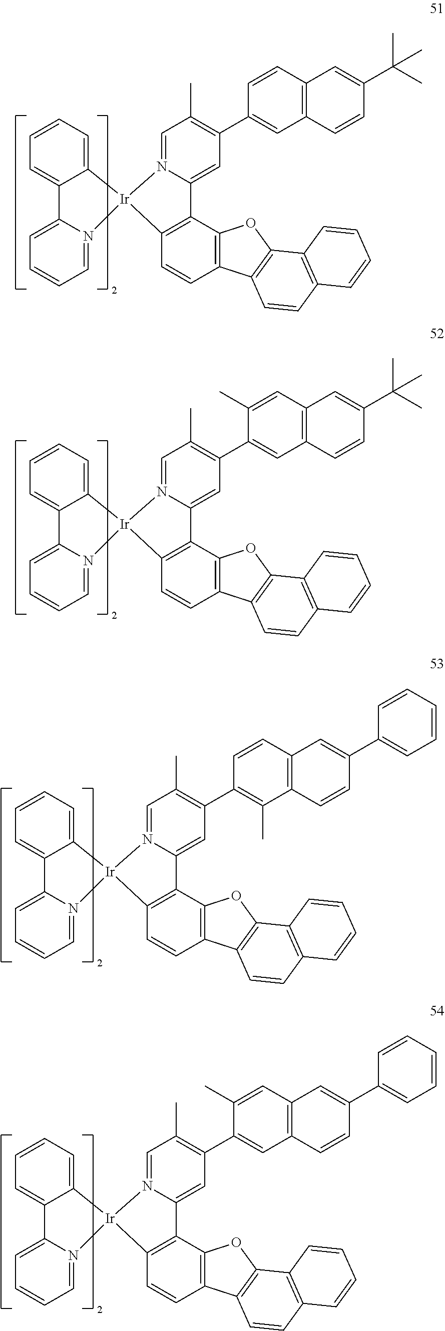

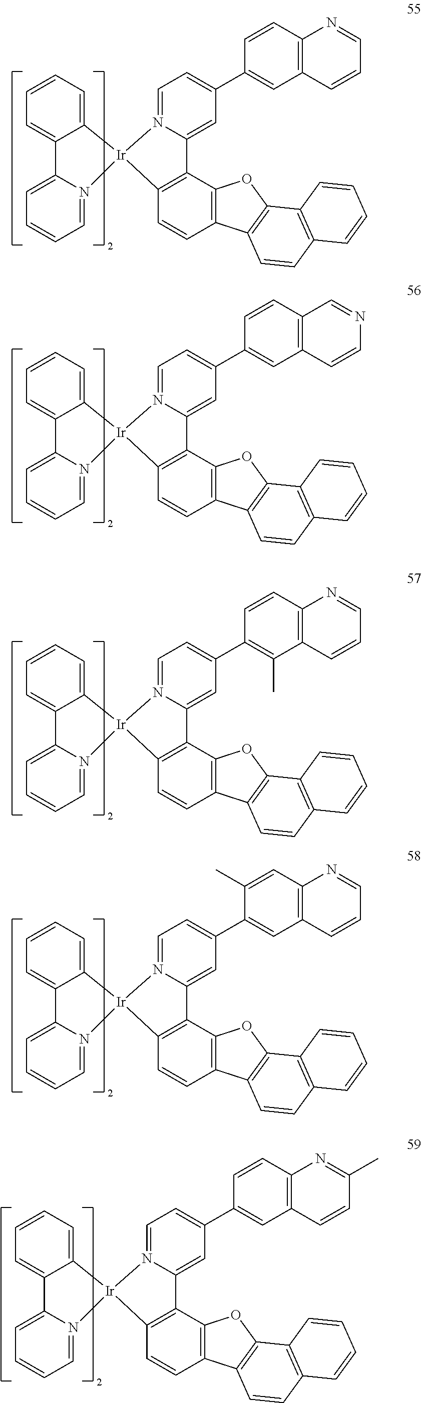

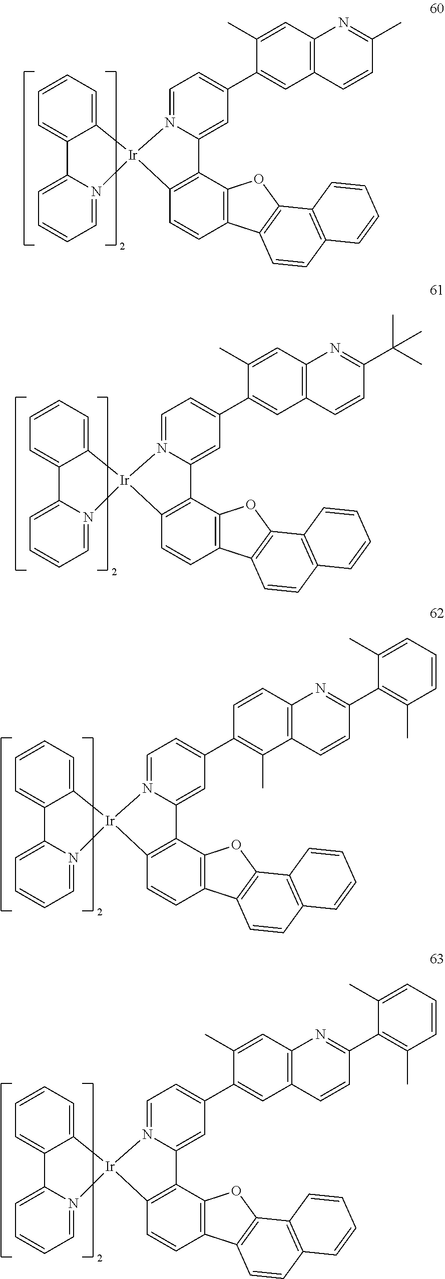

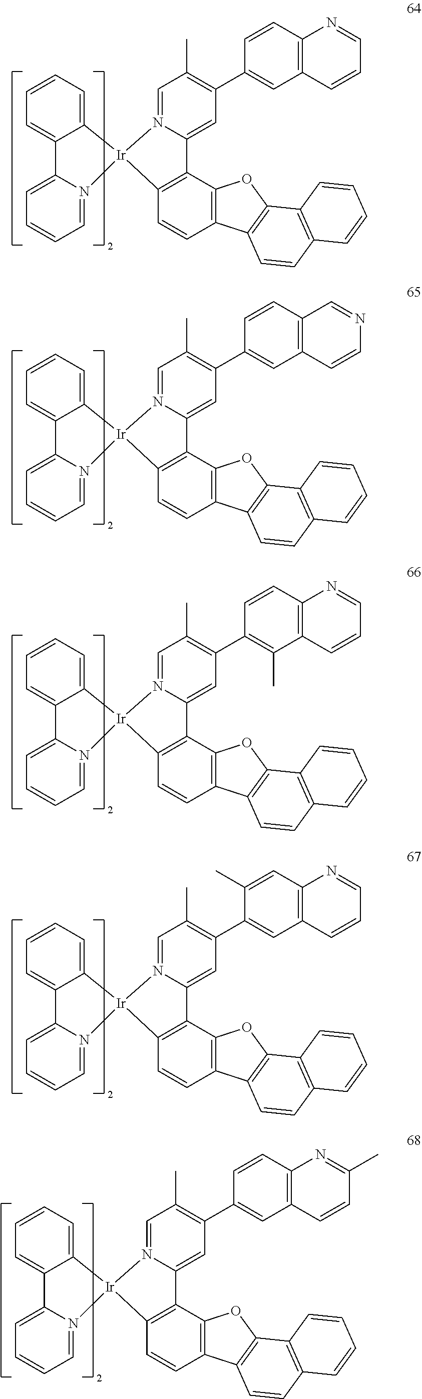

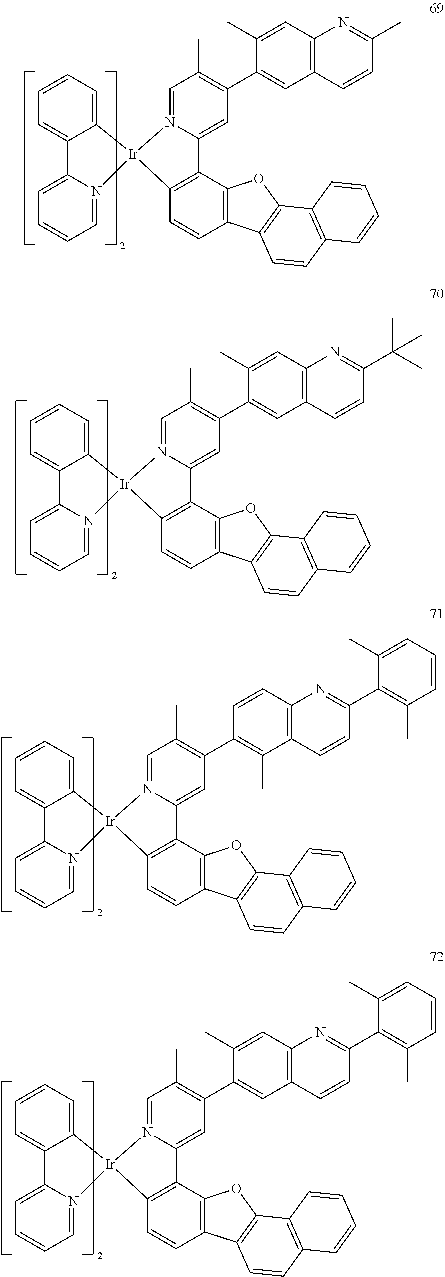

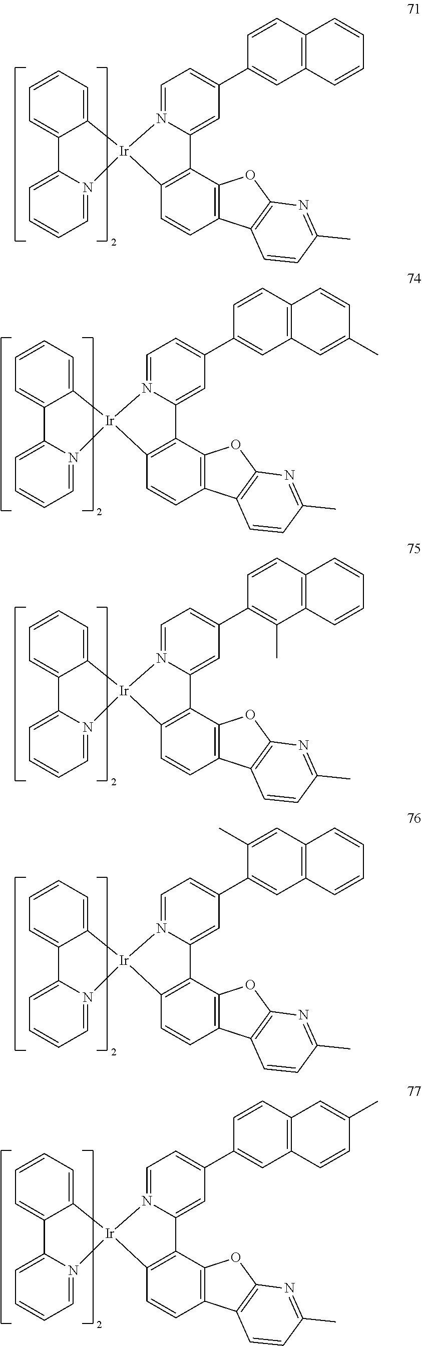

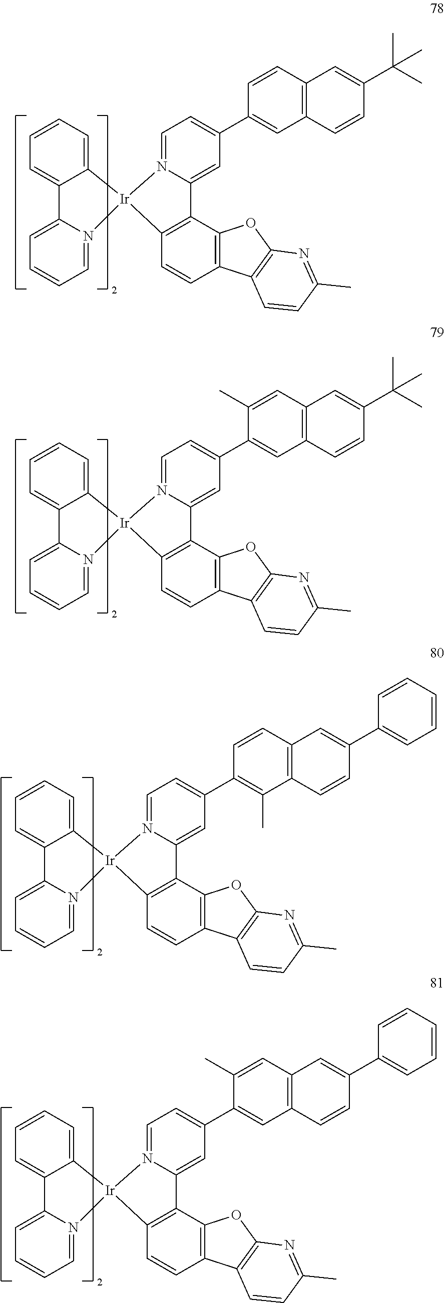

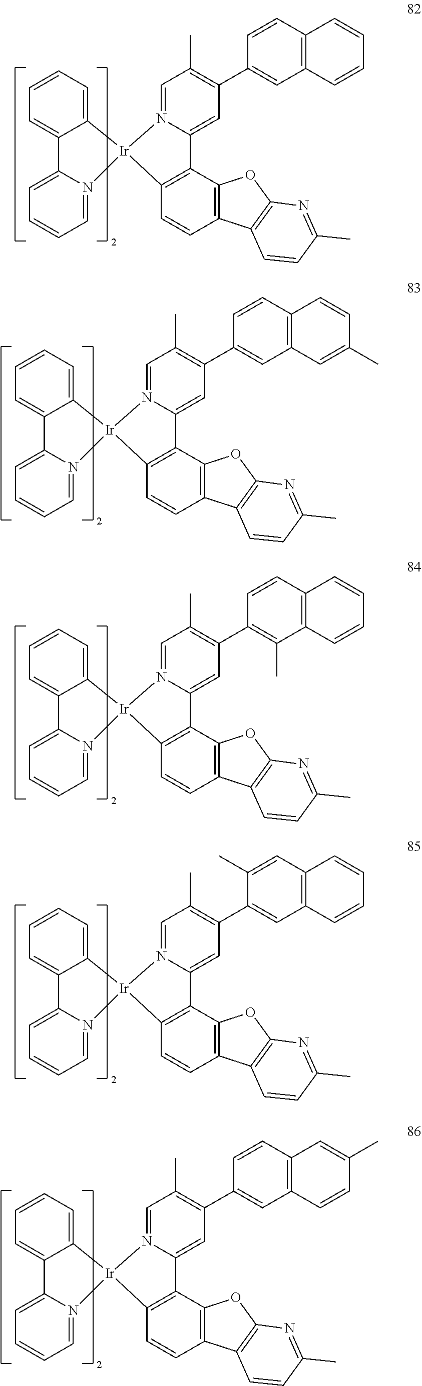

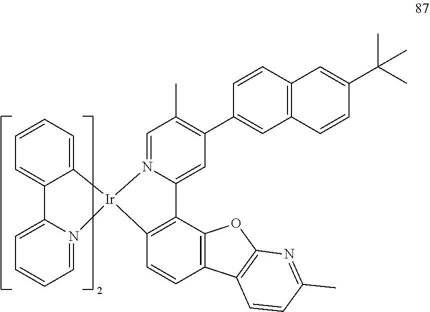

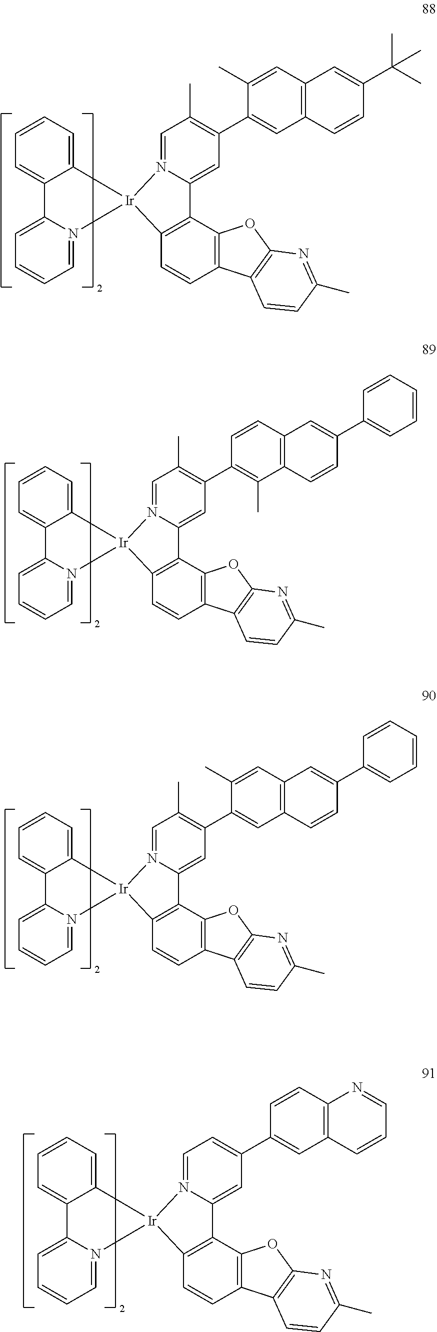

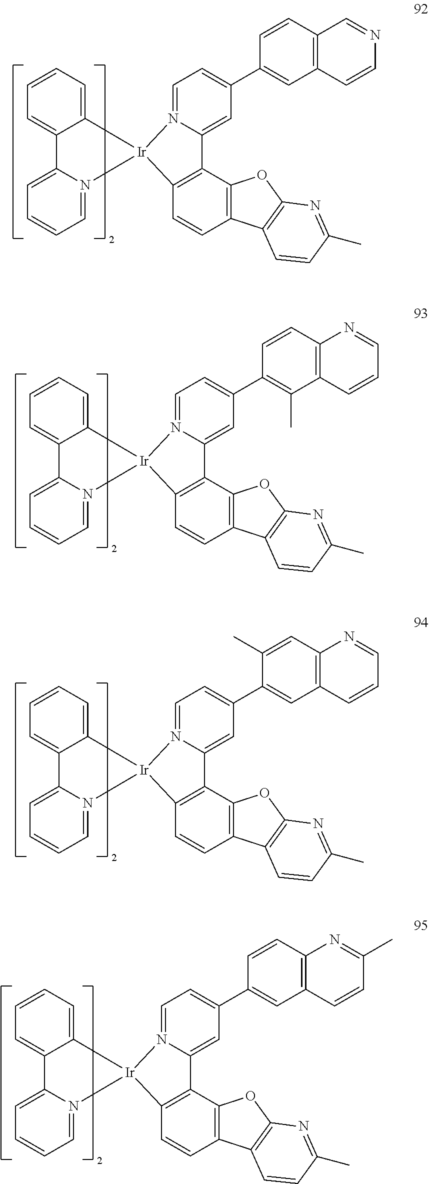

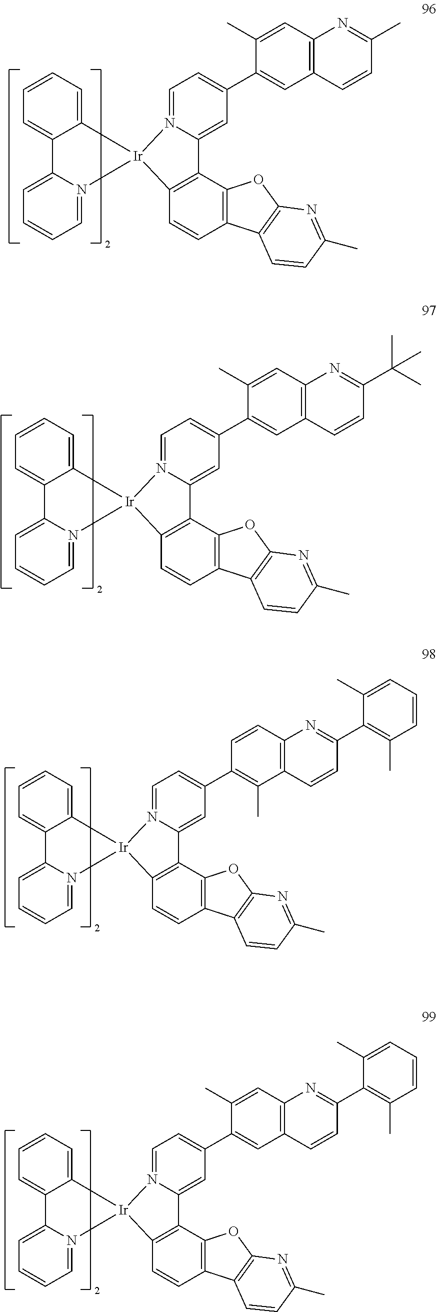

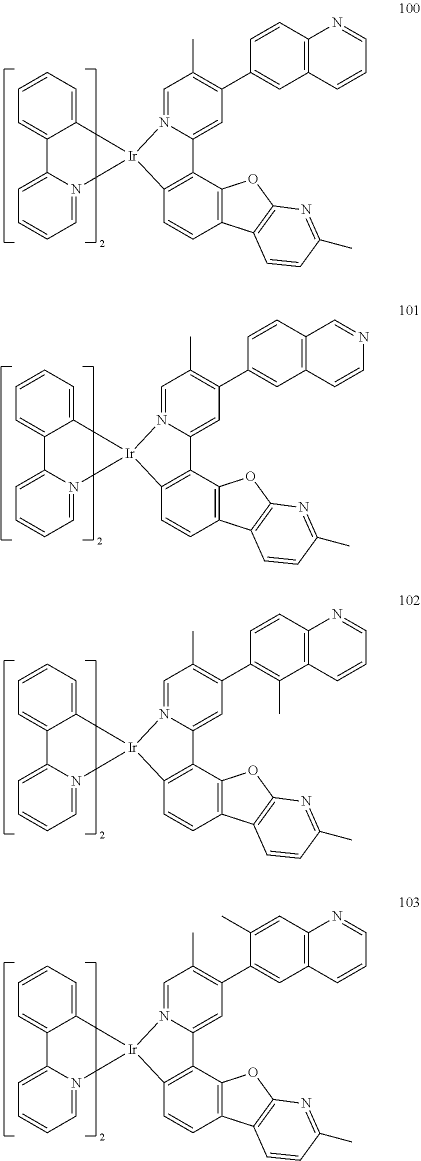

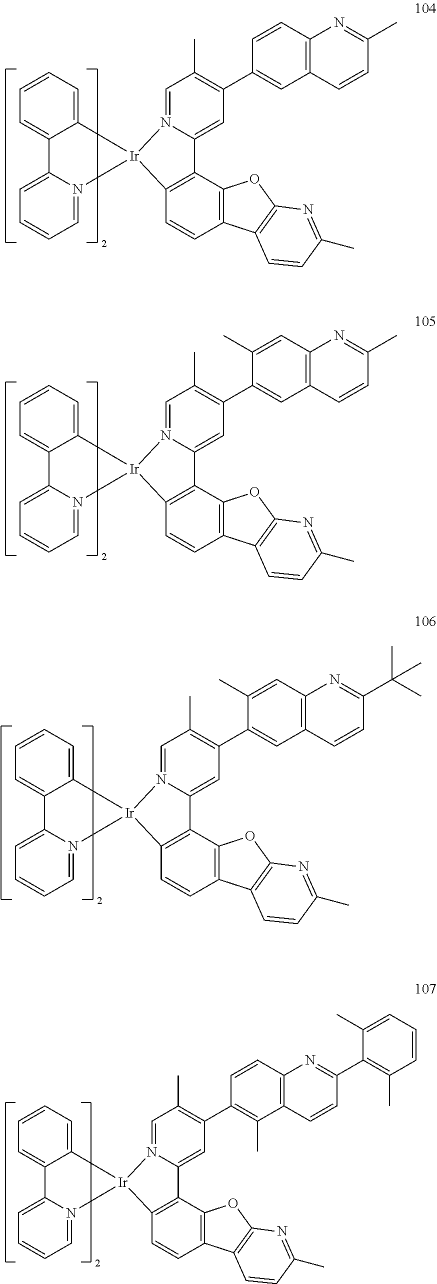

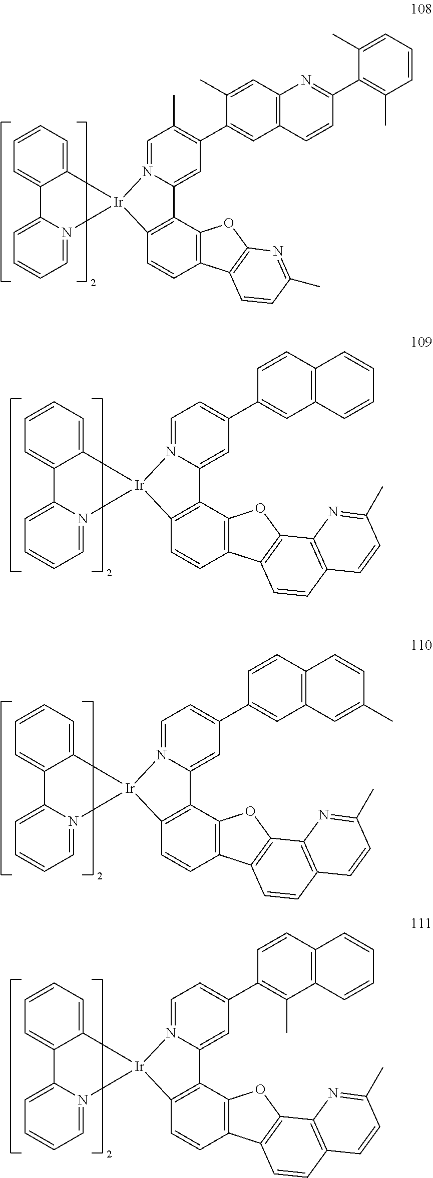

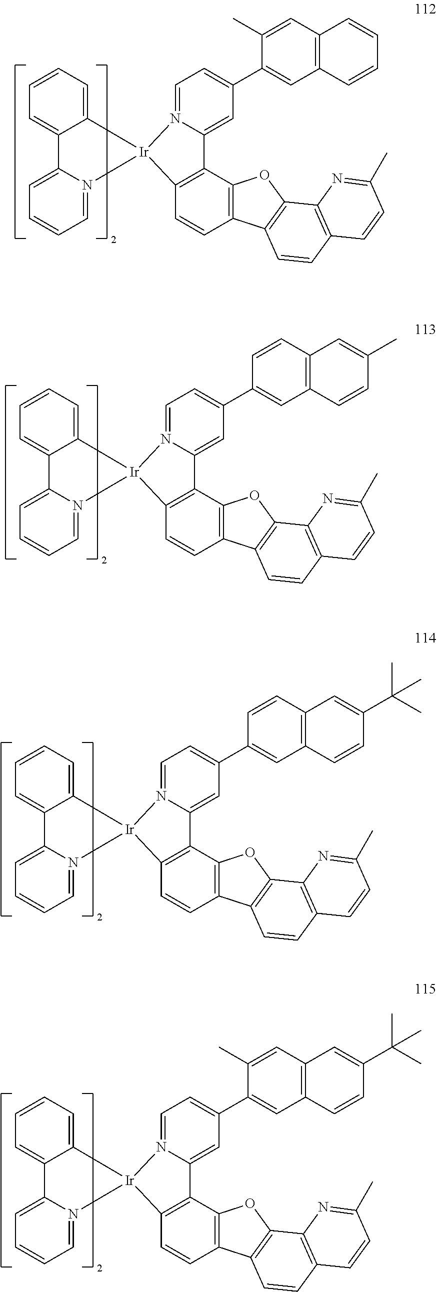

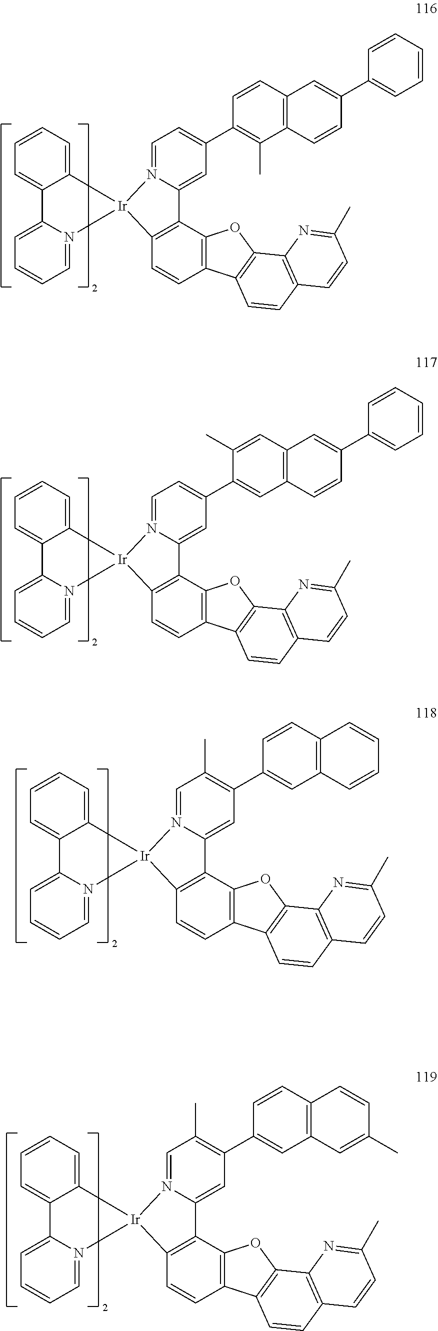

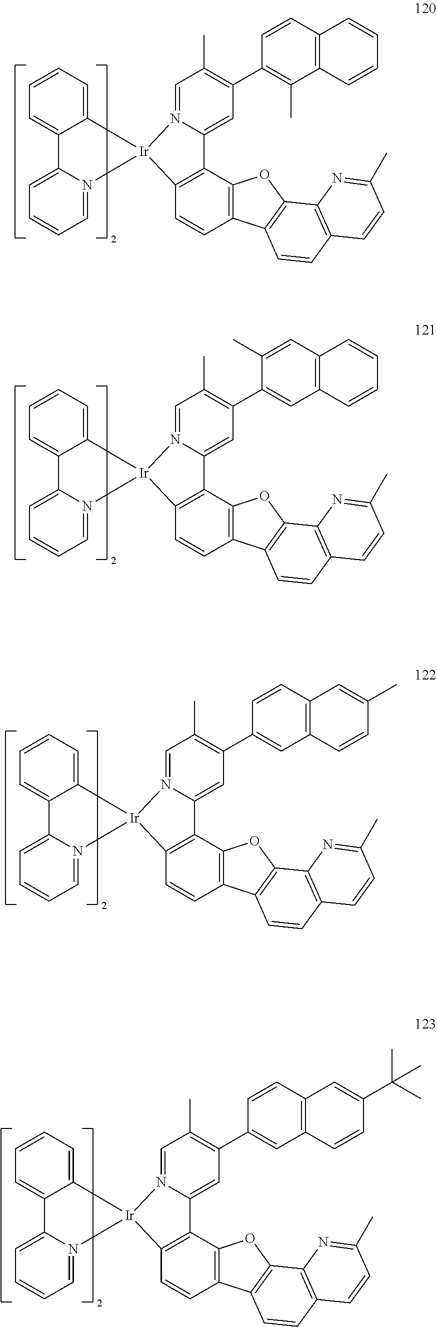

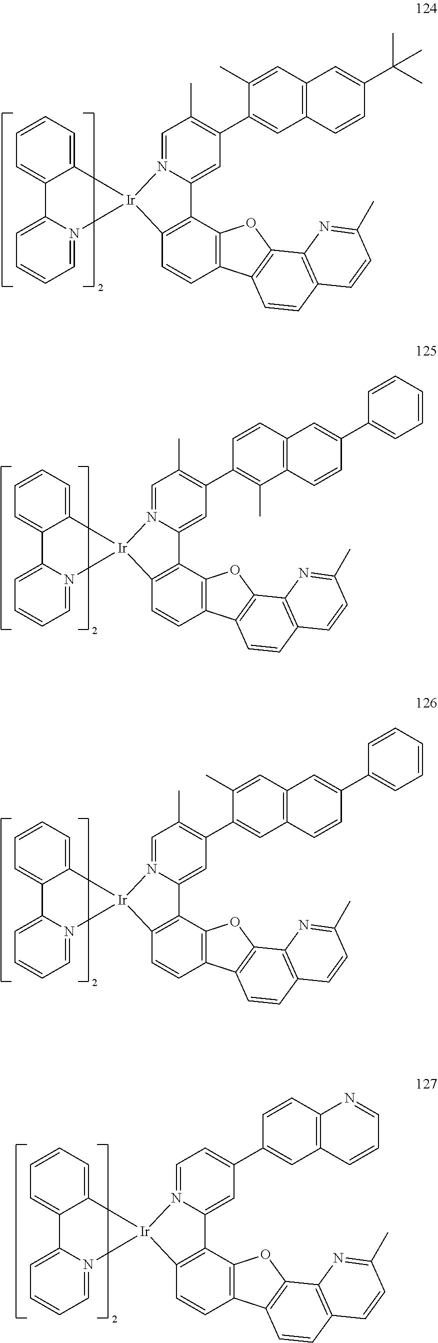

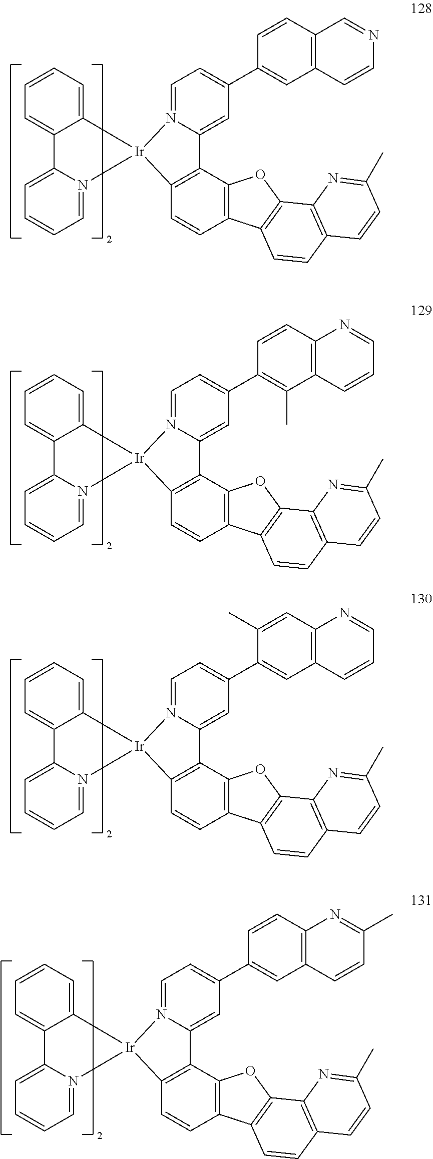

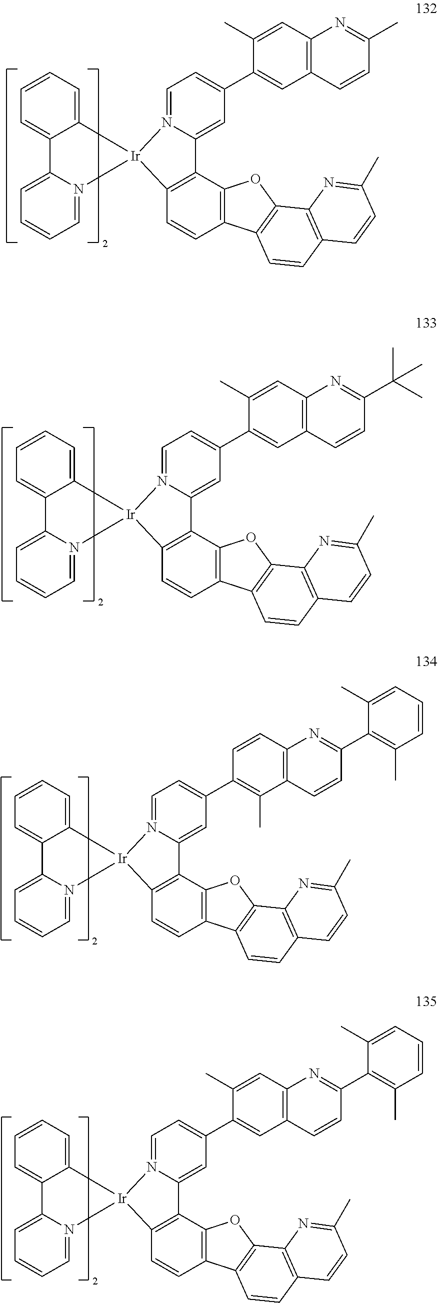

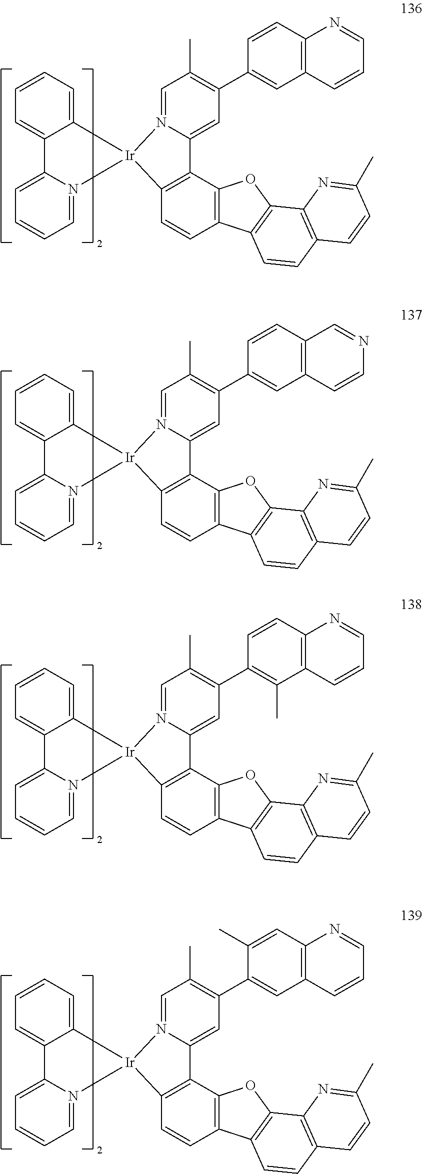

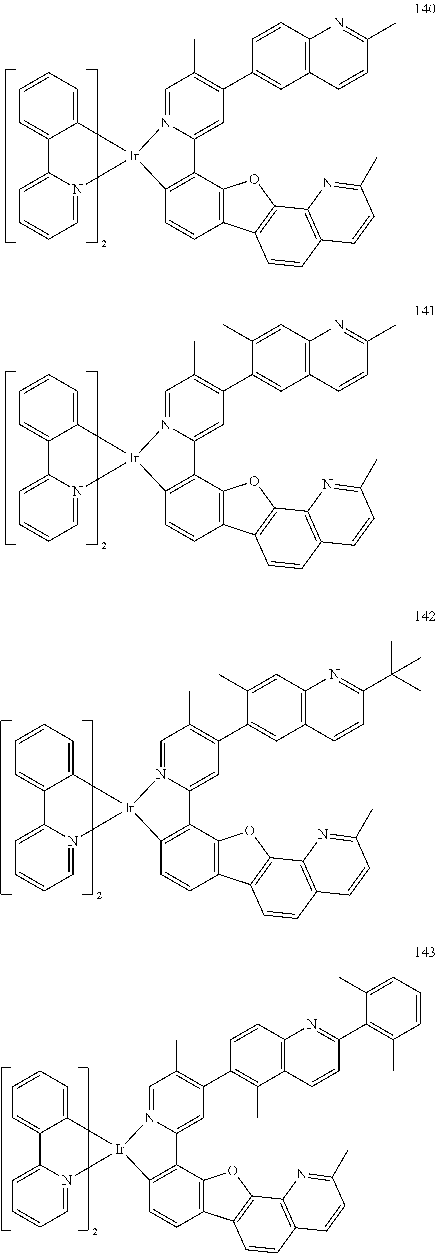

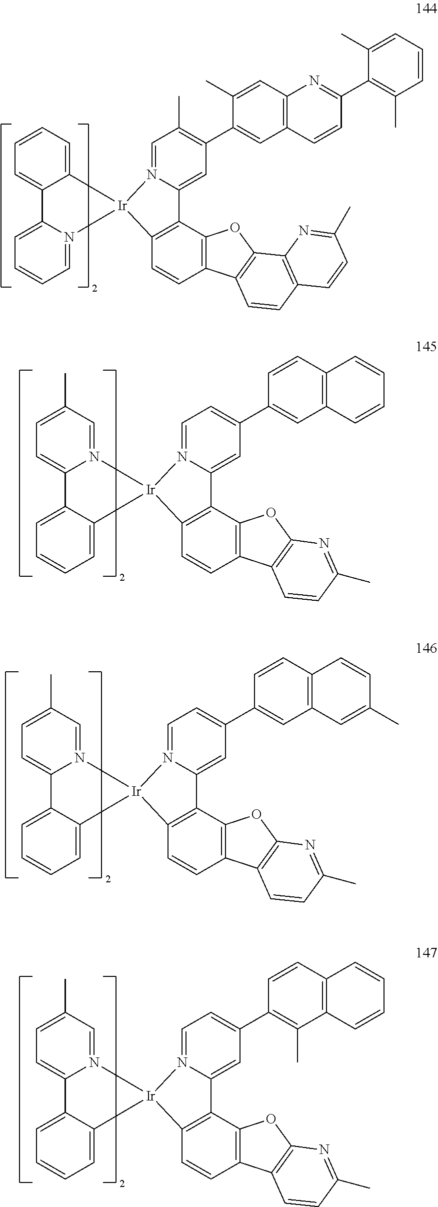

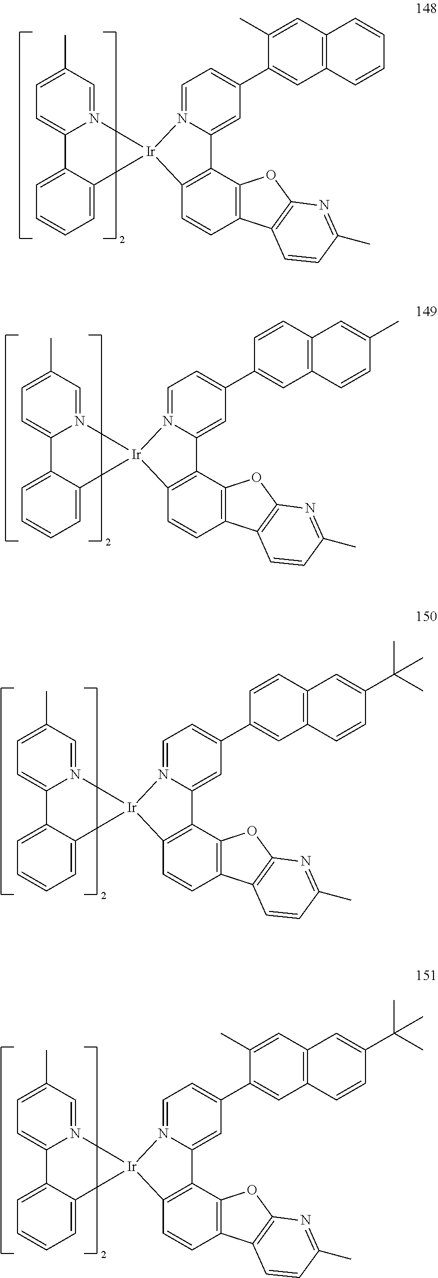

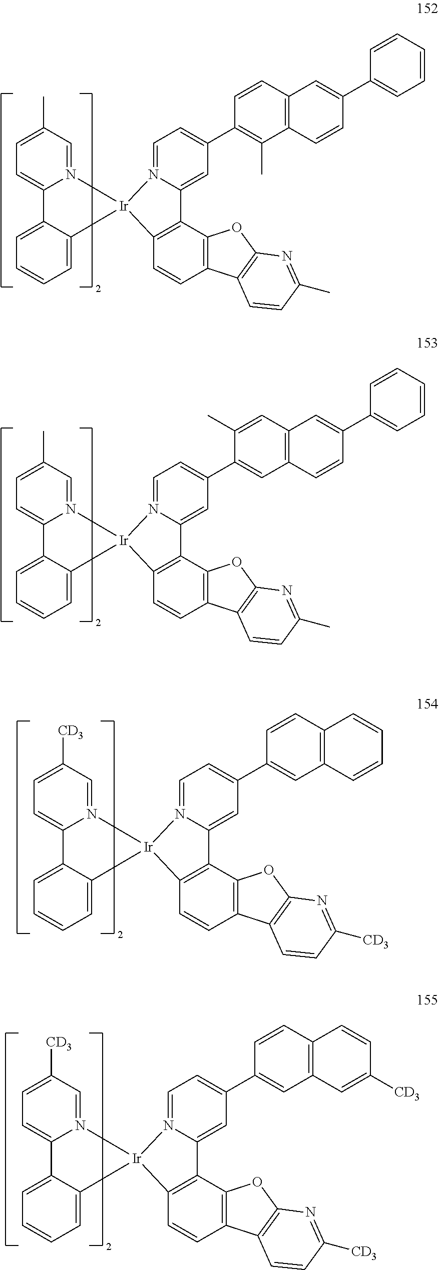

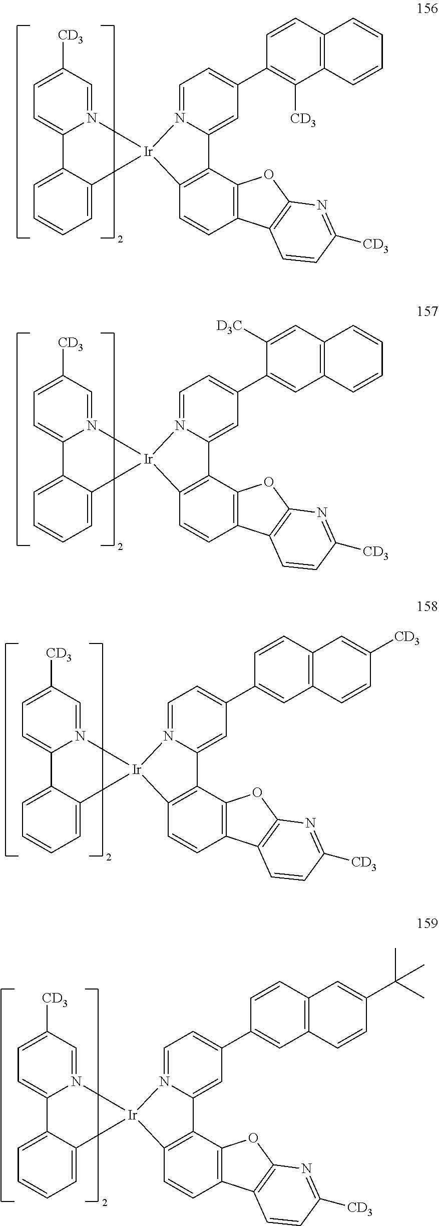

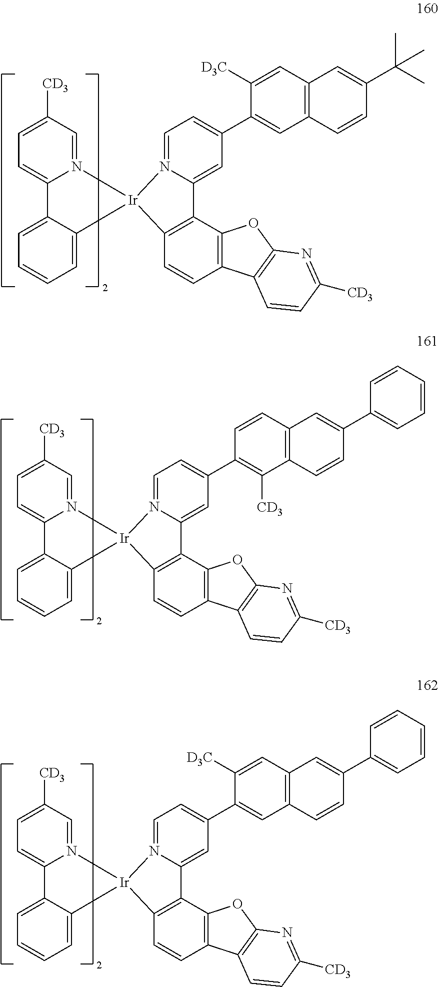

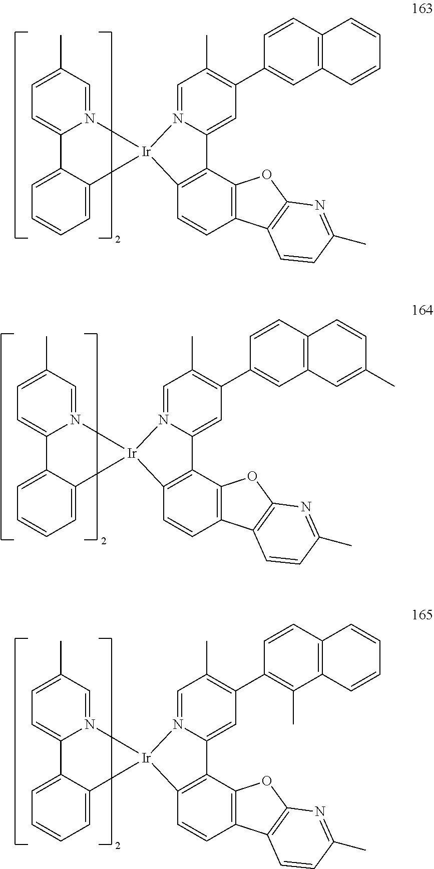

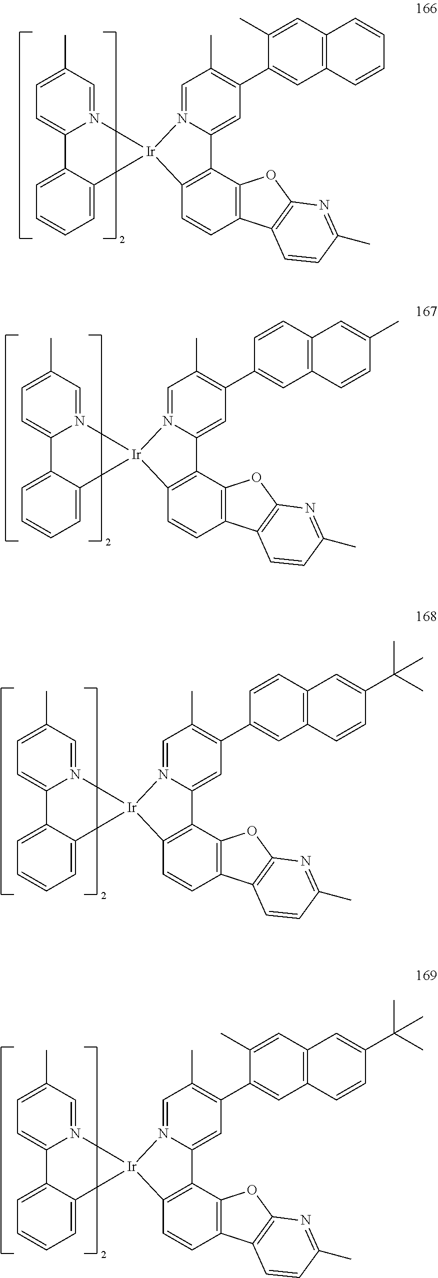

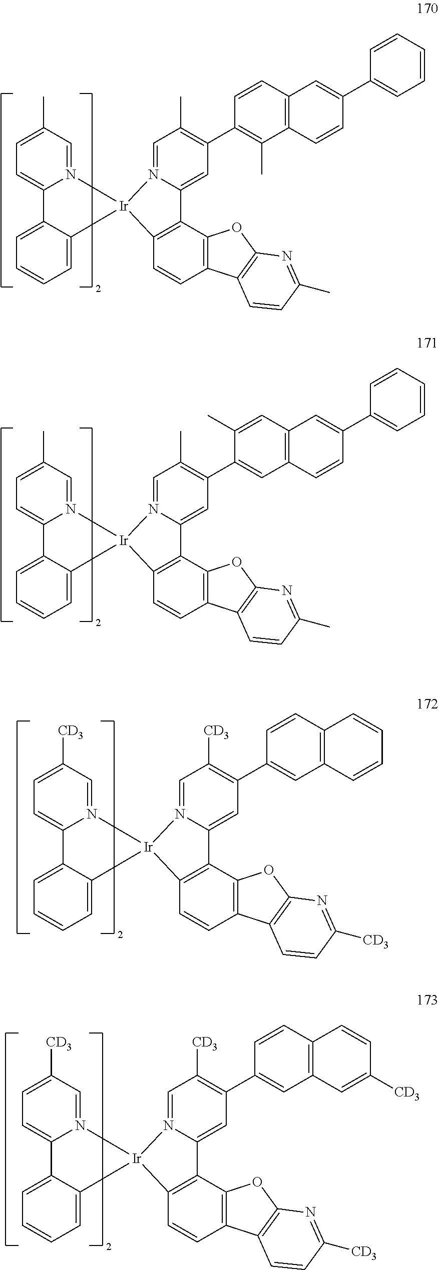

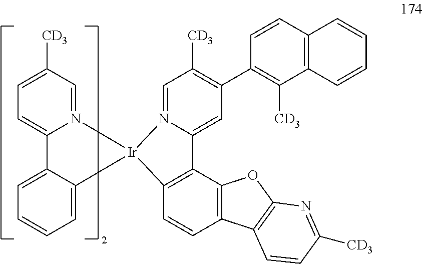

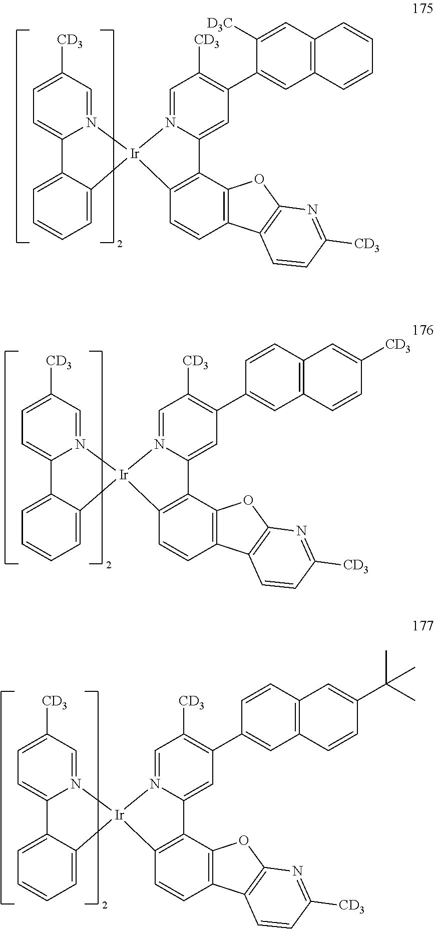

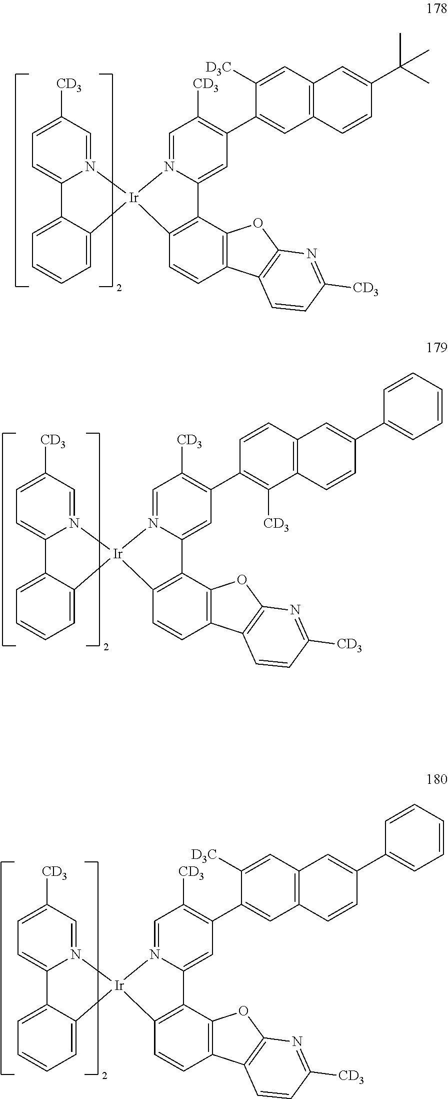

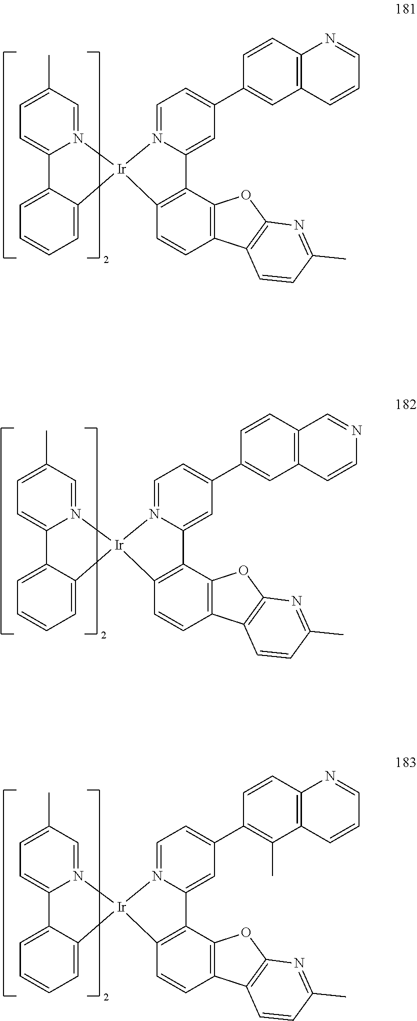

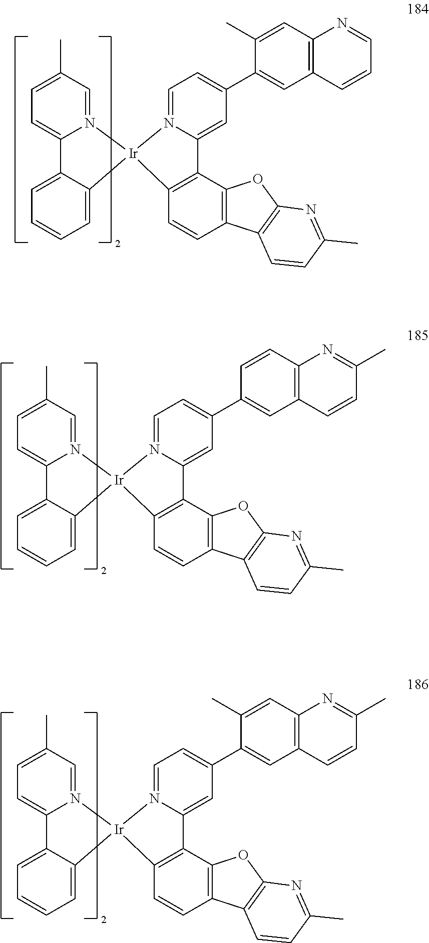

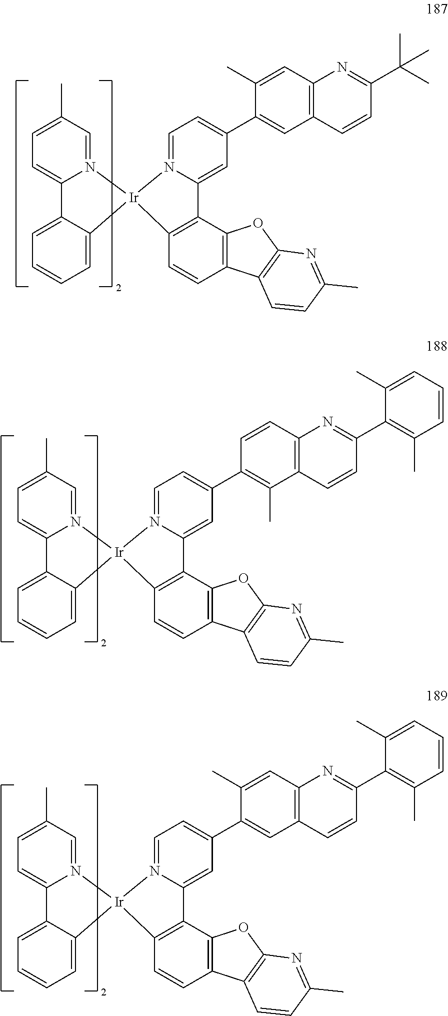

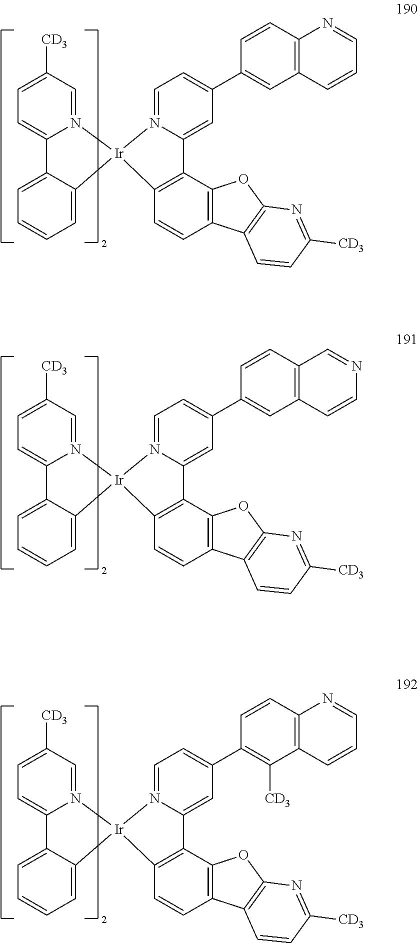

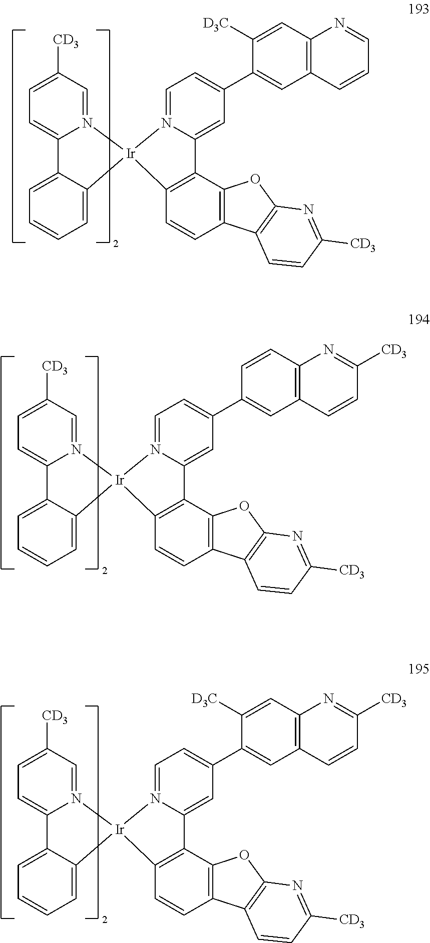

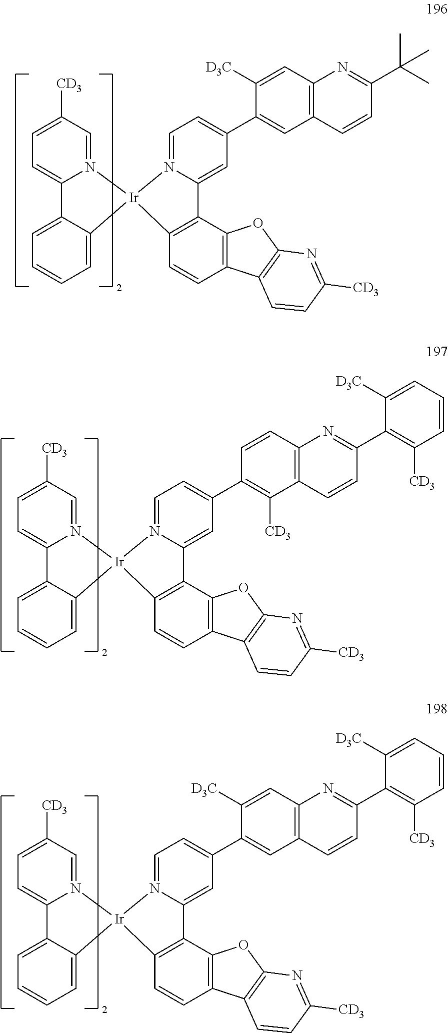

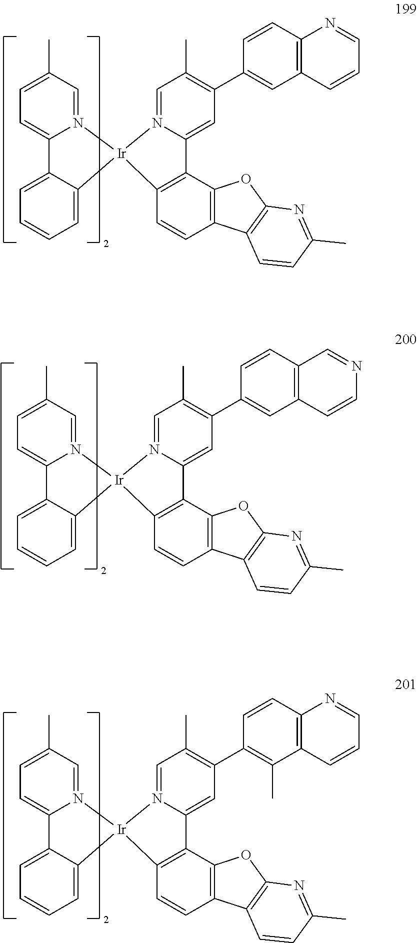

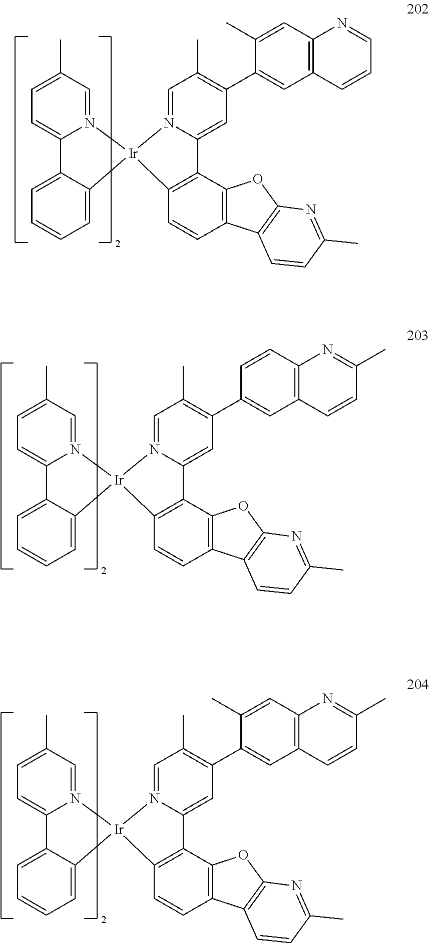

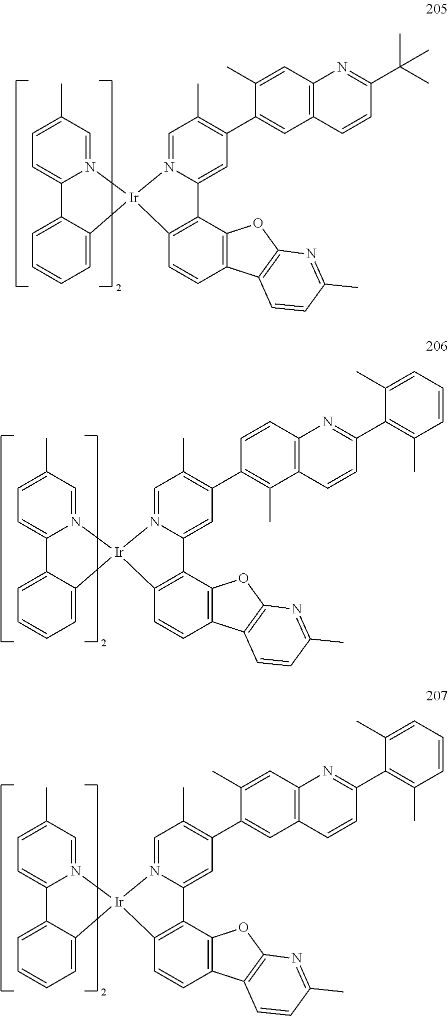

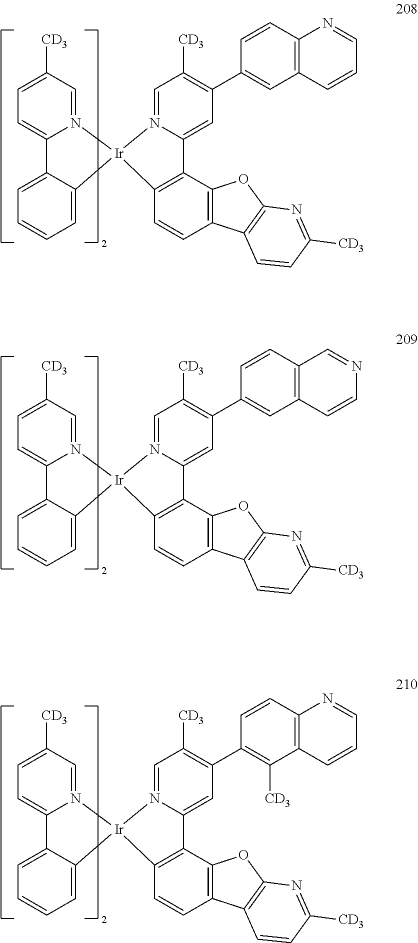

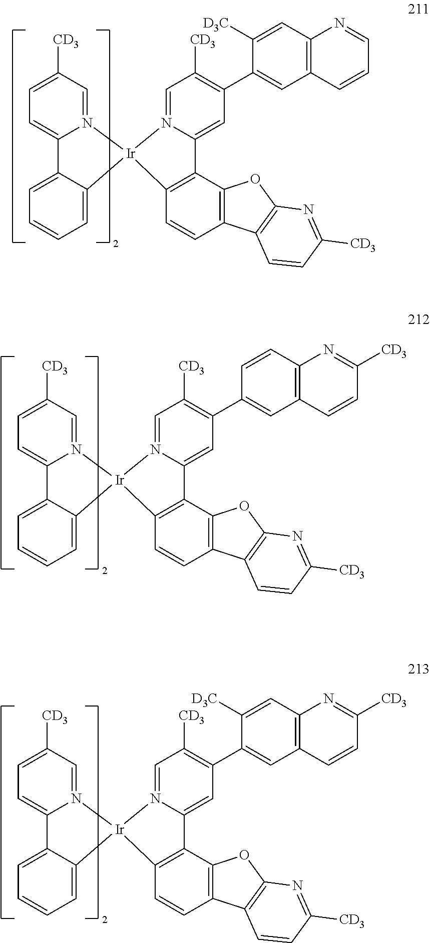

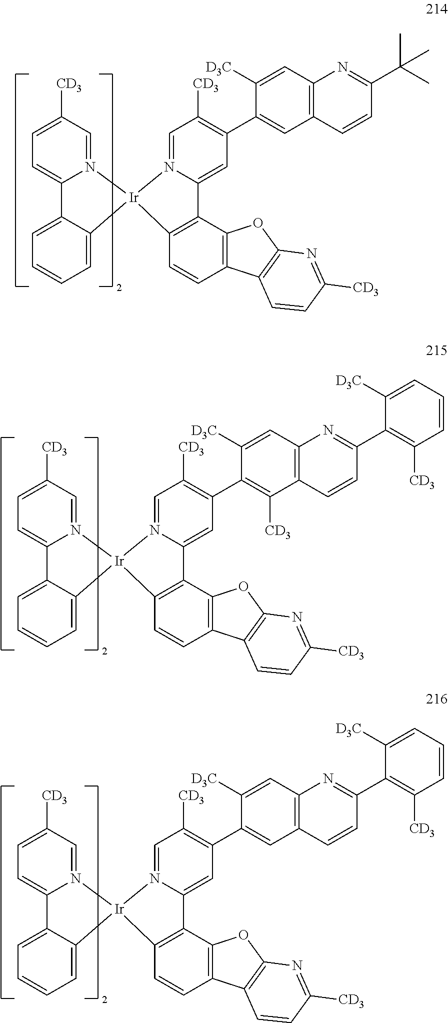

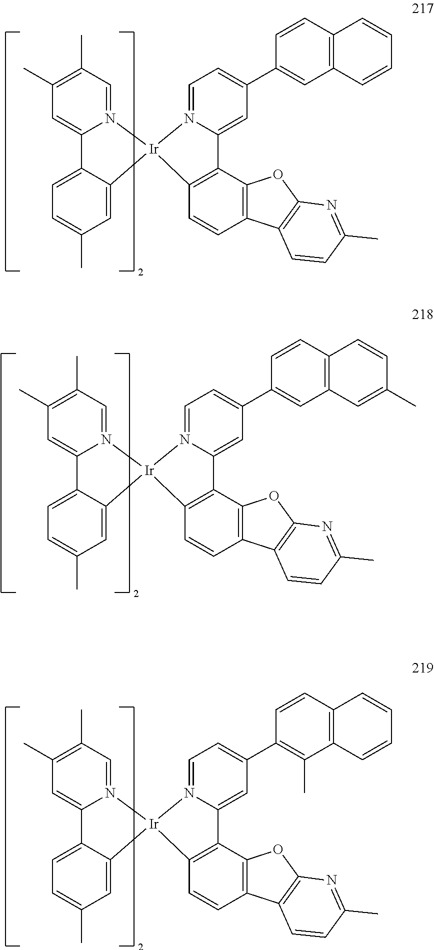

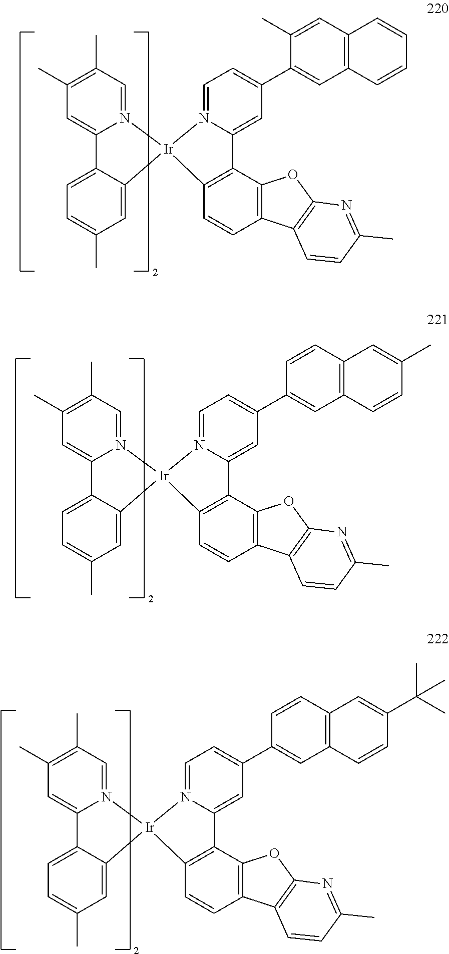

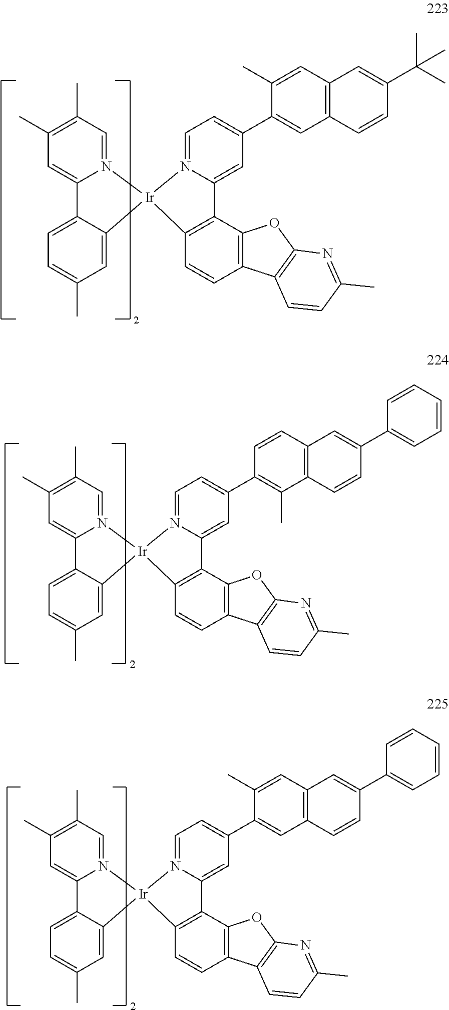

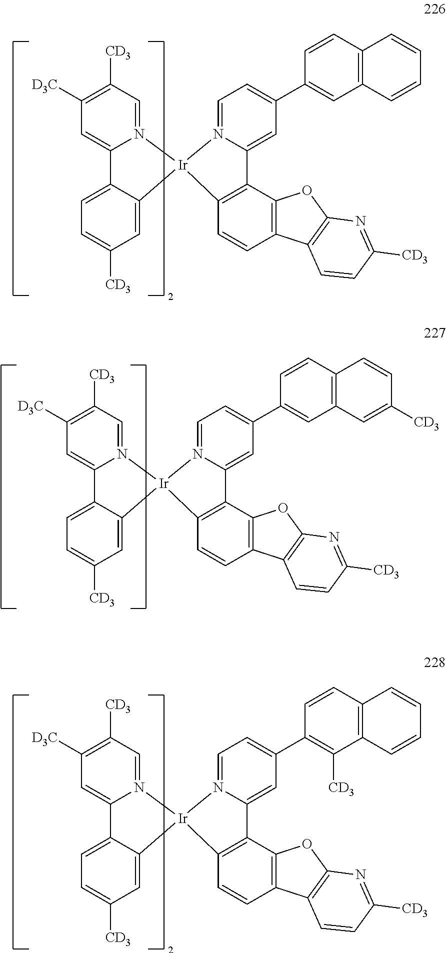

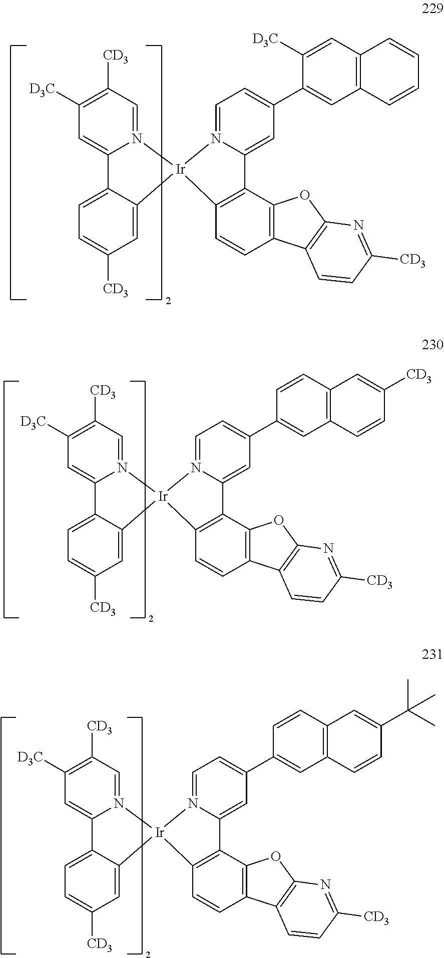

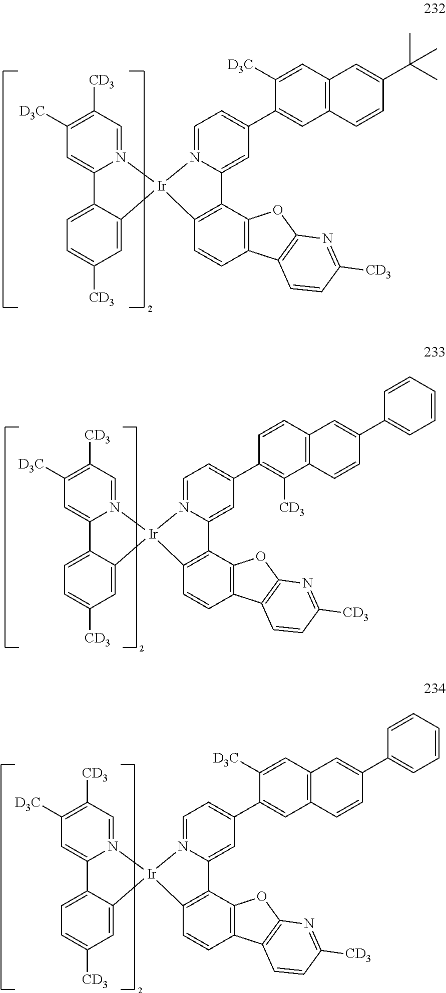

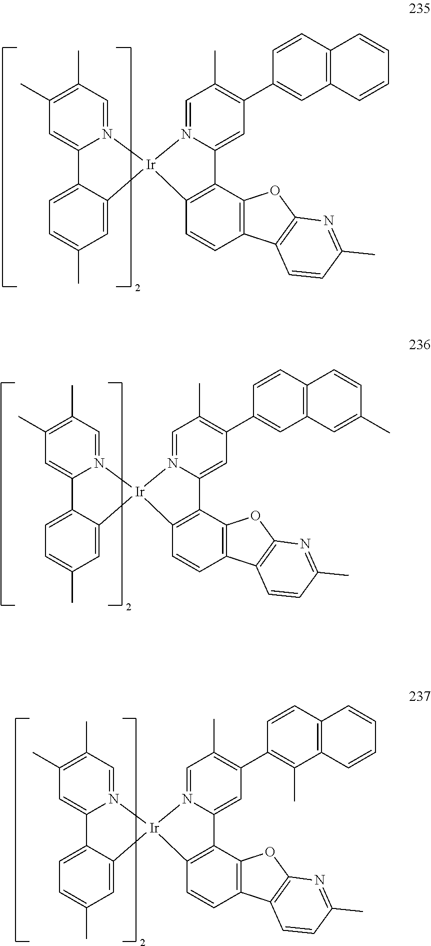

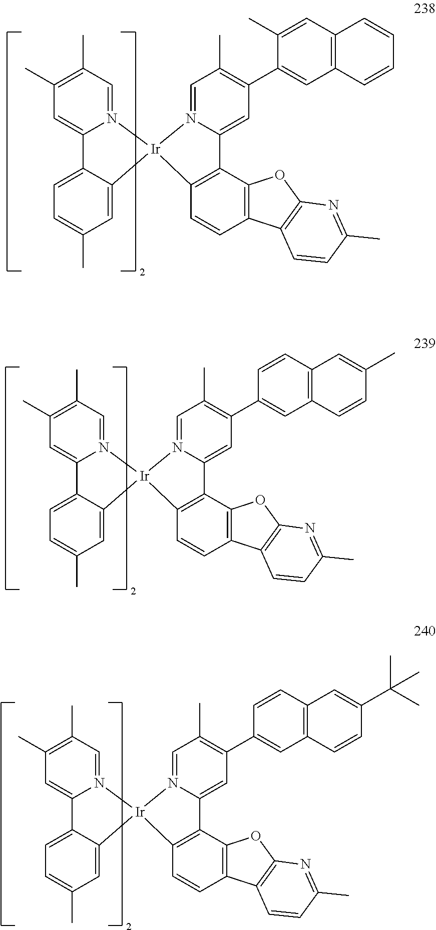

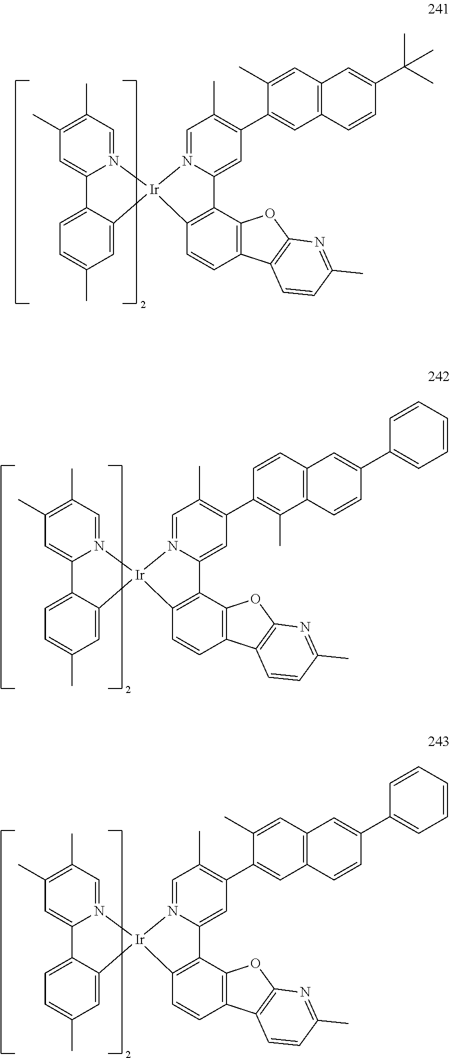

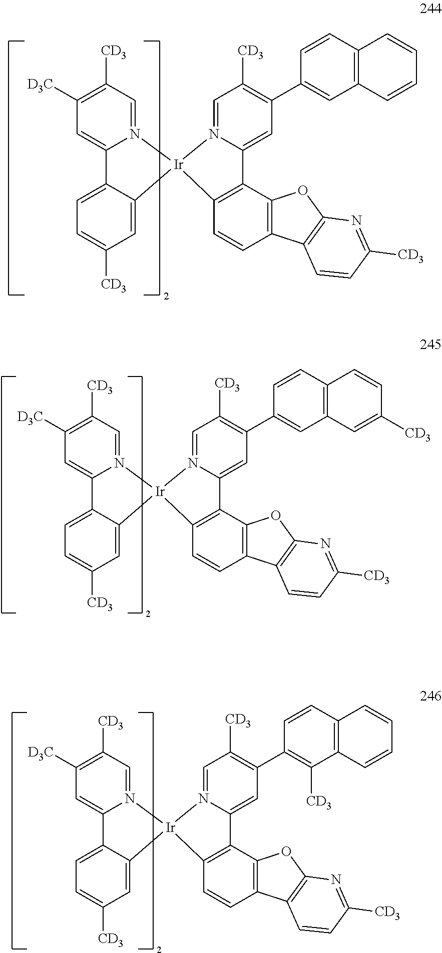

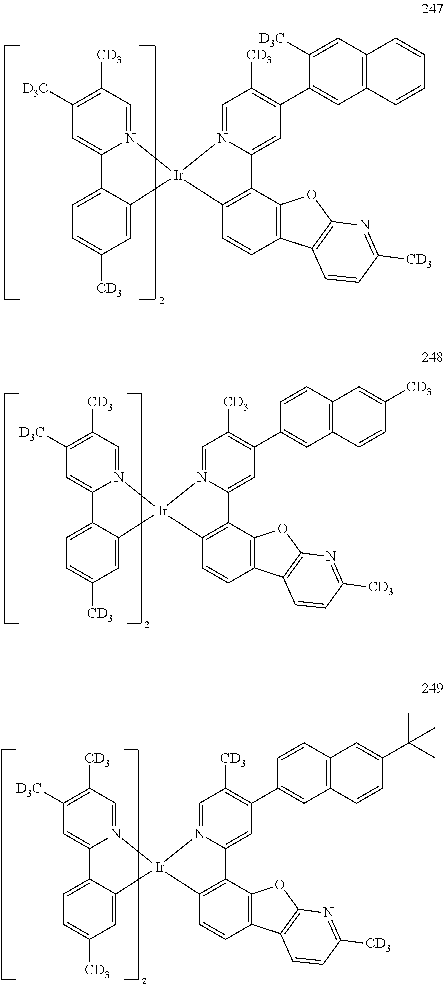

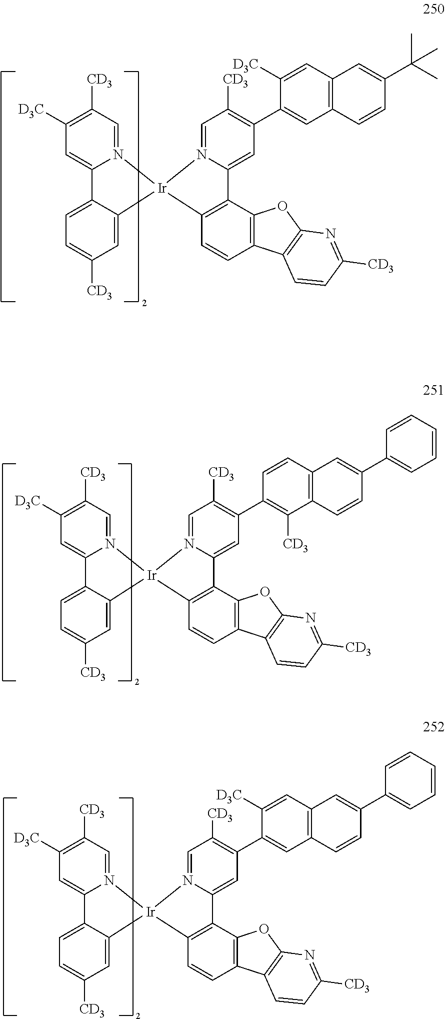

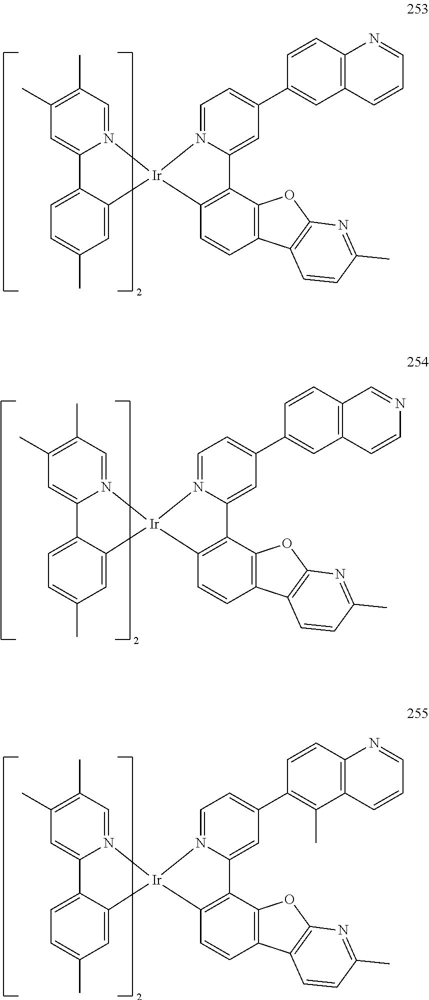

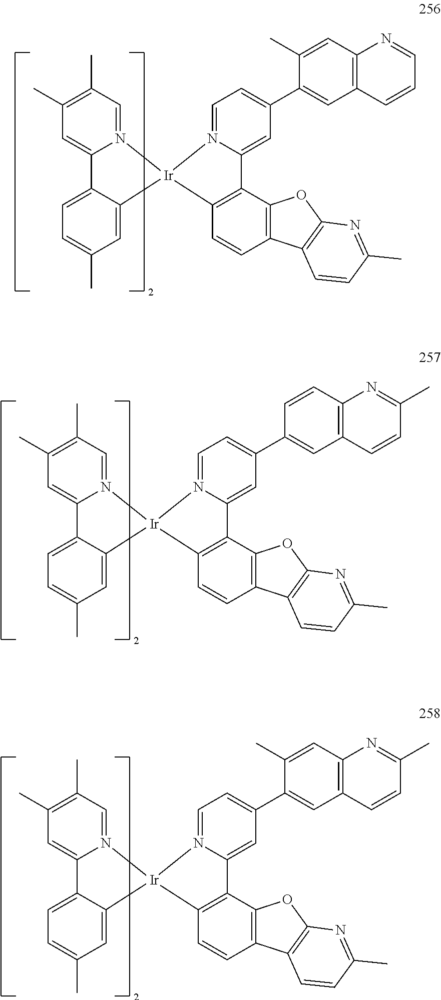

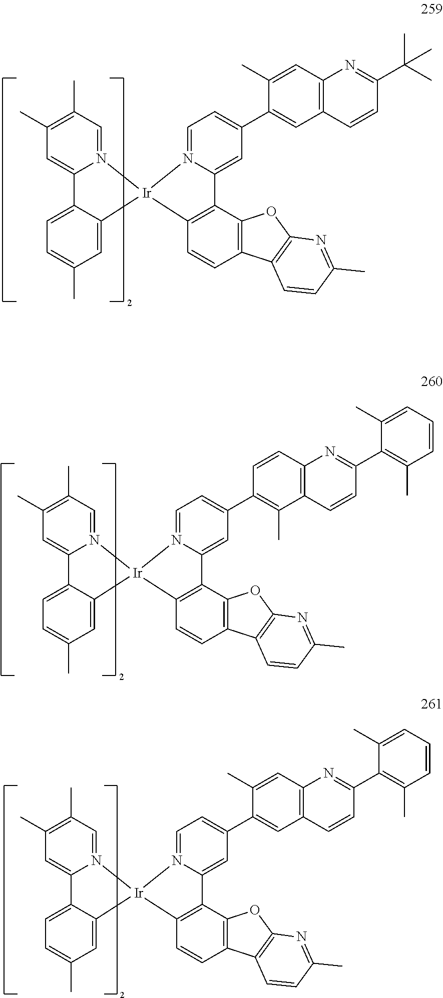

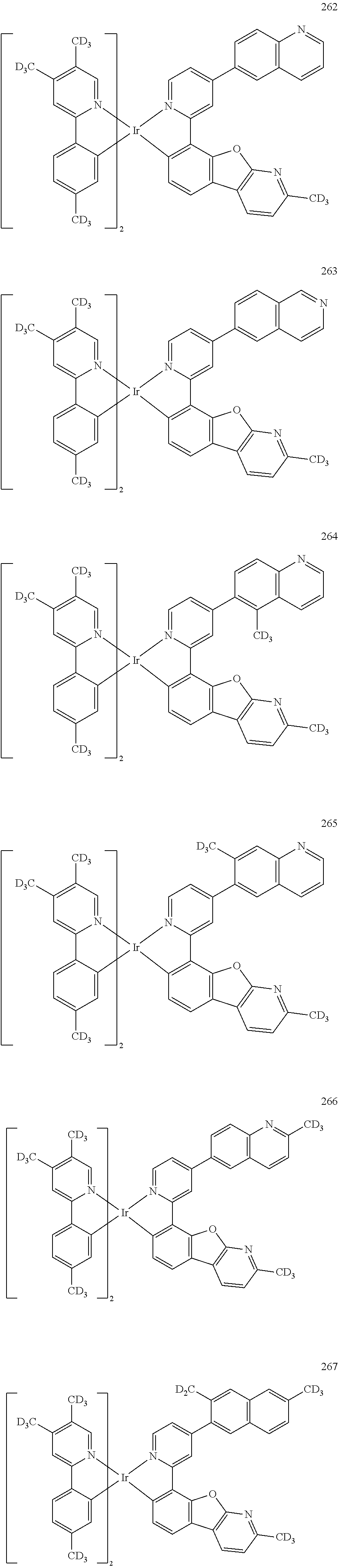

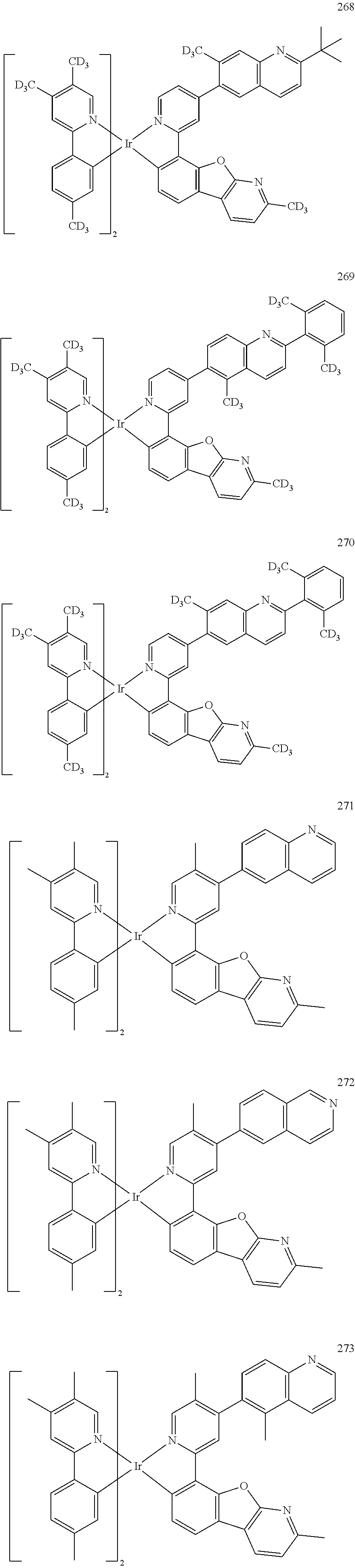

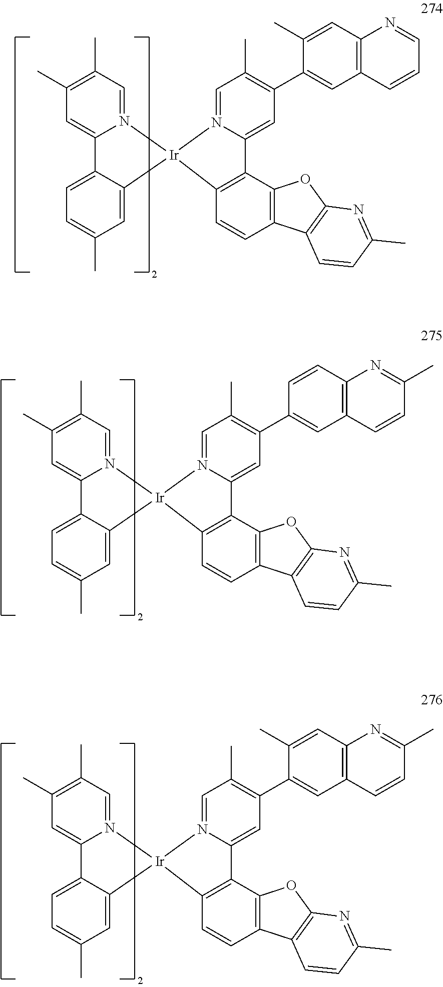

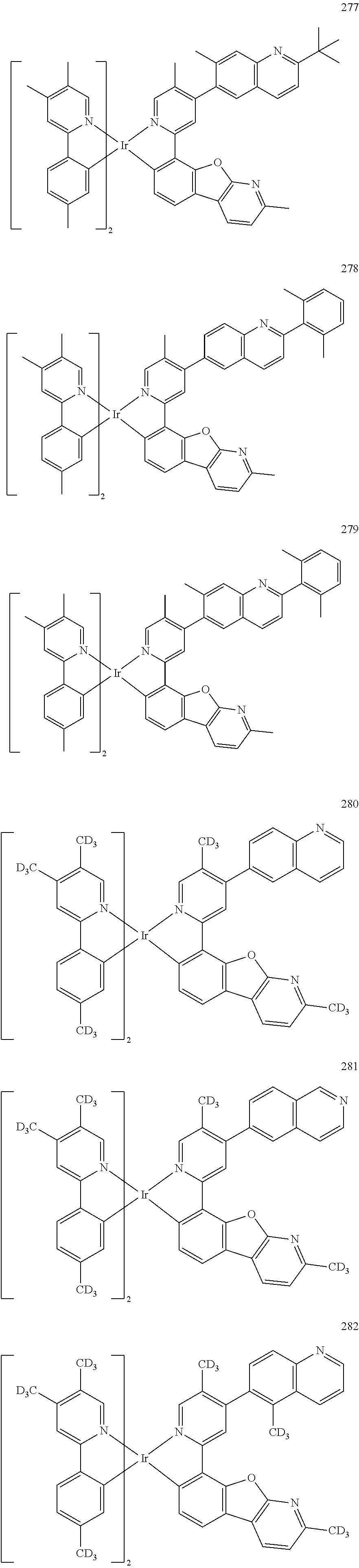

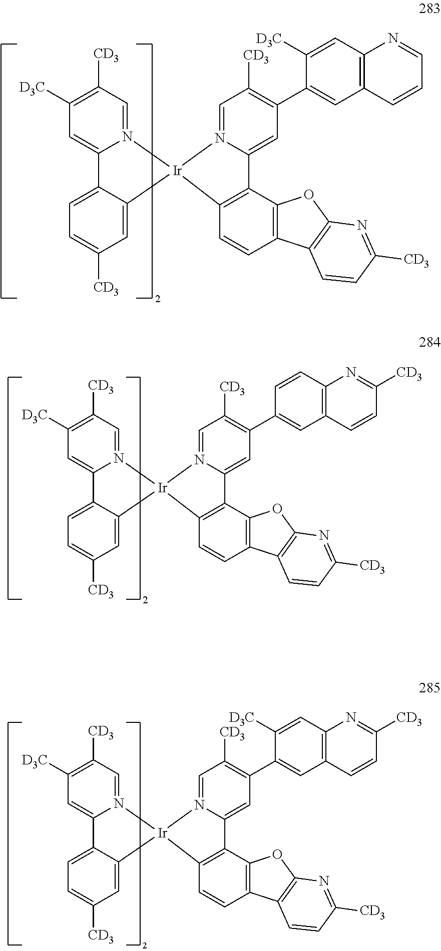

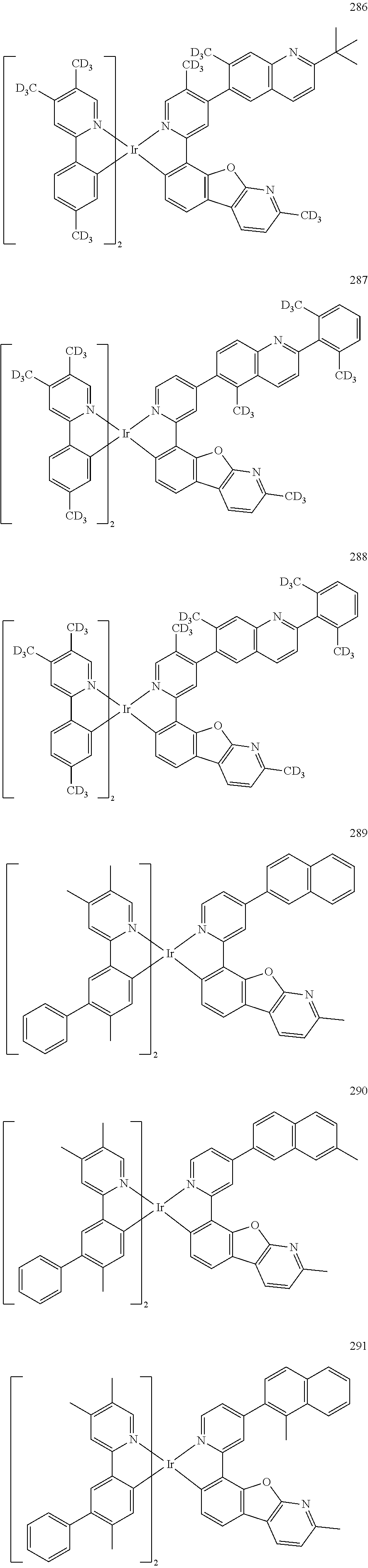

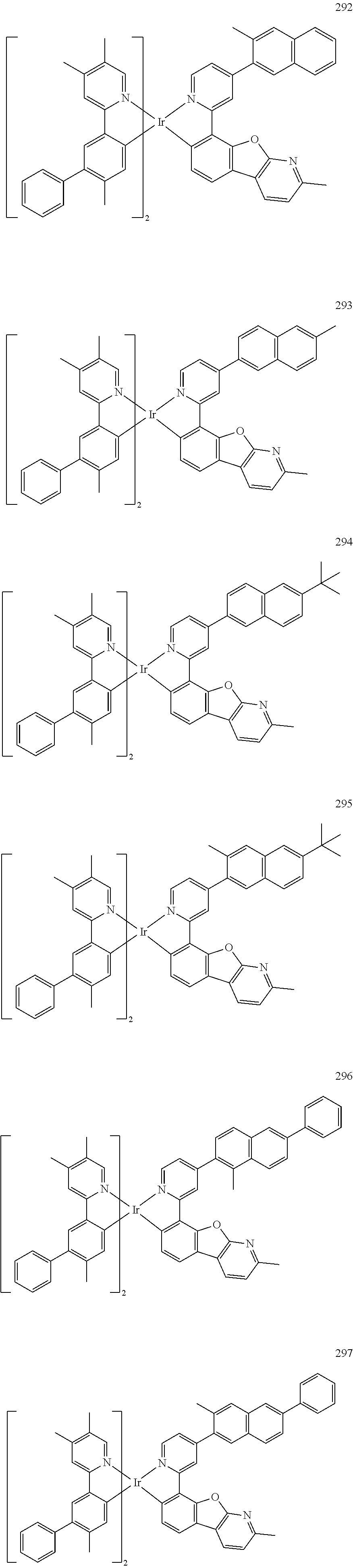

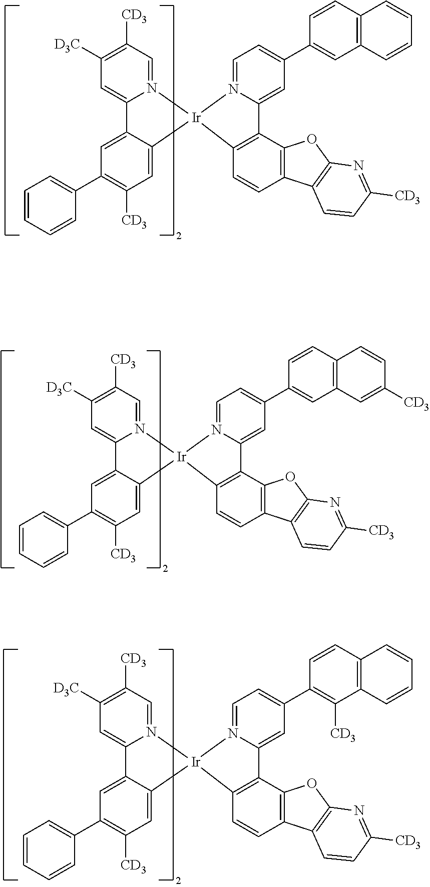

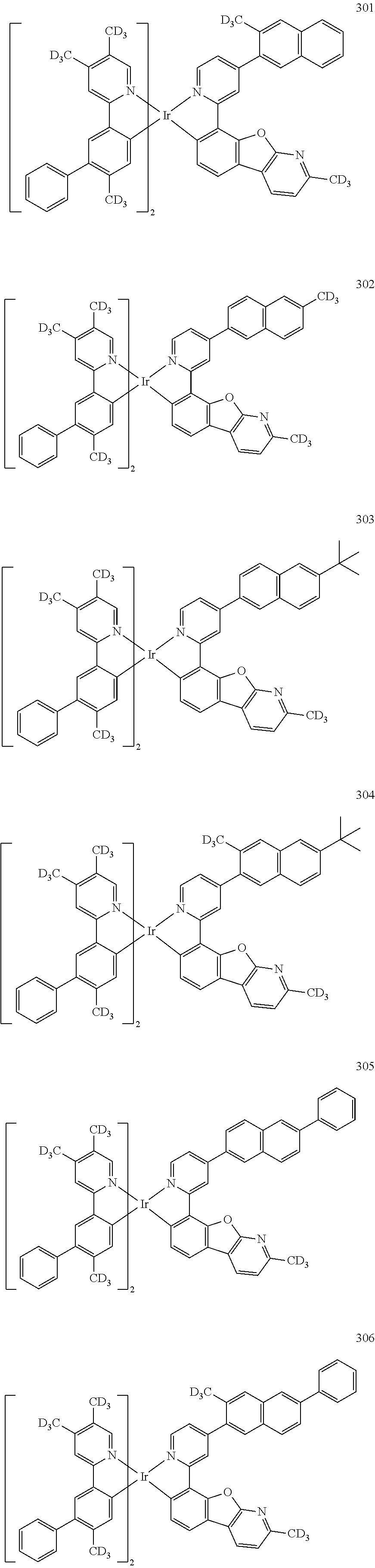

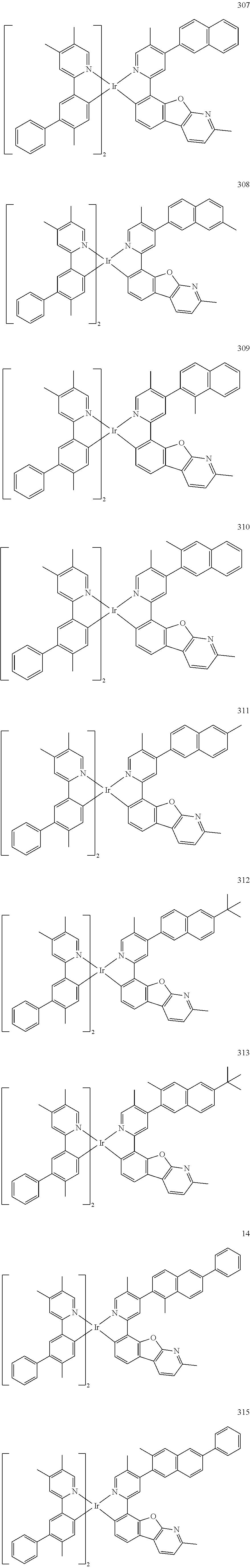

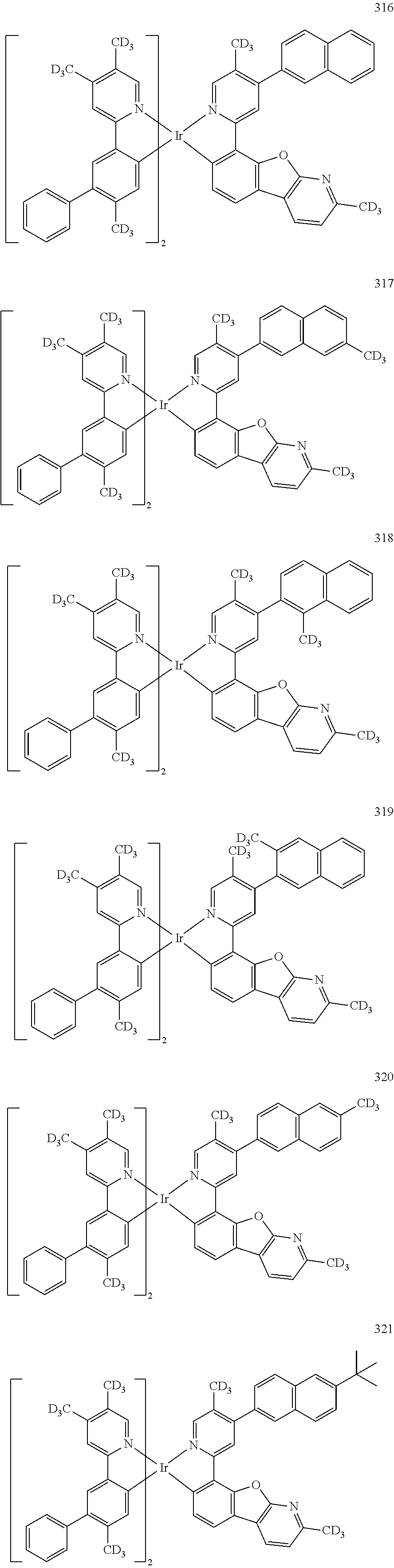

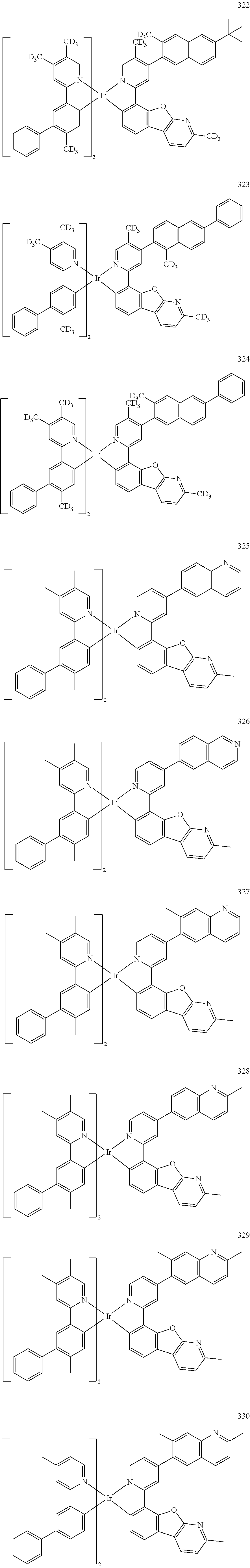

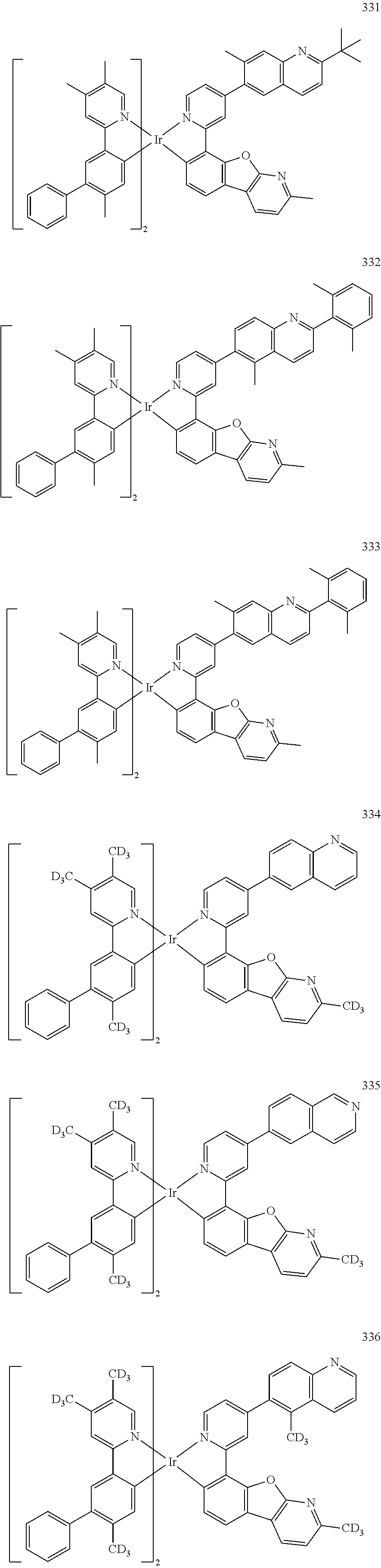

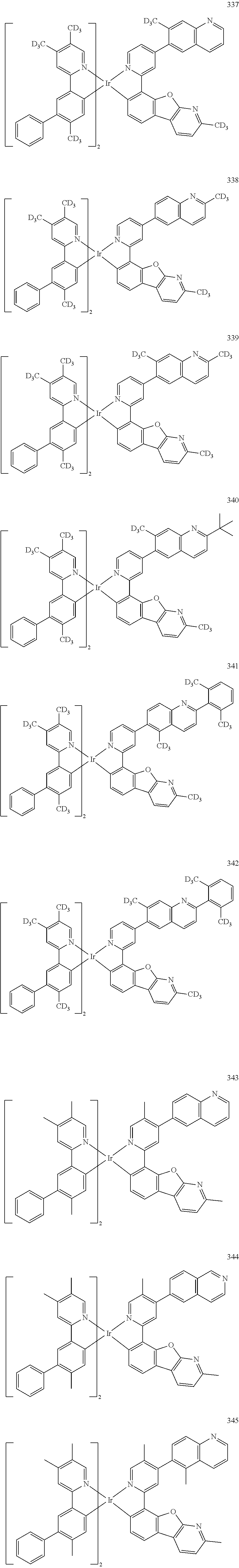

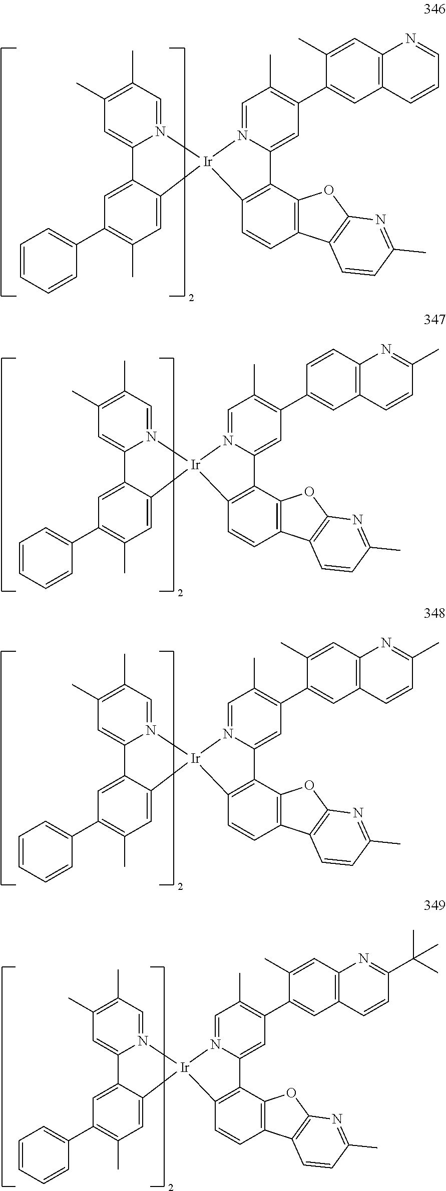

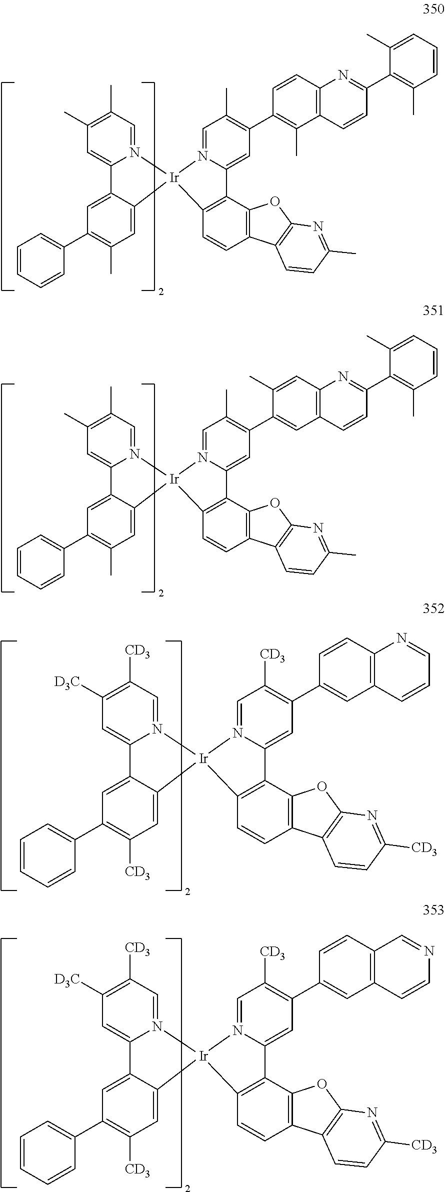

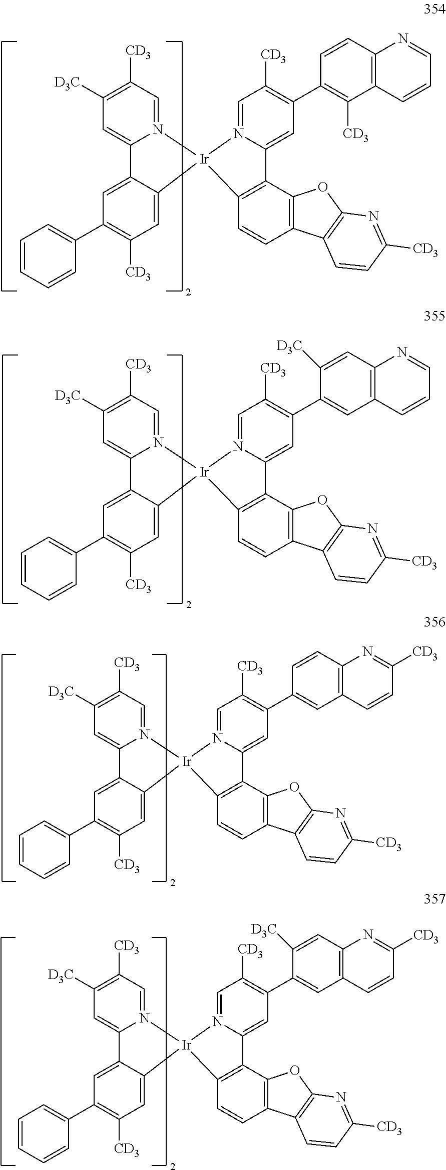

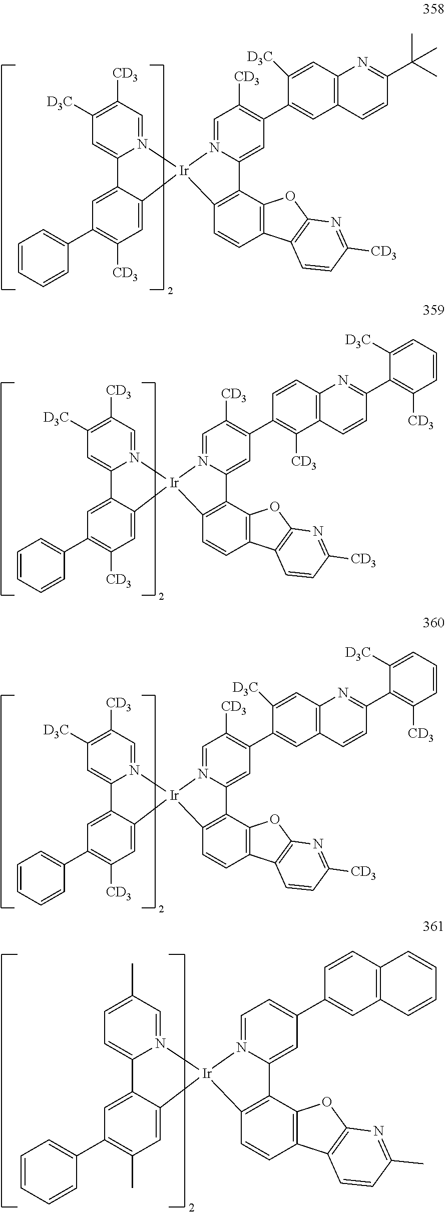

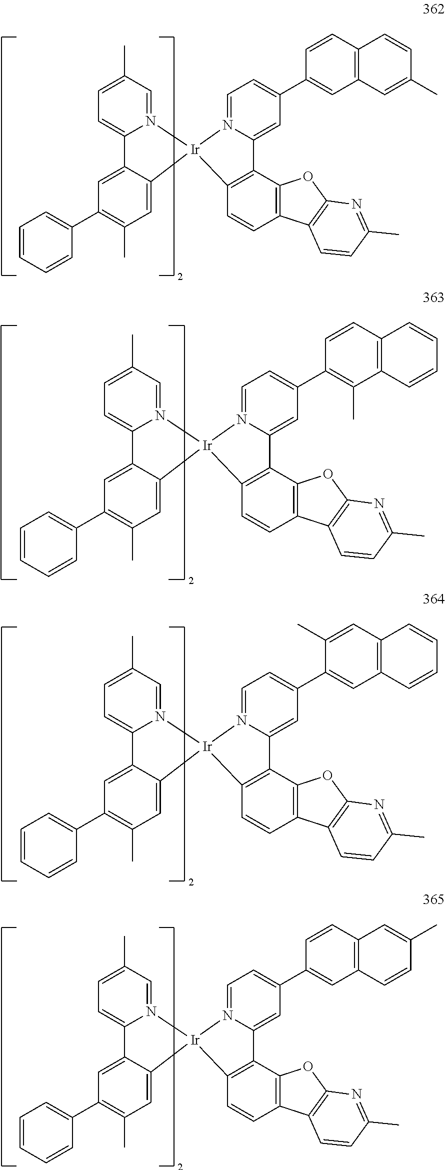

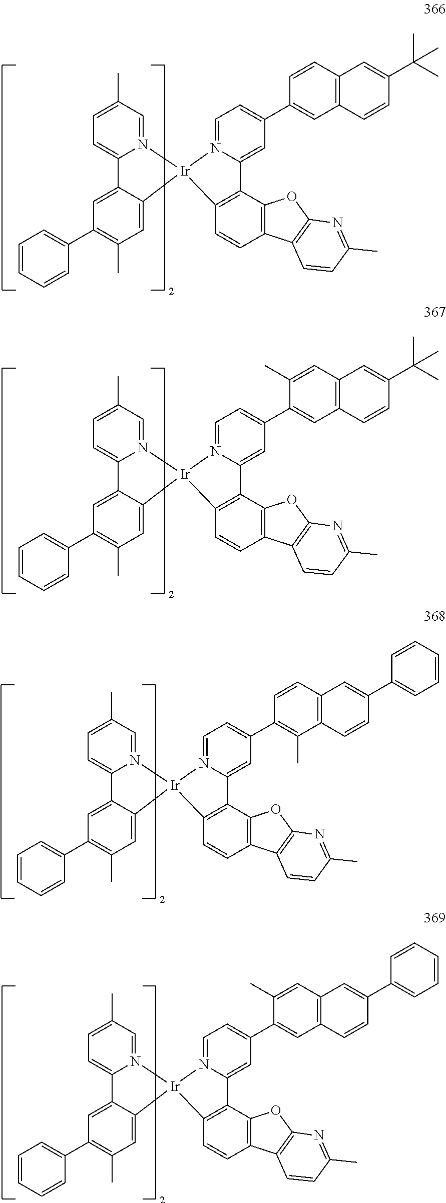

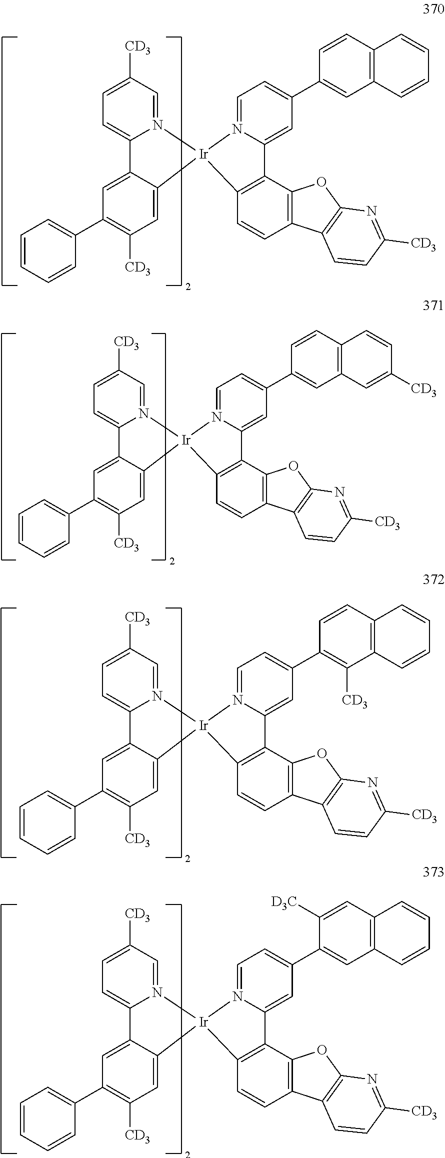

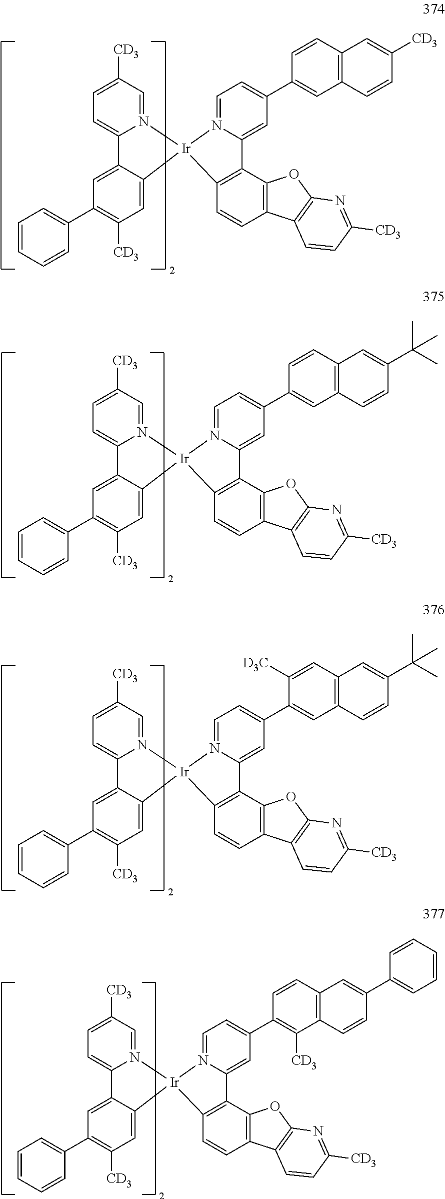

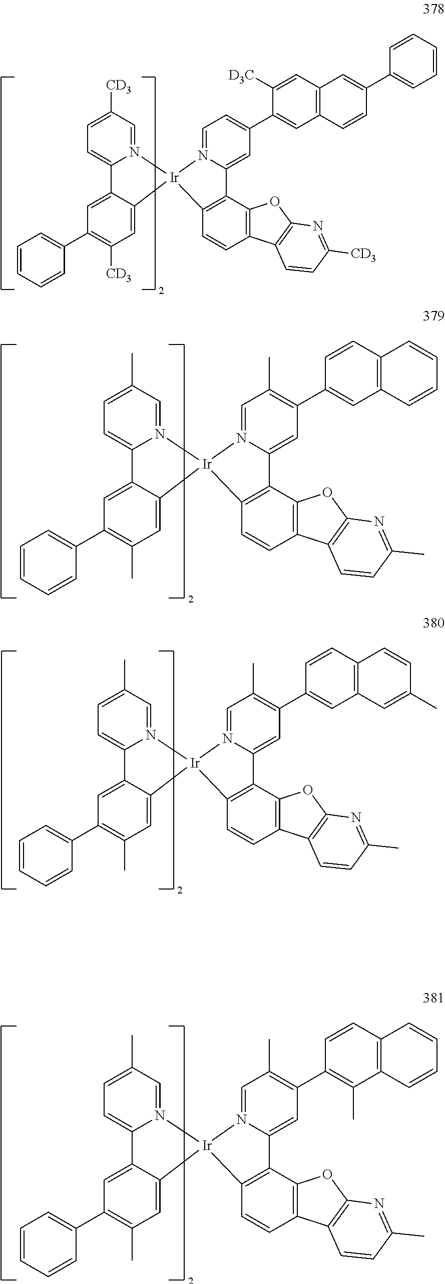

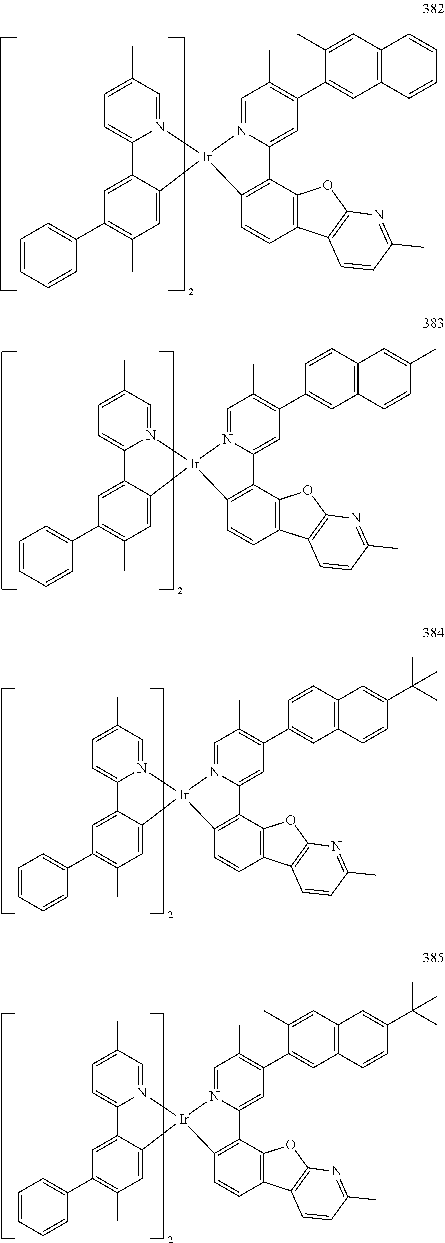

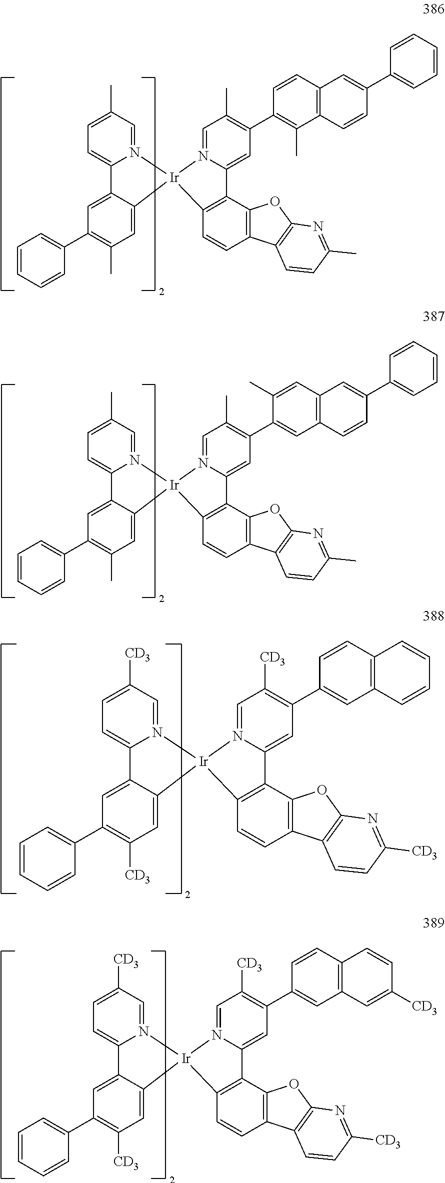

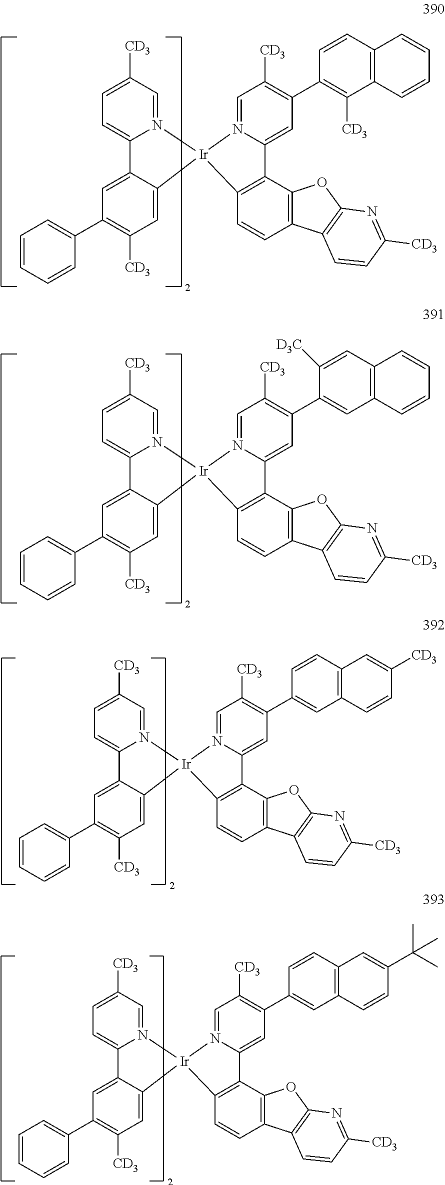

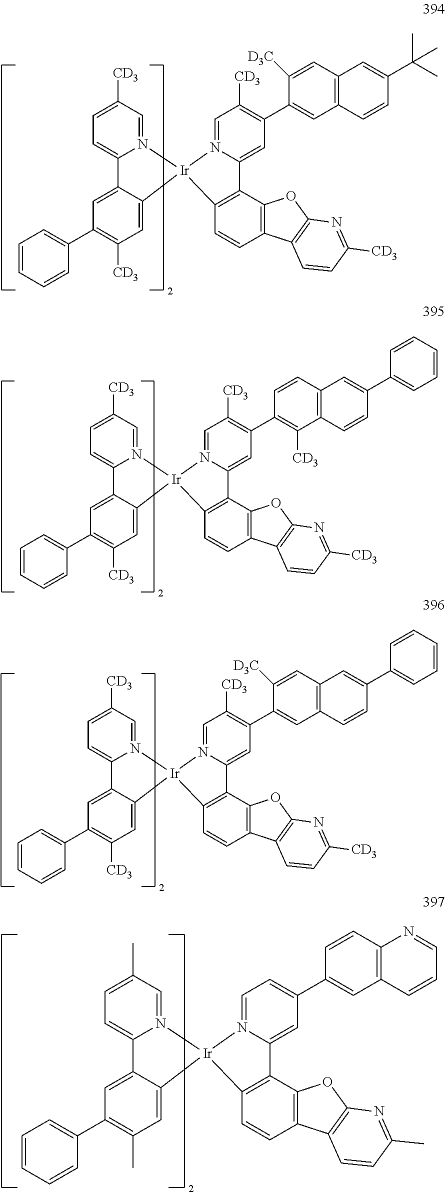

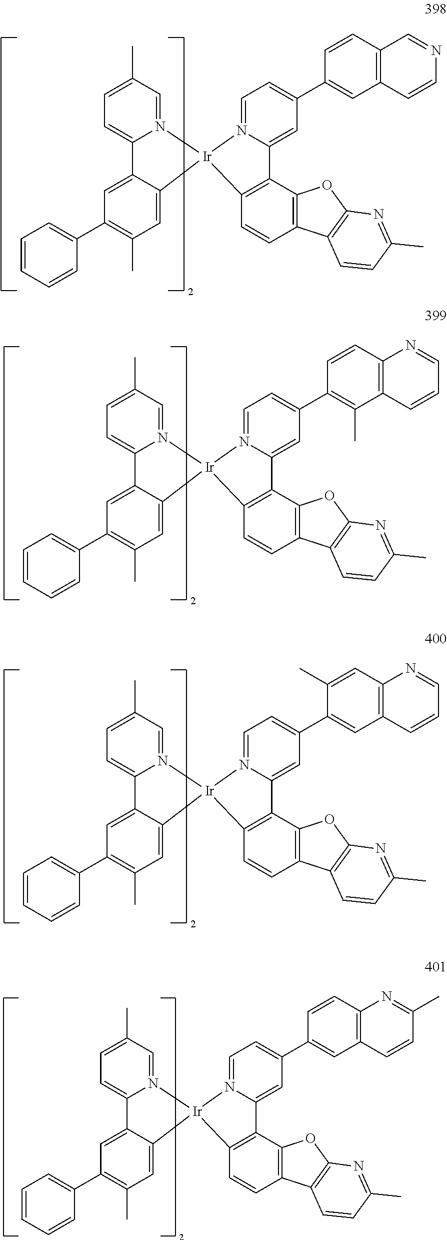

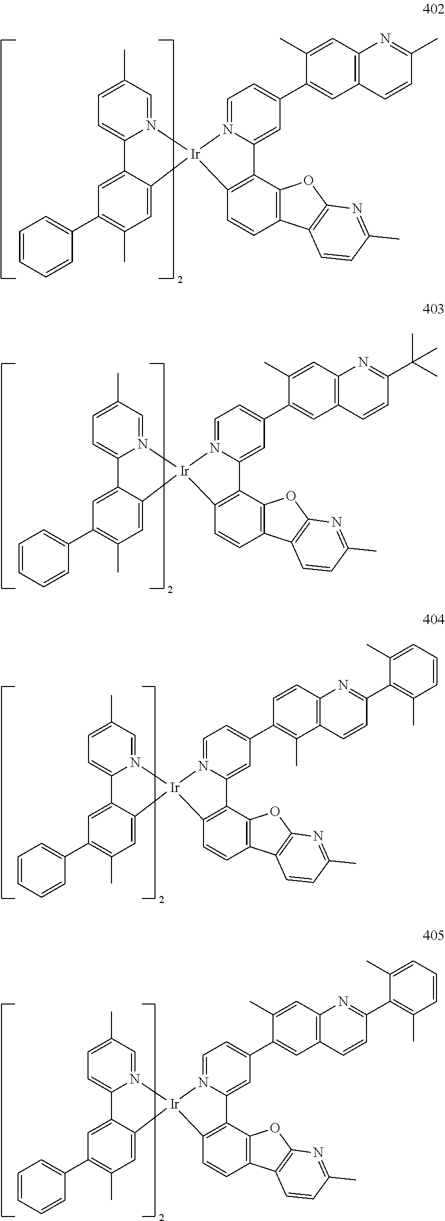

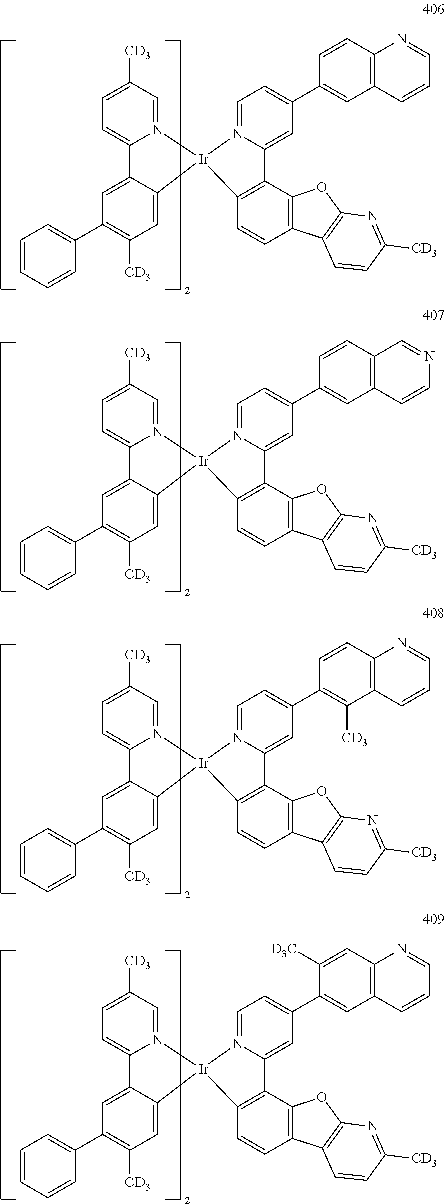

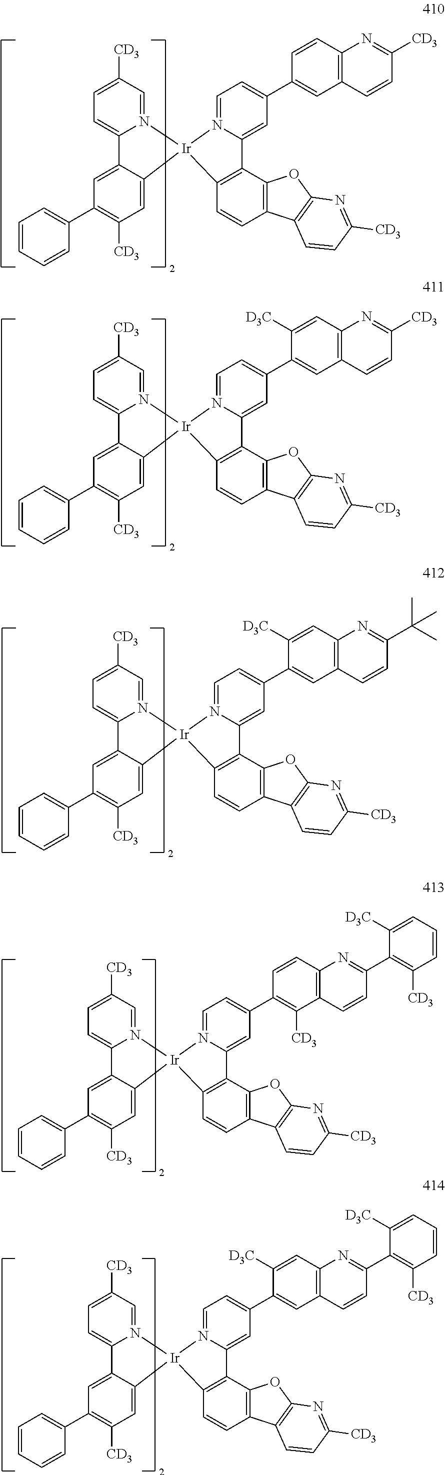

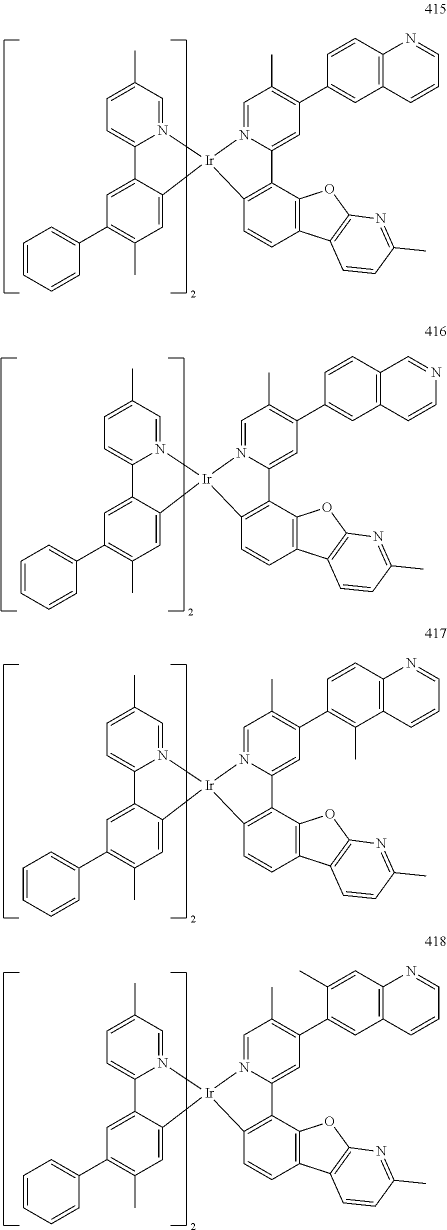

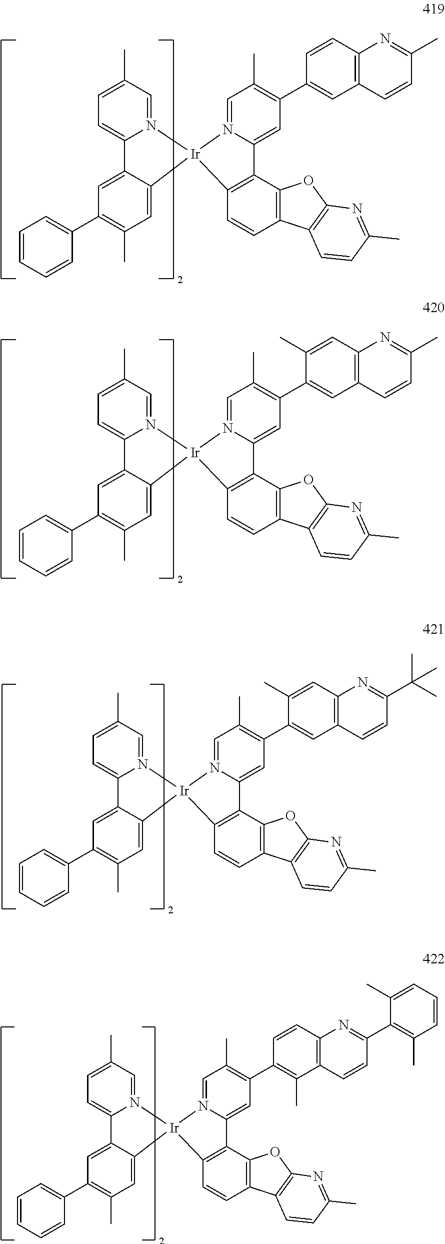

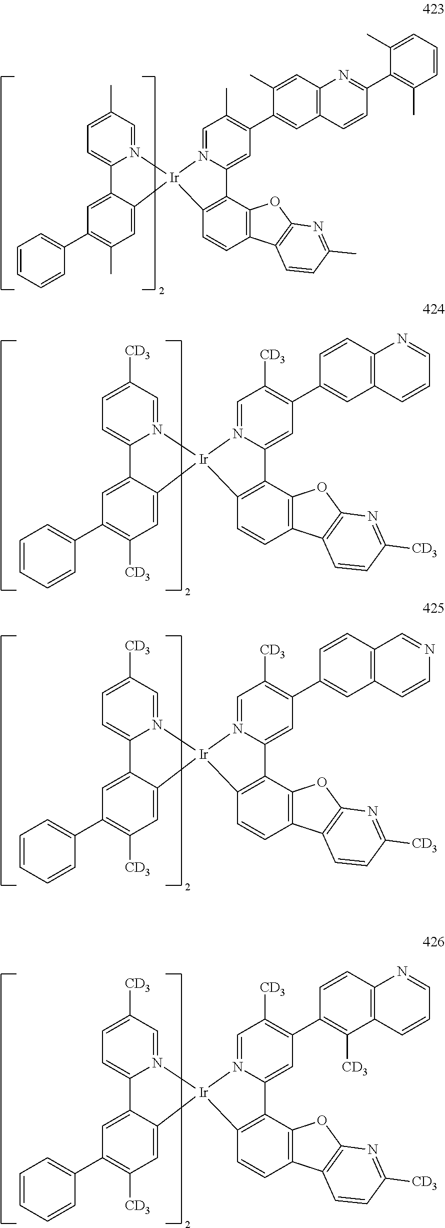

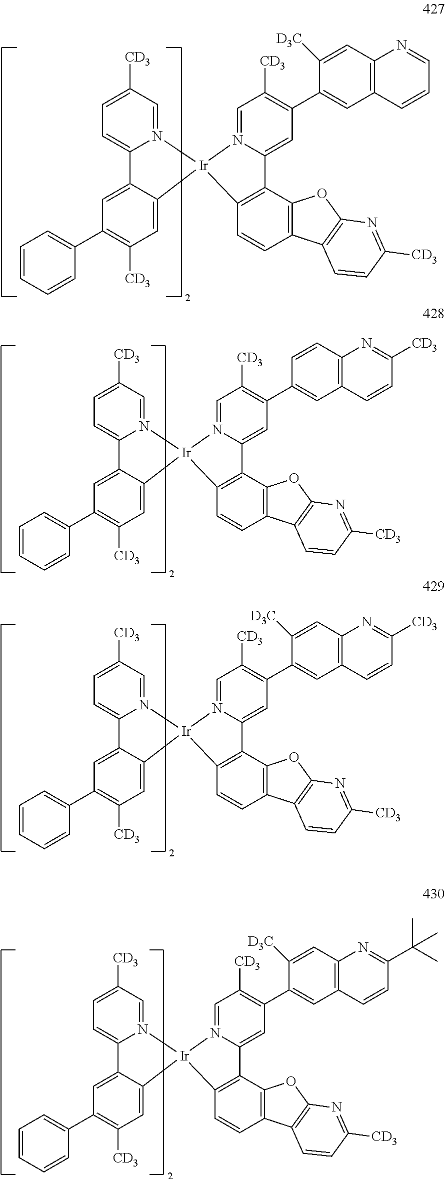

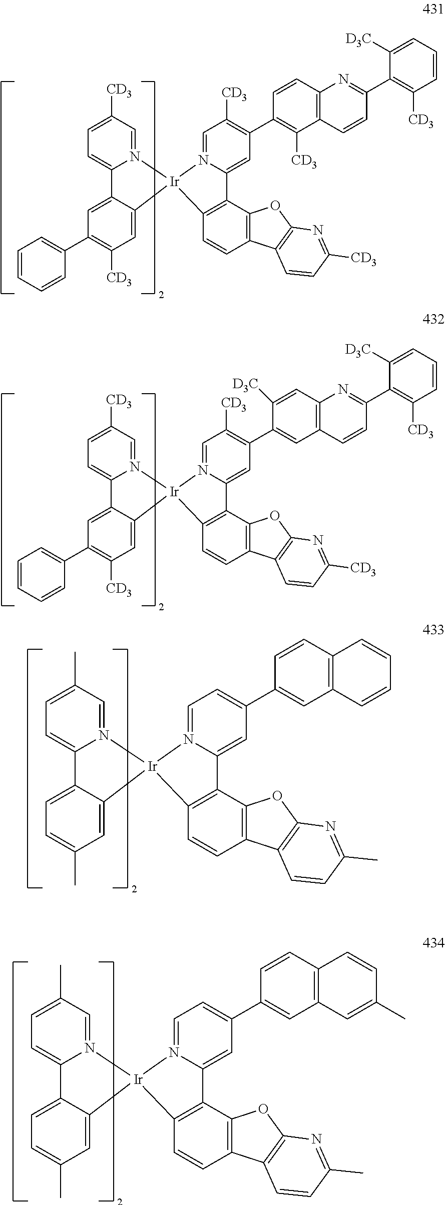

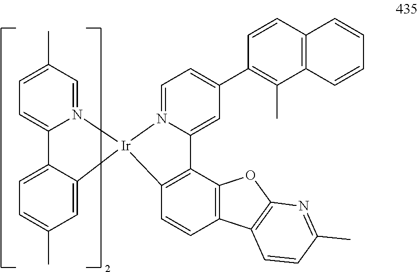

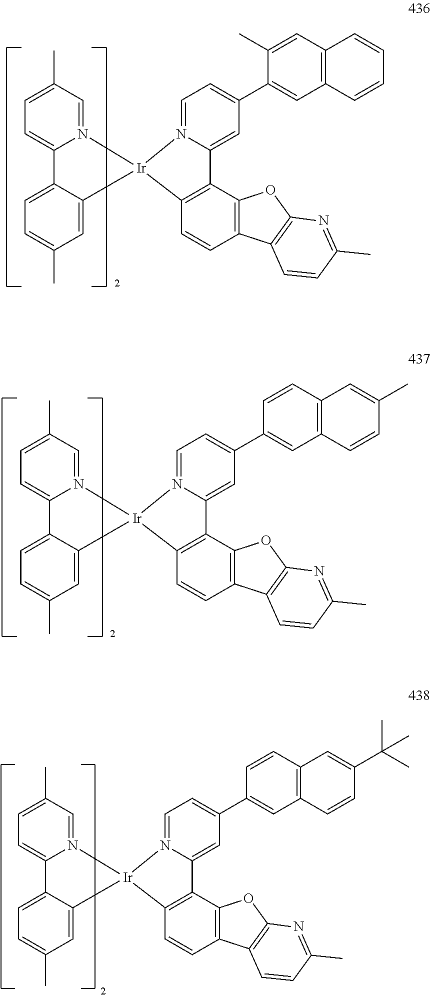

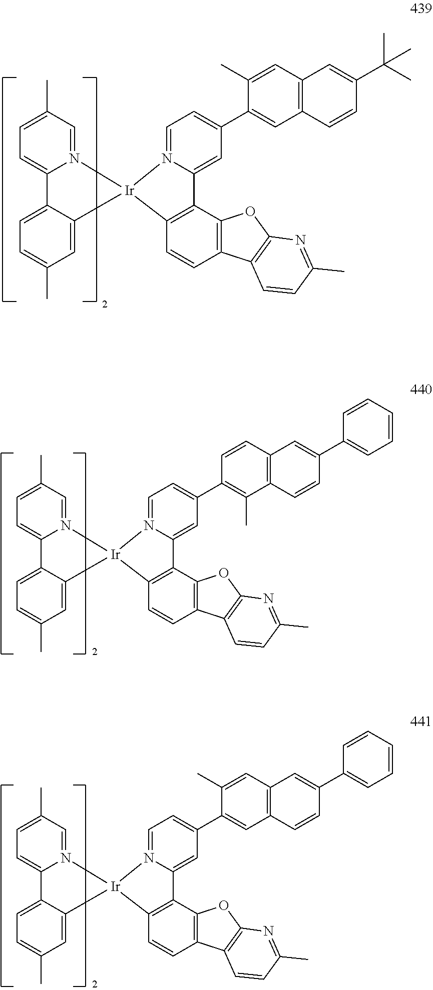

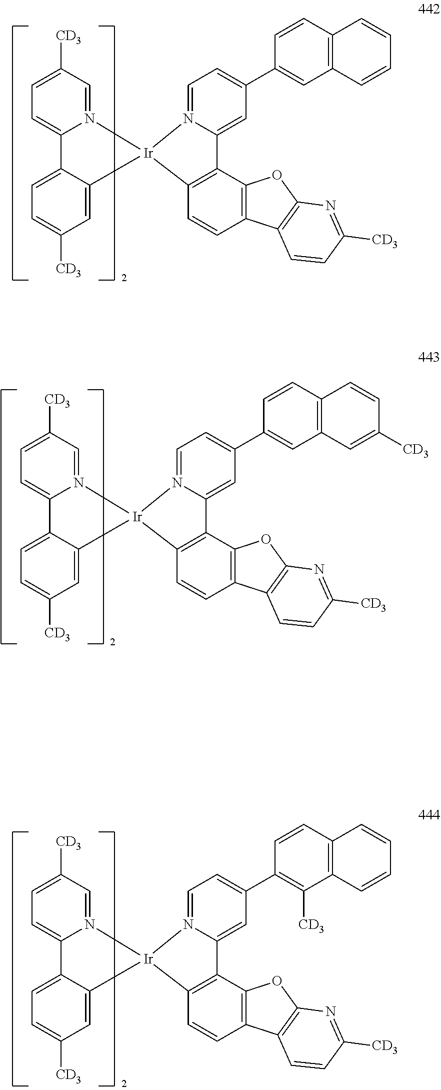

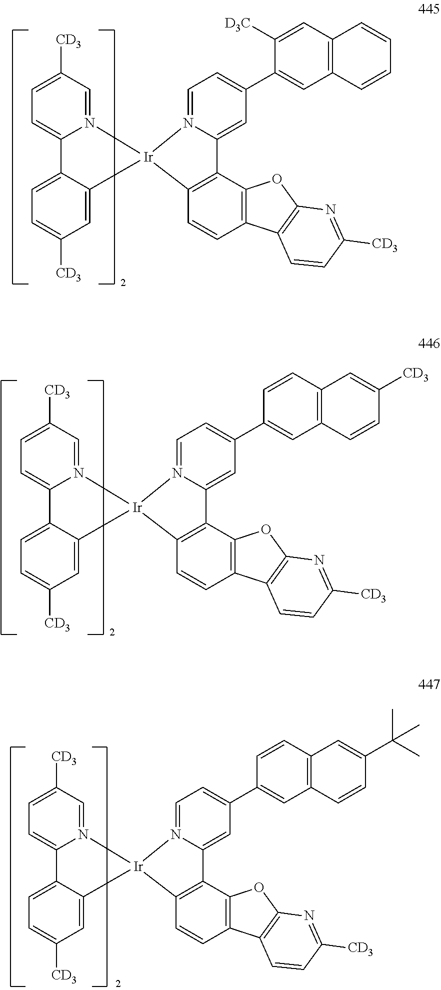

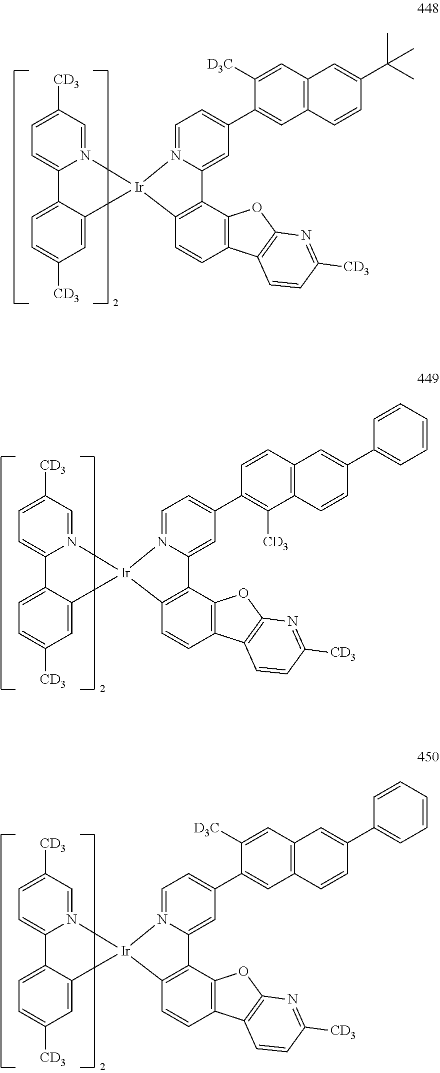

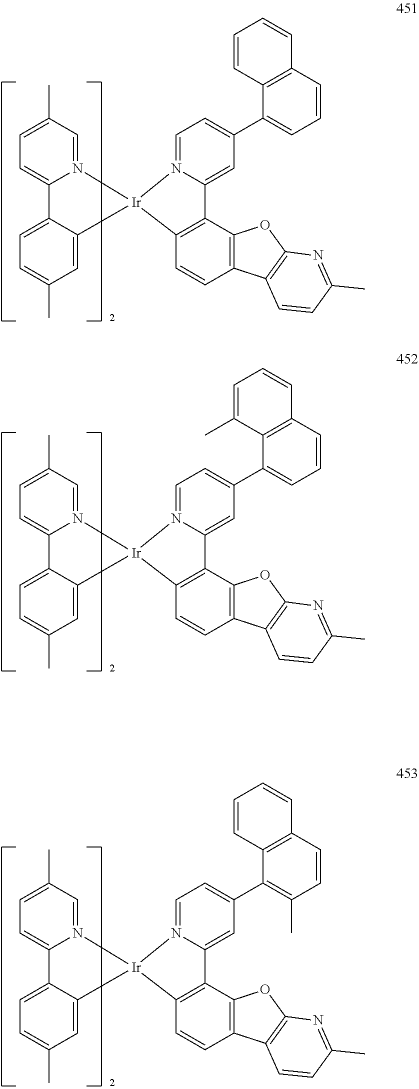

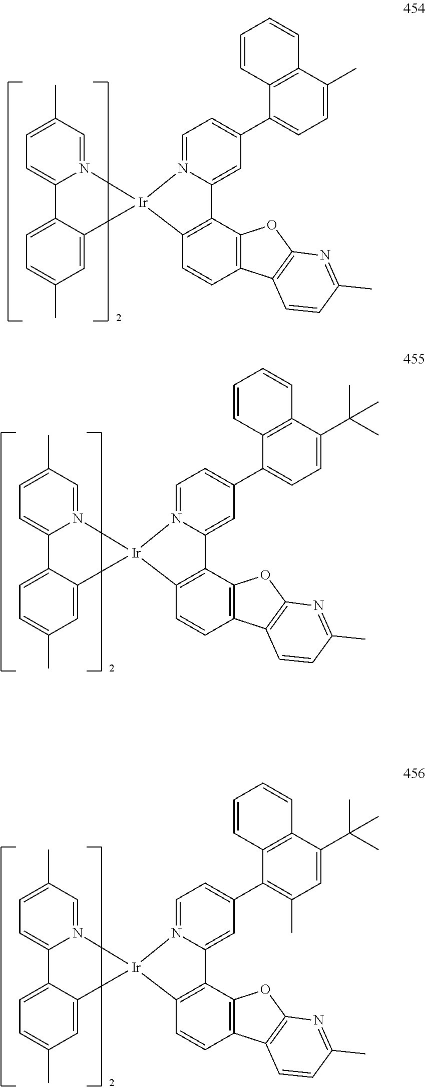

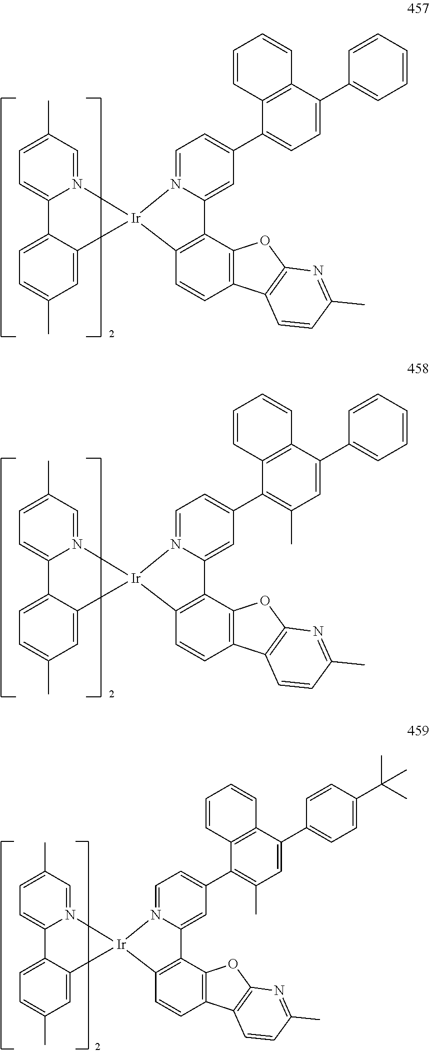

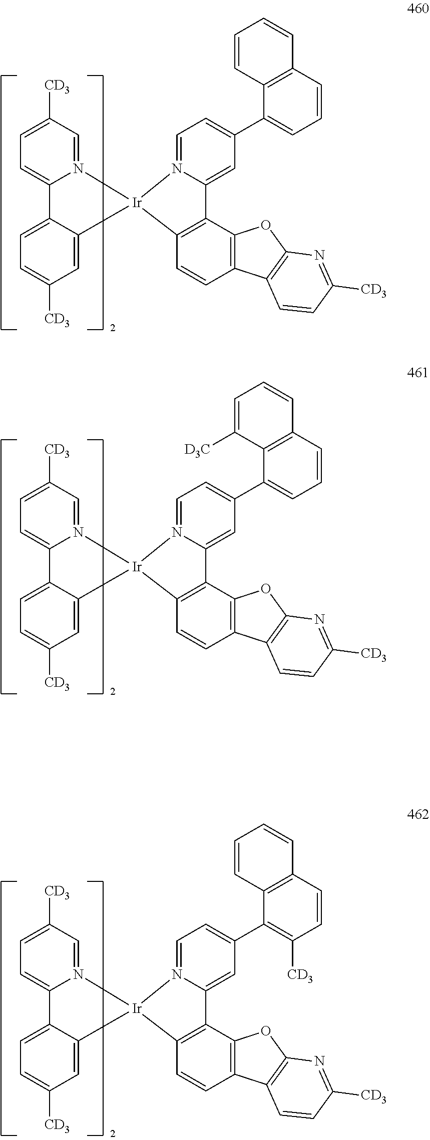

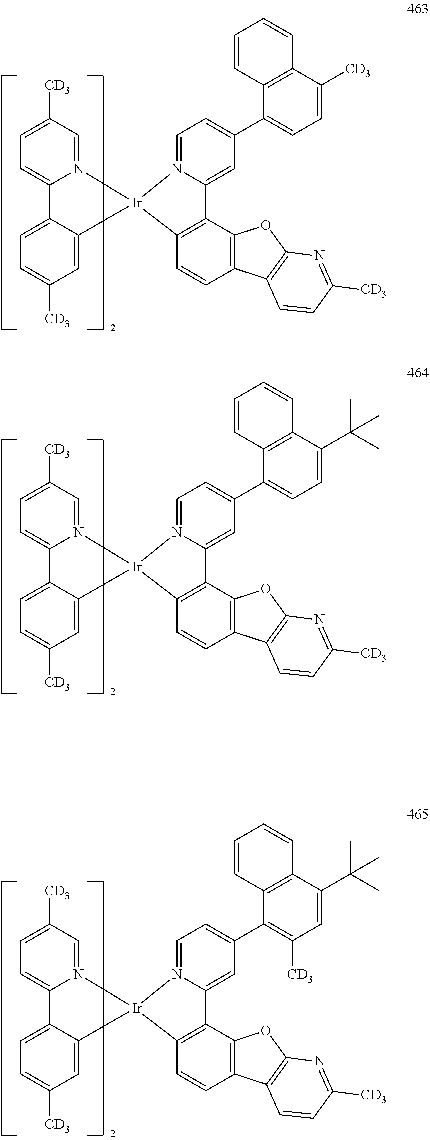

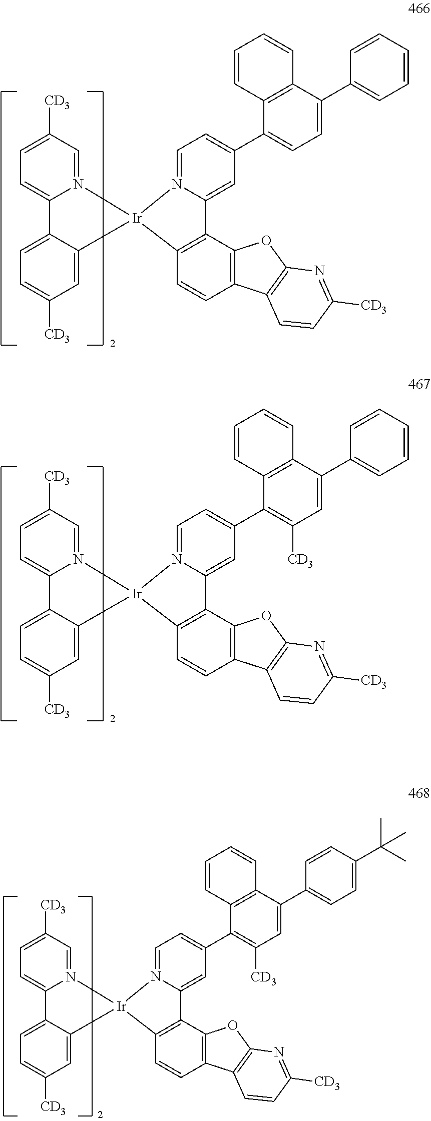

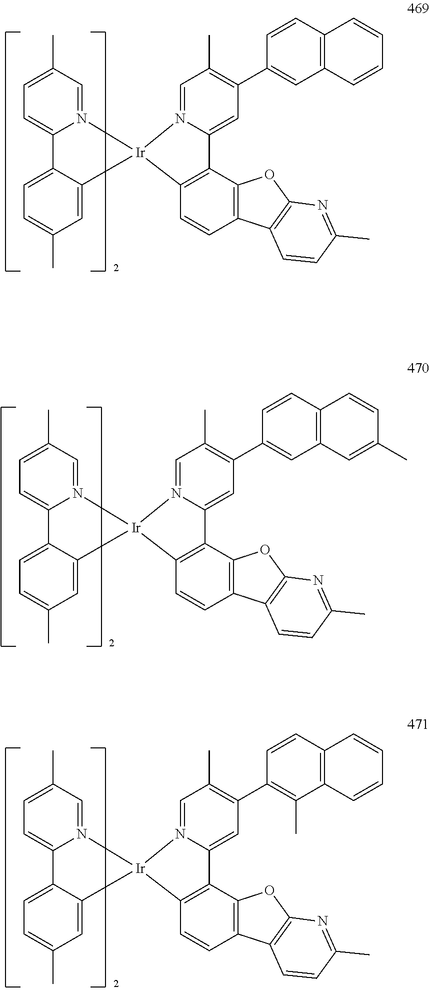

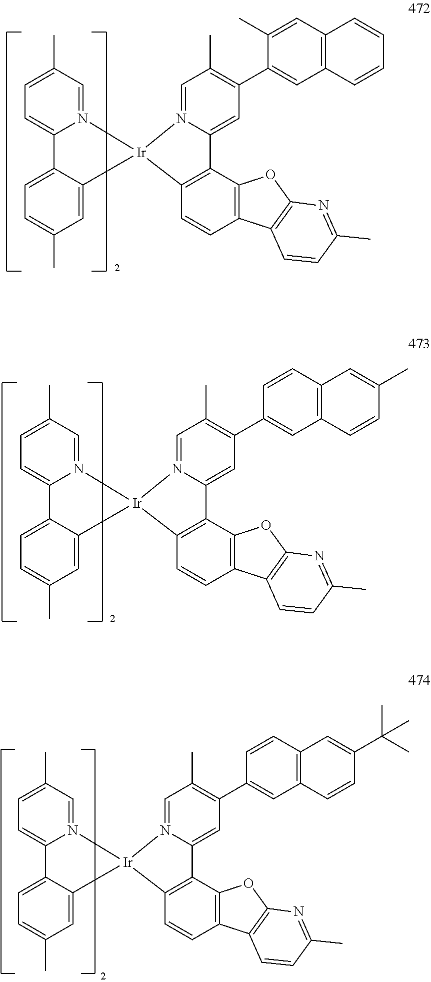

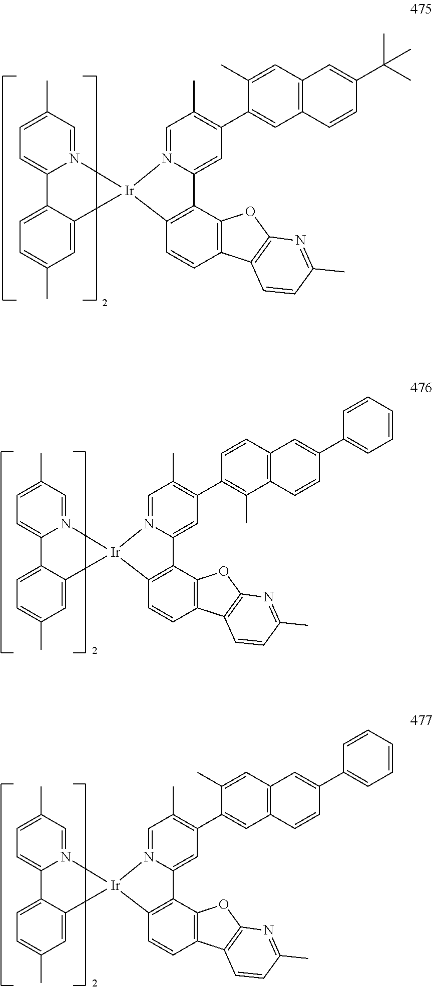

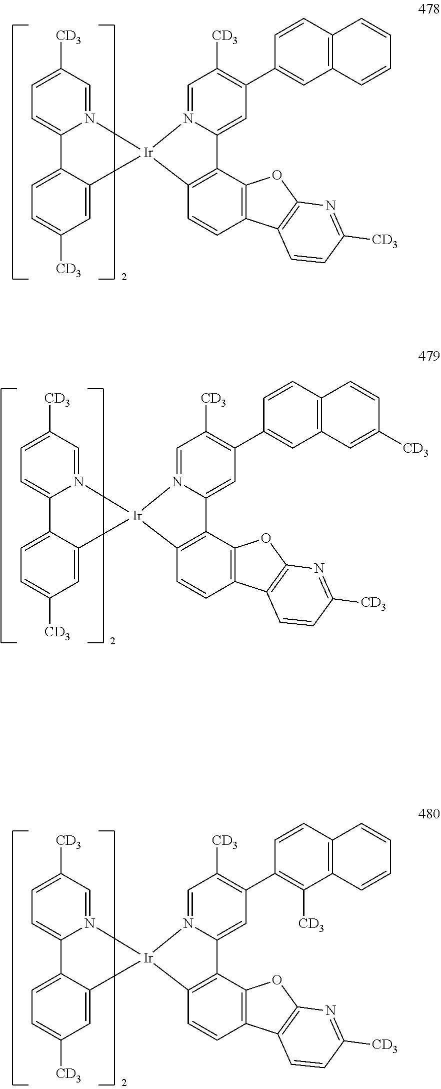

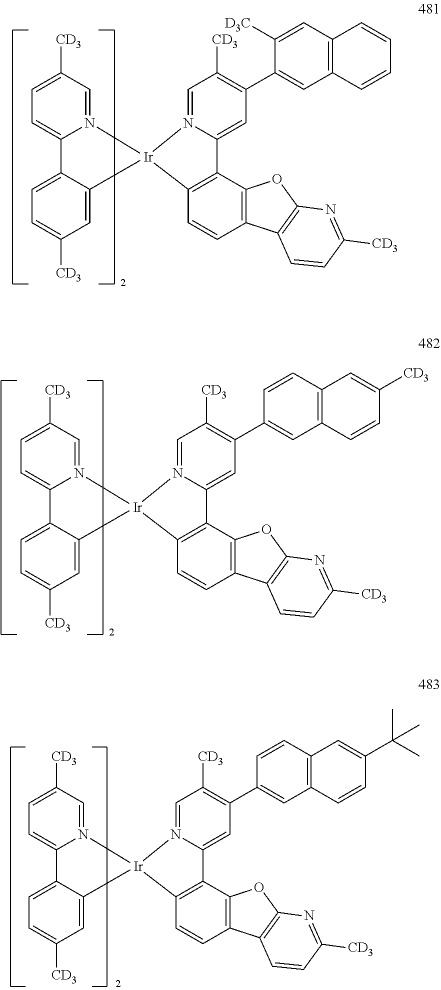

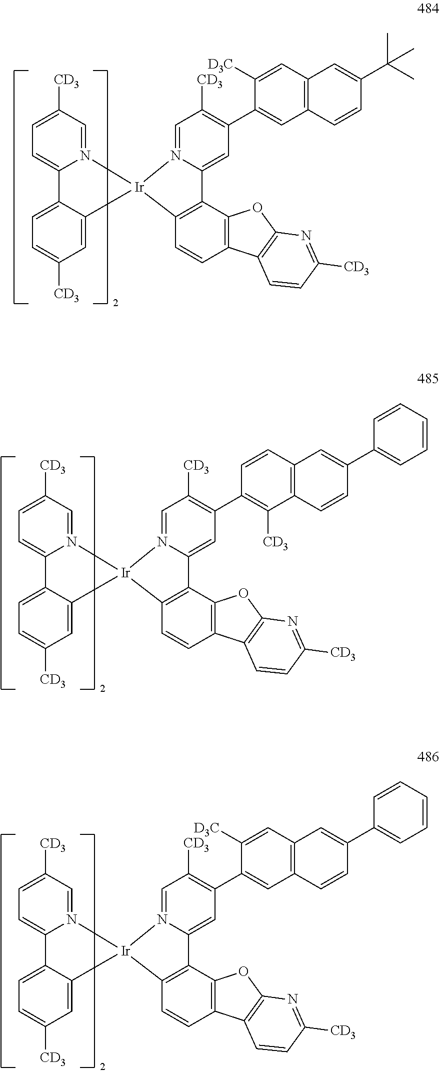

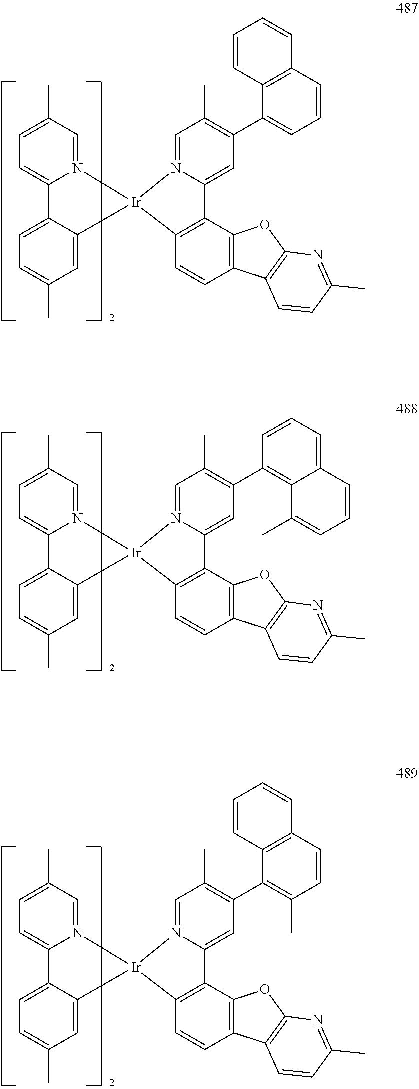

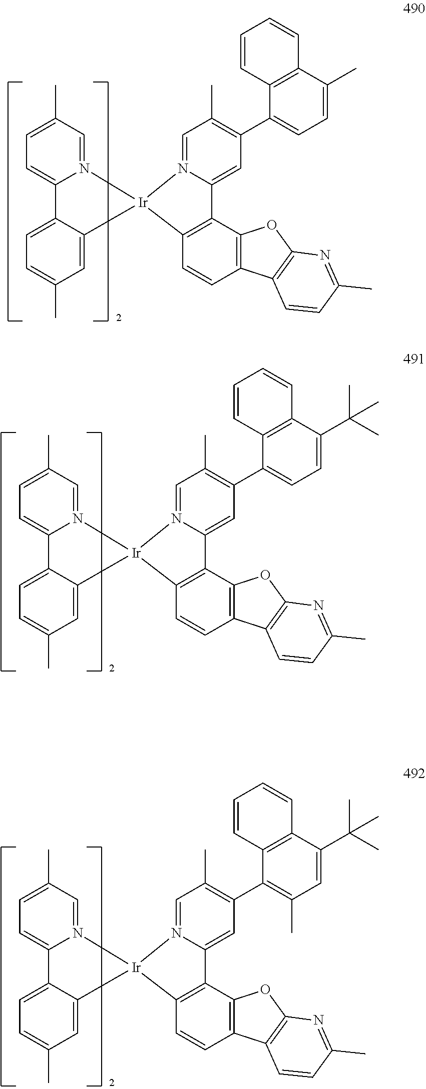

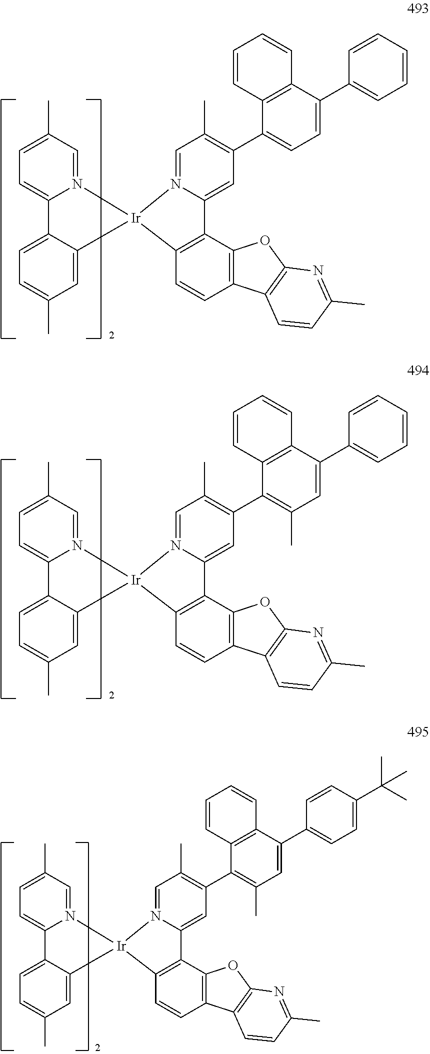

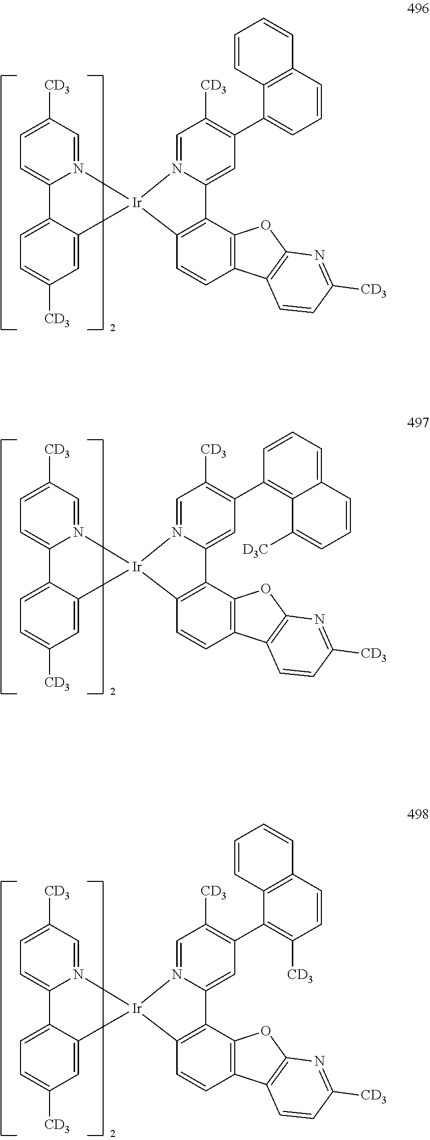

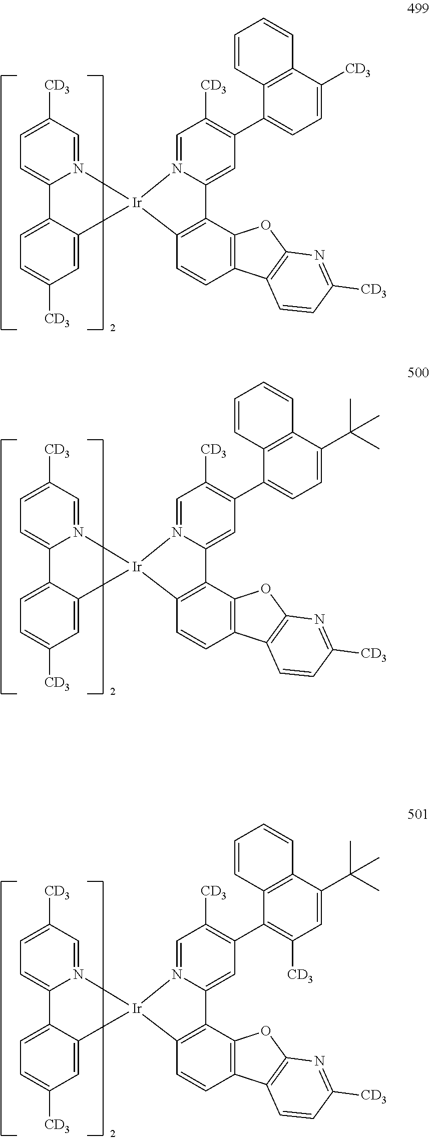

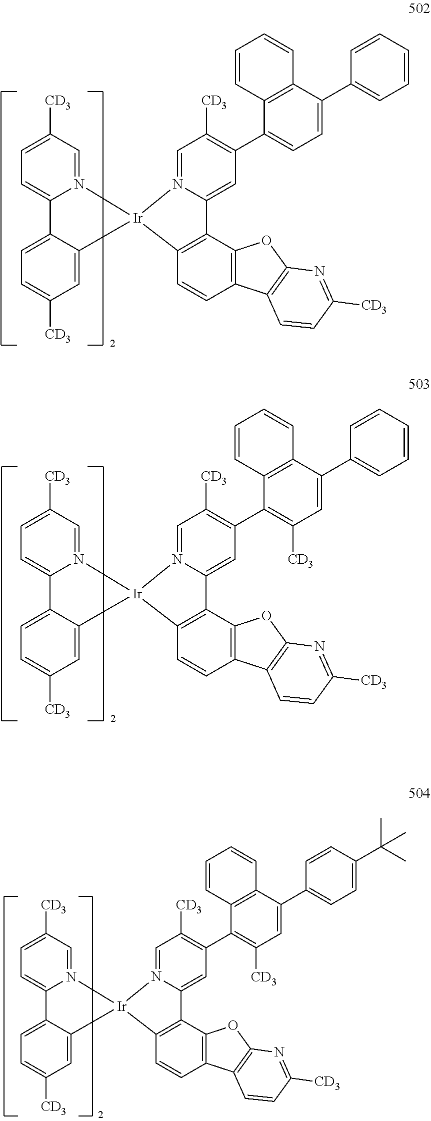

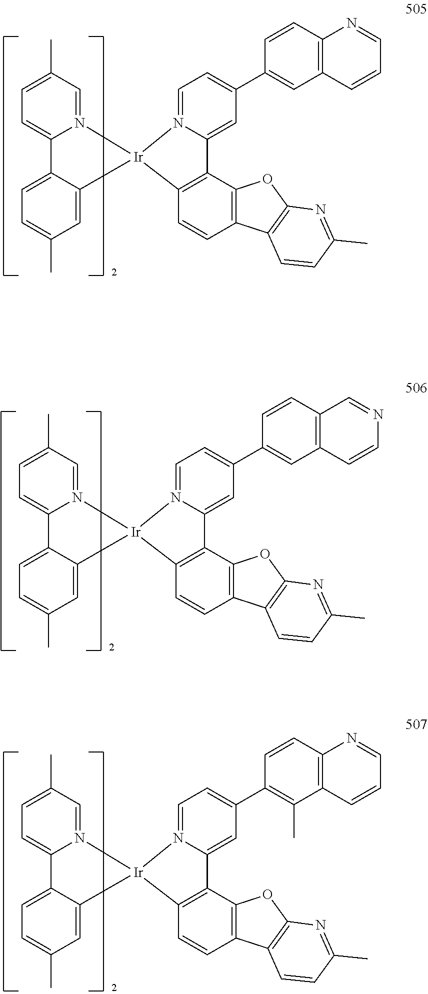

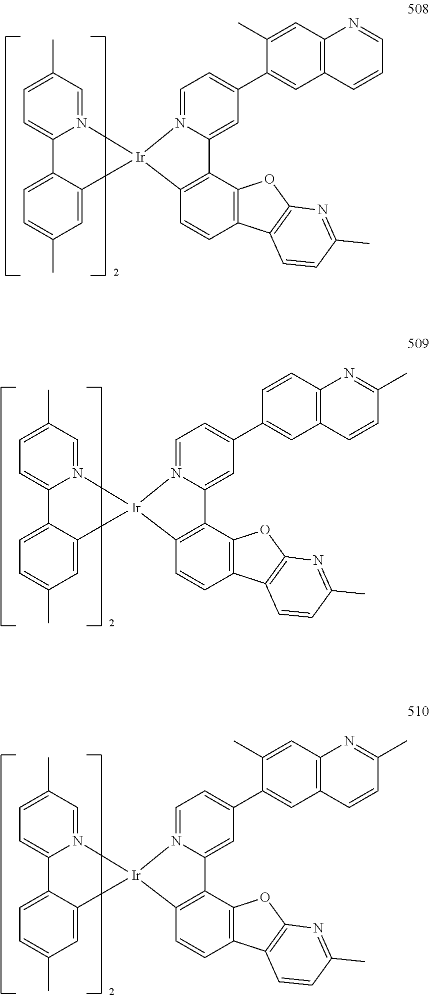

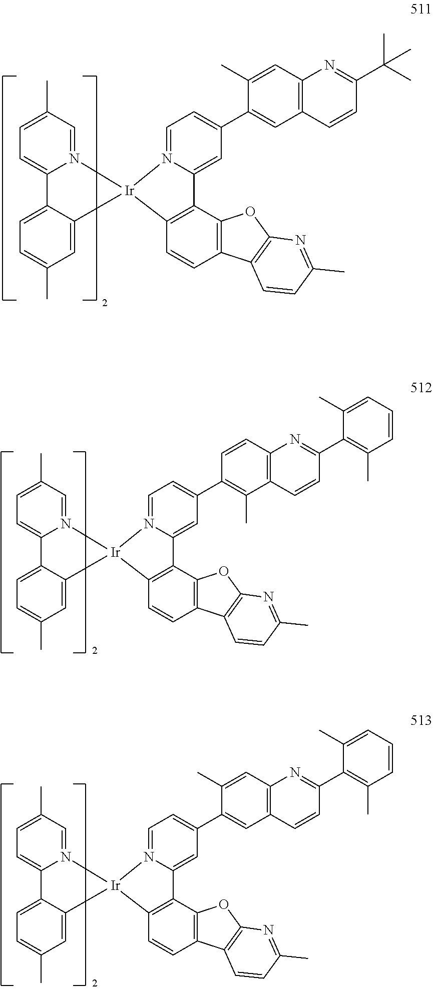

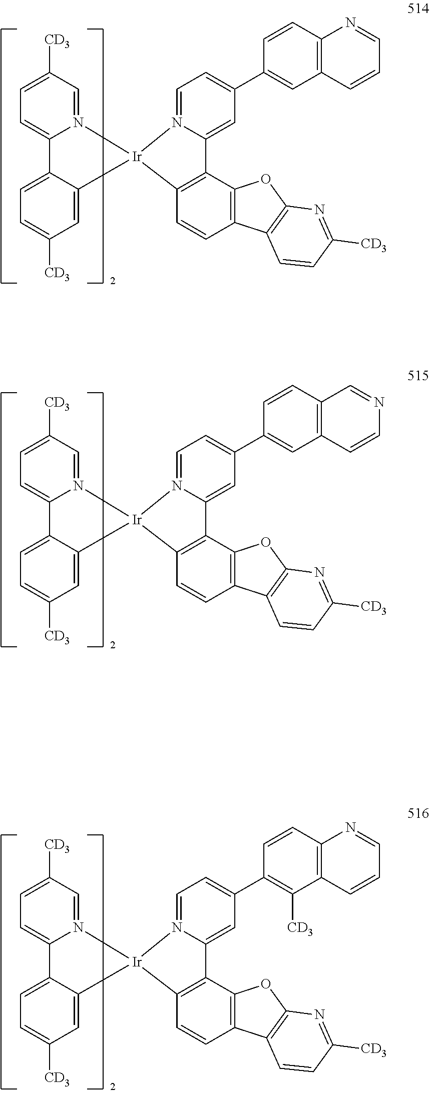

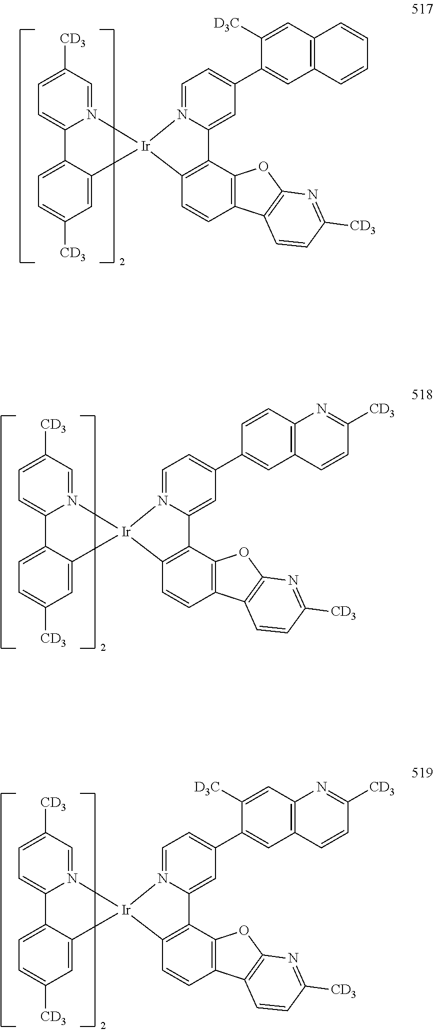

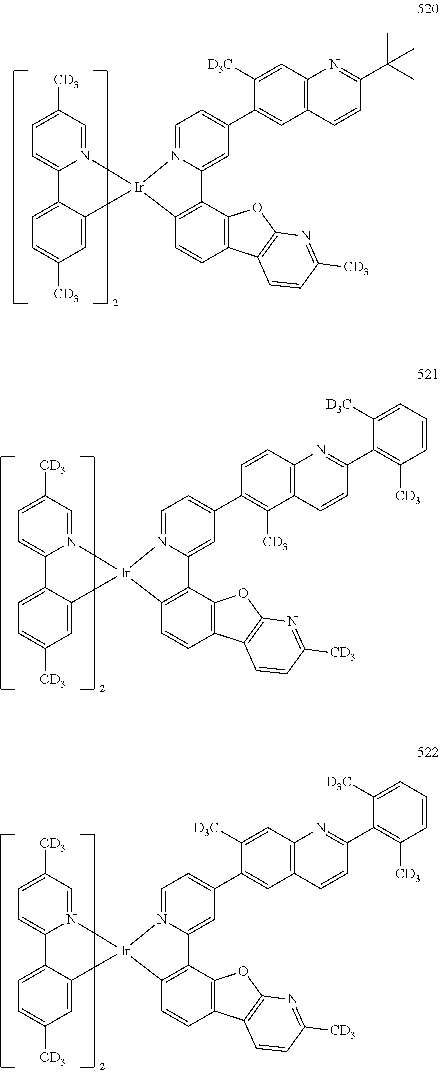

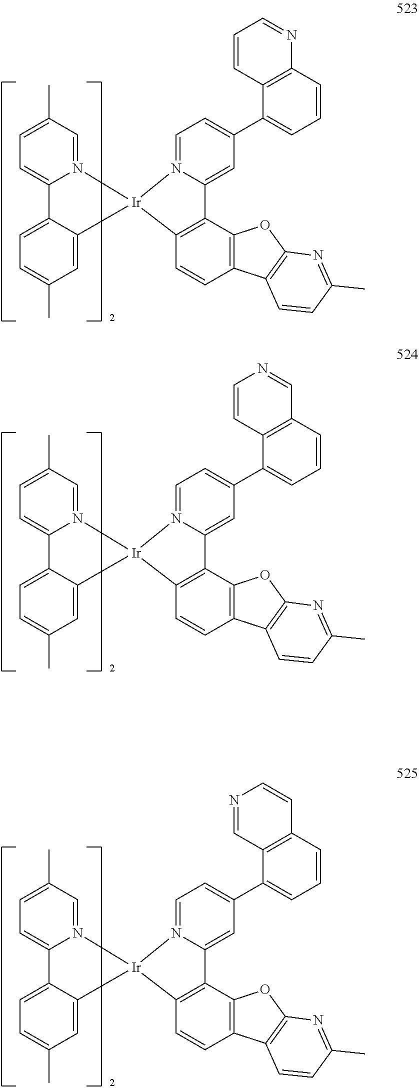

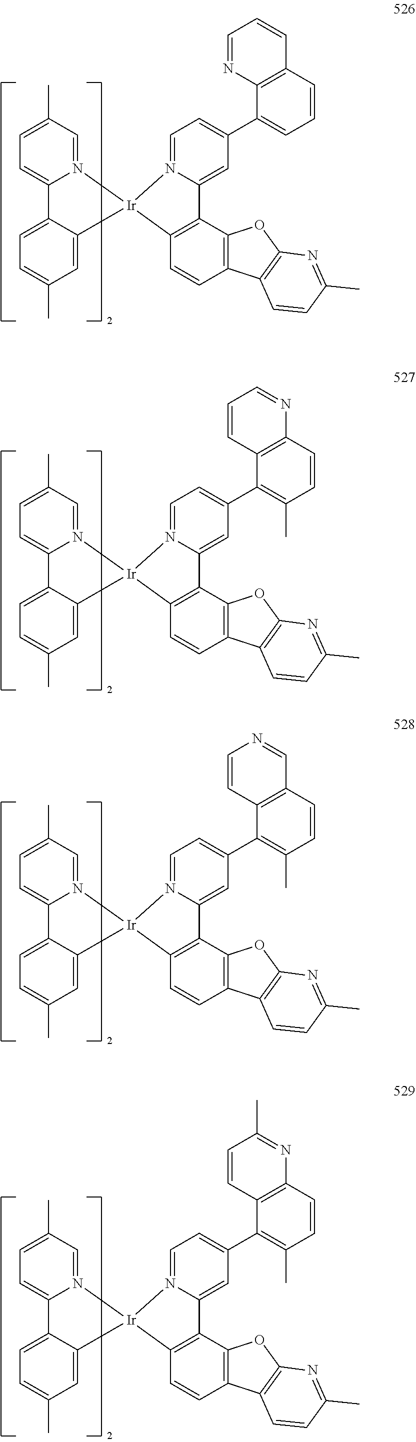

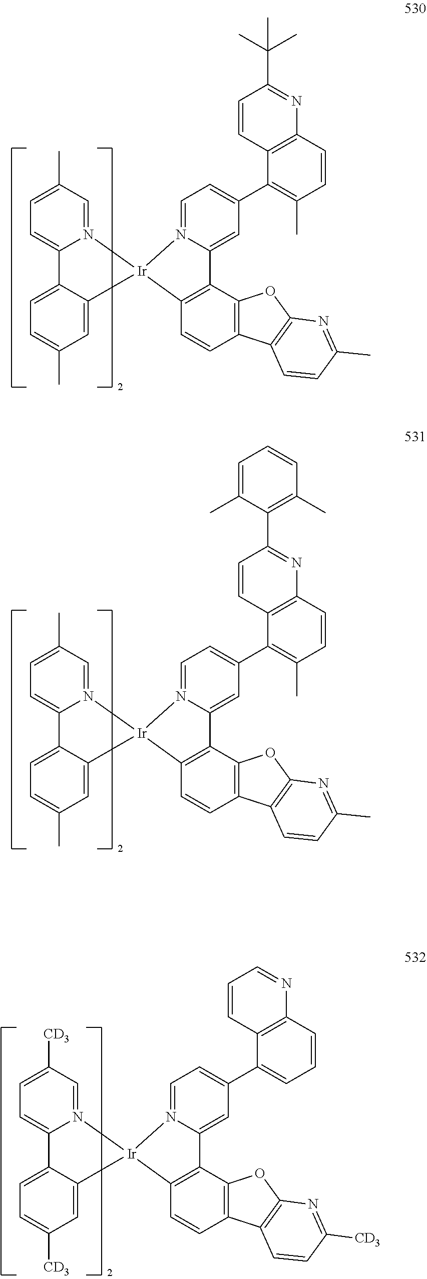

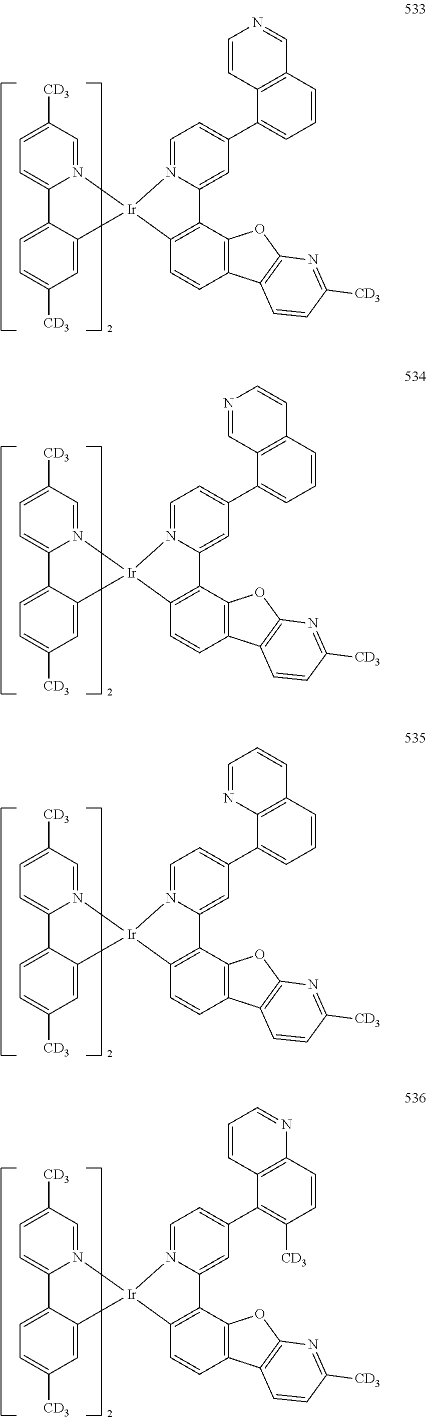

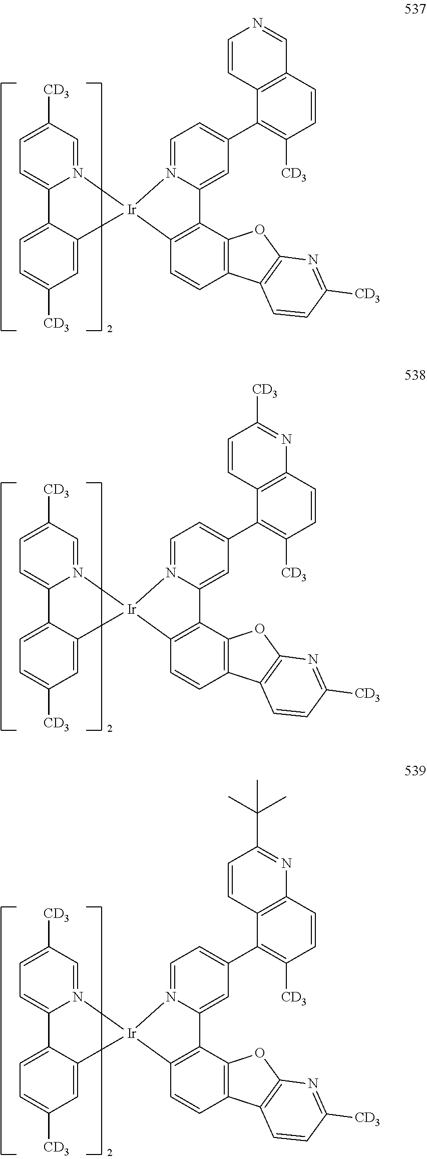

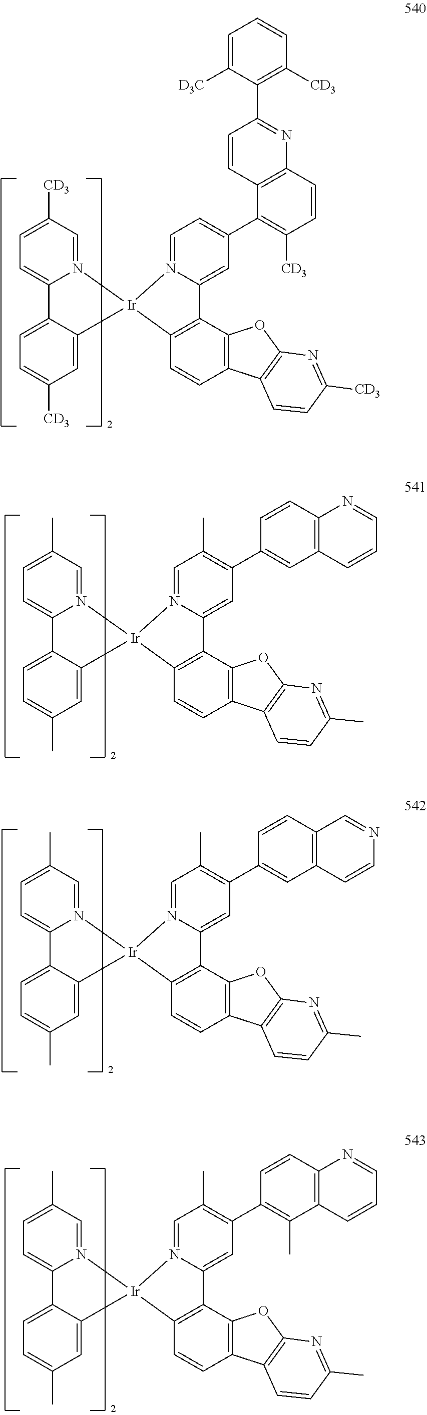

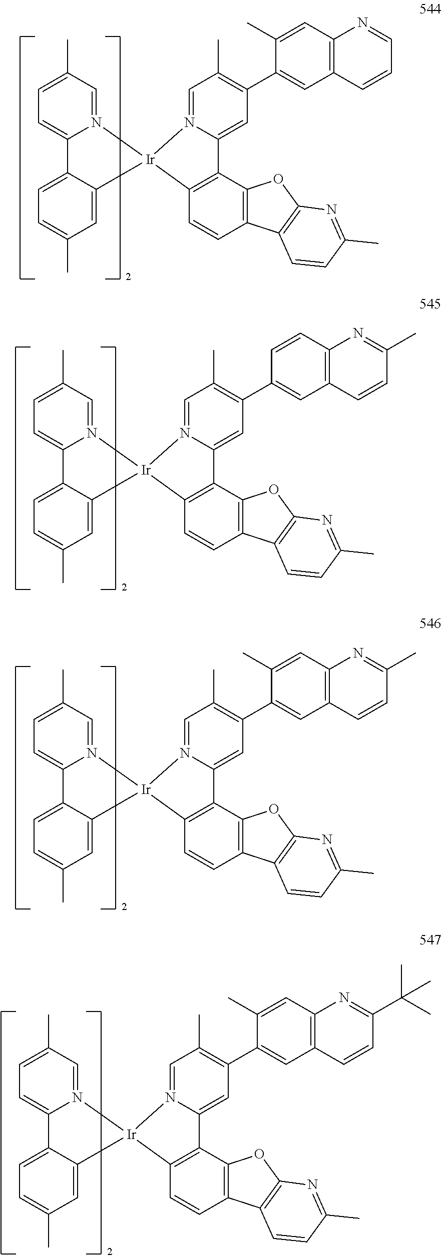

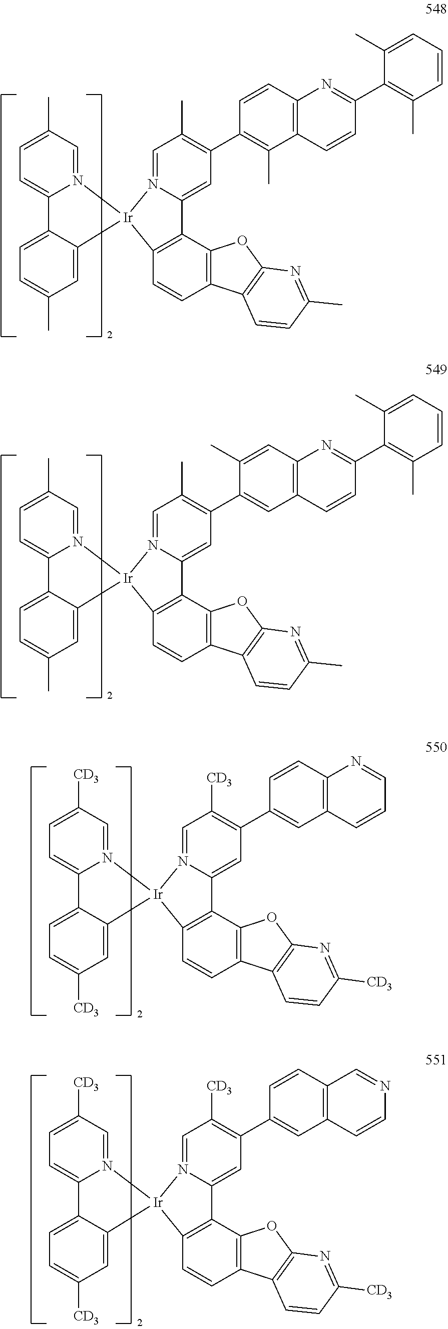

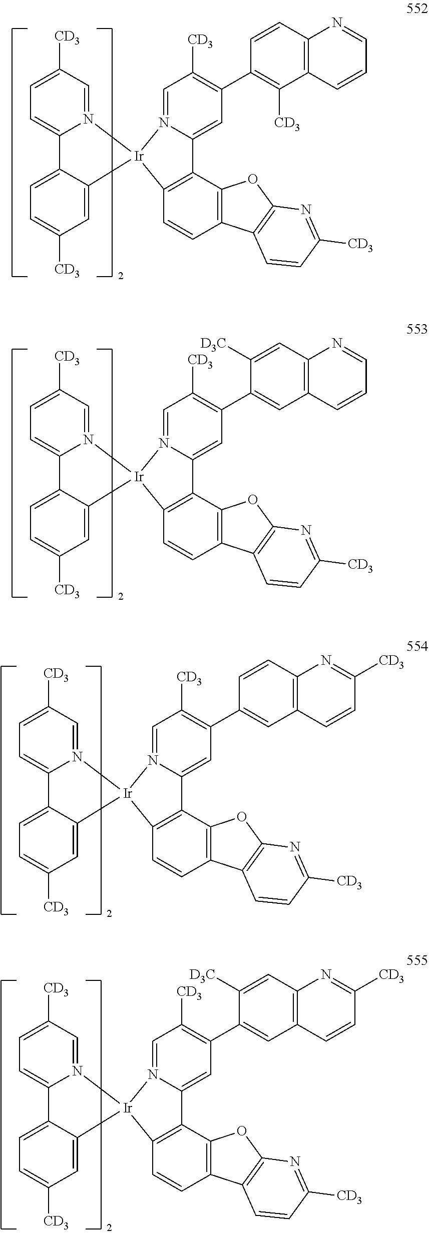

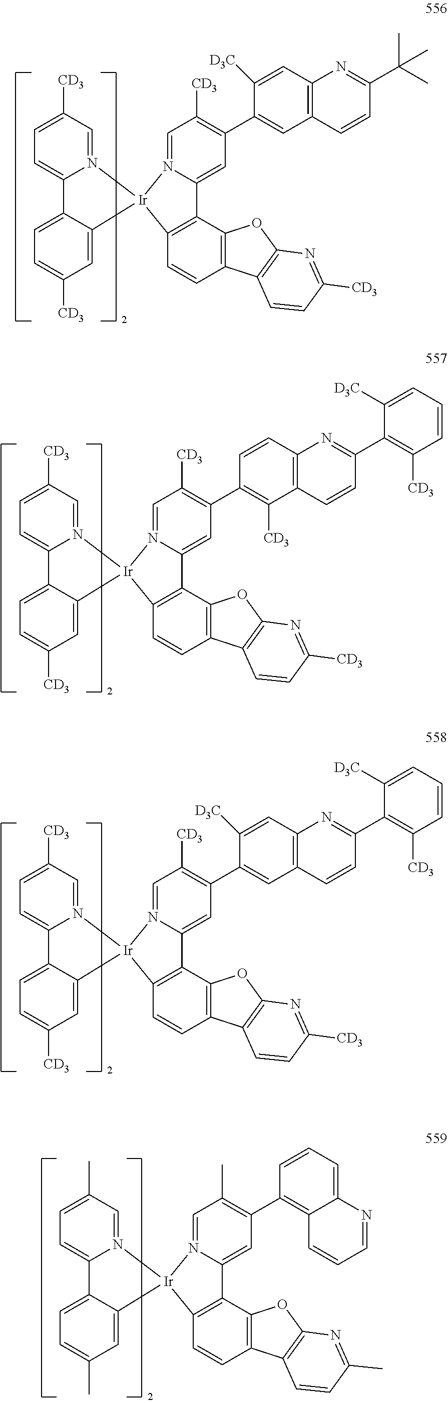

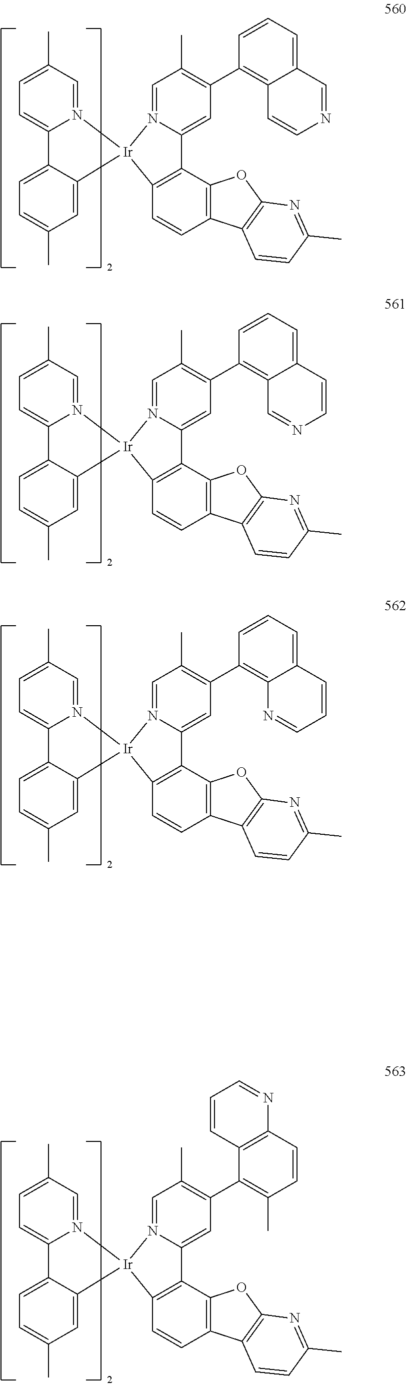

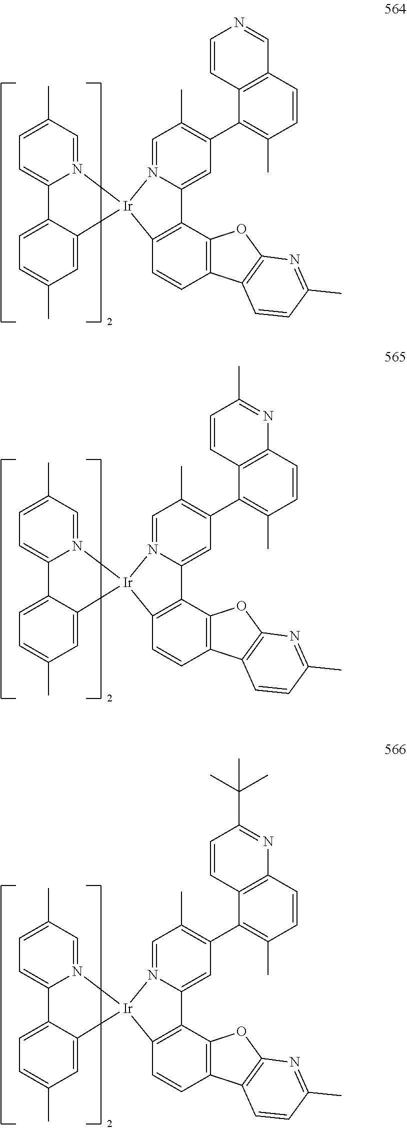

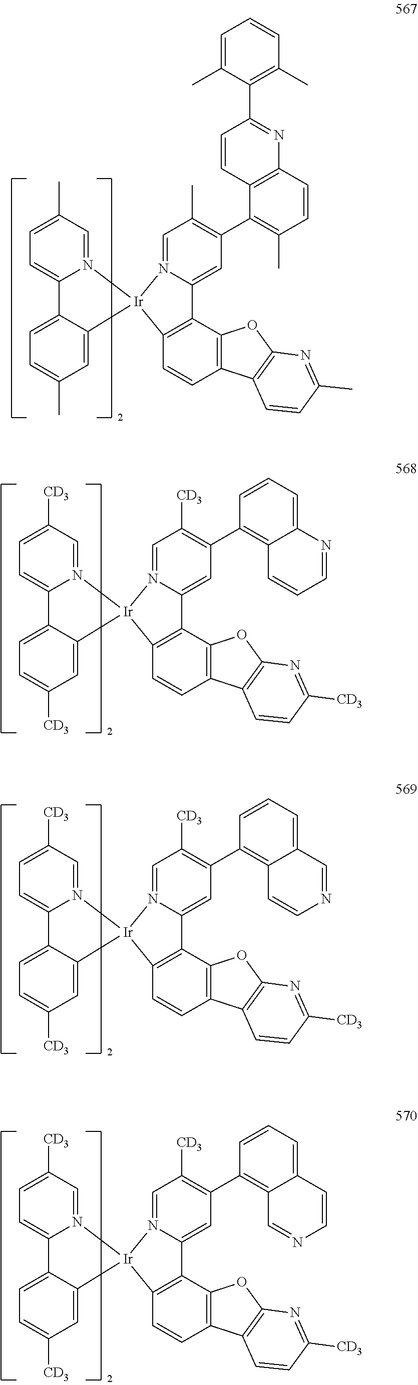

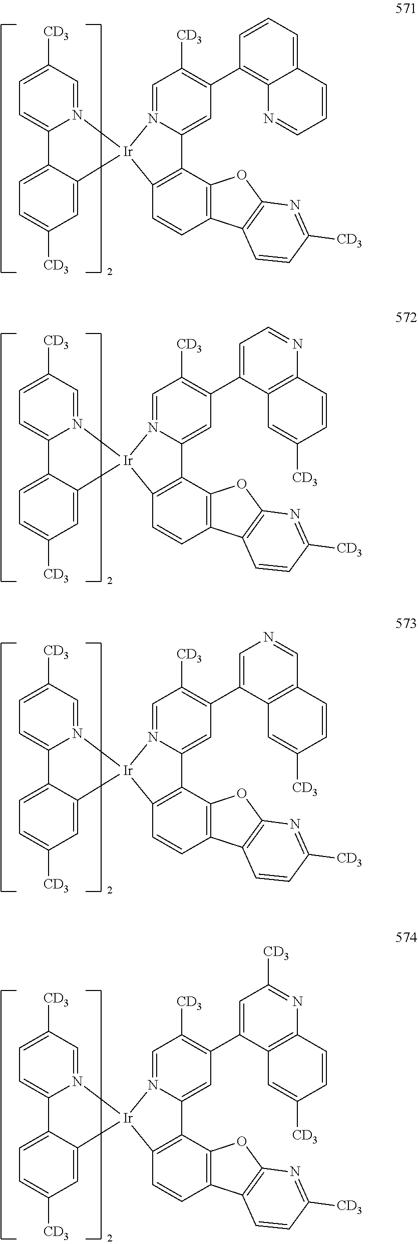

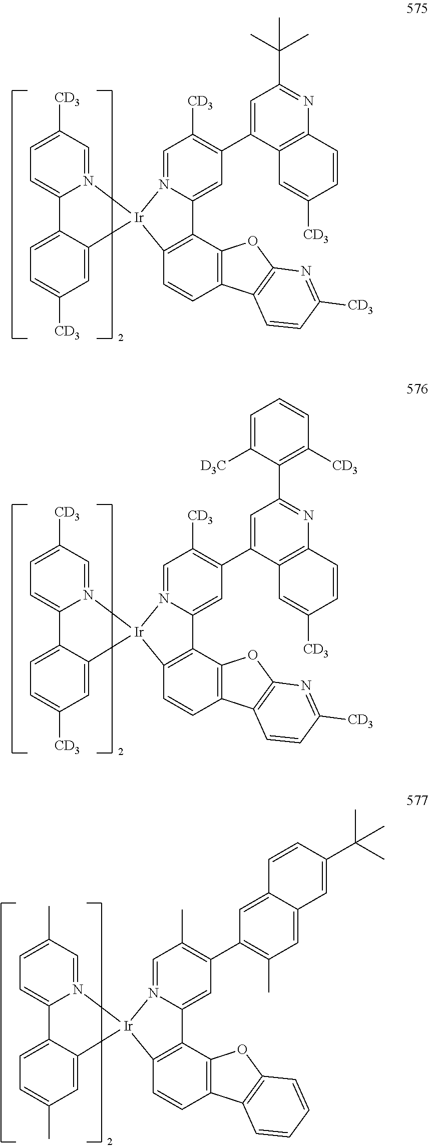

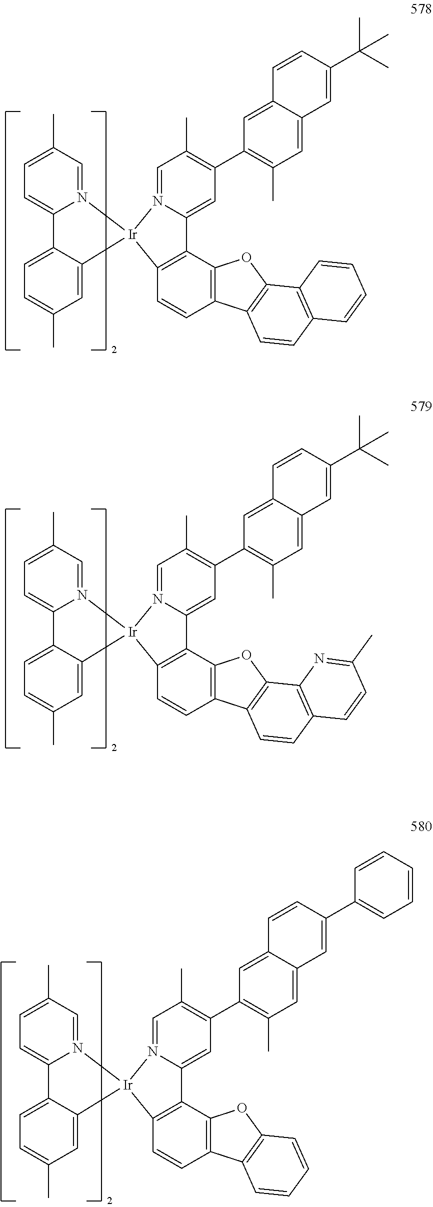

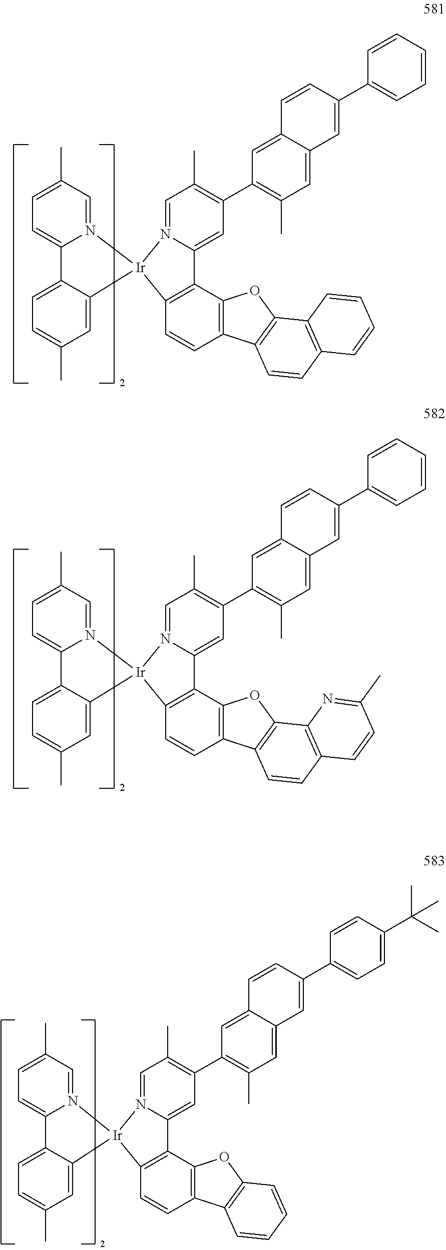

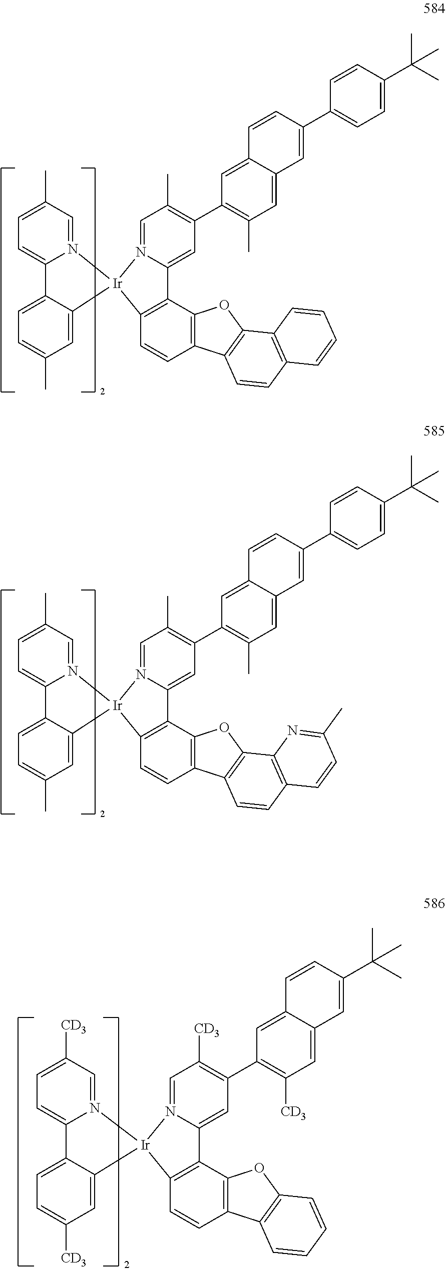

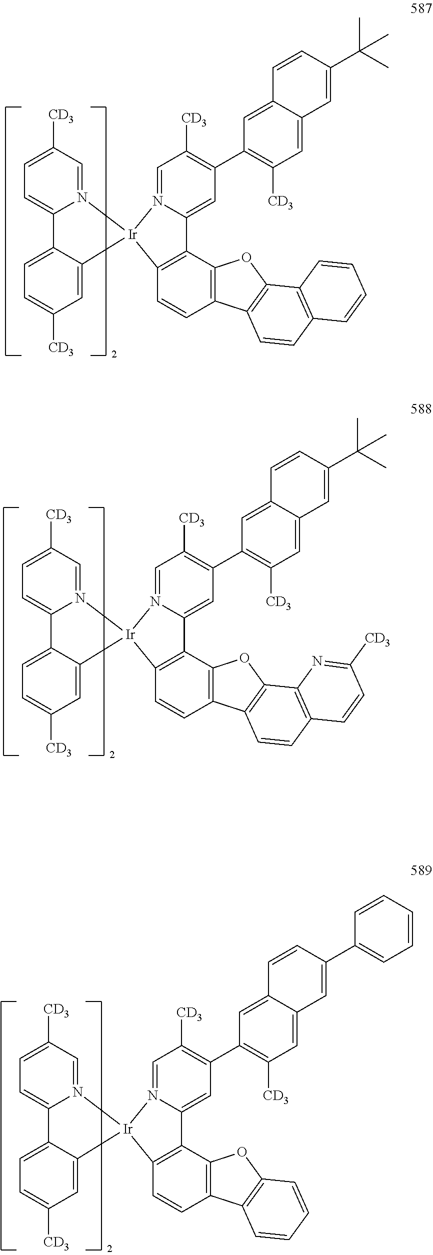

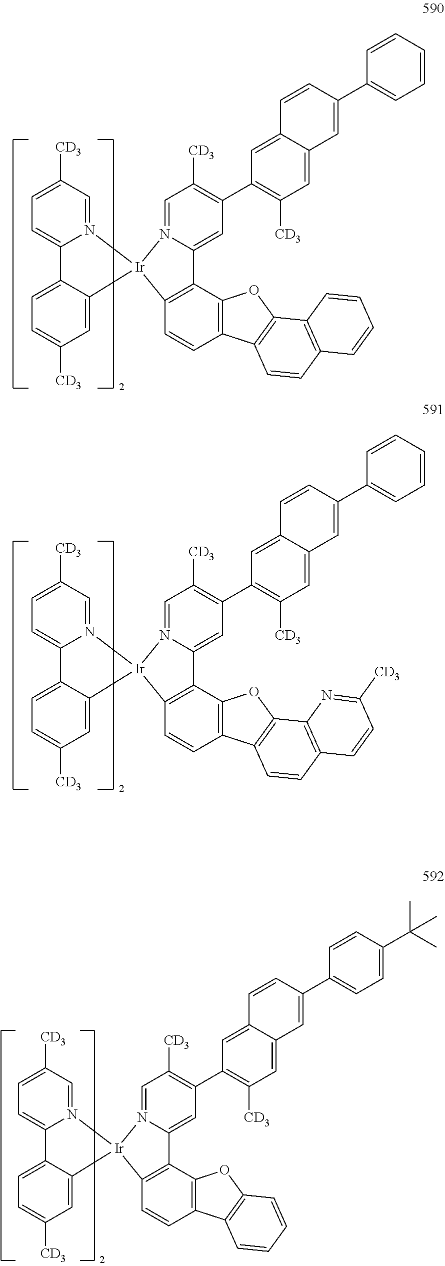

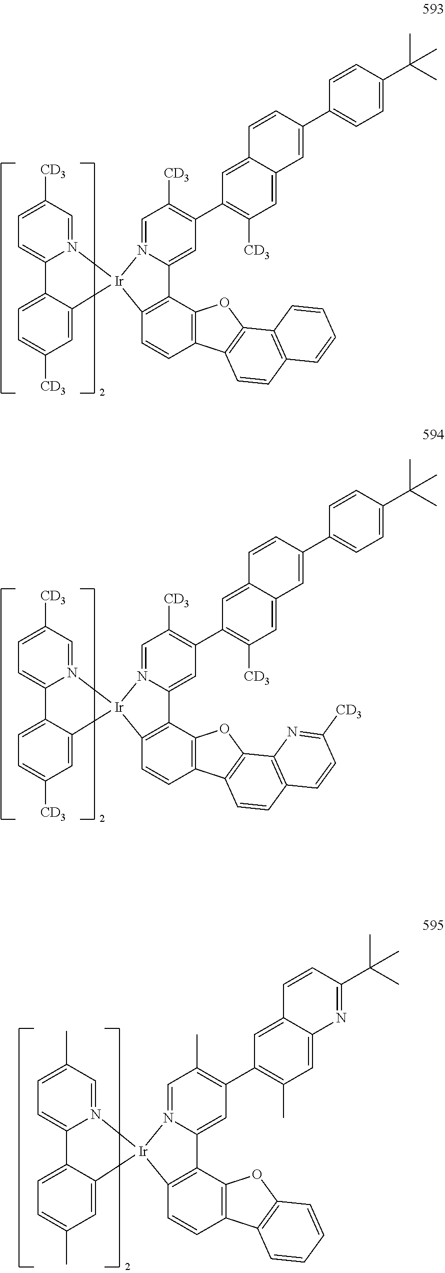

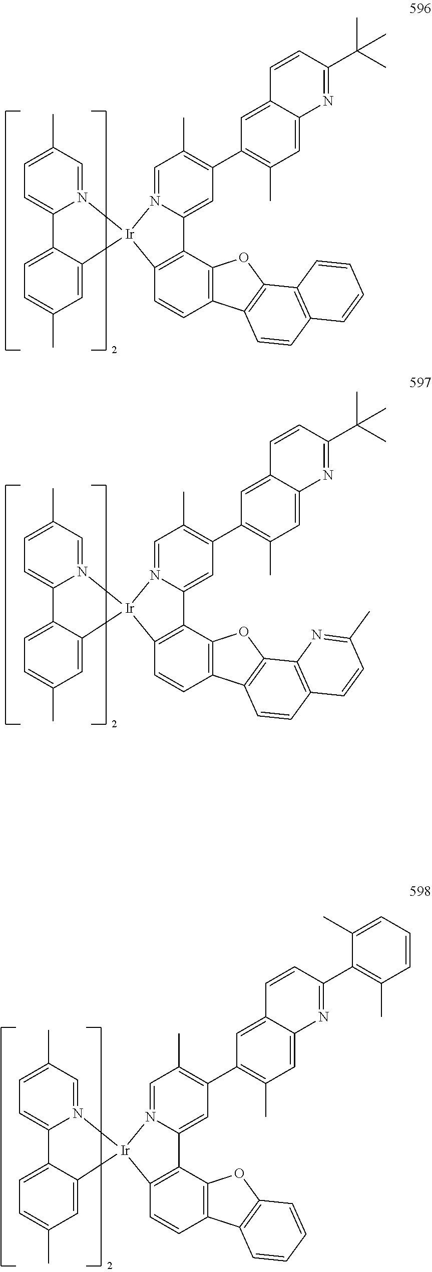

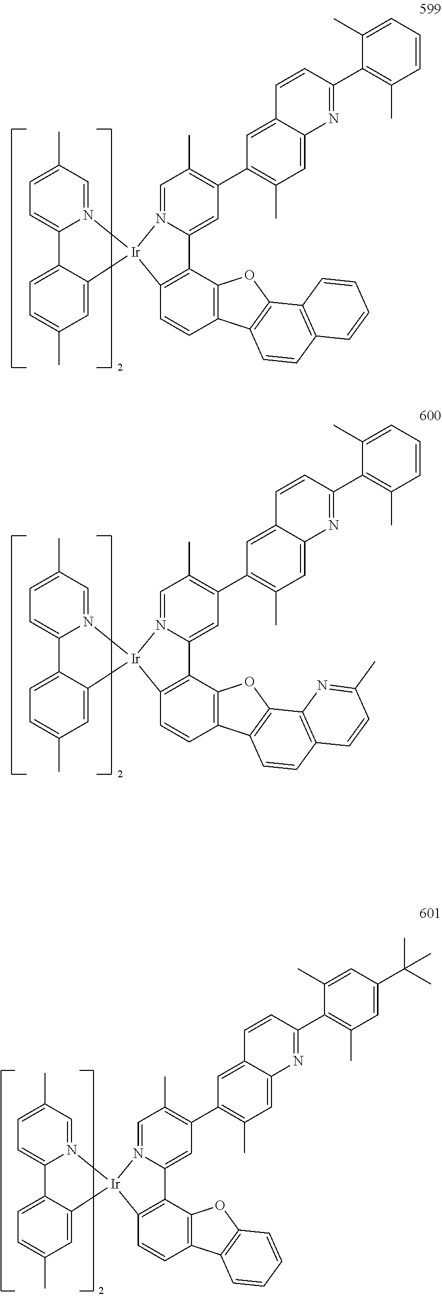

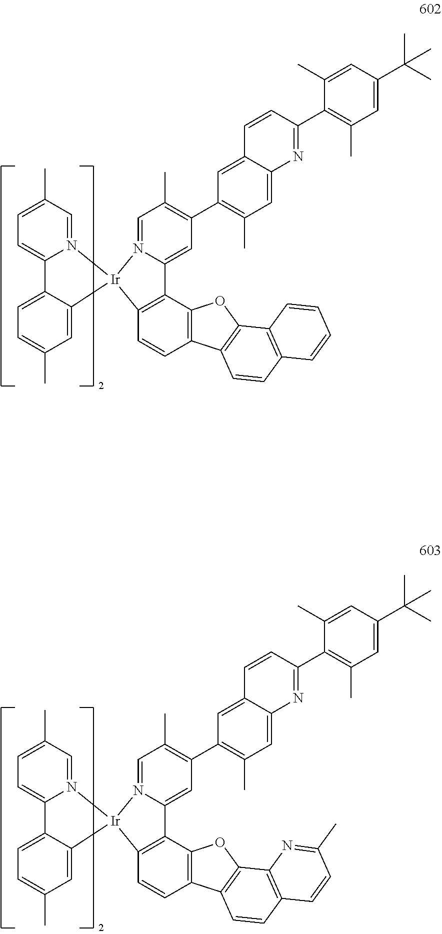

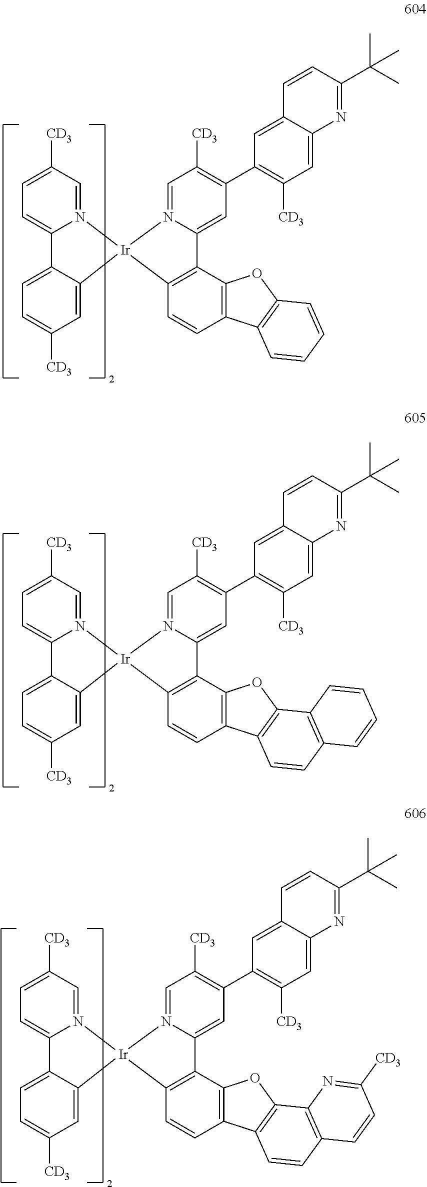

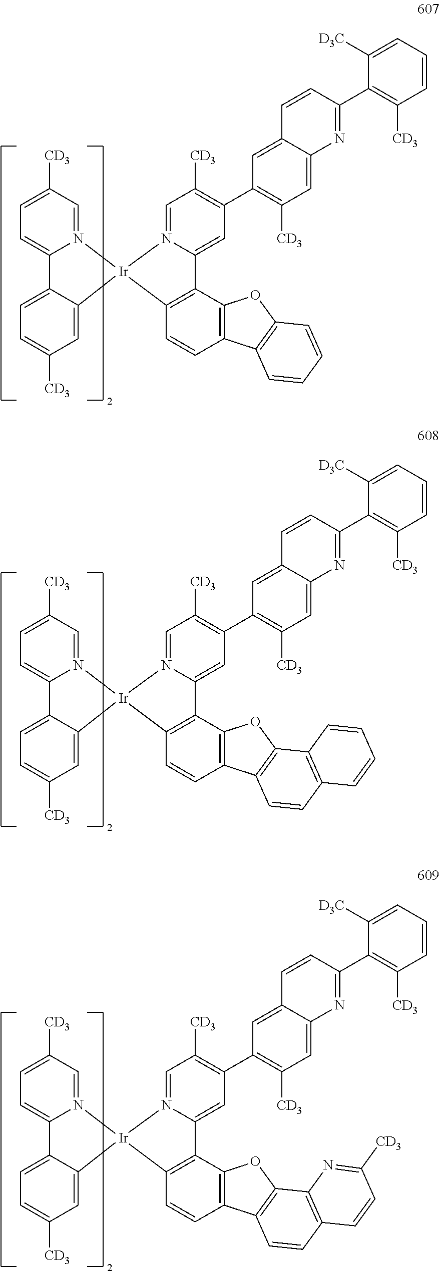

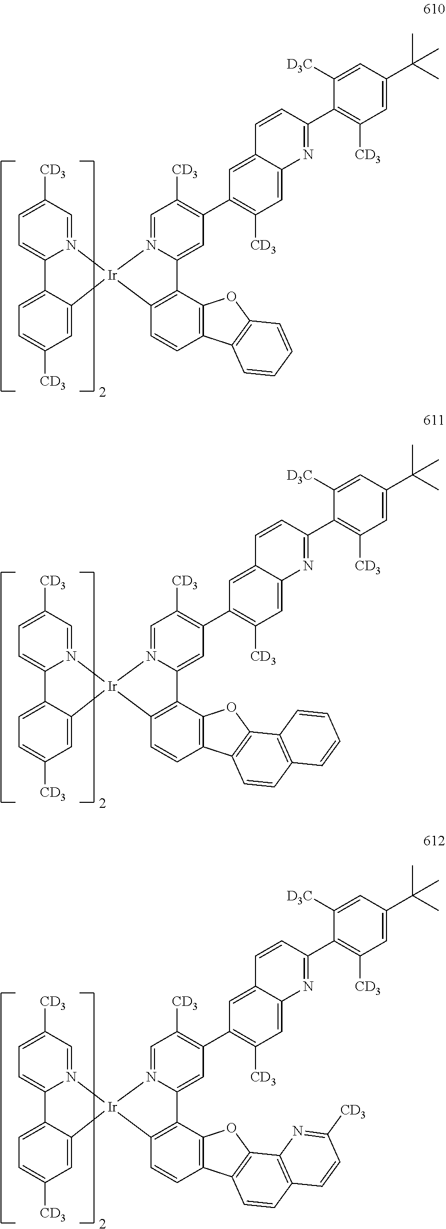

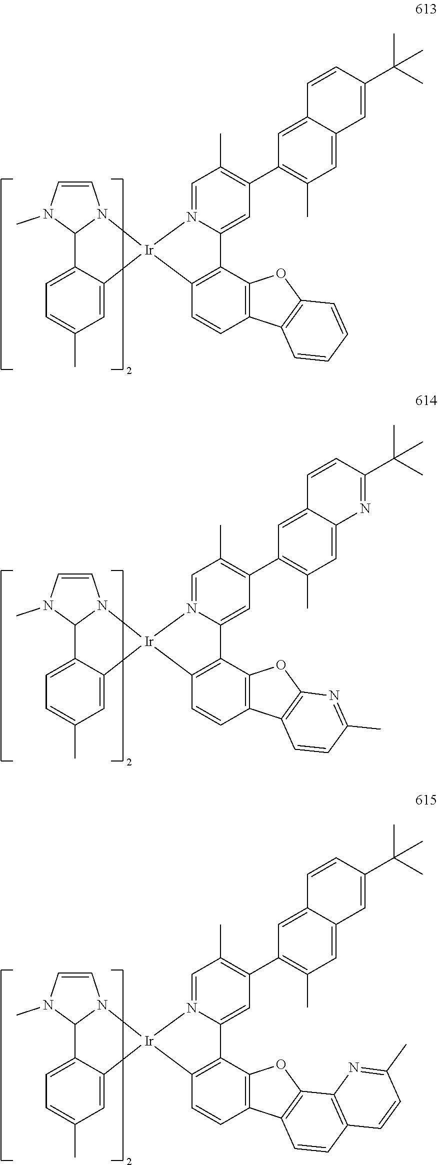

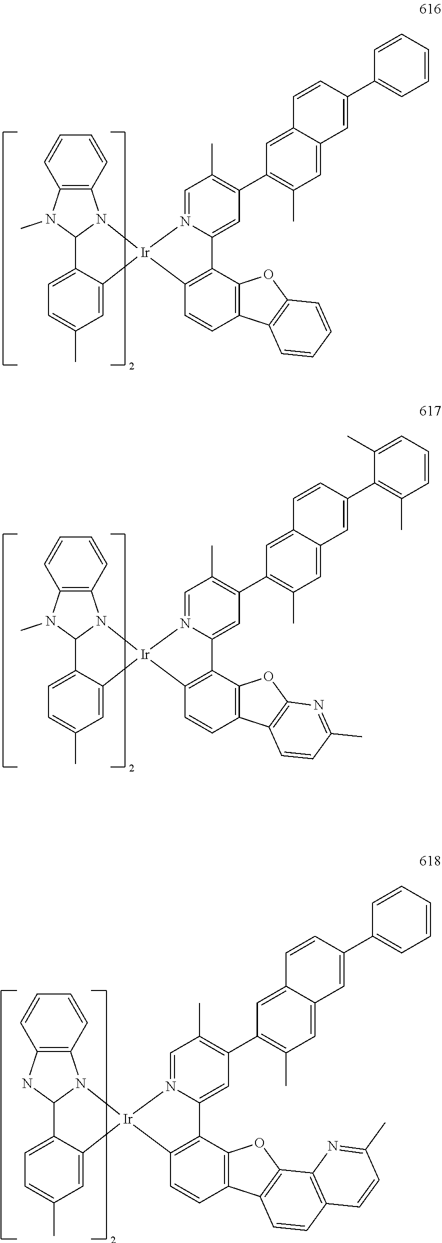

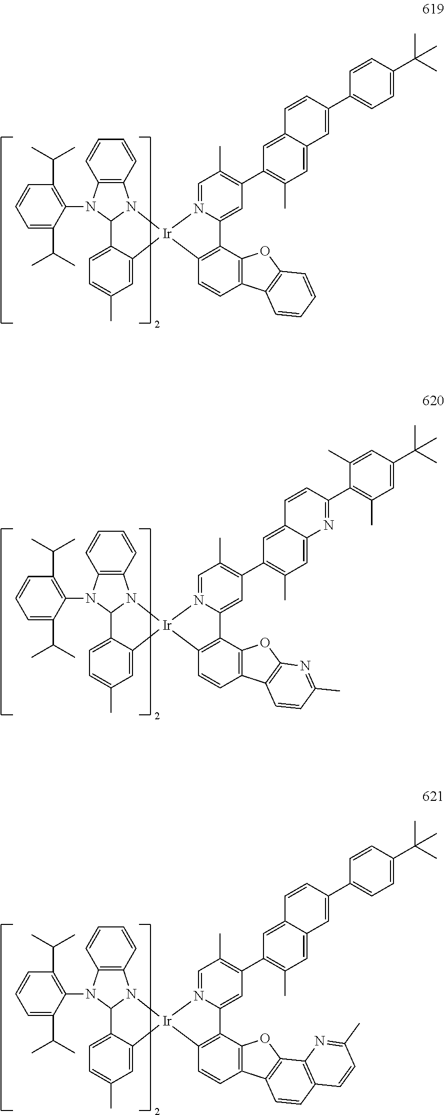

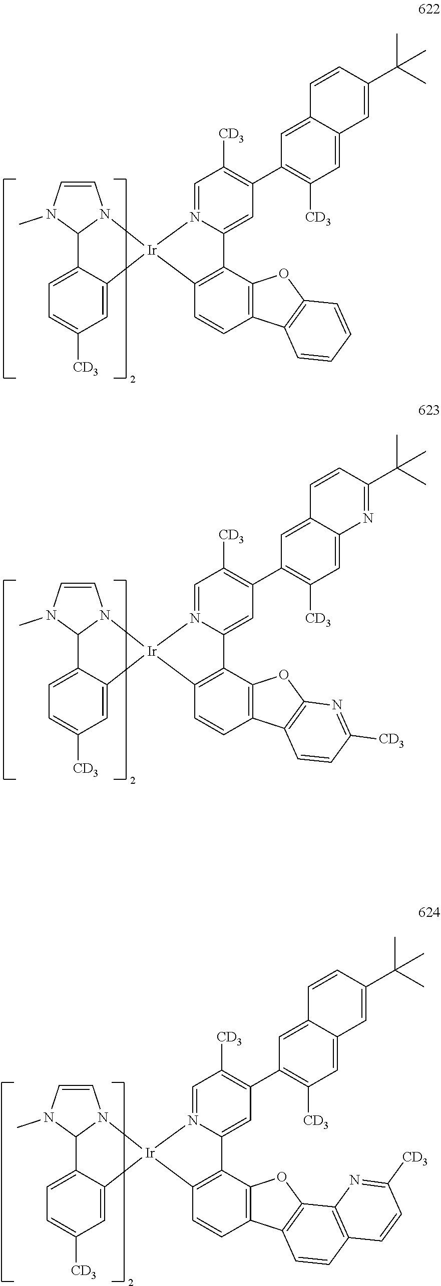

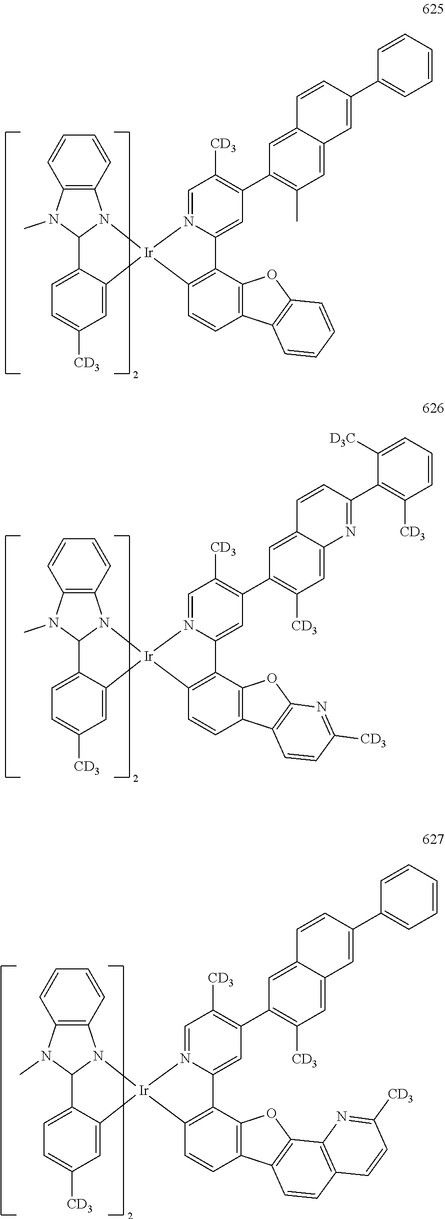

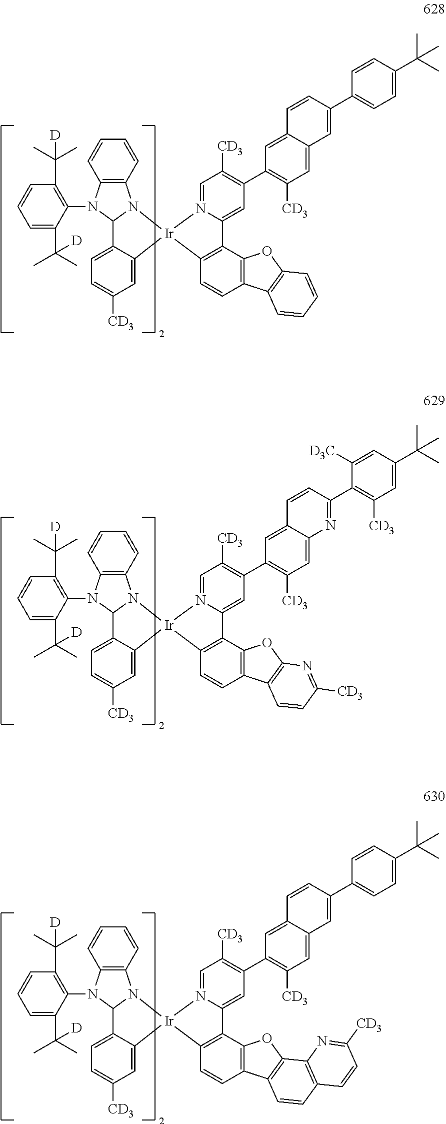

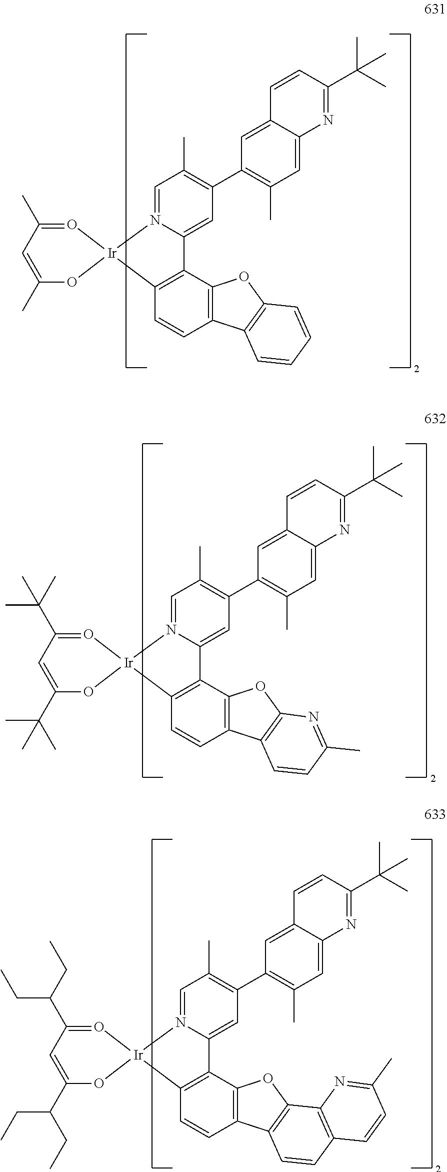

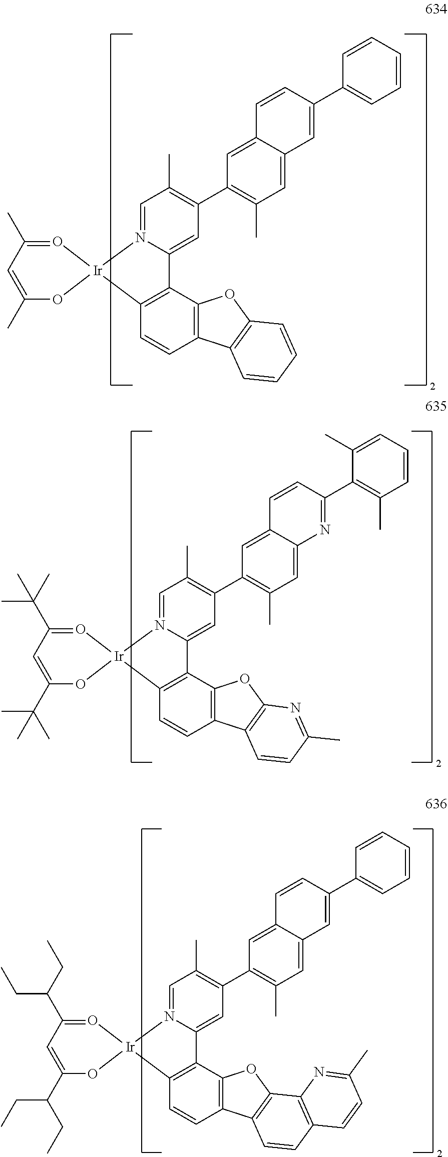

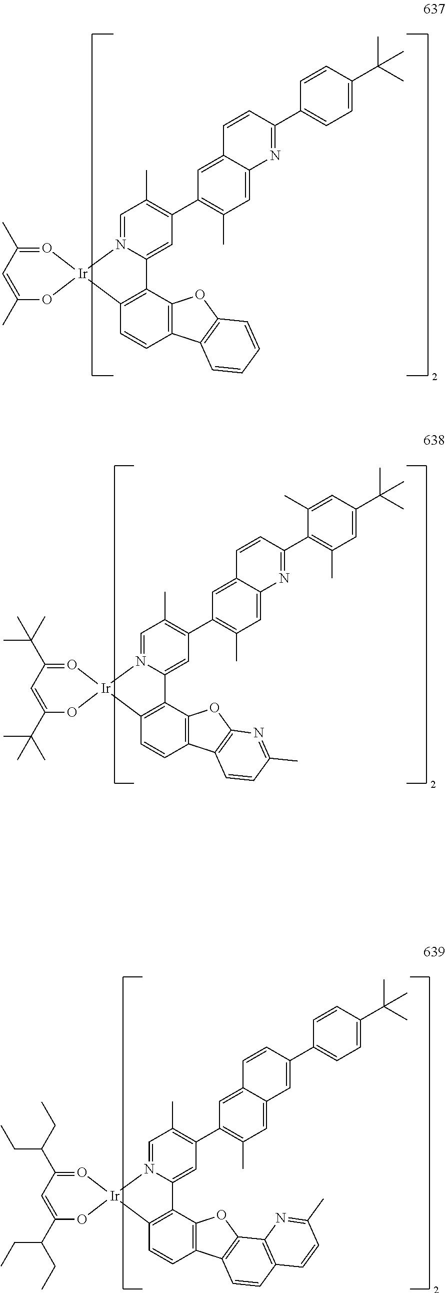

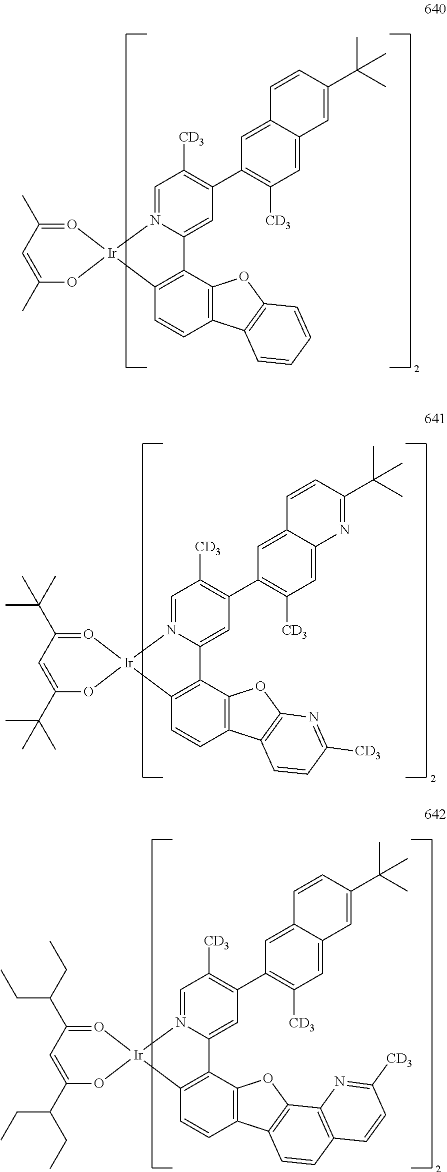

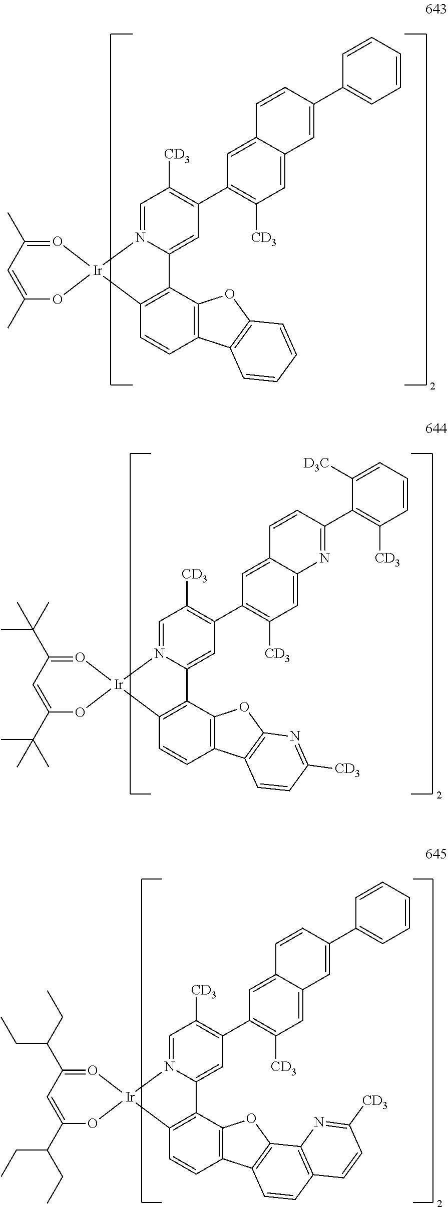

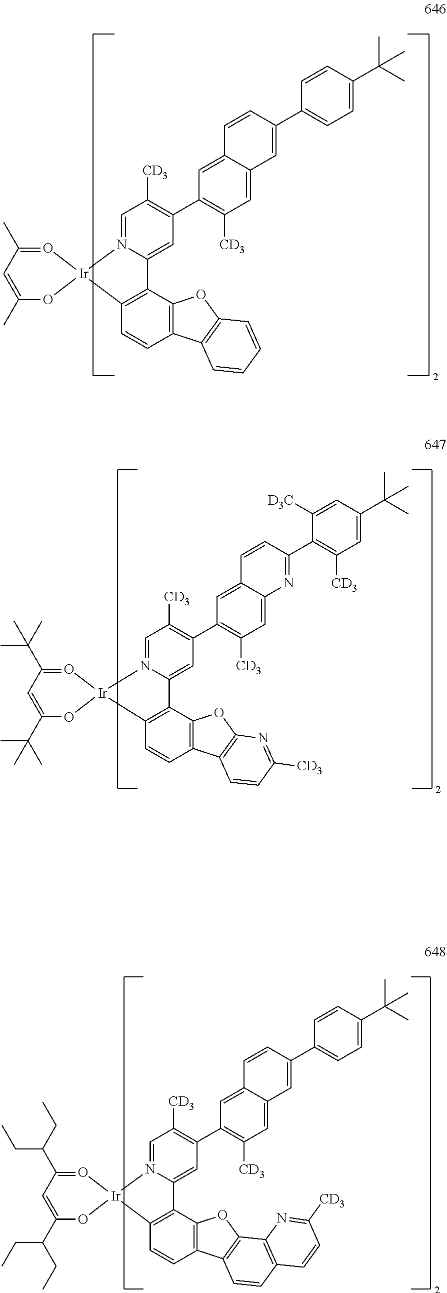

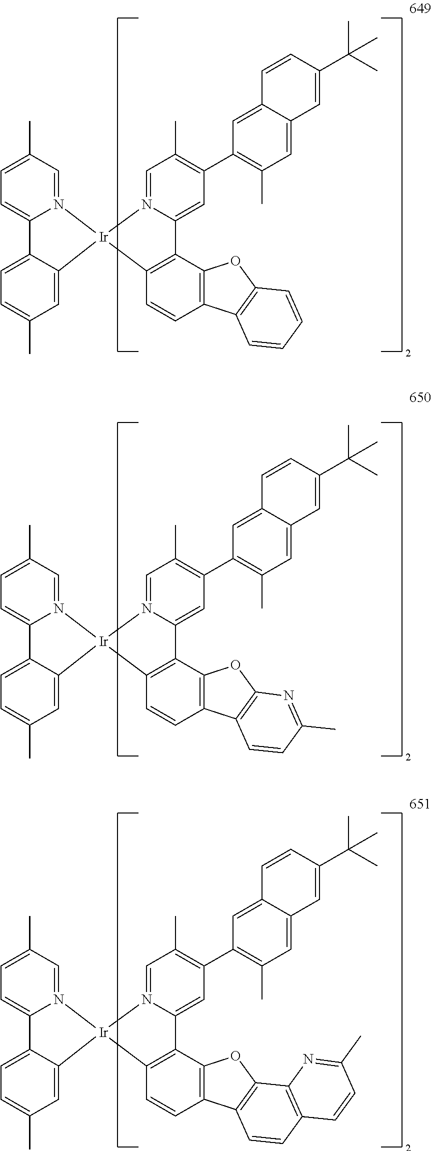

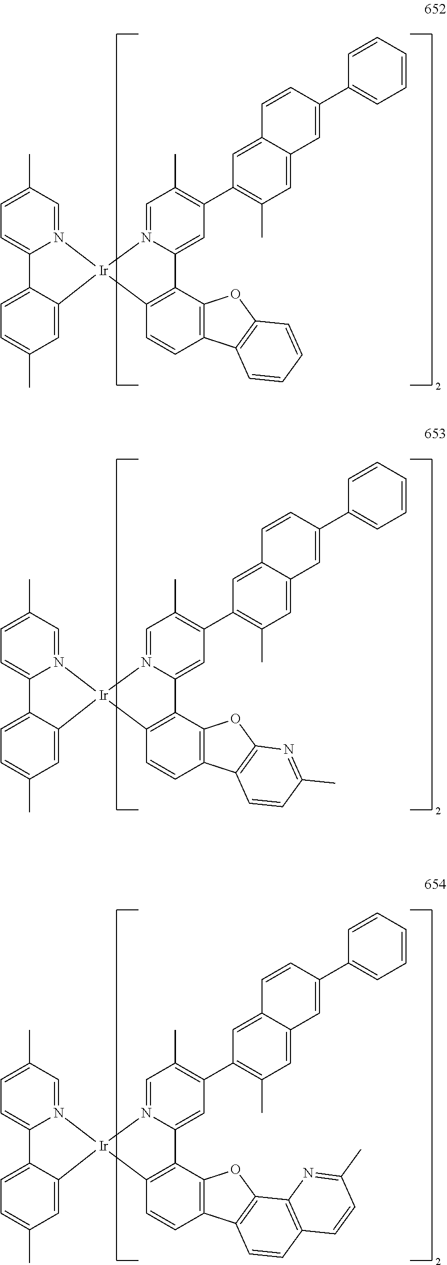

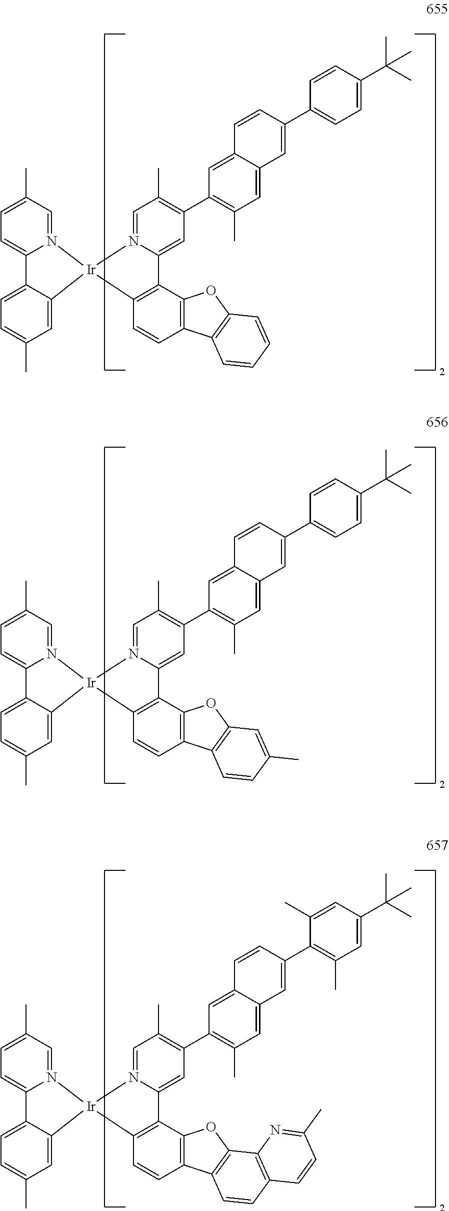

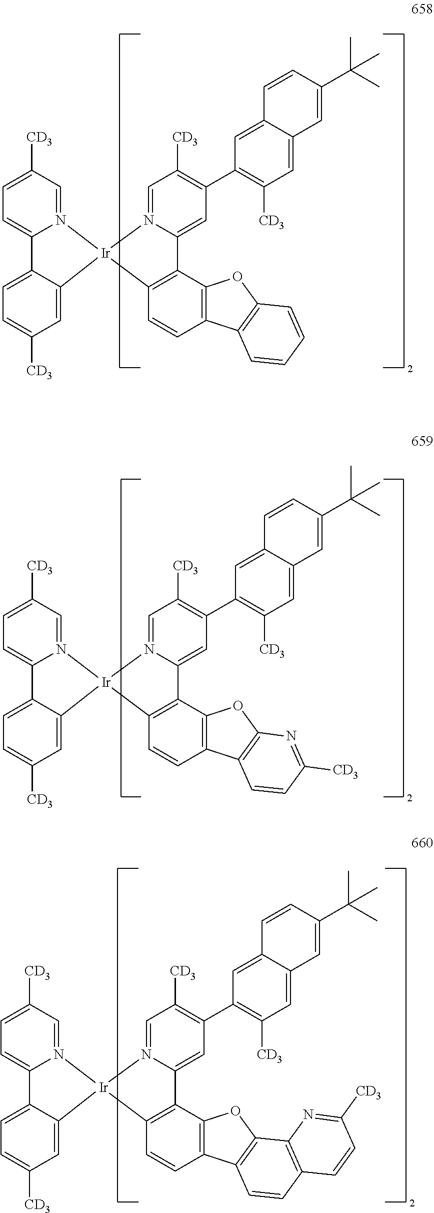

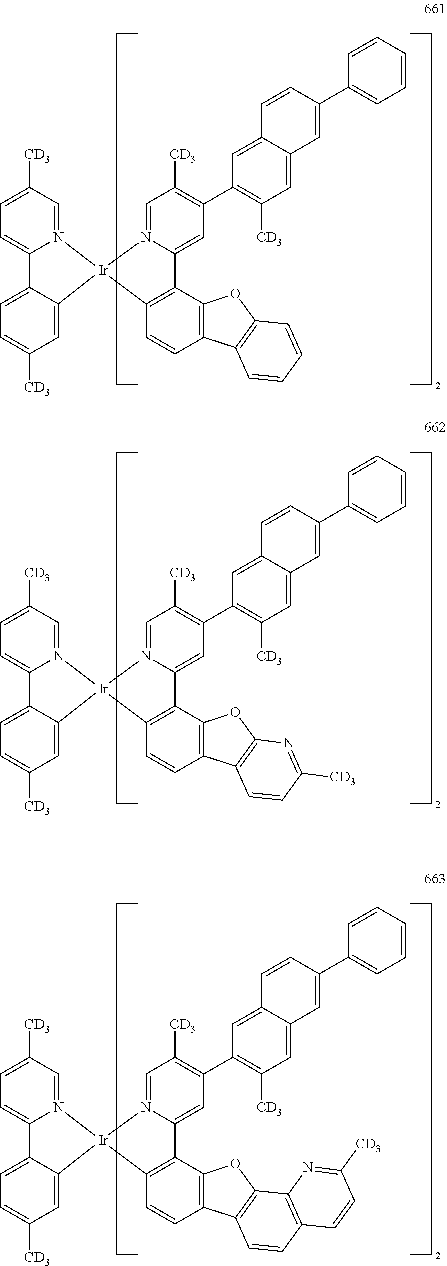

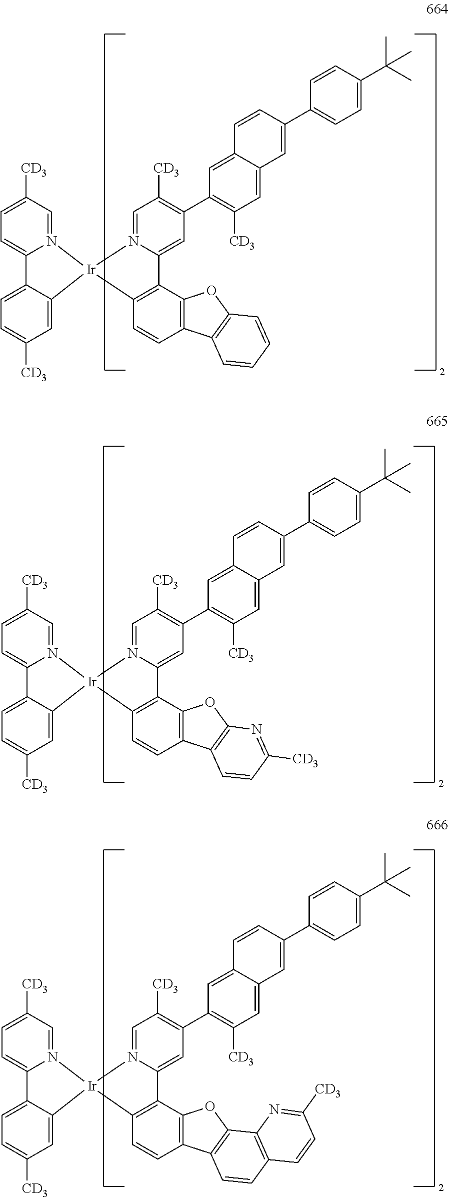

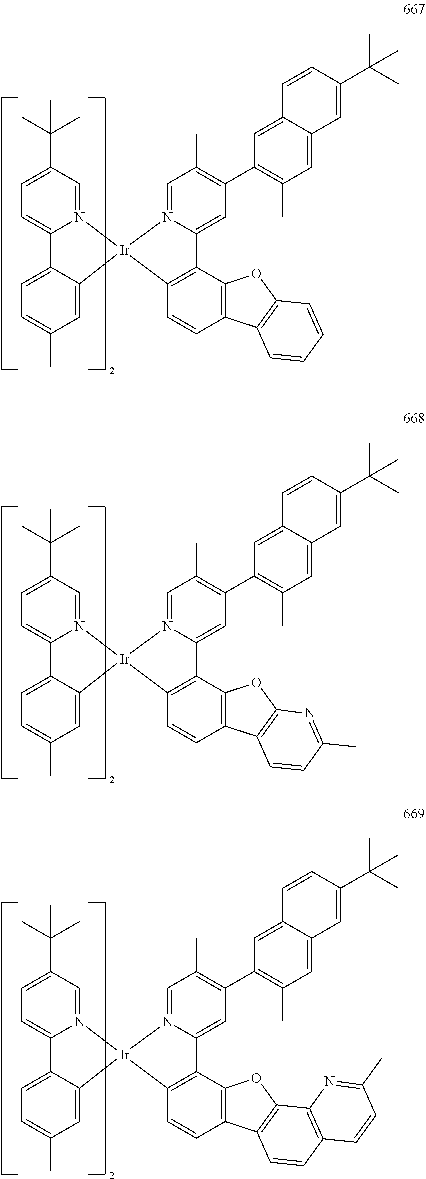

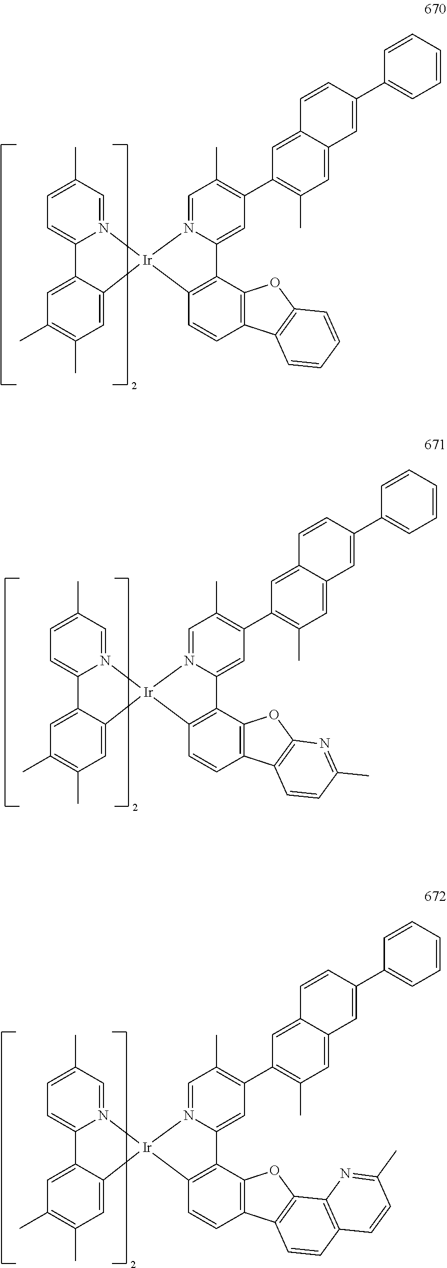

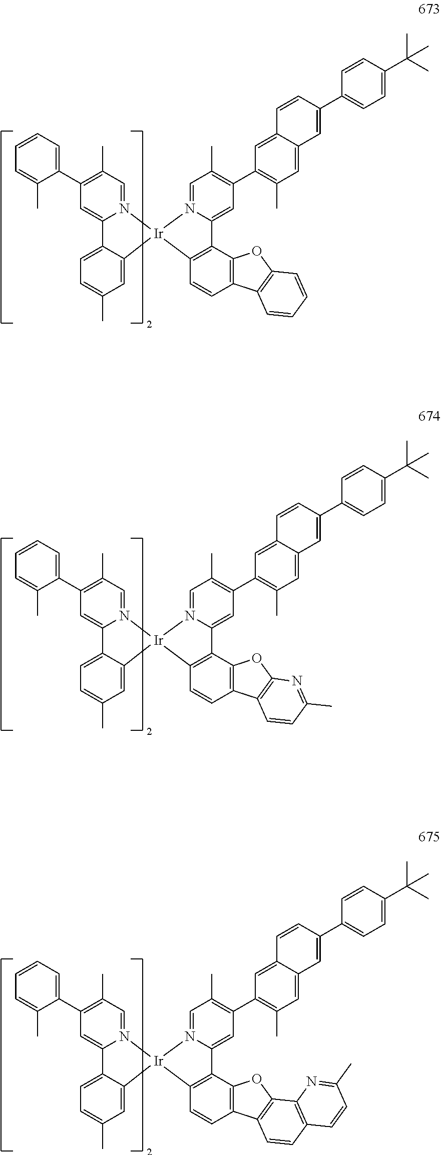

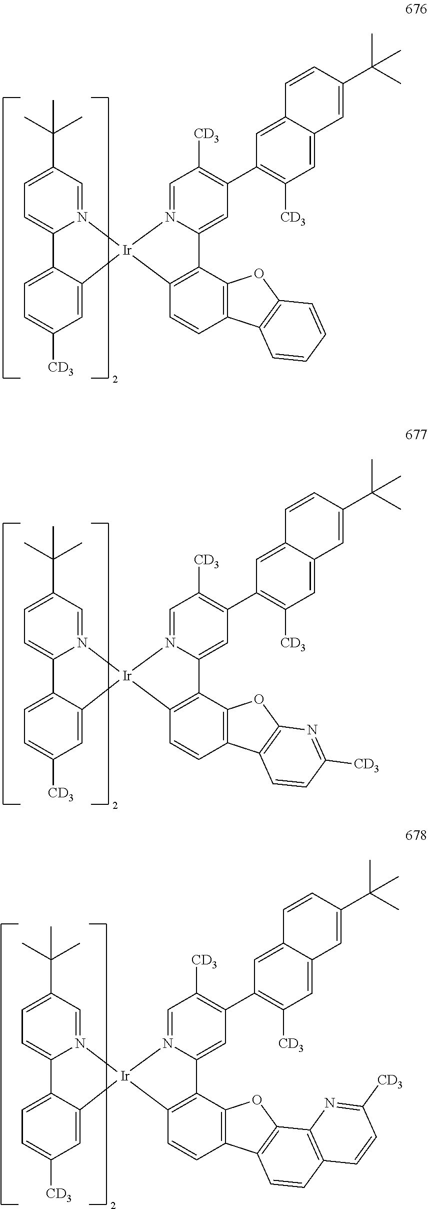

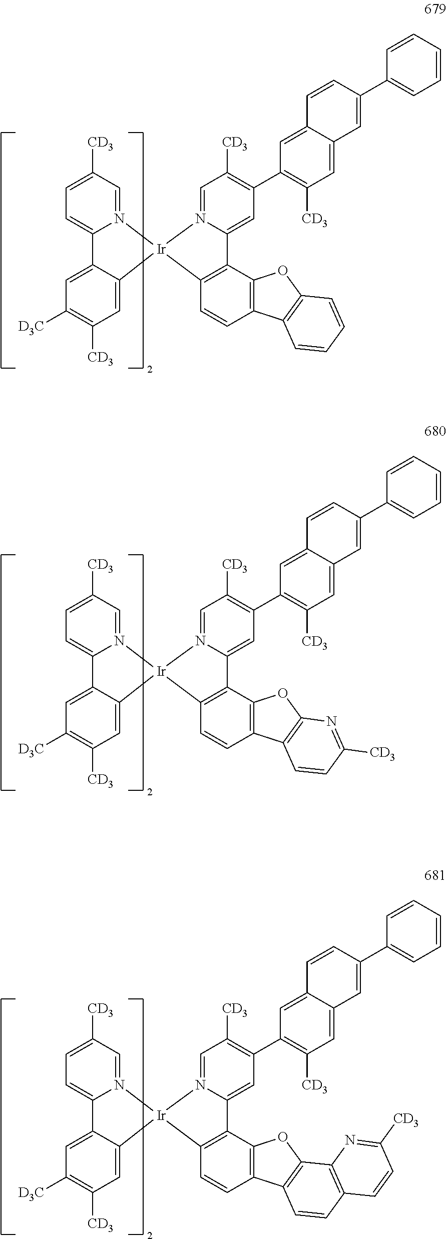

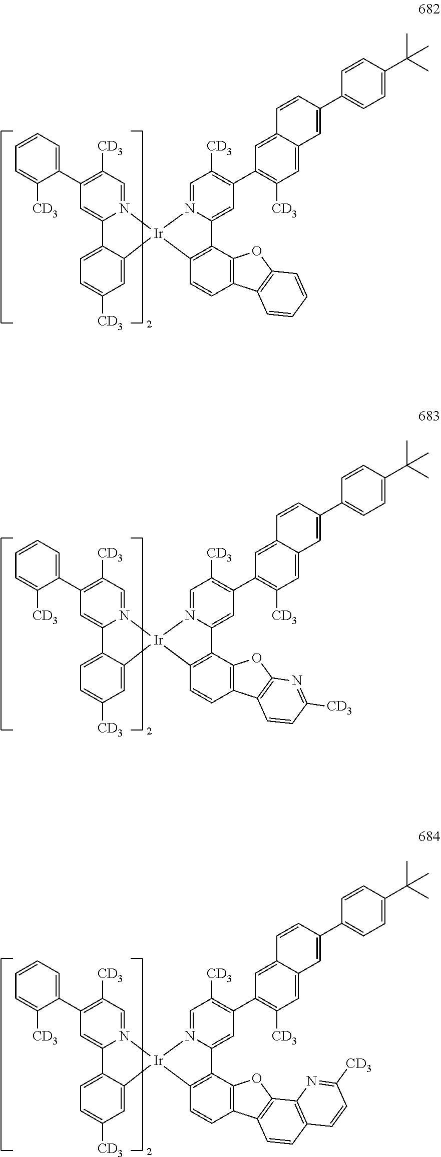

9. An organic light emitting diode, comprising:
a first electrode;
a second electrode facing the first electrode; and
a first emitting part positioned between the first and second electrodes and including a first emitting material layer,
wherein the first emitting material layer includes the organometallic compound of claim 1.

10. The organic light emitting diode according to claim 9, further comprising:
a second emitting part including a second emitting material layer and positioned between the first emitting part and the first electrode; and
a first charge generation layer between the first and second emitting parts,
optionally, wherein the second emitting material layer includes a blue dopant.

11. The organic light emitting diode according to claim 10, wherein the second emitting material layer includes a blue dopant.

12. The organic light emitting diode according to claim 11, wherein the first emitting part further include a third emitting material layer disposed under or on the first emitting material layer, and
optionally, wherein the third emitting material layer includes a red dopant.

13. The organic light emitting diode according to claim 11, further comprising:
a third emitting part positioned between the first emitting part and the second electrode and including a third emitting material layer; and
a second charge generation layer between the first and third emitting parts,
optionally, wherein the third emitting material layer includes a red dopant.

14. The organic light emitting diode according to claim 11, further comprising:
a third emitting part positioned between the first emitting part and the second electrode and including a third emitting material layer; and
a second charge generation layer between the first and third emitting parts,
wherein the first emitting part further includes a fourth emitting material layer disposed under or on the first emitting material layer, and
optionally, wherein the third emitting material layer includes a blue dopant, and the fourth emitting material layer includes a red dopant.

15. An organic light emitting device, comprising:
a substrate;
an organic light emitting diode disposed on the substrate and including a first electrode,
a second electrode facing the first electrode, a first emitting part positioned between the first and second electrodes and including a first emitting material layer; and
an encapsulation layer covering the organic light emitting diode,
wherein the first emitting material layer includes the organometallic compound of claim 1.

16. The organic light emitting device according to claim 15, wherein the organic light emitting diode further includes:
a second emitting part including a second emitting material layer and positioned between the first emitting part and the first electrode; and
a first charge generation layer between the first and second emitting parts,
wherein the second emitting material layer includes a blue dopant.

17. The organic light emitting device according to claim 16, wherein the first emitting part further include a third emitting material layer disposed under or on the first emitting material layer, and
wherein the third emitting material layer includes a red dopant.

18. The organic light emitting device according to claim 16, wherein the organic light emitting diode further includes:
a third emitting part positioned between the first emitting part and the second electrode and including a third emitting material layer; and
a second charge generation layer between the first and third emitting parts,
wherein the third emitting material layer includes a red dopant.

19. The organic light emitting device according to claim 16, wherein the organic light emitting diode further includes:
a third emitting part positioned between the first emitting part and the second electrode and including a third emitting material layer; and
a second charge generation layer between the first and third emitting parts,
wherein the first emitting part further includes a fourth emitting material layer disposed under or on the first emitting material layer, and
wherein the third emitting material layer includes a blue dopant, and the fourth emitting material layer includes a red dopant.

20. An organic light emitting display device, comprising:
a substrate; and
a display comprising an array of pixels on the substrate,
wherein each pixel comprises one or more individually addressable organic light emitting diodes according to claim 9.
